(19) United States
(12) Patent Application Publication
(10) Pub. No.: US 2026/0362973 A1
(43) Pub. Date: Nov. 12, 2026

(54) PHOTOELECTRIC CONVERSION ELEMENT MATERIAL, AND PHOTOELECTRIC CONVERSION ELEMENT USING SAME

(71) Applicant: NIPPON STEEL Chemical & Material Co., Ltd., Tokyo (JP)

(72) Inventors: Kentaro HAYASHI, Tokyo (JP); Munetomo INOUE, Tokyo (JP); Kazunari YOSHIDA, Tokyo (JP); Masahiro NARITA, Tokyo (JP); Momoka MAEDA, Tokyo (JP)

(73) Assignee: NIPPON STEEL Chemical & Material Co., Ltd., Tokyo (JP)

(21) Appl. No.: 19/486,397

(22) PCT Filed: Jul. 9, 2024
(86) PCT No.: PCT/JP2024/024782

§ 371 Date: Nov. 21, 2025

(30) Foreign Application Priority Data
Jul. 14, 2023 (JP) 2023-116155

(51) Int. Cl. H10K 85/60; H10K 30/40; H10K 30/85; H10K 30/86; H10K 85/20

(52) U.S. Cl. CPC H10K 85/6572; H10K 85/211; H10K 85/6574; H10K 85/6576; H10K 30/40; H10K 30/85; H10K 30/86

(57) ABSTRACT

Provided are a material that achieves higher sensitivity and higher resolution of a photoelectric conversion device for imaging and a photoelectric conversion device for imaging using the above material. The material includes a compound represented by general formula (1). L¹ represents an aromatic hydrocarbon group having 6 to 18 carbon atoms or the like, the rings B represents a six-membered ring represented by (1B), the ring C represents a five-membered ring represented by (1C), and X represents N—Ar⁶ or the like. Ar⁶ includes one or more structures represented by general formula (2). “a” to “g” represent the number of substitutions, “a” to “d” and “f” and “g” represent an integer of 0 to 4, and “e” represents an integer of 0 to 2. Y represents N—Ar⁹ or the like, Ar¹ to Ar¹¹ represent an aromatic hydrocarbon group having 6 to 18 carbon atoms or the like.

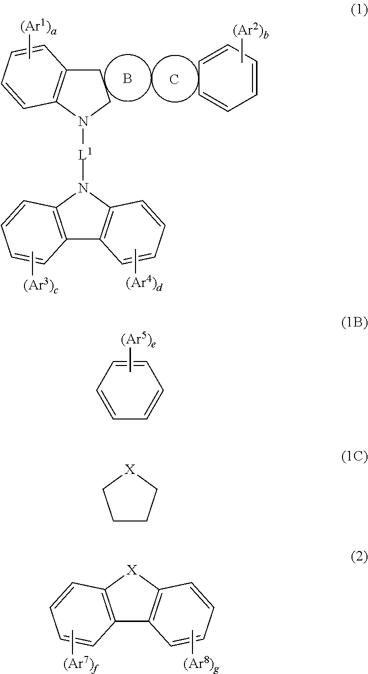

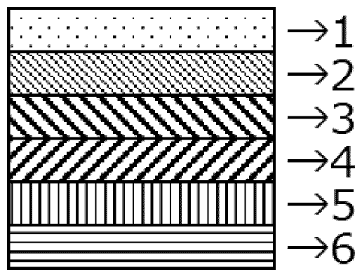

### TECHNICAL FIELD

The present invention relates to a material for a photoelectric conversion device and a photoelectric conversion device using the same, and particularly to a material for a photoelectric conversion device useful for an imaging device.

In recent years, development of an organic electronic device using a thin film formed with an organic semiconductor is in progress. Examples thereof include an electroluminescent device, a solar cell, a transistor device, and a photoelectric conversion device. In particular, development of an organic EL device, which is an electroluminescent device with an organic substance, is most advanced among them. The applications for smartphones, TV and the like are in progress, and development for a purpose of further higher functionality is continuously conducted.

Among these, on the photoelectric conversion device for imaging, a device using a P-N junction of an inorganic semiconductor, such as silicon, has been conventionally developed and practically used, and made are investigations for high functionalization of a digital camera and a camera for a smartphone and investigation for application for a monitoring camera, a sensor for an automobile, and the like. However, problems for these various uses include improving sensitivity and micronizing a pixel (improving resolution). For the photoelectric conversion device using an inorganic semiconductor, a mainly adopted method for obtaining a color image is disposing color filters corresponding to RGB, which are the three primary colors of light, on a light receiving part of the photoelectric conversion device. This method has problems in terms of utilization efficiency of an incident light and resolution, because the method disposes the RGB color filters on a plane (Non Patent Literature 1 and 2).

As a solution for such problems of the photoelectric conversion device, a photoelectric conversion device using an organic semiconductor instead of the inorganic semiconductor is developed (Non Patent Literature 1 and 2). This utilizes an ability to selectively absorb only light having a specific wavelength region with high sensitivity that the organic semiconductor has, and proposed is stacking photoelectric conversion devices composed of organic semiconductors corresponding to the three primary colors of light to solve the problem of improving the sensitivity and improving the resolution. A device in which a photoelectric conversion device composed of the organic semiconductor and a photoelectric conversion device composed of the inorganic semiconductor are stacked is also proposed (Non Patent Literature 3).

Here, the photoelectric conversion device composed of the organic semiconductor is a device having a photoelectric conversion layer composed of a thin film of the organic semiconductor between two electrodes, wherein a hole blocking layer and/or an electron blocking layer is disposed between the photoelectric conversion layer and the two electrodes, as necessary. In the photoelectric conversion device, light having a desired wavelength is absorbed in the photoelectric conversion layer to generate an exciton, and then charge separation of the exciton generates a hole and an electron. Thereafter, the hole and the electron move toward each electrode to convert the light into an electric signal. For a purpose of accelerating this process, a method of applying a bias voltage between both the electrodes is commonly used, but one of objects is reducing a leakage current from both the electrodes generated by applying the bias voltage. Accordingly, it can be mentioned that controlling the move of the hole and the electron in the photoelectric conversion device is a key to exhibit characteristic of the photoelectric conversion device.

The organic semiconductor used for each layer of the photoelectric conversion device can be classified into a P-type organic semiconductor and an N-type organic semiconductor. The P-type organic semiconductor is used as a hole transport material, and the N-type organic semiconductor is used as an electron transport material. To control the move of the hole and the electron in the photoelectric conversion device, made are various developments of an organic semiconductor having appropriate physical properties such as hole mobility, electron mobility, an energy value of a highest occupied orbital (HOMO), and an energy value of a lowest unoccupied molecular orbital (LUMO). However, the organic semiconductor still has insufficient characteristics.

Various compounds that are excellent as an organic electroluminescent device or a hole transport material or an electron blocking material for an organic solar cell have been disclosed, but these compounds are not always excellent as a hole transport material or an electron blocking material for imaging. Specifically, as one important characteristic required for the hole transport material of the photoelectric conversion device for imaging, for example, it is important to increase a difference between a current value in a state of a closed shutter and a current value in a state of an opened shutter (a contrast ratio) in order to perform clear imaging with a camera in a dark place. Therefore, a lower current value in a dark place is more preferable, and a higher current value in a bright place is more preferable. That is, “high contrast ratio” is important. Meanwhile, characteristics to be improvement targets in the organic electroluminescent device are a voltage required for flowing a constant current, luminescent efficiency, device lifetime, and the like, which are significantly different from the characteristics required in the photoelectric conversion device for imaging. In addition, it is important for the organic solar cell to have a large quantity of current generation in both of the dark place and the bright place, which is different from the characteristics required in the photoelectric conversion device for imaging, and a lower current value in the dark place is more preferable. As above, the required characteristics are different between: the hole transport material or the electron blocking material for the organic electroluminescent device or the organic solar cell; and the hole transport material or the electron blocking material for the photoelectric conversion device for imaging. Thus, it has not been clear until confirmation by experiment whether a material excellent as the hole transport material or the electron blocking material for the organic electroluminescent device or the organic solar cell is also excellent as the hole transport material or the electron blocking material for the photoelectric conversion device for imaging.

Patent literature 1 proposes a device using quinacridone as the P-type organic semiconductor and subphthalocyanine chloride as the N-type organic semiconductor for the photoelectric conversion layer, and an indolocarbazole derivative for a first buffer layer disposed between the photoelectric conversion layer and the electrode.

Patent literature 2 proposes a photoelectric conversion device using a carbazole derivative for an electron blocking layer disposed between the photoelectric conversion layer and the electrode.

Patent Literatures 3 and 4 propose a photoelectric conversion device using an indolocarbazole derivative for an electron blocking layer disposed between the photoelectric conversion layer and the electrode.

Patent Literatures 5 and 6 propose an organic EL device using an indolocarbazole derivative as a luminescent layer material.

### CITATION LIST

### Patent Literature

### Patent Literature 1

JP 2018-85427 (A)

### Patent Literature 2

JP 2011-228614 (A)

### Patent Literature 3

WO2022114065

### Patent Literature 4

WO2022114067

### Patent Literature 5

US20170271598

### Patent Literature 6

WO2011099374

### Non Patent Literature

### Non Patent Literature 1

NHK Science & Technology Research Laboratories R&D No. 132, pp. 4-11 (2012.3)

### Non Patent Literature 2

NHK Science & Technology Research Laboratories R&D No. 174, pp. 4-17 (2019.3)

### Non Patent Literature 3

2019 IEEE International Electron Devices Meeting (IEDM), pp. 16.6.1-16.6.4 (2019)

### SUMMARY OF INVENTION

In the use of the photoelectric conversion device for imaging for highly functionalizing a digital camera and a camera for a smartphone and for application for a monitoring camera, a sensor for an automobile, and the like, keys are organification to achieve further higher sensitivity and higher resolution. Required to increase a contrast of an image is a material that has both a low dark current value and a high bright current value, which exhibits a high contrast ratio. In view of such a circumstance, an object of the present invention is to provide a material that achieves higher sensitivity and higher resolution of the photoelectric conversion device for imaging, and a photoelectric conversion device for imaging using the same.

The present inventors have made intensive investigation, and consequently found that using a compound of the present invention can control behavior of a hole and an electron in the photoelectric conversion device to achieve the photoelectric conversion device that exhibits a high contrast ratio. This finding has led to the completion of the present invention.

The present invention is a material for a photoelectric conversion device comprising a compound represented by the following general formula (1).

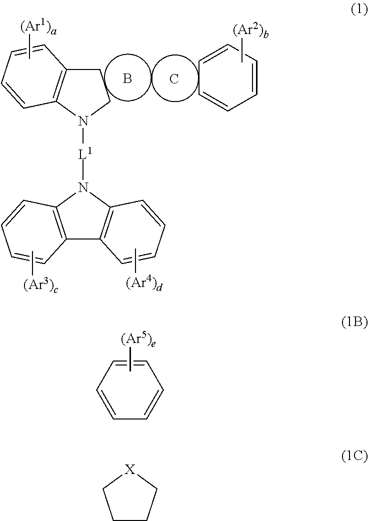

In the general formula (1), L¹ represents an substituted or unsubstituted aromatic hydrocarbon group having 6 to 18 carbon atoms or a substituted or unsubstituted linked aromatic group in which 2 to 6 of these aromatic groups are linked. The ring B is fused with an adjacent ring at any position, and represents a six-membered ring represented by the formula (1B). The ring C is fused with an adjacent ring at any position, and represents a five-membered ring represented by the formula (1C). X is represented by O, S, and N—Ar⁶. Ar¹ to Ar⁶ each independently represent deuterium, a halogen, an alkyl group having 1 to 20 carbon atoms, a substituted or unsubstituted aromatic amino group having 12 to 36 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 10 of these aromatic groups are linked. Provided that, when X is represented by N—Ar⁶, Ar⁶ includes one or more structures represented by the following general formula (2). “a” to “e” represent the number of substitutions, “a” to “d” each independently represent an integer of 0 to 4, and “e” represents an integer of 0 to 2.

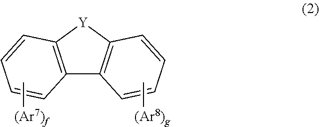

In the general formula (2), Y is each independently represented by any of N—Ar⁹, O, S, and C—Ar¹⁰Ar¹¹. Ar⁷ to Ar¹¹ each independently represents deuterium, a halogen, an alkyl group having 1 to 20 carbon atoms, a substituted or unsubstituted aromatic amino group having 12 to 36 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 5 of these aromatic groups are linked. “f” and “g” represent the number of substitutions, and each independently represent an integer of 0 to 4. Note that, when Ar⁶ includes the general formula (2), a group bonded to N described in the general formula (1) may be Ar⁷ to Ar¹¹, or may be directly bonded to the fused ring represented by the formula (2). N described in the general formula (1) refers to N to which Ar⁶ is bonded when X represented by the formula (1C) is represented by N—Ar⁶.

The material for a photoelectric conversion device represented by the general formula (1) is preferably a material for a photoelectric conversion device for imaging, and the photoelectric conversion device is preferably a photoelectric conversion device for imaging.

The material for a photoelectric conversion device represented by the general formula (1) preferably has an energy level of highest occupied molecular orbital (HOMO) obtained by structural optimization calculation with a density functional calculation B3LYP/6-31G(d) of −4.3 eV or lower. An energy level of lowest unoccupied molecular orbital (LUMO) is preferably −2.5 eV or higher.

The material for a photoelectric conversion device for imaging represented by the general formula (1) preferably has a hole mobility of 1×10⁻⁶ cm²/Vs or more. The material for a photoelectric conversion device for imaging represented by the general formula (1) is preferably amorphous.

The material for a photoelectric conversion device for imaging represented by the general formula (1) may be used as a hole transport material.

The present invention is a photoelectric conversion device for imaging, wherein the photoelectric conversion device for imaging comprises a photoelectric conversion layer and an electron blocking layer between two electrodes, wherein at least one layer of the photoelectric conversion layer and the electron blocking layer contains the material for a photoelectric conversion device for imaging represented by the general formula (1).

The photoelectric conversion device of the present invention may contain the material for a photoelectric conversion device for imaging represented by the general formula (1) in the electron blocking layer, and may contain an electron transport material such as a fullerene derivative in the photoelectric conversion layer.

In the photoelectric conversion device of the present invention, appropriate move of the hole and the electron in the photoelectric conversion device for imaging can be achieved by using the material for a photoelectric conversion device for imaging represented by the general formula (1), and consequently enables to reduce a leakage current generated by applying a bias voltage during the conversion of light into electric energy. As a result, it is considered that the photoelectric conversion device that achieves a low dark current value and a high contrast ratio has been obtained. Therefore, the material of the present invention is useful as a material for a photoelectric conversion device for a photoelectric-converting film-stacked imaging device.

### BRIEF DESCRIPTION OF DRAWING

[FIGURE] Figure is a sectional schematic view illustrating a structure example of a photoelectric conversion device used in the present invention.

### DESCRIPTION OF EMBODIMENTS

The photoelectric conversion device for imaging of the present invention is a photoelectric conversion device having at least one organic layer between two electrodes and converting light into electric energy. This organic layer contains the material for a photoelectric conversion device for imaging comprising the compound represented by the following general formula (1). Specifically, in the photoelectric conversion device for imaging having the photoelectric conversion layer and the electron blocking layer between two electrodes, at least one layer of the photoelectric conversion layer and the electron blocking layer contains the material for a photoelectric conversion device represented by the following general formula (1). Hereinafter, the material for a photoelectric conversion device for imaging composed of the compound represented by the general formula (1) is simply referred to as “material for a photoelectric conversion device”, or may be referred to as “material of the present invention” or “compound represented by the general formula (1)”.

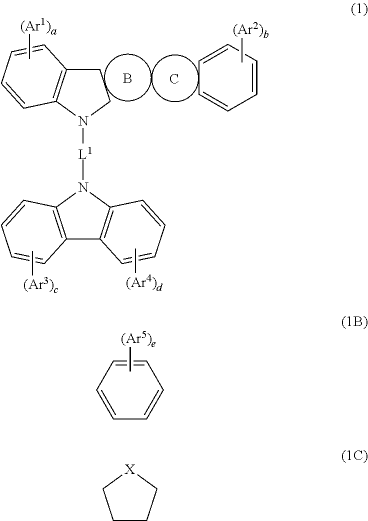

The compound represented by the general formula (1) will be described below.

In the general formula (1), L¹ represents a substituted or unsubstituted aromatic hydrocarbon group having 6 to 18 carbon atoms or a substituted or unsubstituted linked aromatic group in which 2 to 6 of these aromatic groups are linked, preferably a substituted or unsubstituted phenyl group, a substituted or unsubstituted biphenyl group, or a substituted or unsubstituted terphenyl group, and more preferably a substituted or unsubstituted phenyl group or a substituted or unsubstituted biphenyl group. The substituted or unsubstituted terphenyl group may be linear or branched. The ring B is fused with an adjacent ring at any position, and represents a six-membered ring represented by the formula (1B). The ring C is fused with an adjacent ring at any position, and represents a five-membered ring represented by the formula (1C). X is represented by any of O, S, and N—Ar⁶, preferably represented by N—Ar⁶. “a” to “e” represent the number of substitutions, “a” to “d” each independently represent an integer of 0 to 4, “e” represents an integer of 0 to 2, and all of them are preferably 0. Provided that Ar⁶ includes one or more structures represented by the following general formula (2).

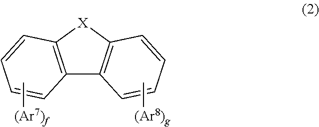

In the general formula (2), Y is independently represented by any of N—Ar⁹, O, S, and C—Ar¹⁰Ar¹¹, preferably N—Ar⁹, O, or S. “f” and “g” represent the number of substitutions, and each independently represent an integer of 0 to 4 and all of them are preferably 0.

Ar¹ to Ar⁶ each independently represent deuterium, a halogen, an alkyl group having 1 to 20 carbon atoms, a substituted or unsubstituted aromatic amino group having 12 to 36 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 10 of these aromatic groups are linked, and preferably a substituted or unsubstituted aromatic hydrocarbon group having 6 to 18 carbon atoms or a substituted or unsubstituted aromatic heterocyclic group having 3 to 18 carbon atoms, more preferably a substituted or unsubstituted aromatic hydrocarbon group having 6 to 13 carbon atoms or a substituted or unsubstituted aromatic heterocyclic group having 3 to 17 carbon atoms, and further preferably a substituted or unsubstituted aromatic hydrocarbon group having 6 to 13 carbon atoms or a substituted or unsubstituted aromatic heterocyclic group having 6 to 12 carbon atoms. Ar⁷ to Ar¹¹ each independently represent deuterium, a halogen, an alkyl group having 1 to 20 carbon atoms, a substituted or unsubstituted aromatic amino group having 12 to 36 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 5 of these aromatic groups are linked, and preferably a substituted or unsubstituted aromatic hydrocarbon group having 6 to 18 carbon atoms or a substituted or unsubstituted aromatic heterocyclic group having 3 to 18 carbon atoms, more preferably a substituted or unsubstituted aromatic hydrocarbon group having 6 to 13 carbon atoms or a substituted or unsubstituted aromatic heterocyclic group having 3 to 17 carbon atoms, and further preferably a substituted or unsubstituted aromatic hydrocarbon group having 6 to 13 carbon atoms or a substituted or unsubstituted aromatic heterocyclic group having 6 to 12 carbon atoms. When Ar¹ to Ar⁶ represent the linked aromatic group, the number of linking is preferably 2 to 6, and more preferably 2 to 4. When Ar⁷ to Ar¹¹ represent the linked aromatic group, the number of linking is preferably 2 to 4, and more preferably 2 to 3. Further, when Ar³, Ar⁴, Ar⁶, to Ar¹¹ represent the aromatic heterocyclic group and the linked aromatic group including the aromatic heterocyclic group, Ar³, Ar⁴, Ar⁶ to Ar¹¹ preferably include none of a nitrogen-containing six-membered ring and quinoline, isoquinoline, quinazoline, quinoxaline, benzimidazole, aza-triphenylene, phenanthroline, aza-pyrene, aza-anthracene, aza-fluorene, aza-dibenzofuran, aza-dibenzothiophene, aza-dibenzoselenophene, nor aza-carbazole. Specific examples of the nitrogen-containing six-membered ring include pyridine, pyrimidine, pyrazine, pyridazine, triazine and tetrazine. When Ar¹ to Ar¹¹ represent a group having a hydrogen atom, this hydrogen atom may be substituted with deuterium or a halogen.

The general formula (1) is preferably represented by the following formulae (3) to (8), and preferably a compound represented by any of them.

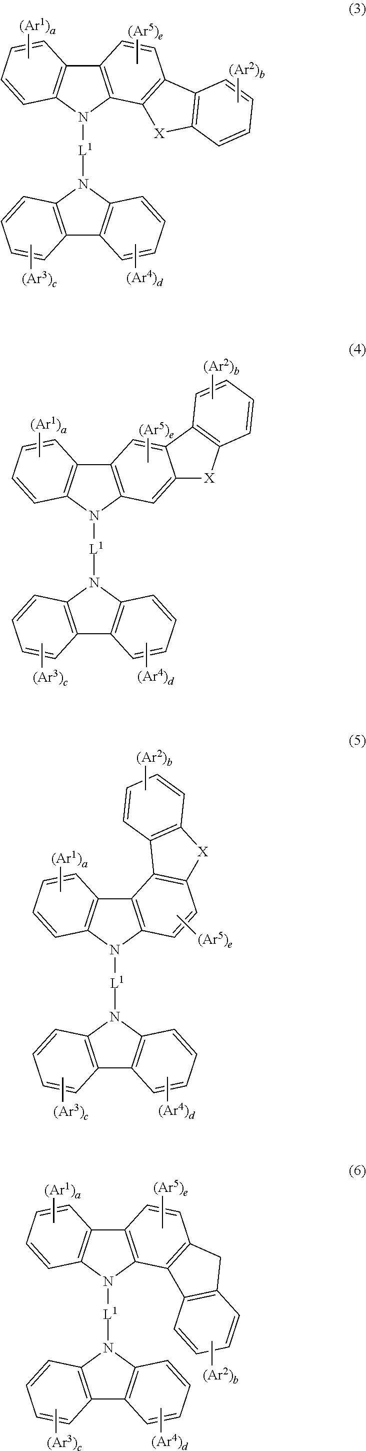

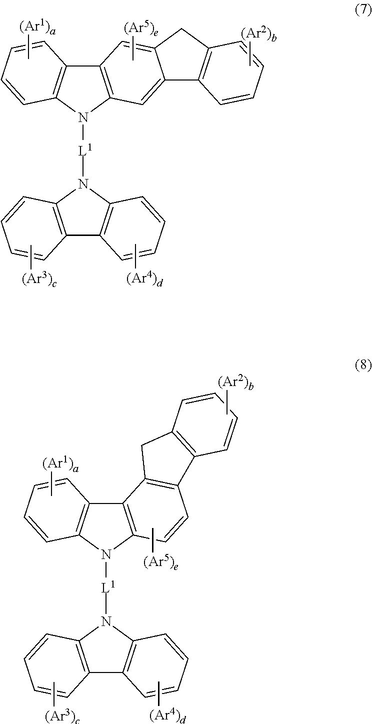

Specific examples of the halogen for Ar¹ to Ar¹¹ include a fluoro group, a chloro group, a bromo group, and an iodo group.

When Ar¹ to Ar¹¹ represent an alkyl group having 1 to 20 carbon atoms, the alkyl group may be any of linear, branched, and cyclic alkyl groups, and is preferably a linear, branched, or cyclic alkyl group having 1 to 10 carbon atoms. Specific examples thereof include: linear saturated hydrocarbon groups, such as a methyl group, an ethyl group, a n-propyl group, a n-butyl group, a n-pentyl group, a n-hexyl group, a n-octyl group, a n-dodecyl group, a n-tetradecyl group, or a n-octadecyl group; branched saturated hydrocarbon groups, such as an isopropyl group, an isobutyl group, a neopentyl group, a 2-ethylhexyl group, or a 2-hexyloctyl group; and saturated alicyclic hydrocarbon groups, such as a cyclopentyl group, a cyclohexyl group, a cyclooctyl group, or a 4-butylcyclohexyl group.

When Ar¹ to Ar¹¹ represent an unsubstituted aromatic amino group having 12 to 36 carbon atoms, specific examples of an aryl group in the aromatic amino group include groups obtained by removing one hydrogen atom from a phenyl group, a biphenyl group, a terphenyl group, a quaterphenyl group, a naphthyl group, a phenanthrenyl group, an anthracenyl group, a triphenylenyl group, a pyrenyl group, a fluorenyl group, a spirobifluorenyl group, and the like, and preferably a phenyl group, a biphenyl group, a terphenyl group, a naphthyl group, a phenanthrenyl group, a fluorenyl group, or a triphenylenyl group. Specific examples of a heteroaryl group in the aromatic amino group include groups obtained by removing one hydrogen atom from pyrrole, pyrrolopyrrole, indole, pyrroloindole, benzoindole, naphthopyrrole, isoindole, pyrroloisoindole, benzoisoindole, naphthoisopyrrole, carbazole, benzocarbazole, indoloindole, carbazolocarbazole, benzofurocarbazole, benzothienocarbazole, carboline, thiophene, benzothiophene, naphthothiophene, dibenzothiophene, benzothienonaphthalene, benzothienobenzothiophene, benzothienodibenzothiophene, dinaphthothiophene, dinaphthothienothiophene, naphthobenzothiophene, furan, benzofuran, naphthofuran, dibenzofuran, benzofuronaphthalene, benzofurobenzofuran, benzofurodibenzofuran, dinaphthofuran, dinaphthofuranofuran, naphthobenzofuran, pyridine, pyrimidine, triazine, quinoline, isoquinoline, quinazoline, quinoxaline, or the like, and preferably dibenzofuran, dibenzothiophene, carbazole, benzofurocarbazole, or benzothienocarbazole.

When Ar¹ to Ar¹¹ represent an unsubstituted aromatic hydrocarbon group having 6 to 18 carbon atoms, examples thereof include groups obtained by removing one hydrogen from known aromatic hydrocarbons. Provided that, when Ar⁶ includes the general formula (2) and a group bonded to N described in the general formula (1) is Ar⁷ to Ar¹¹, examples thereof include groups obtained by removing two hydrogens from known aromatic hydrocarbon groups. Specific examples thereof include: monocyclic aromatic hydrocarbons, such as benzene; bicyclic aromatic hydrocarbons, such as naphthalene; tricyclic aromatic hydrocarbons, such as indacene, biphenylene, phenalene, anthracene, phenanthrene, and fluorene; and tetracyclic aromatic hydrocarbons, such as fluoranthene, acephenanthrylene, aceanthrylene, triphenylene, pyrene, chrysene, tetraphene, tetracene, and pleiadene. The aromatic hydrocarbon group is preferably benzene, naphthalene, anthracene, triphenylene, or pyrene.

When Ar¹ to Ar¹¹ represent the unsubstituted aromatic heterocyclic group having 3 to 18 carbon atoms, examples thereof include groups obtained by removing one hydrogen from an aromatic heterocyclic group. Provided that, when Ar⁶ includes the general formula (2) and a group bonded to N described in the general formula (1) is Ar⁷ to Ar¹¹, examples thereof include groups obtained by removing two hydrogens from known aromatic heterocyclic groups. Specific examples thereof include: nitrogen-containing aromatic compounds having a pyrrole ring, such as pyrrole, pyrrolopyrrole, indole, pyrroloindole, benzoindole, naphthopyrrole, isoindole, pyrroloisoindole, benzoisoindole, naphthoisopyrrole, carbazole, benzocarbazole, indoloindole, carbazolocarbazole, indolocarbazole, or carboline; sulfur-containing aromatic compounds having a thiophene ring, such as thiophene, benzothiophene, naphthothiophene, dibenzothiophene, benzothienonaphthalene, benzothienobenzothiophene, benzothienodibenzothiophene, dinaphthothiophene, dinaphthothienothiophene, naphthobenzothiophene, or benzothienocarbazole; oxygen-containing aromatic compounds having a furan ring, such as furan, benzofuran, naphthofuran, dibenzofuran, benzofuronaphthalene, benzofurobenzofuran, benzofurodibenzofuran, dinaphthofuran, dinaphthofuranofuran, naphthobenzofuran, and benzofurocarbazole; and nitrogen-containing aromatic compounds, such as pyridine, pyrimidine, triazine, quinoline, isoquinoline, quinazoline, and quinoxaline. The aromatic heterocyclic group is preferably dibenzofuran, dibenzothiophene, or carbazole.

Provided that, when Ar³, Ar⁴, and Ar⁶, to Ar¹¹ represent the aromatic heterocyclic group and the linked aromatic group including the aromatic heterocyclic group, the aromatic heterocyclic group preferably includes none of a nitrogen-containing six-membered ring and quinoline, isoquinoline, quinazoline, quinoxaline, benzimidazole, aza-triphenylene, phenanthroline, aza-pyrene, aza-anthracene, aza-fluorene, aza-dibenzofuran, aza-dibenzothiophene, aza-dibenzoselenophene, nor aza-carbazole. Specific examples of the nitrogen-containing six-membered ring include pyridine, pyrimidine, pyrazine, pyridazine, triazine and tetrazine.

The linked aromatic group herein refers to an aromatic group in which two or more aromatic rings of aromatic groups are bonded and linked with a single bond. These linked aromatic groups may be linear or branched. A linking position in linking the benzene rings each other may be any of ortho, meta, and para, but preferably para-liking or meta-linking. The aromatic group may be an aromatic hydrocarbon group or an aromatic heterocyclic group. The plurality of the aromatic groups may be same as or different from each other. Note that the aromatic group constituting the linked aromatic group does not include an aromatic amino group.

When Ar¹ to Ar¹¹ represent the aromatic hydrocarbon group, the aromatic heterocyclic group, or the linked aromatic group, these groups may have a substituent. Examples of the substituent include deuterium, a halogen, an alkyl group having 1 to 20 carbon atoms, an aralkyl group having 7 to 38 carbon atoms, an alkenyl group having 2 to 20 carbon atoms, an alkynyl group having 2 to 20 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a nitro group, and an alkylsilyl group having 3 to 12 carbon atoms. When Ar¹ to Ar¹¹ represent the aromatic amino group, the aromatic group may have a substituent, and the substituent in this case is the same as the case where the aromatic hydrocarbon group, the aromatic heterocyclic group, or the linked aromatic group has a substituent.

The alkyl group having 1 to 20 carbon atoms as the substituent may be any of linear, branched, and cyclic alkyl groups, and is preferably a linear, branched, or cyclic alkyl group having 1 to 10 carbon atoms. Specific examples thereof include: linear saturated hydrocarbon groups, such as a methyl group, an ethyl group, a n-propyl group, a n-butyl group, a n-pentyl group, a n-hexyl group, a n-octyl group, a n-dodecyl group, a n-tetradecyl group, or a n-octadecyl group; branched saturated hydrocarbon groups, such as an isopropyl group, an isobutyl group, a neopentyl group, a 2-ethylhexyl group, and a 2-hexyloctyl group; and saturated alicyclic hydrocarbon groups, such as a cyclopentyl group, a cyclohexyl group, a cyclooctyl group, a 4-butylcyclohexyl group, and a 4-dodecylcyclohexyl group.

Specific examples of the halogen as the substituent include a fluoro group, a chloro group, a bromo group, and an iodo group. Specific examples of the aralkyl group having 7 to 38 carbon atoms include a benzyl group, a phenethyl group, a phenylpropyl group, a phenylbutyl group, a naphthylmethyl group, and a triphenylenylmethyl group. Specific examples of the alkenyl group having 2 to 20 carbon atoms as the substituent include an ethylene group, a propylene group, a butylene group, a pentene group, a cyclopentene group, a hexene group, a cyclohexene group, and an octene group. Specific examples of the alkynyl group having 2 to 20 carbon atoms as the substituent include an acetylene group, a propyne group, a butyne group, and a pentyne group. Specific examples of the acyl group having 2 to 20 carbon atoms as the substituent include a formyl group, an acetyl group, a propionyl group, and a benzoyl group. Specific examples of the alkoxy group having 1 to 20 carbon atoms as the substituent include a methoxy group, an ethoxy group, a propoxy group, and a butoxy group. Specific examples of the alkoxycarbonyl group having 2 to 20 carbon atoms as the substituent include a methyl ester group and an ethyl ester group. Specific examples of the alkylsilyl group having 3 to 12 carbon atoms as the substituent include a trimethylsilyl group, a triethylsilyl group, and a tripropylsilyl group.

Preferable specific examples of the compound represented by the general formula (1) being the material for a photoelectric conversion device of the present invention are shown below, but the material is not limited thereto. Note that “D” in the following formulae represents deuterium, and the number represents the number of substitutions of deuterium.

[chemical structure]

[chemical structure]

[chemical structure]

[chemical structure]

[chemical structure]

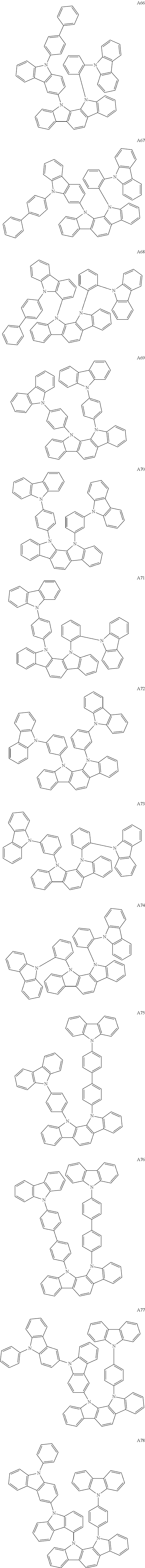

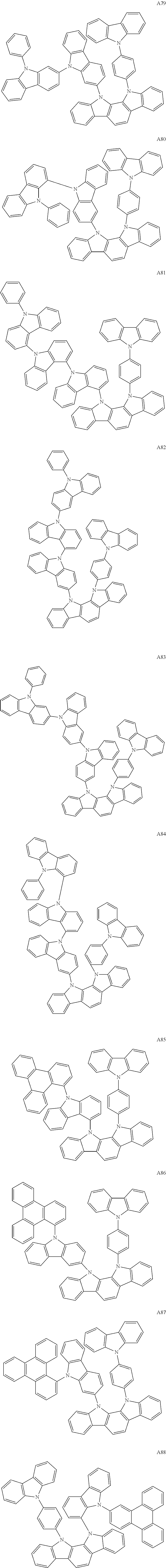

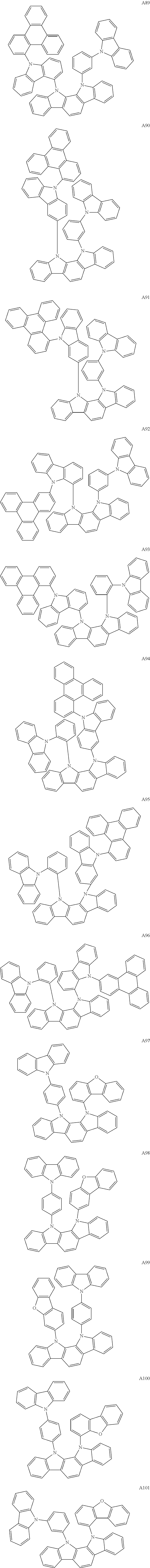

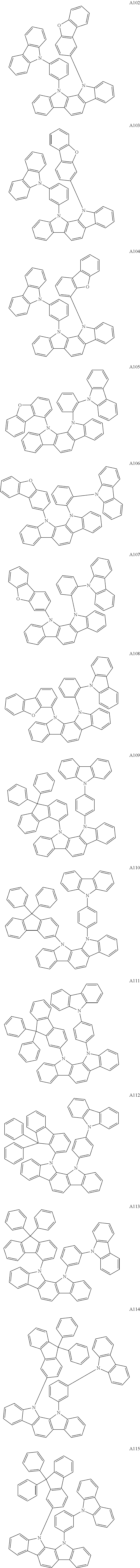

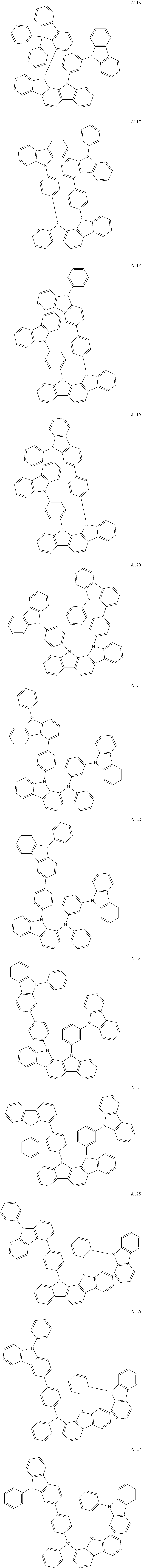

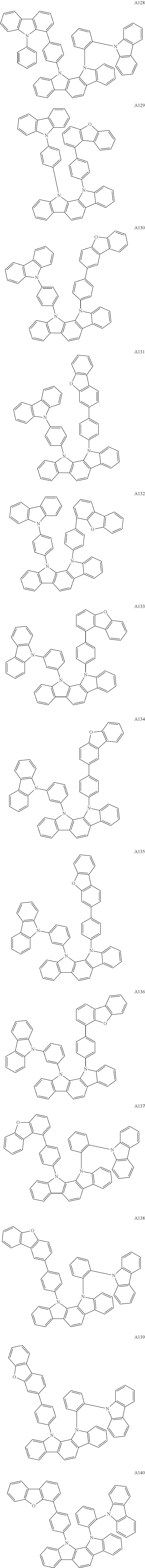

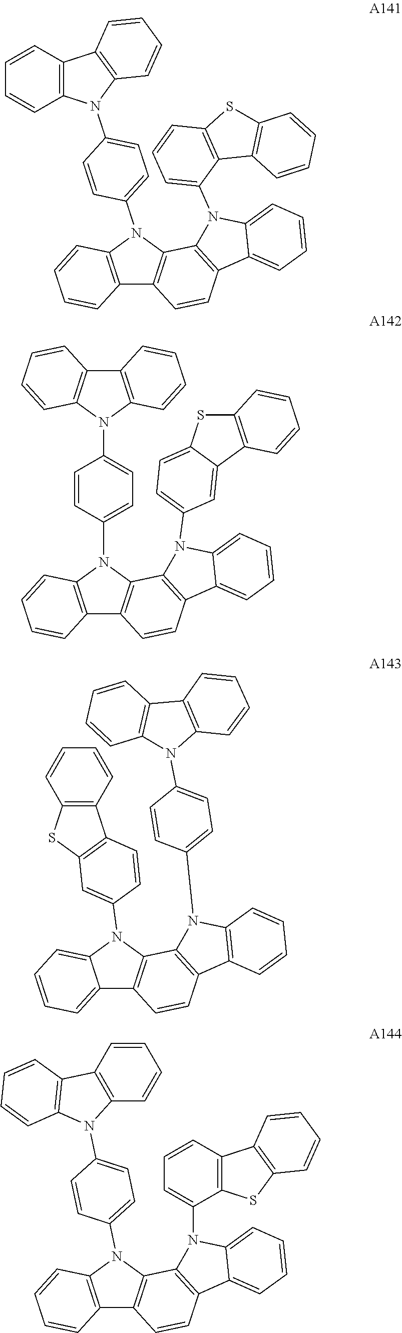

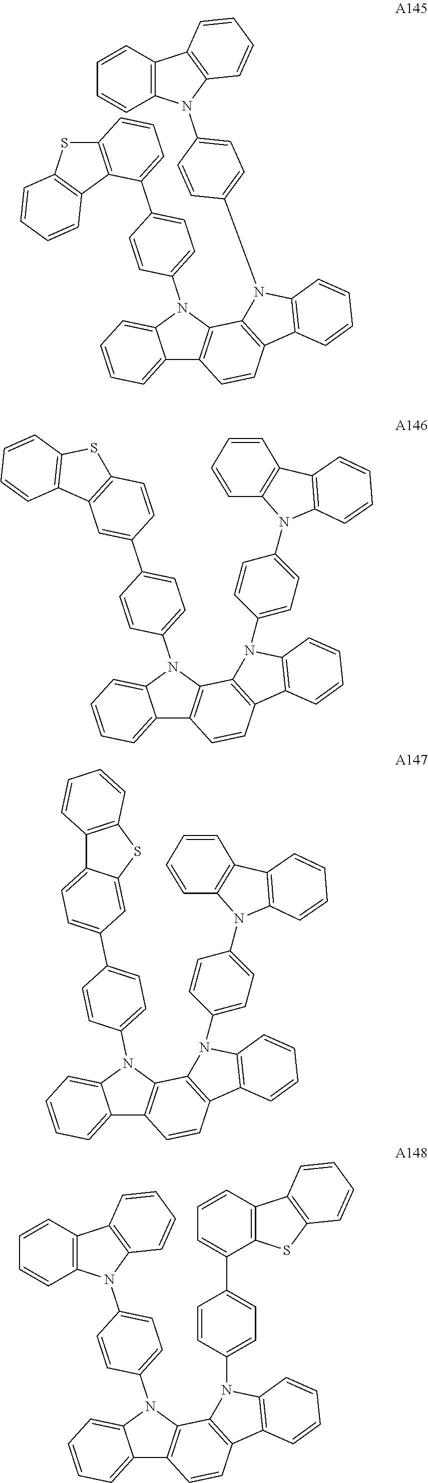

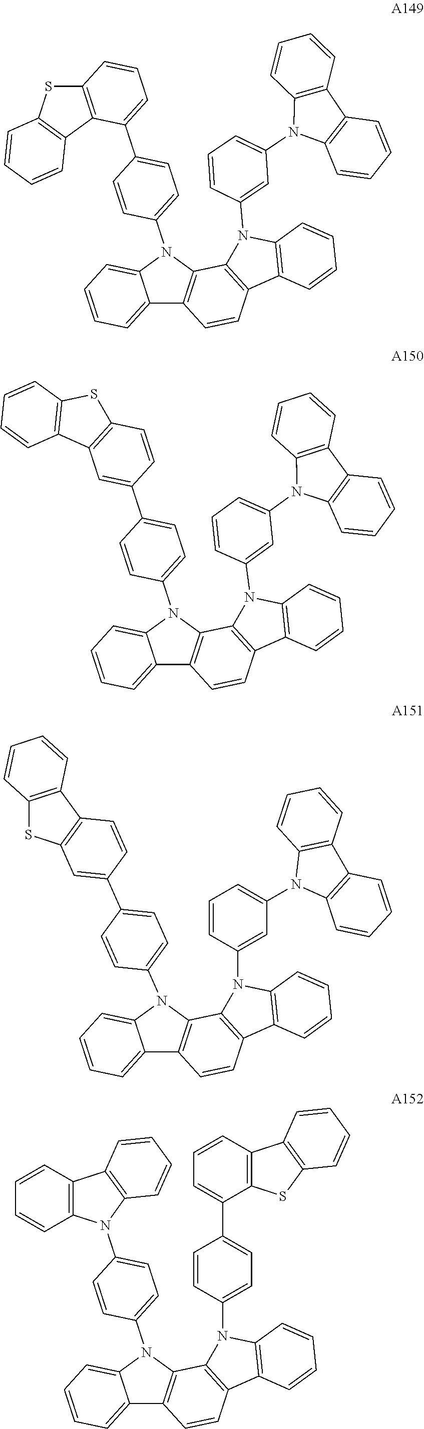

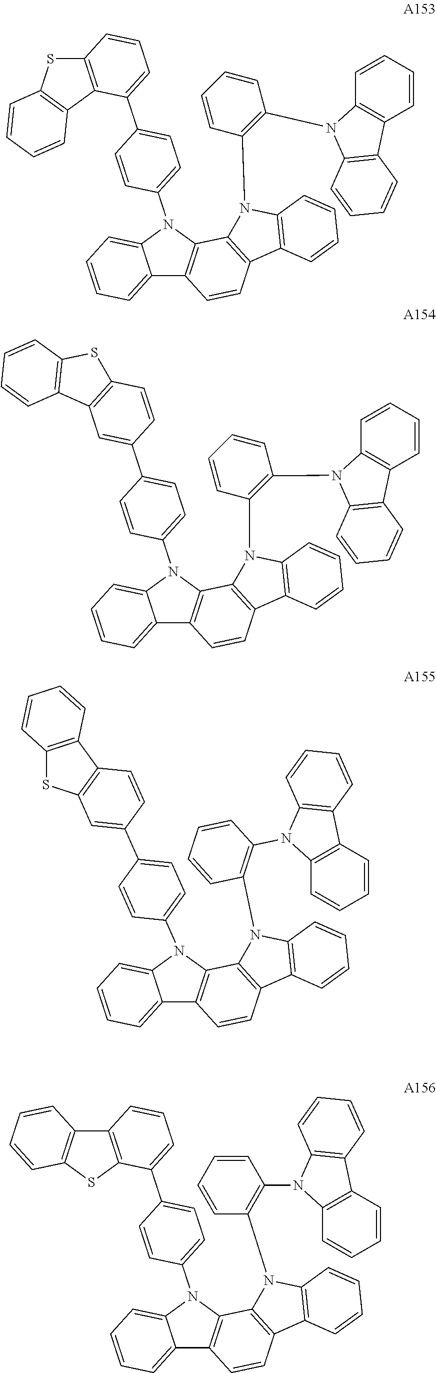

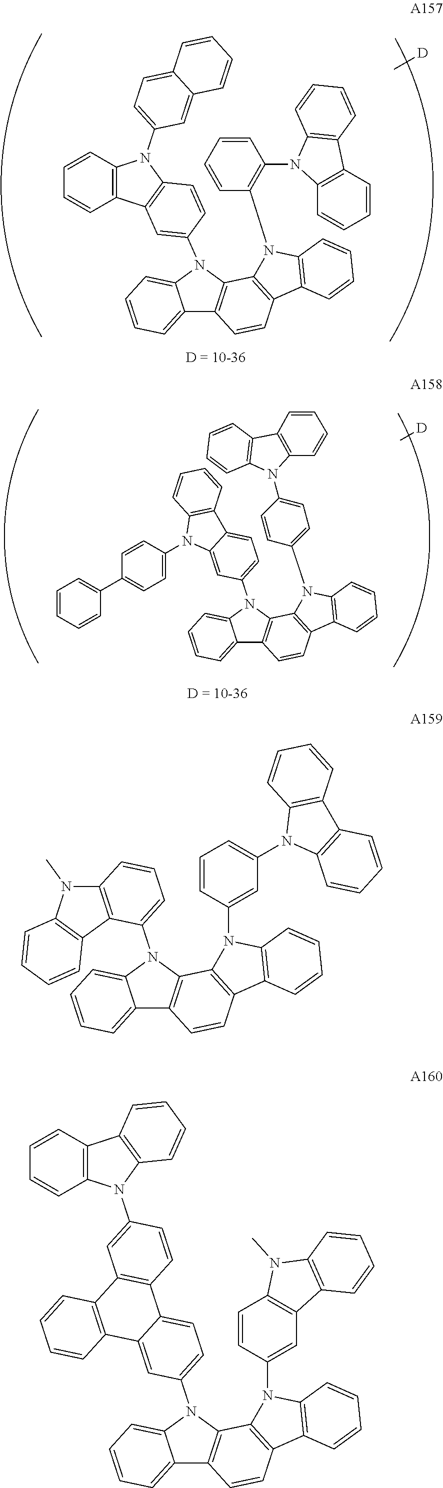

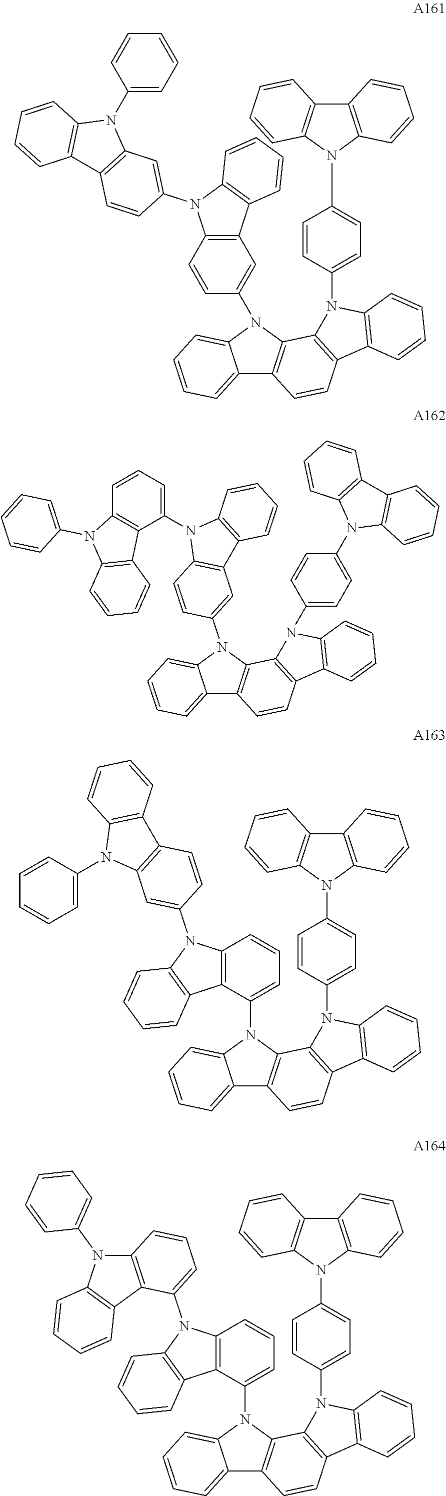

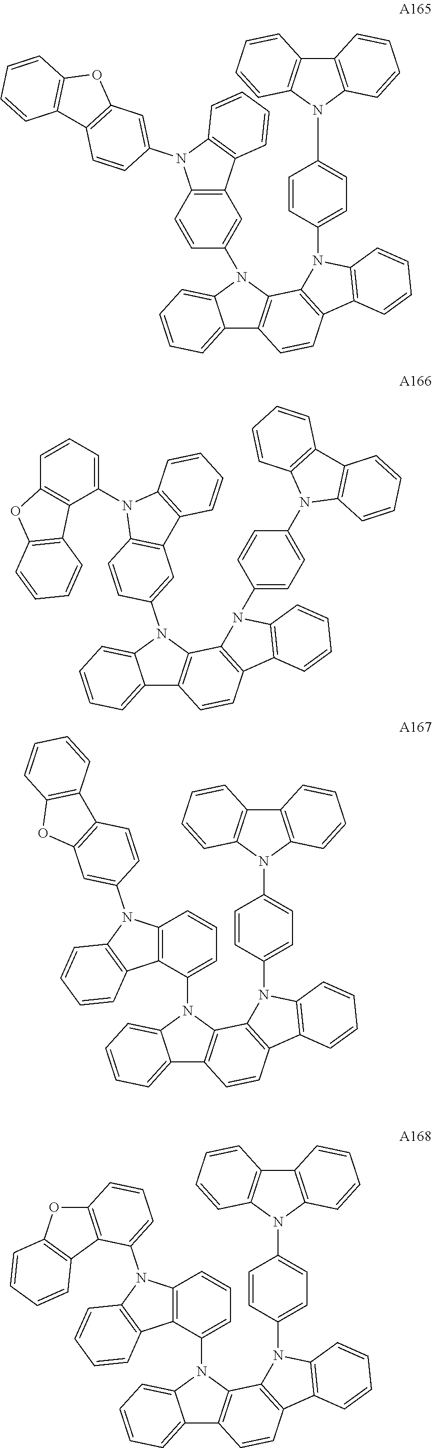

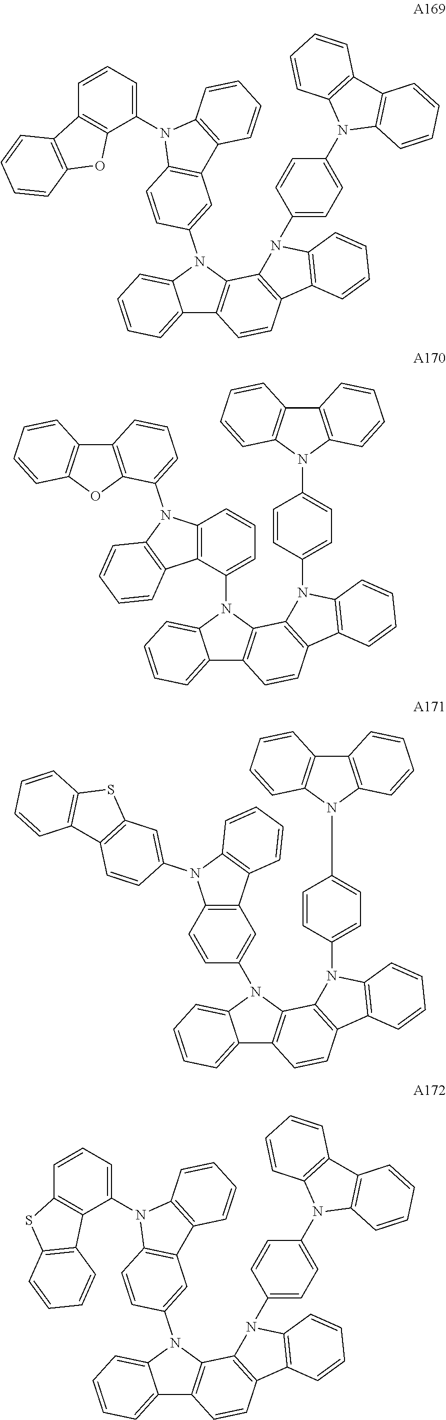

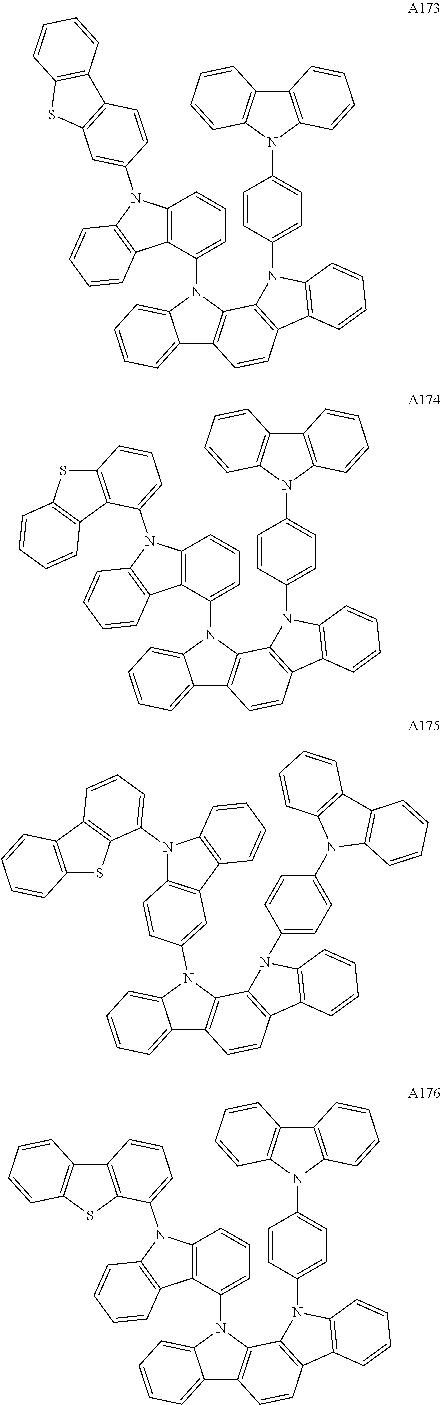

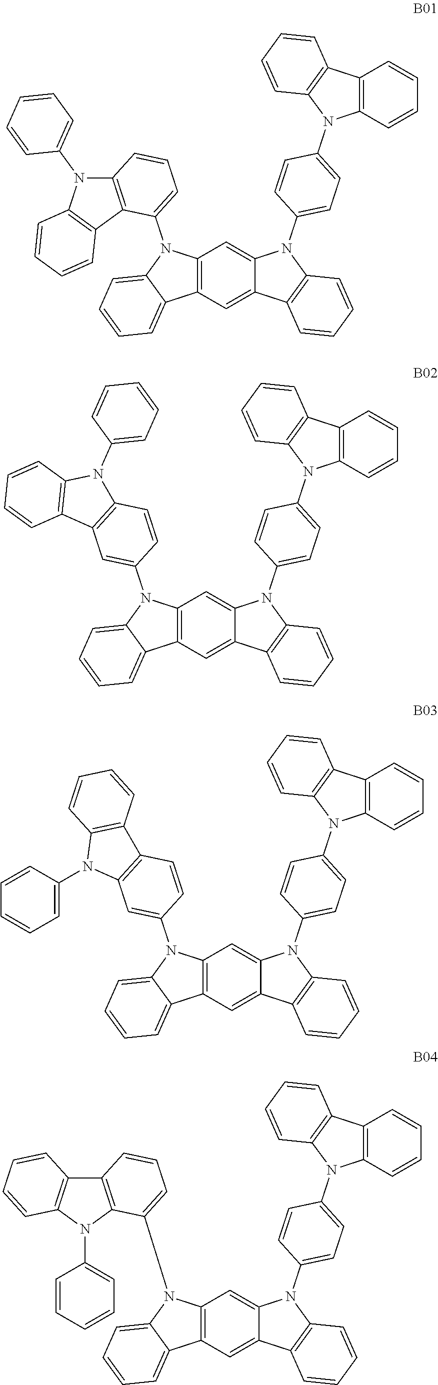

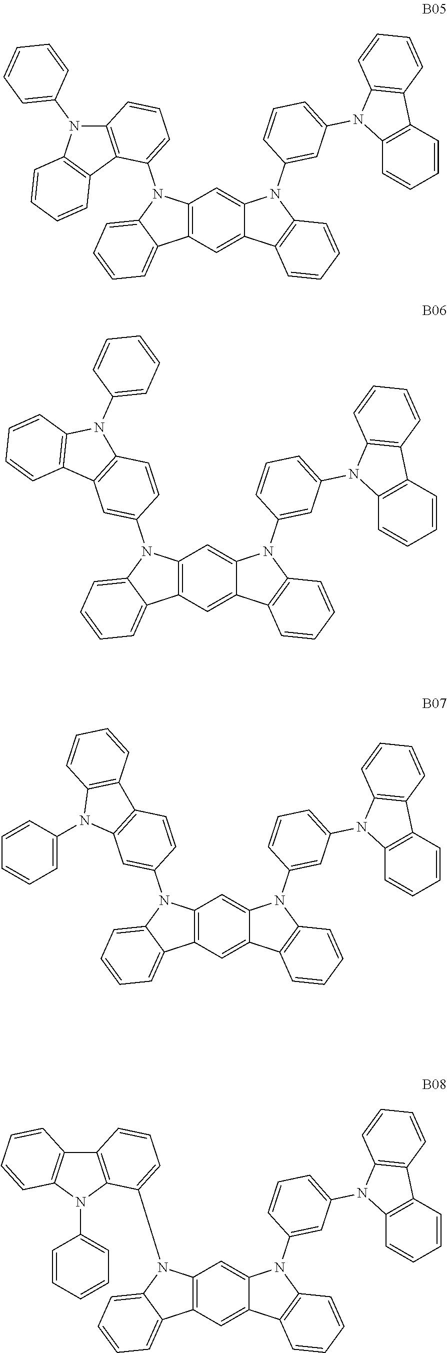

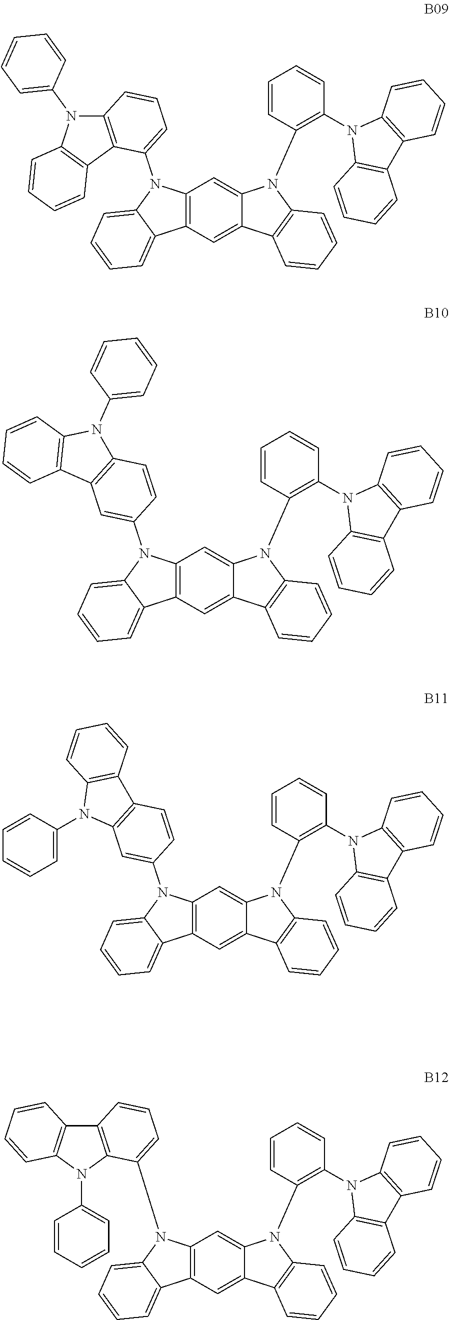

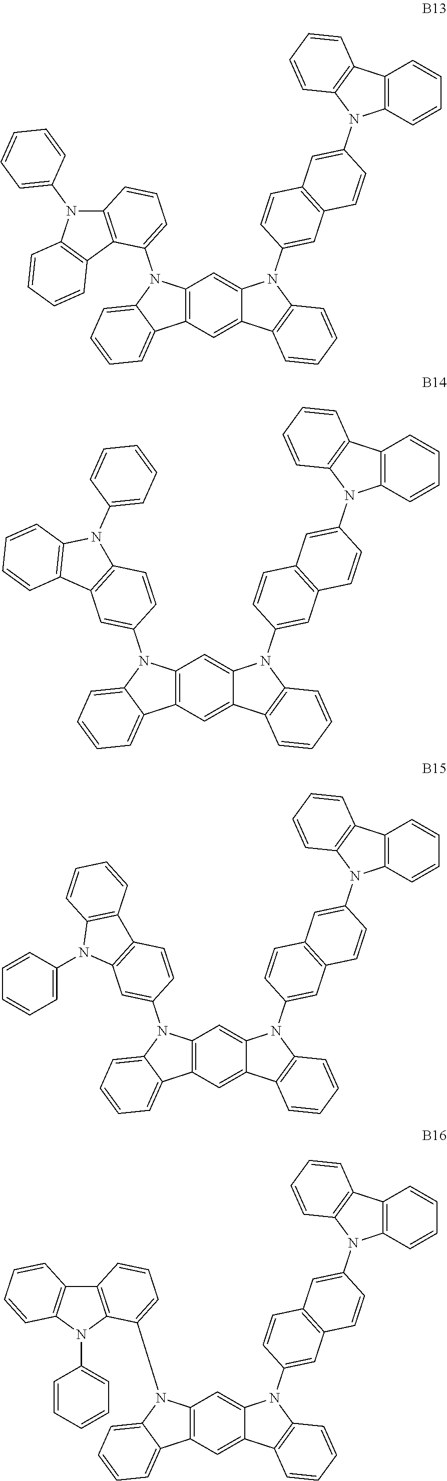

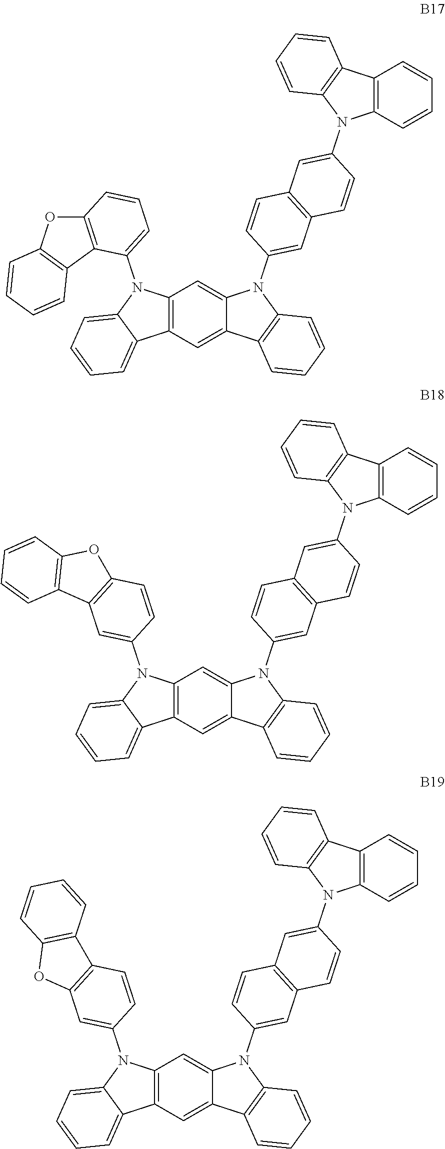

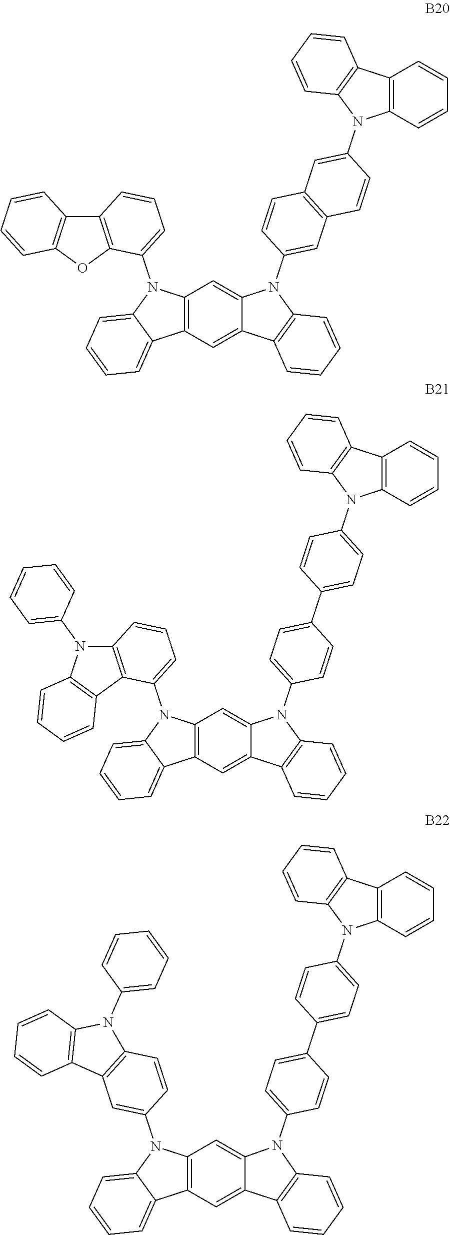

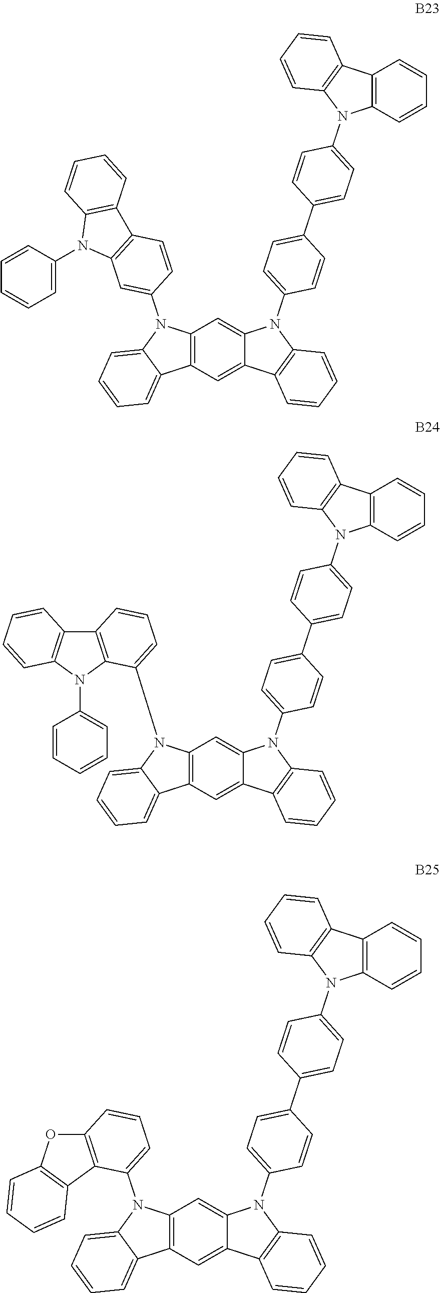

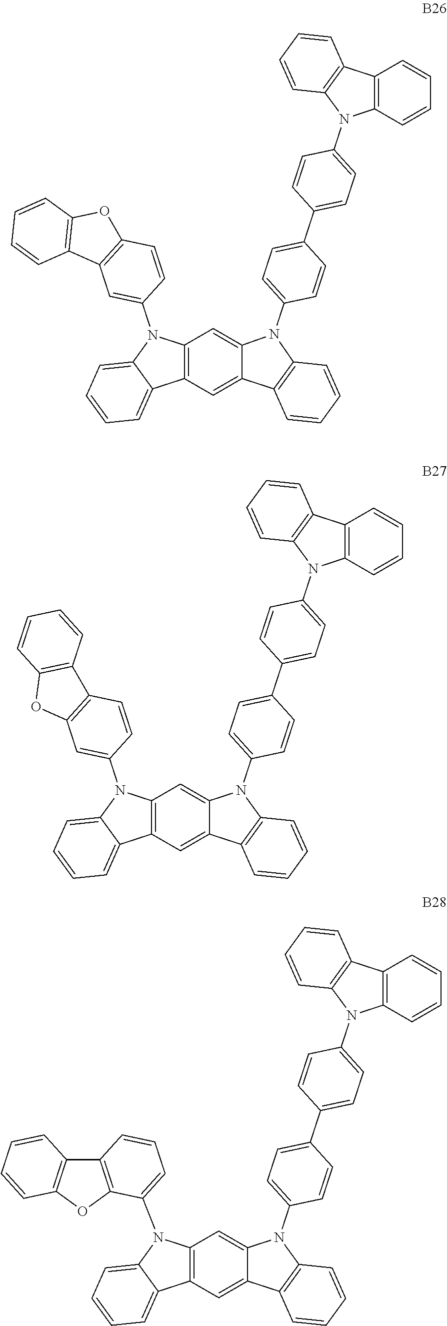

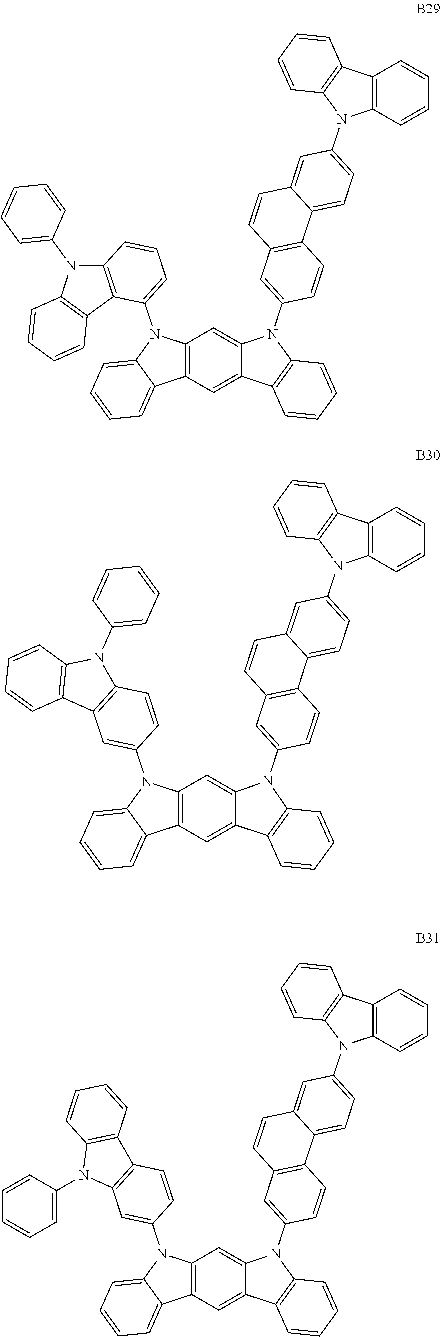

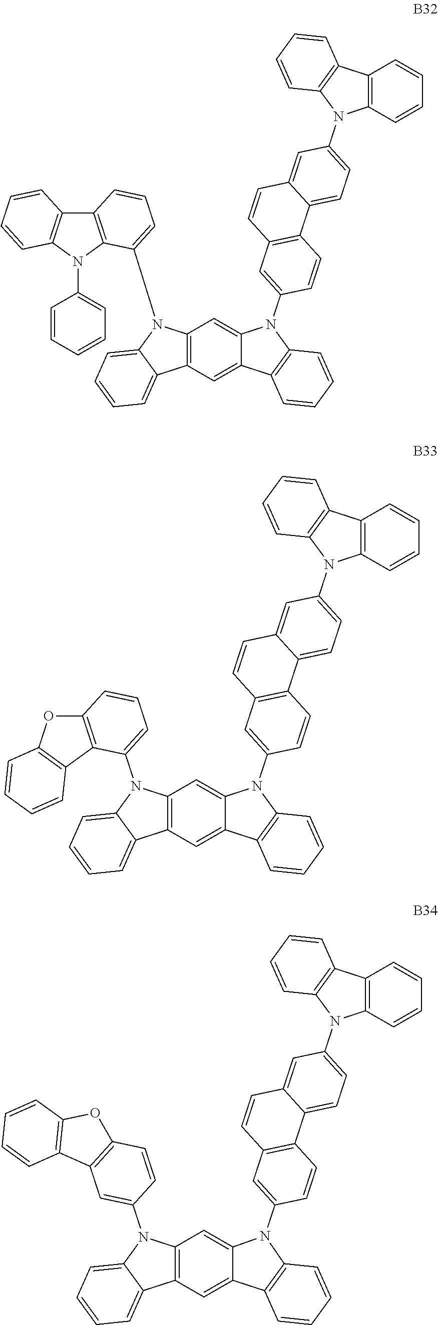

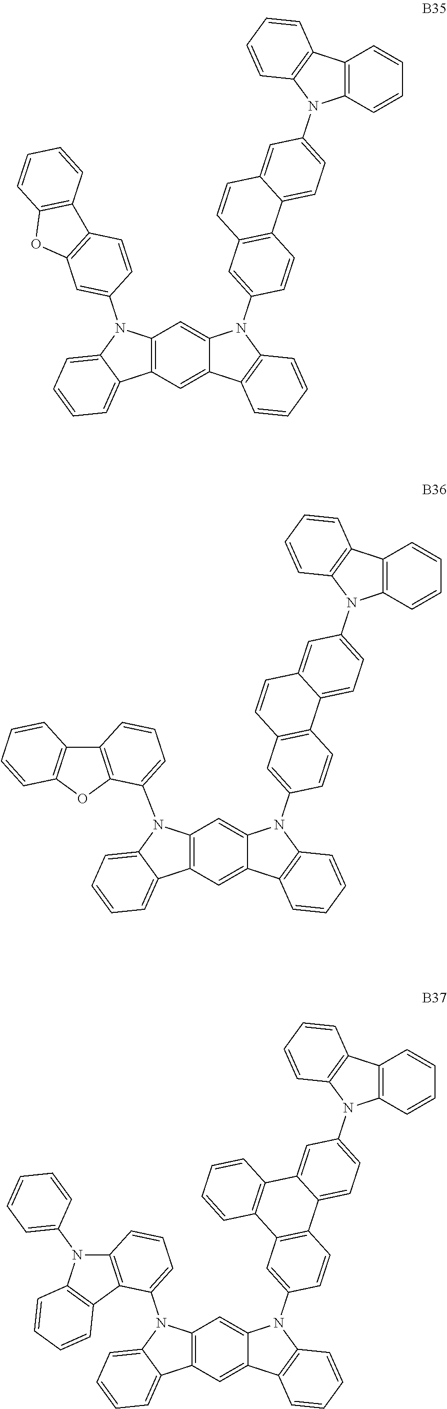

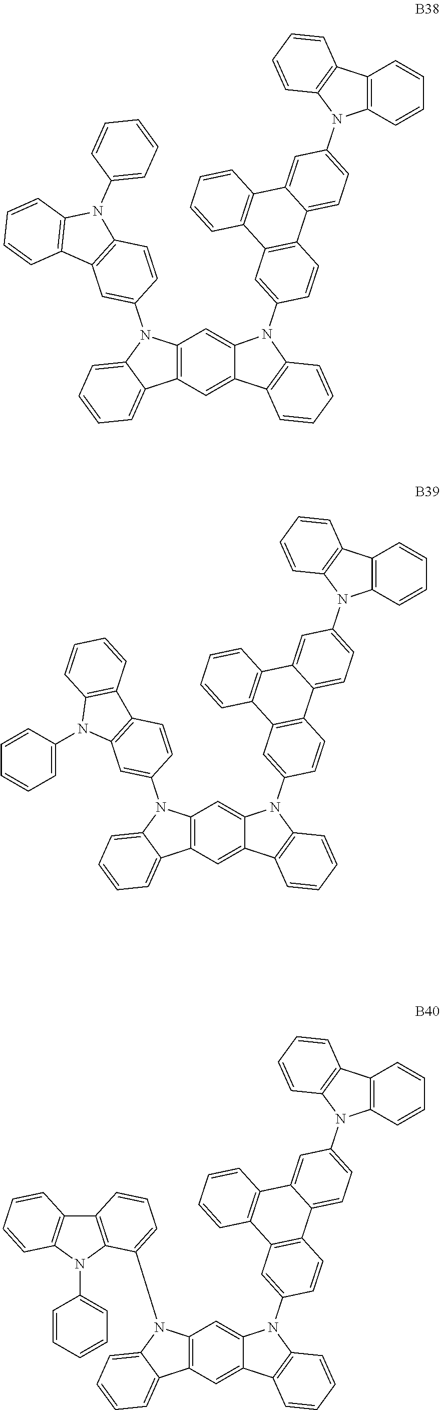

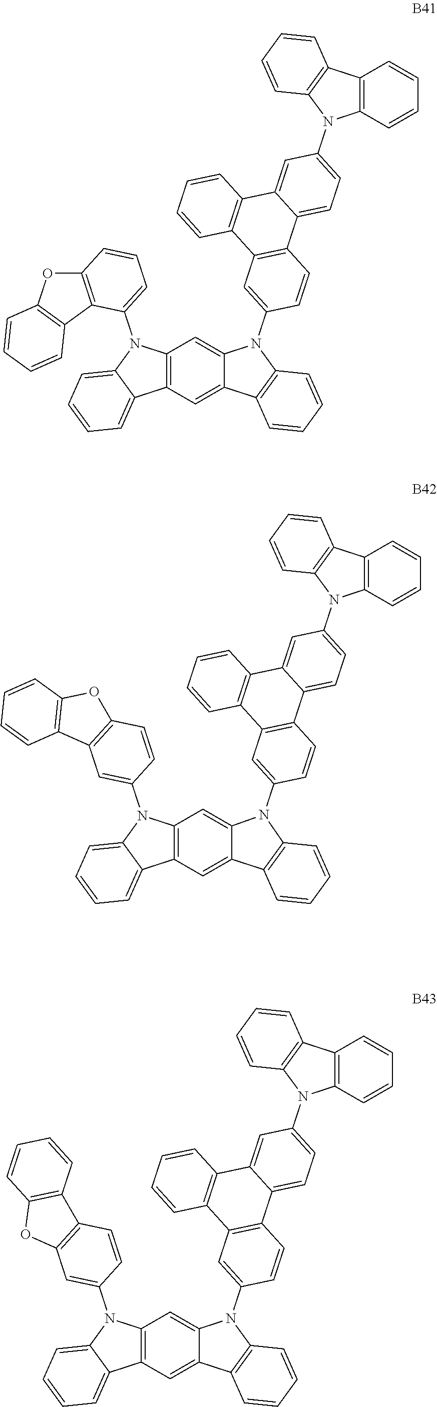

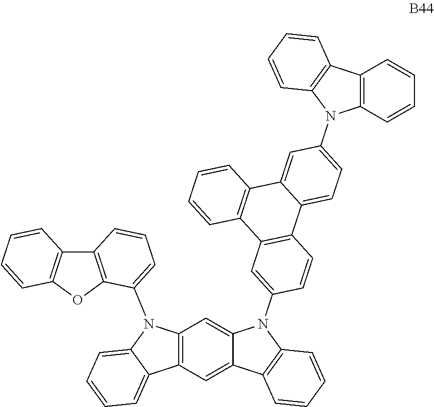

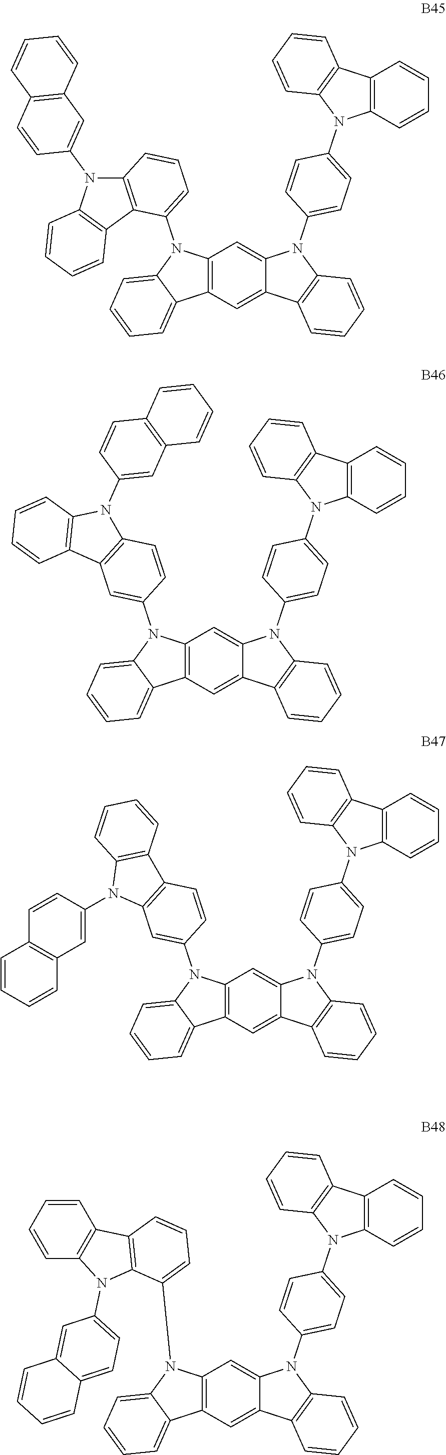

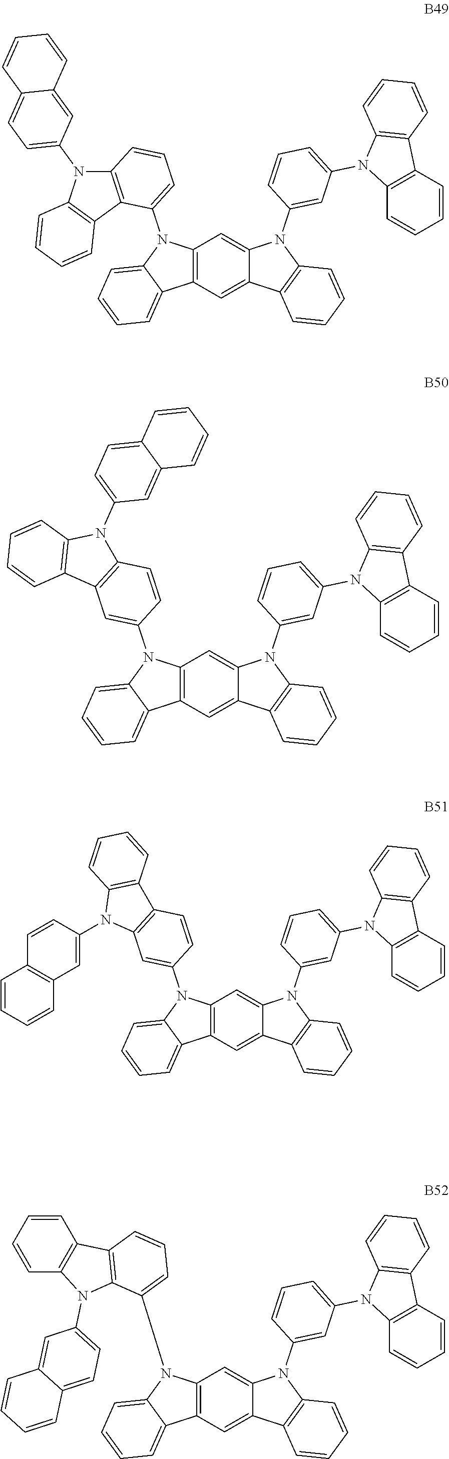

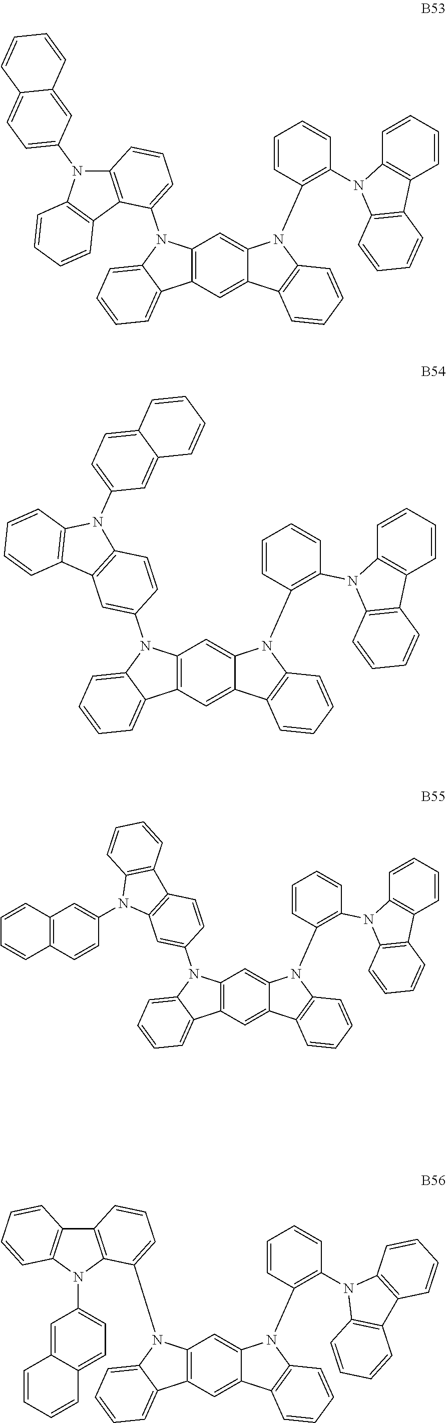

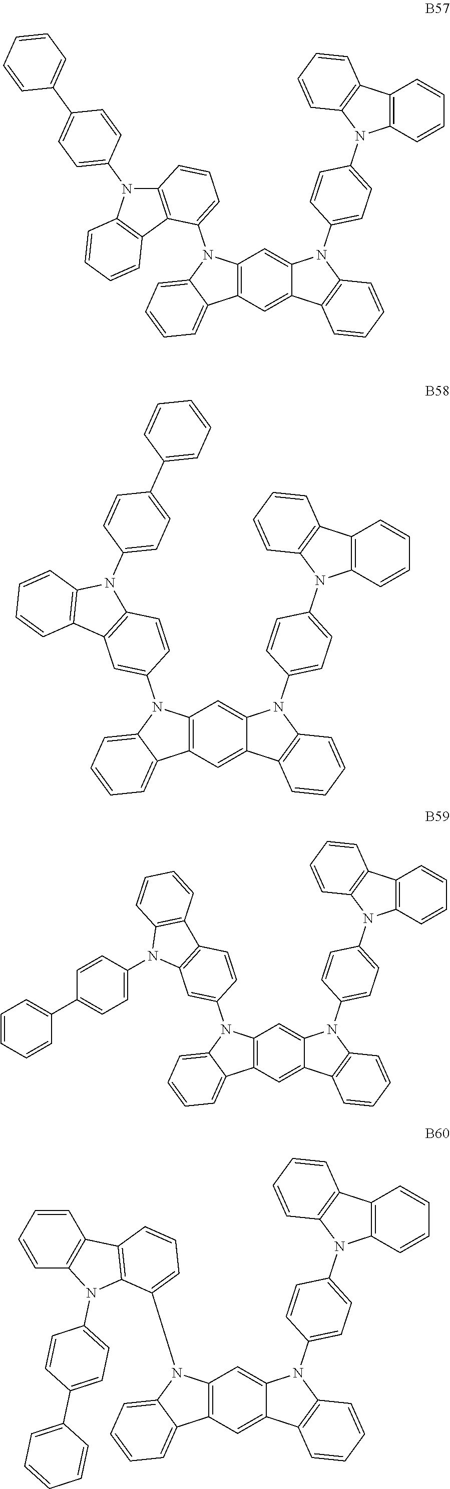

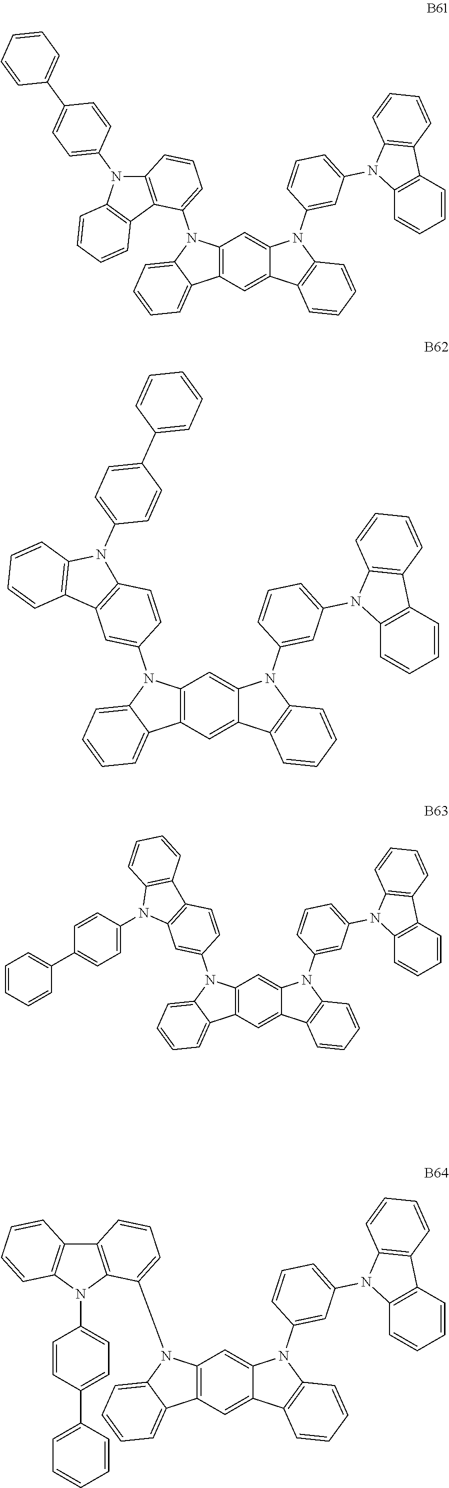

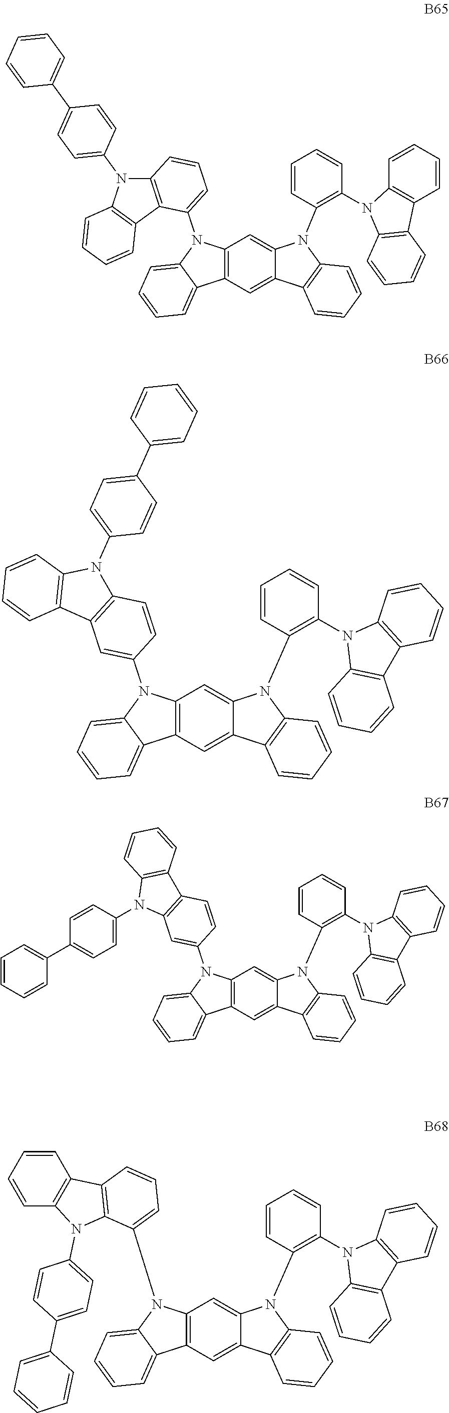

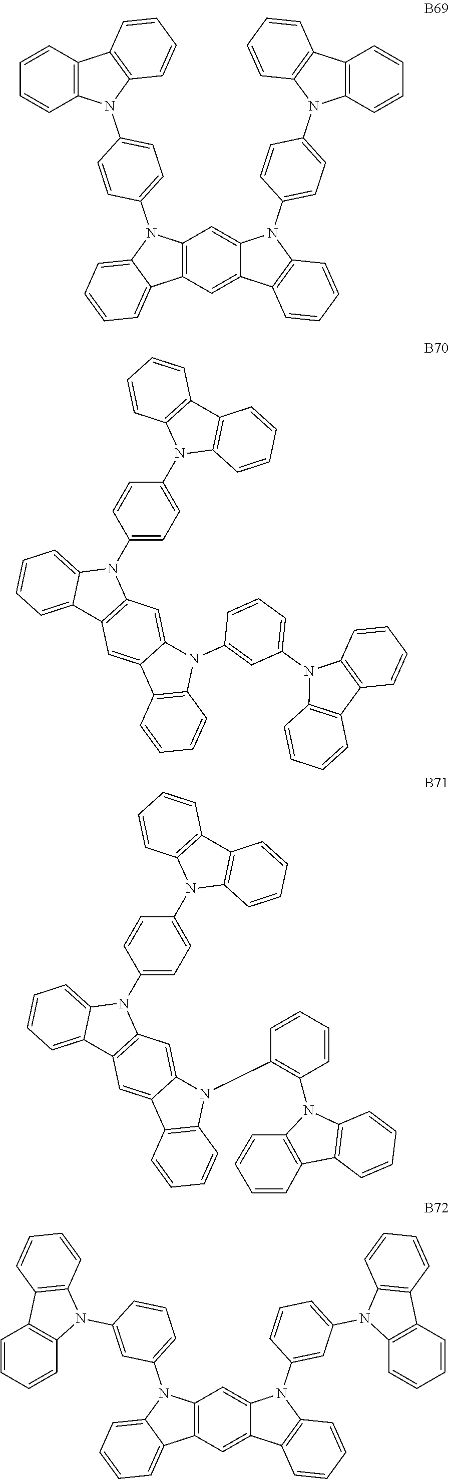

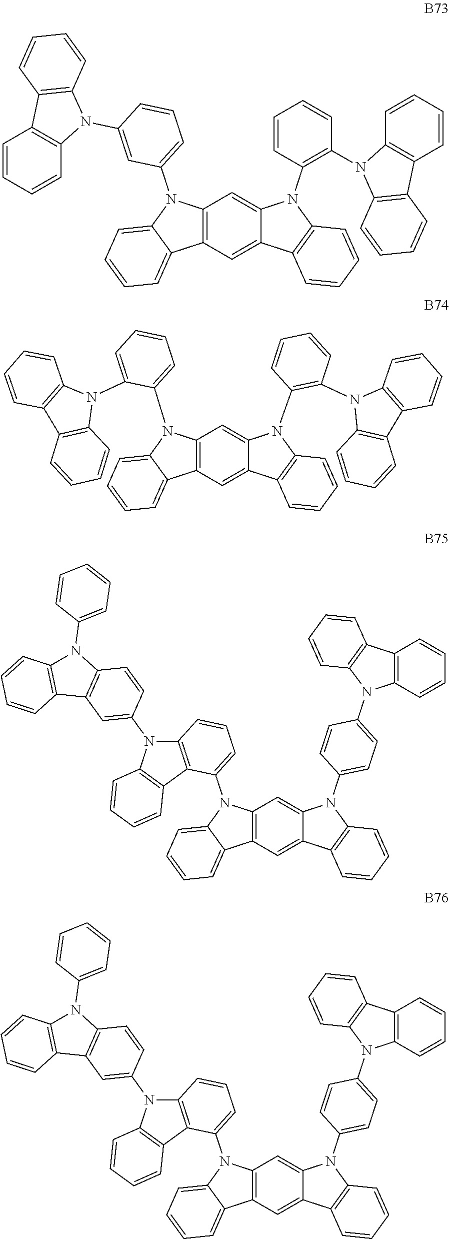

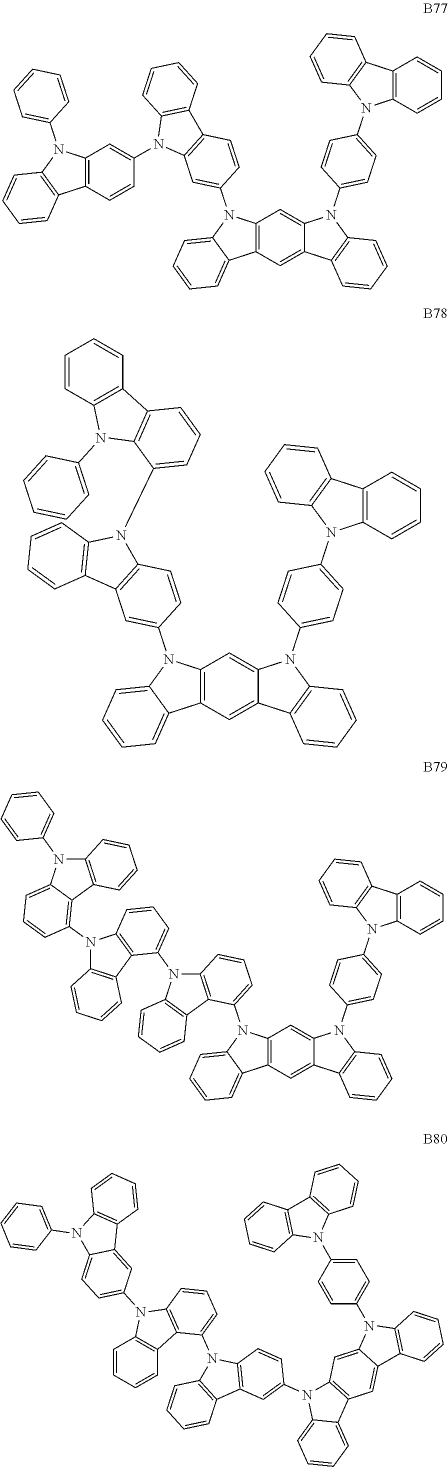

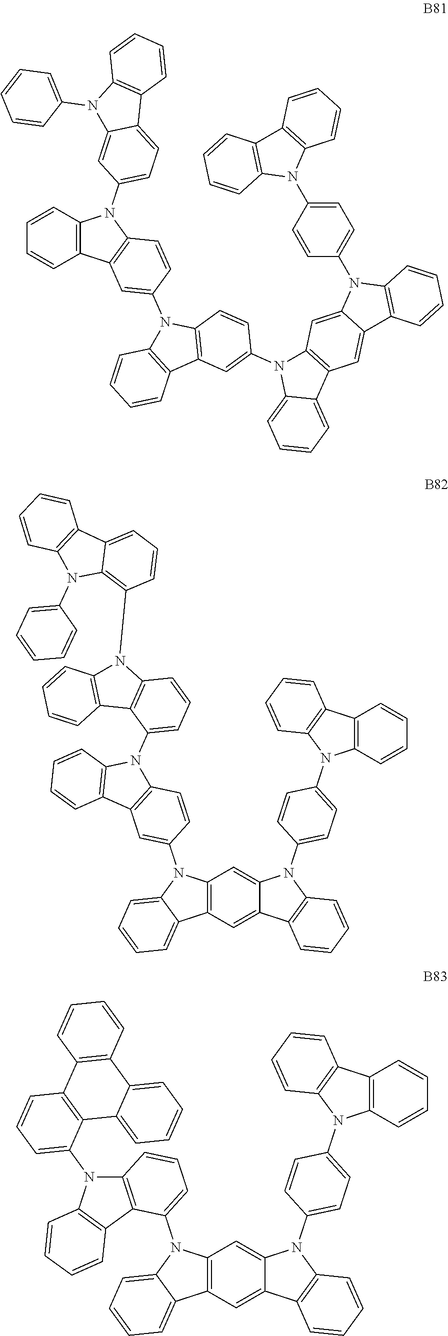

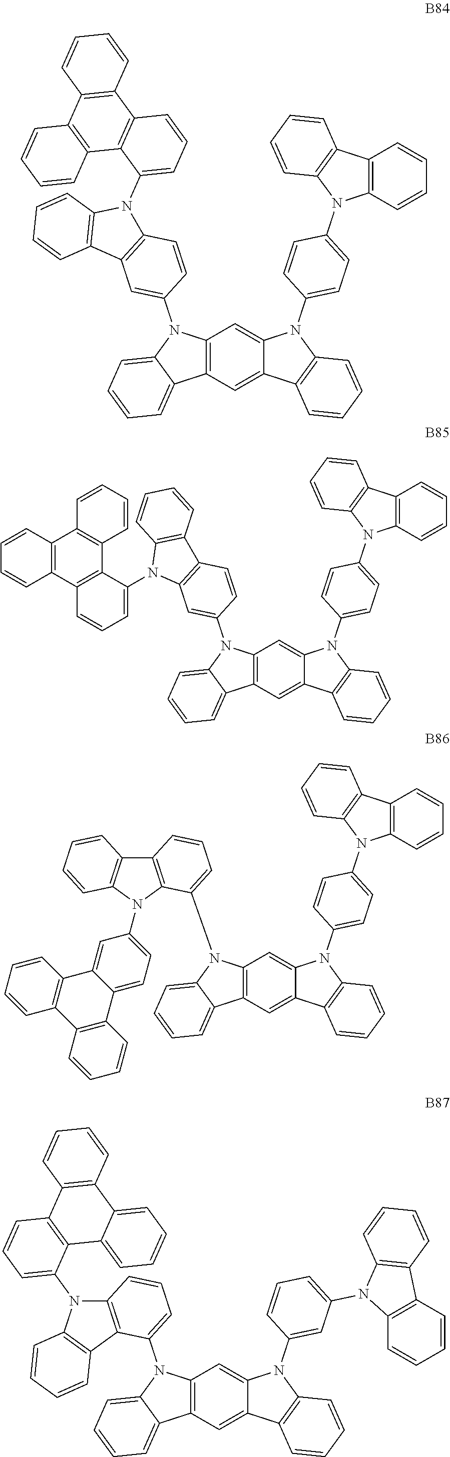

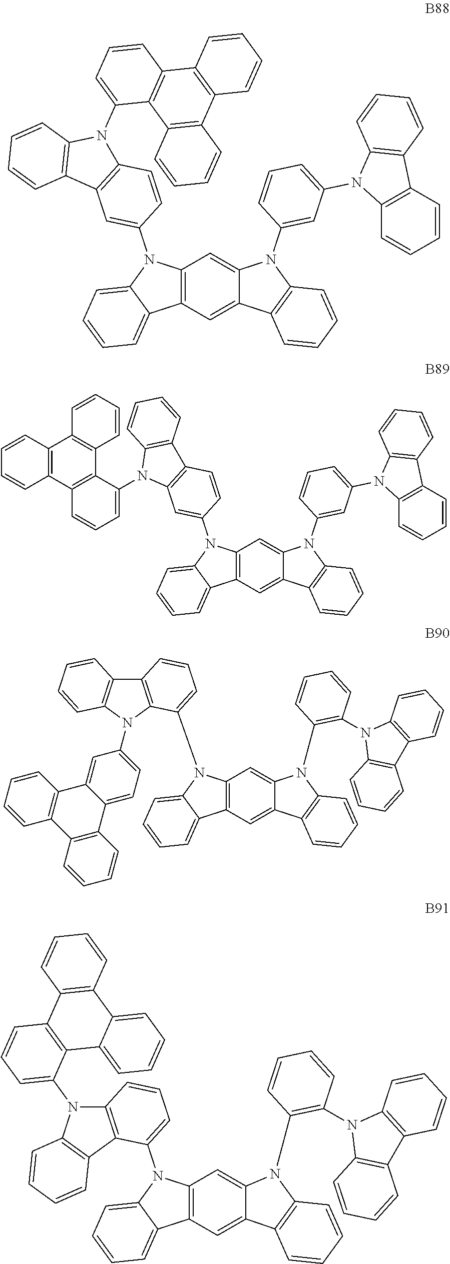

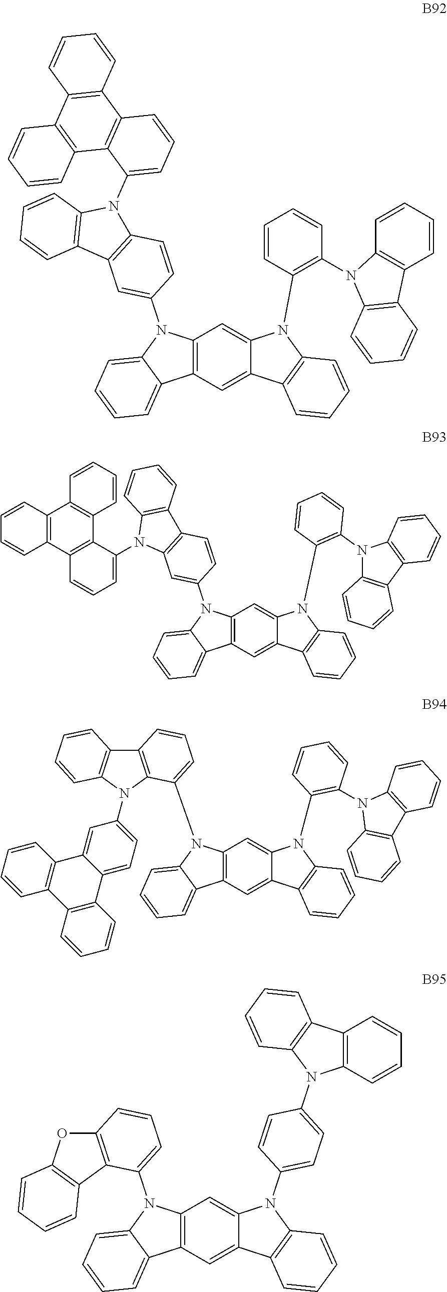

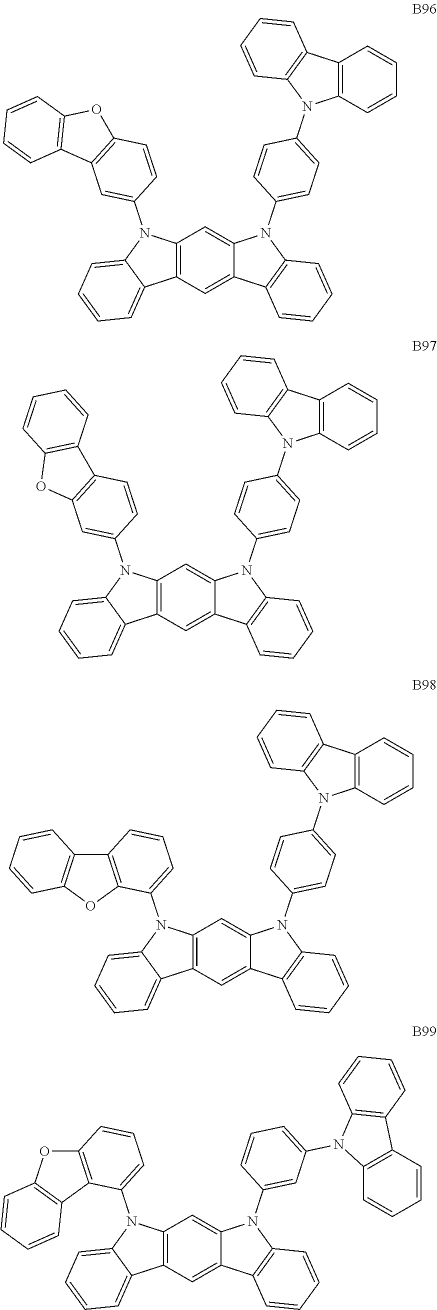

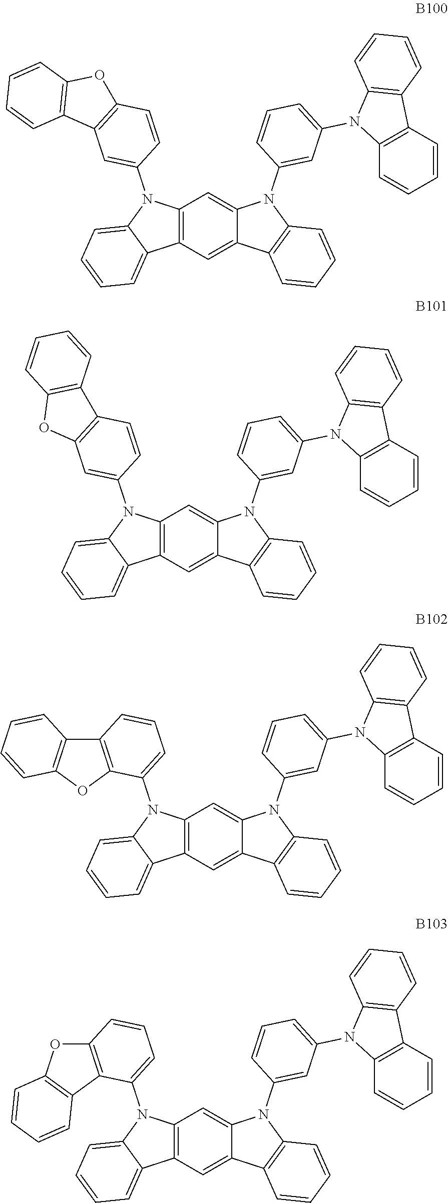

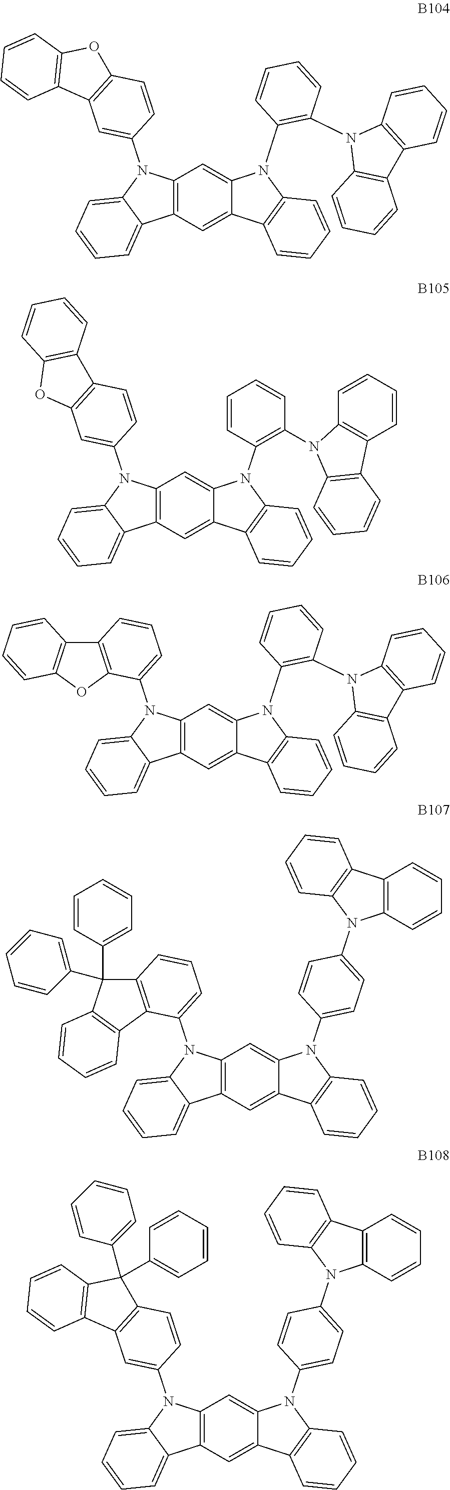

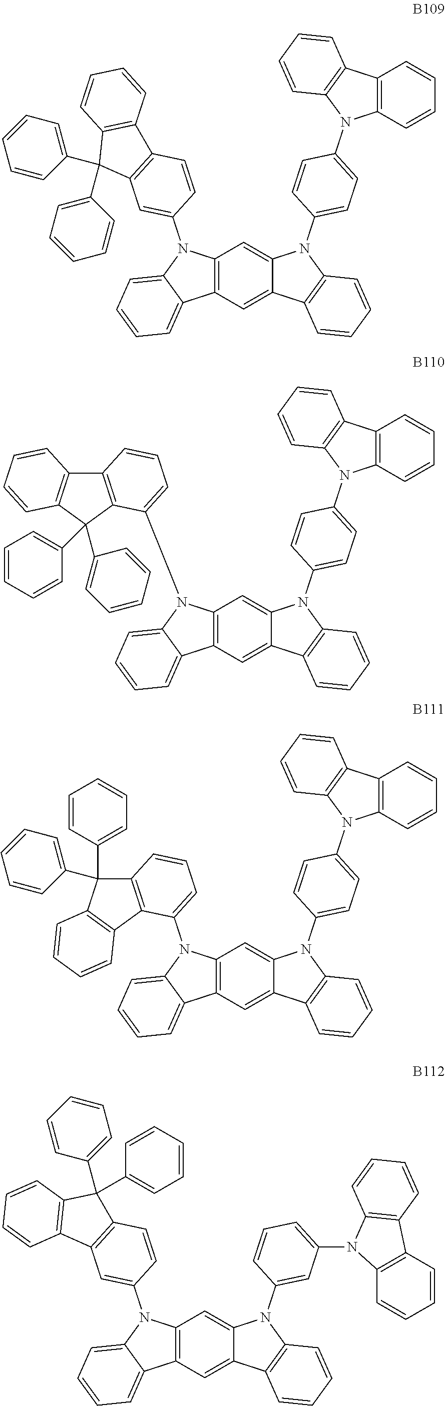

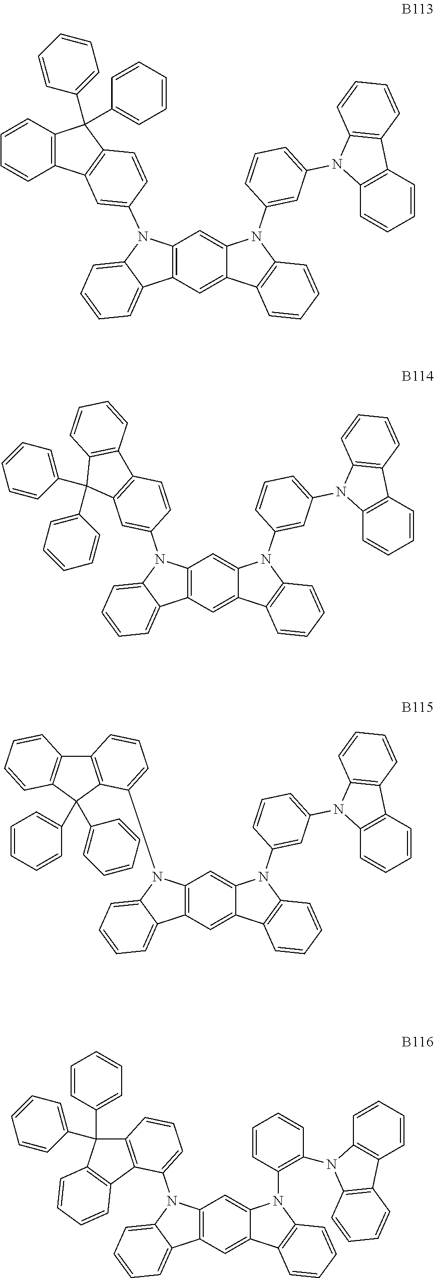

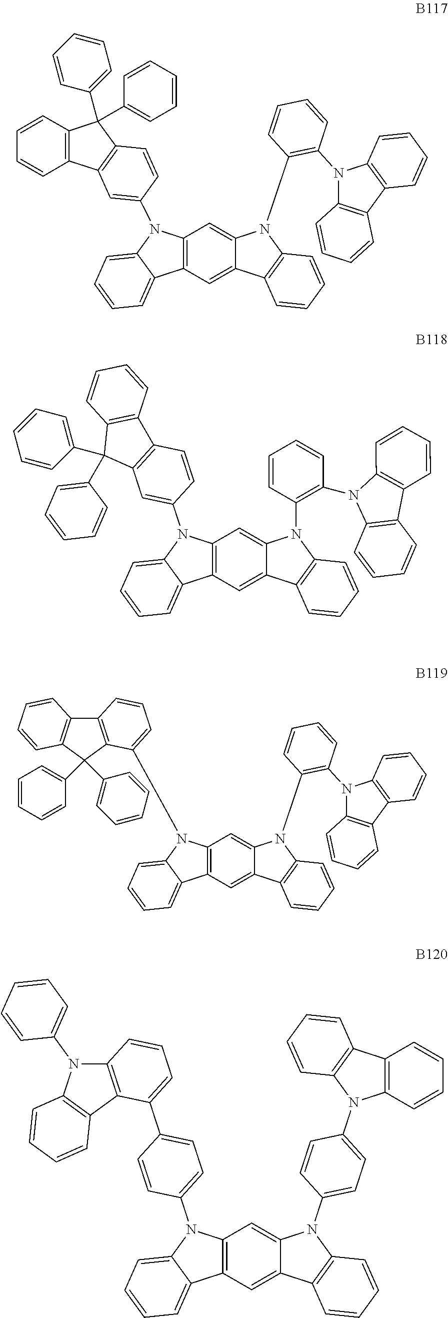

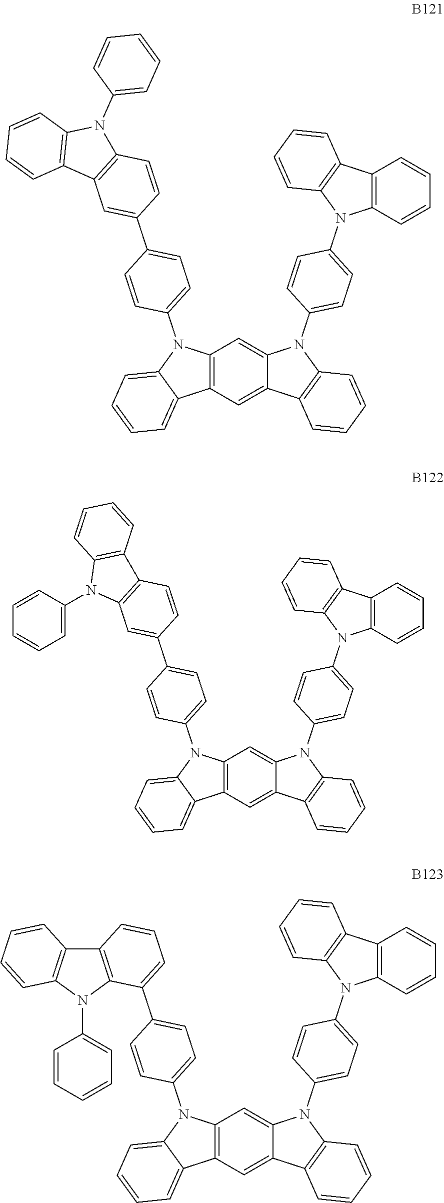

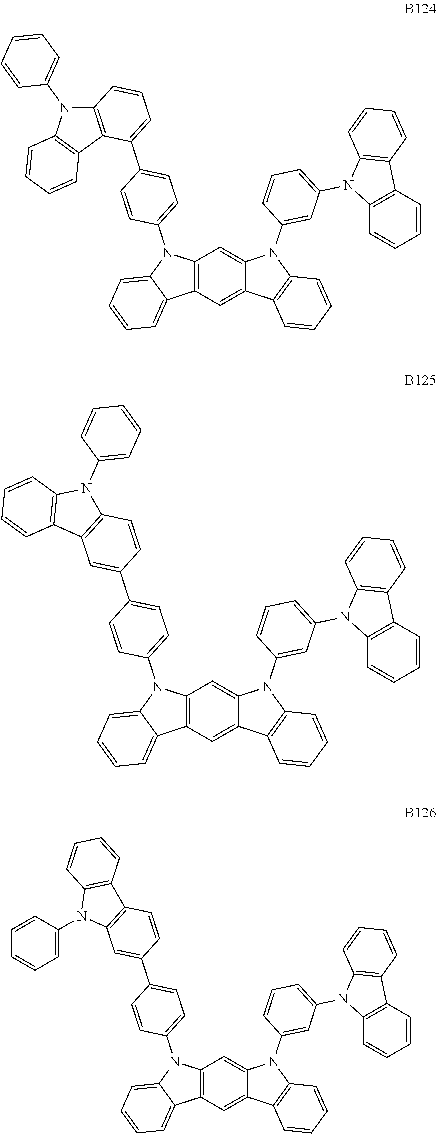

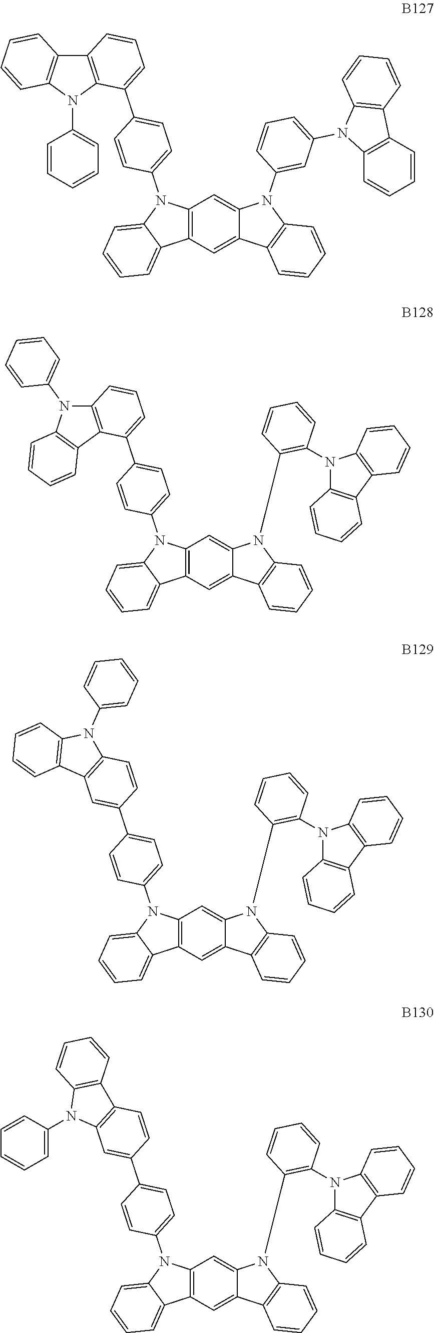

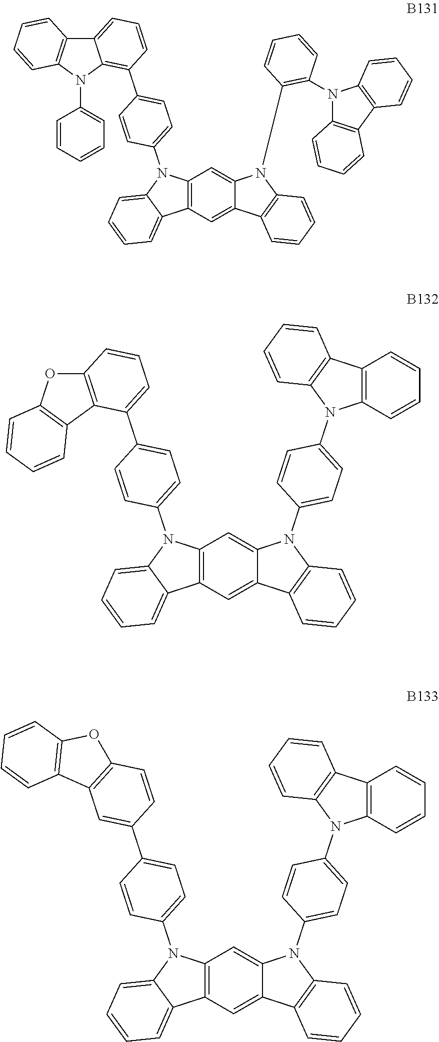

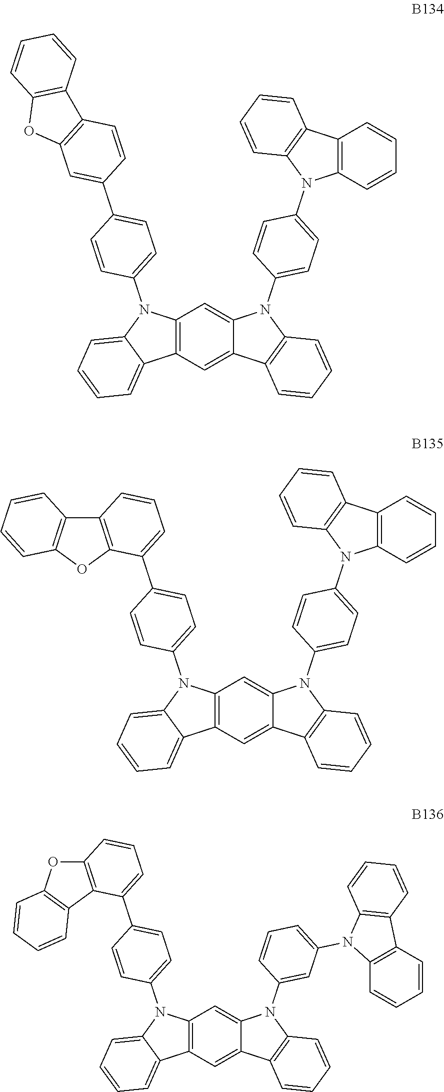

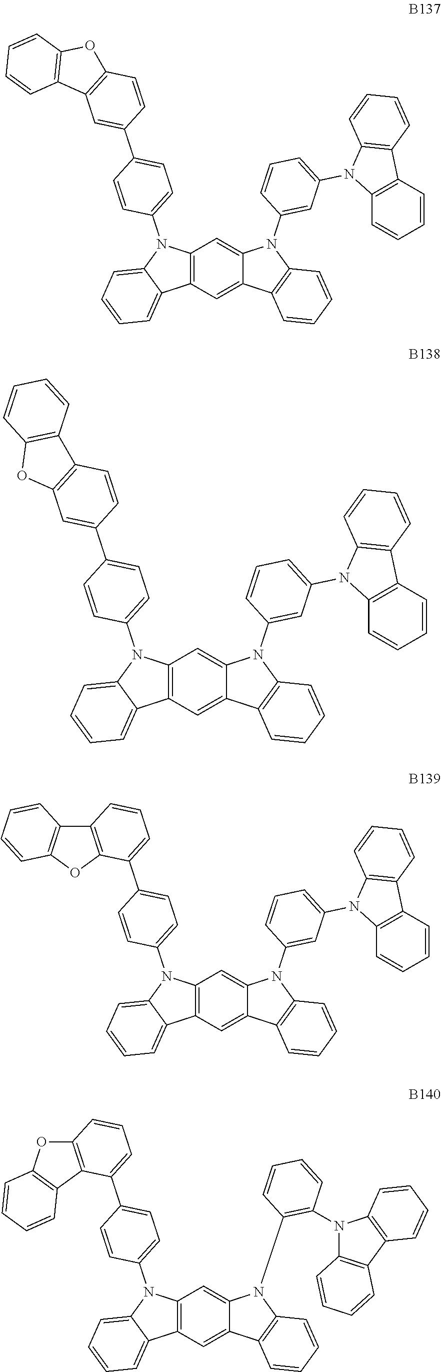

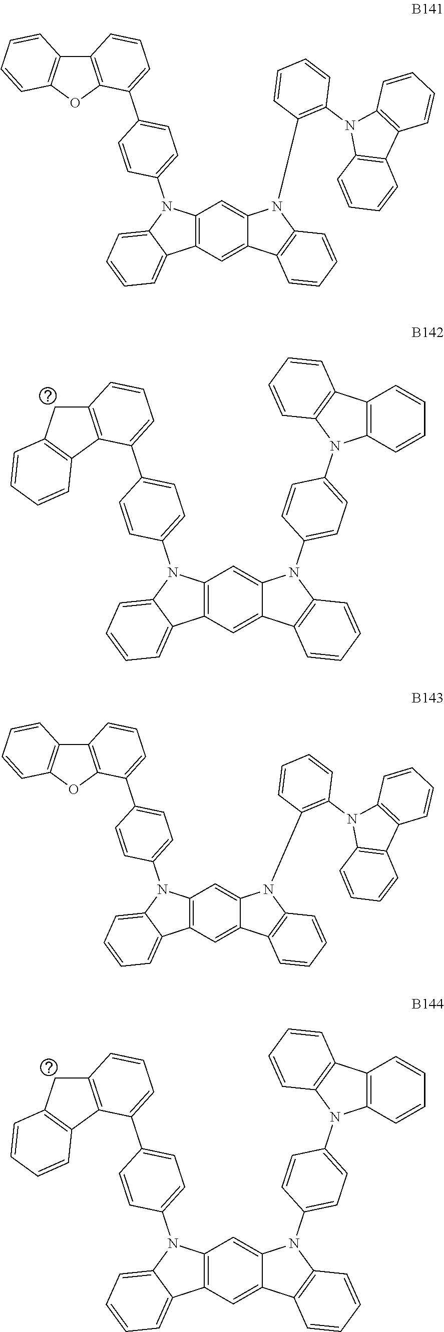

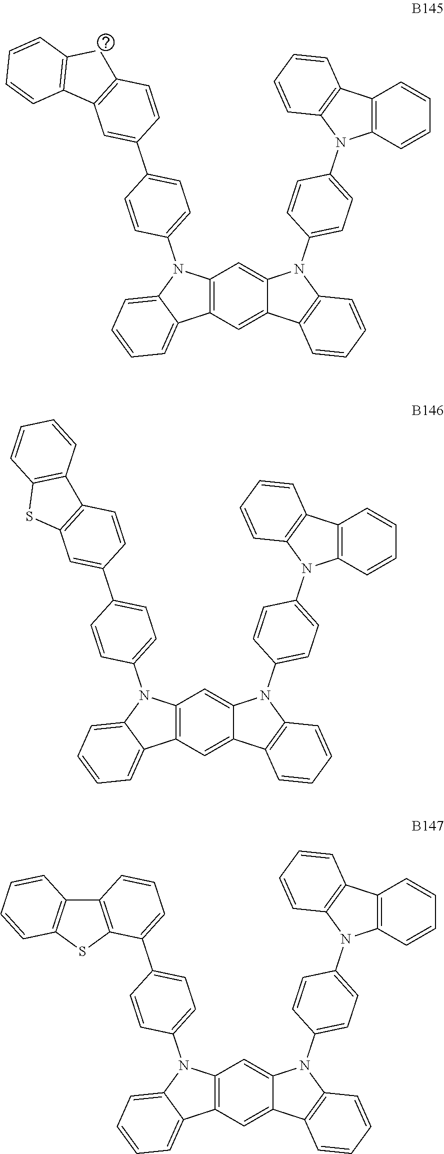

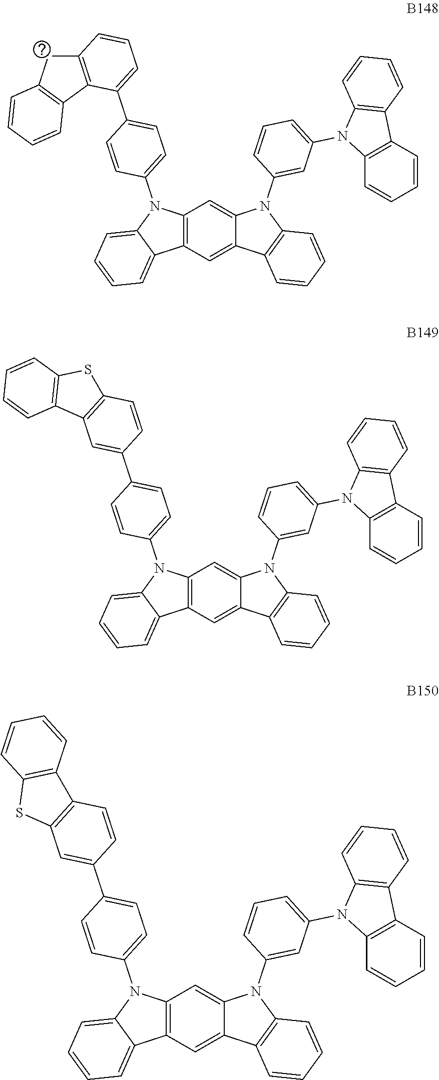

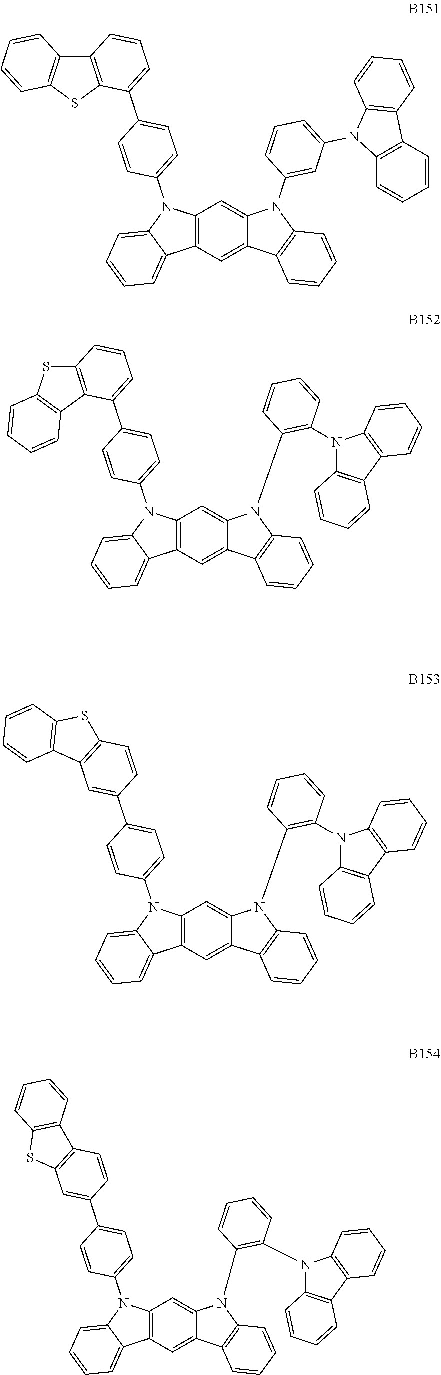

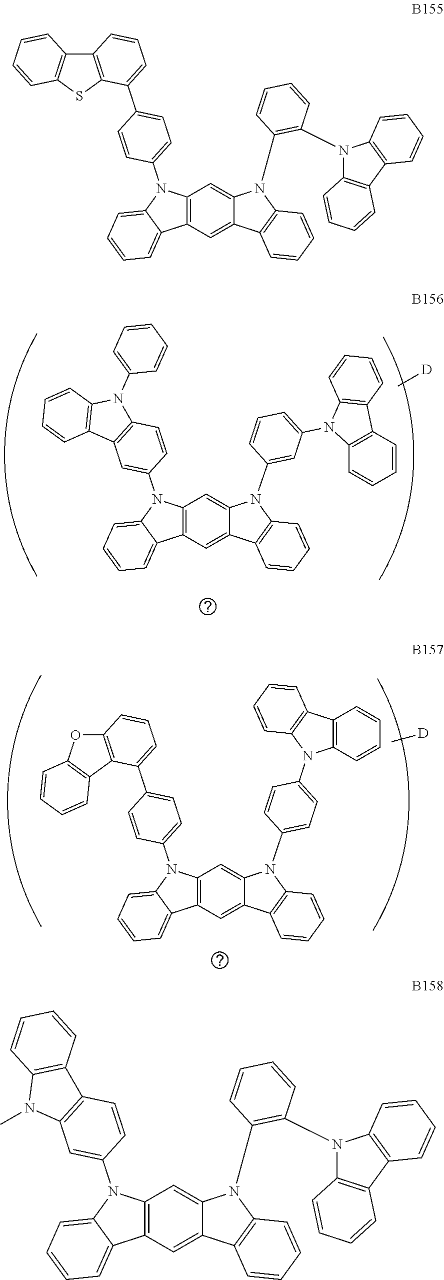

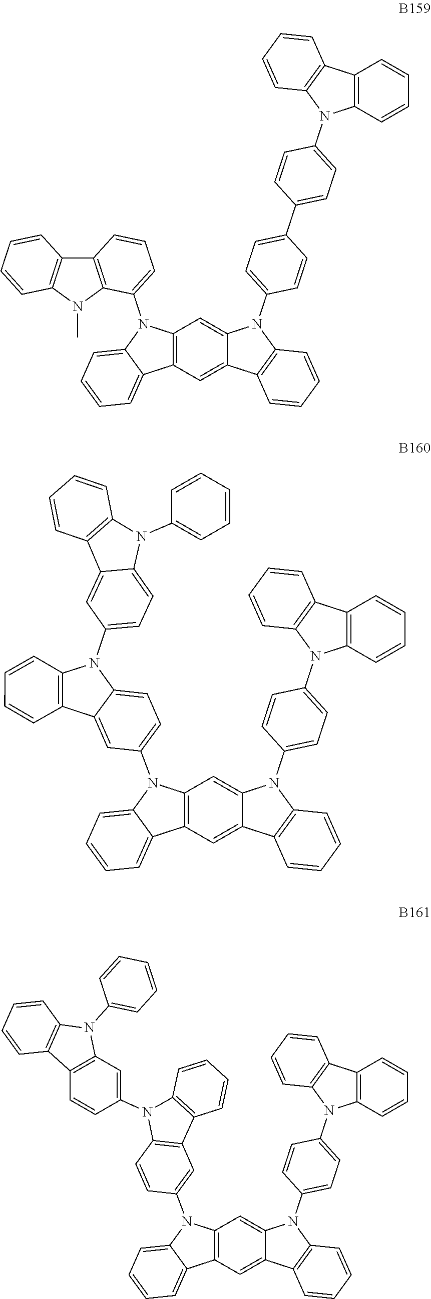

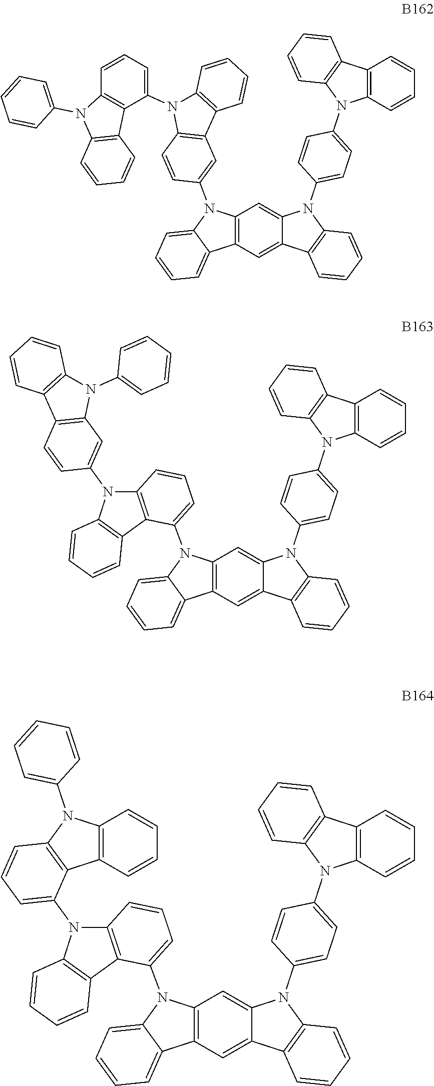

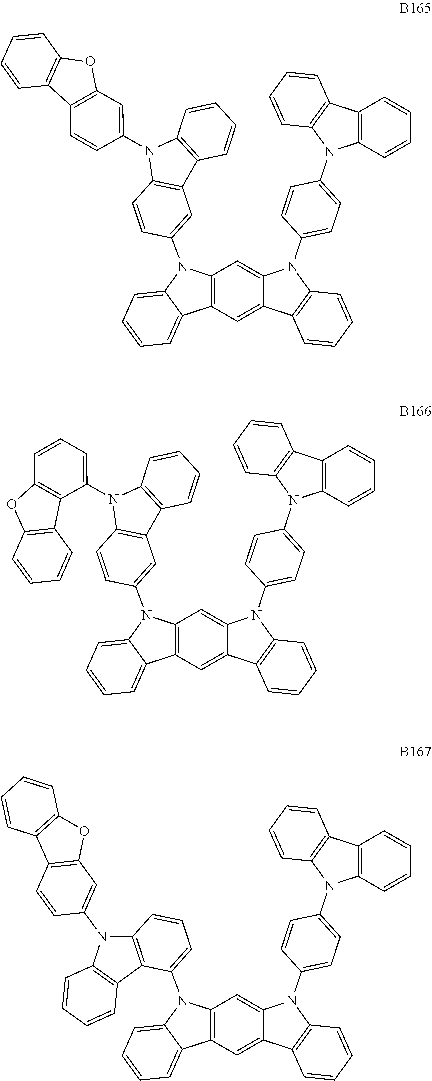

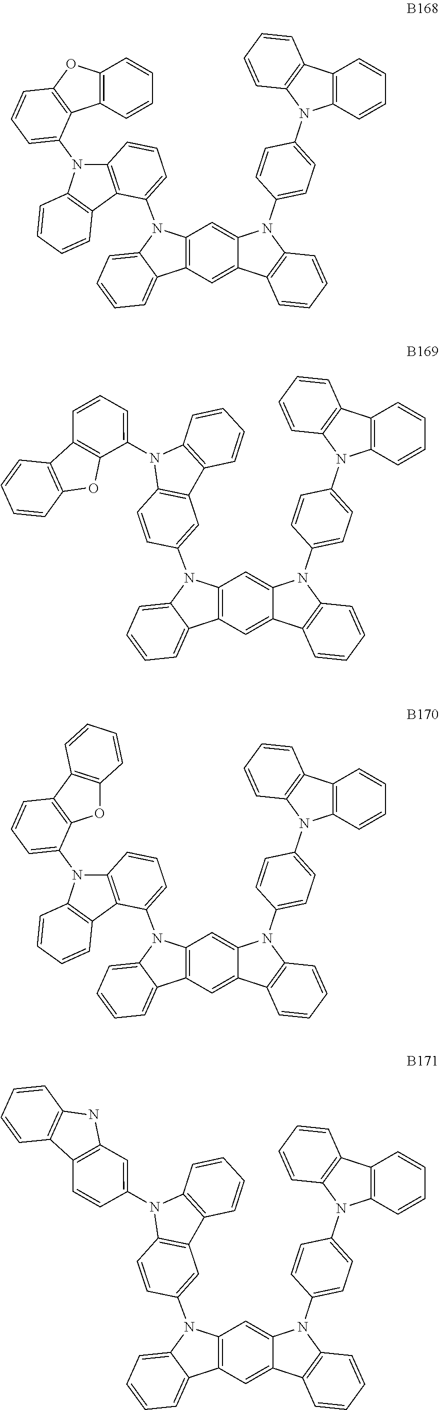

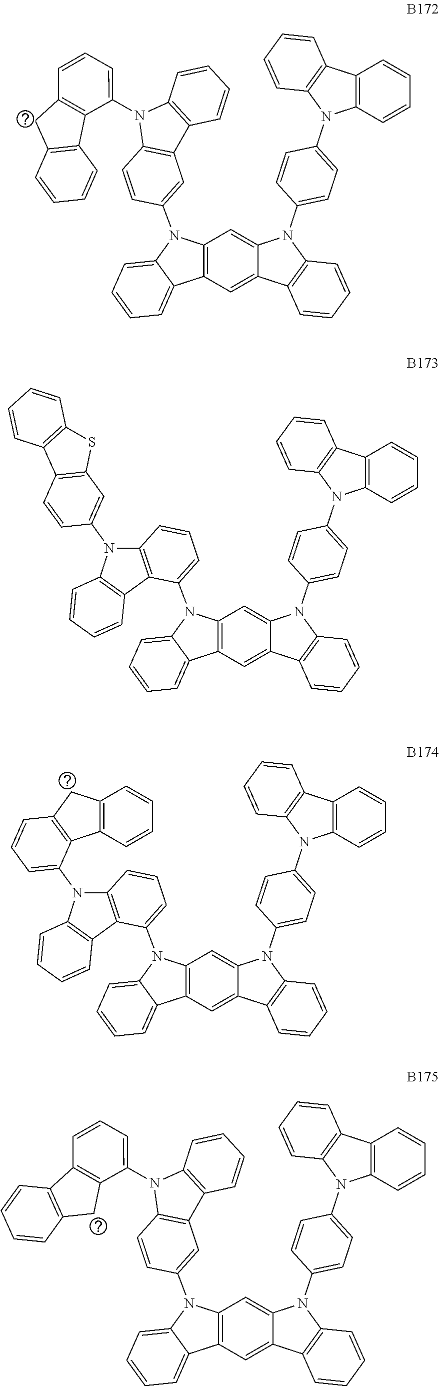

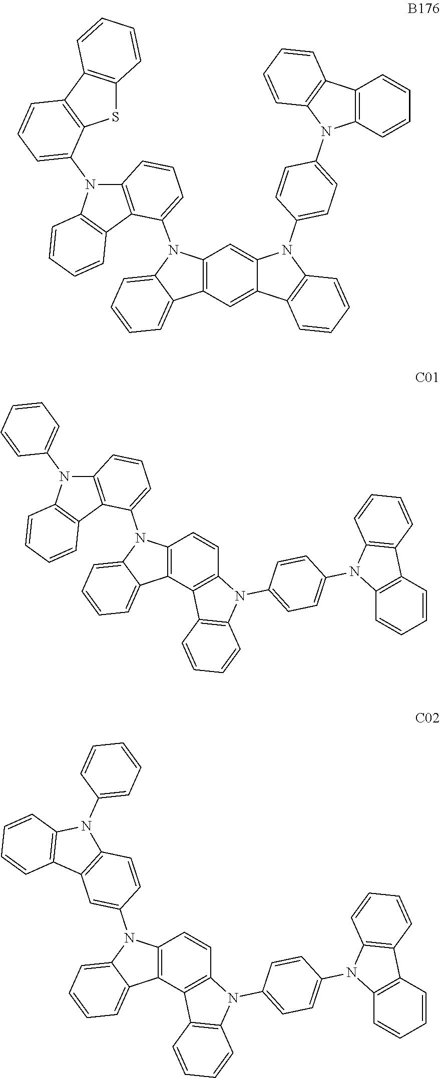

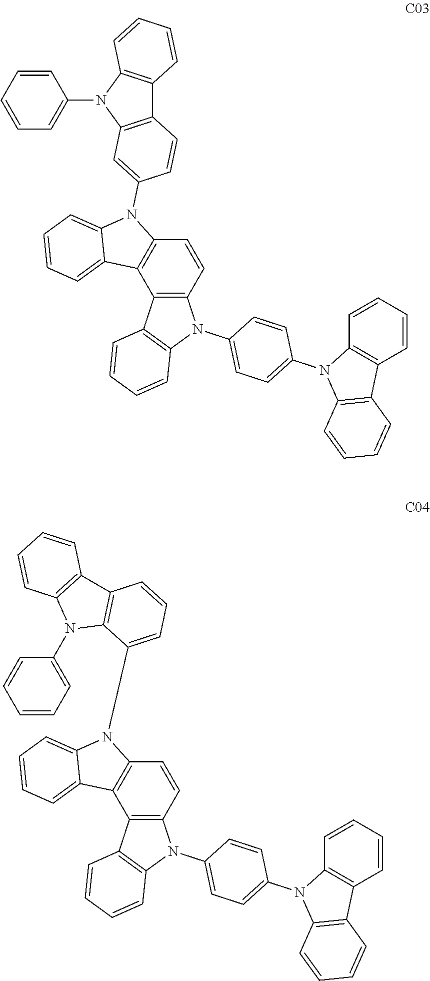

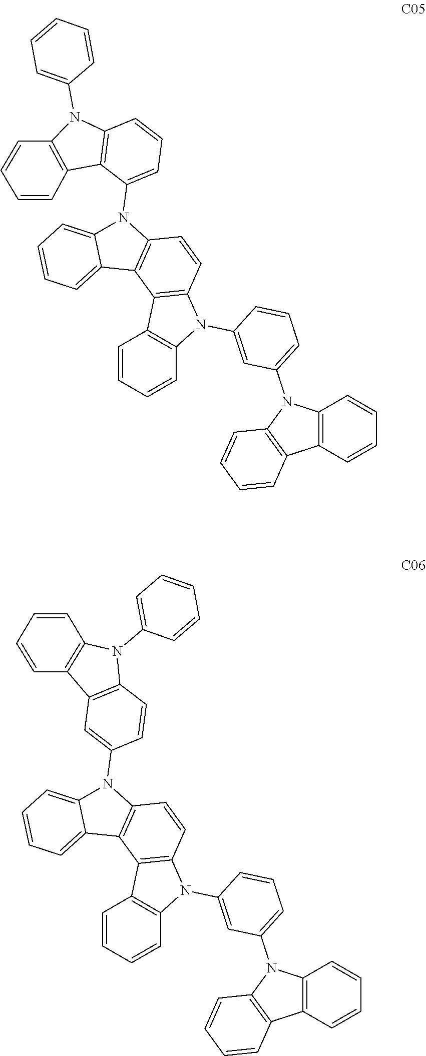

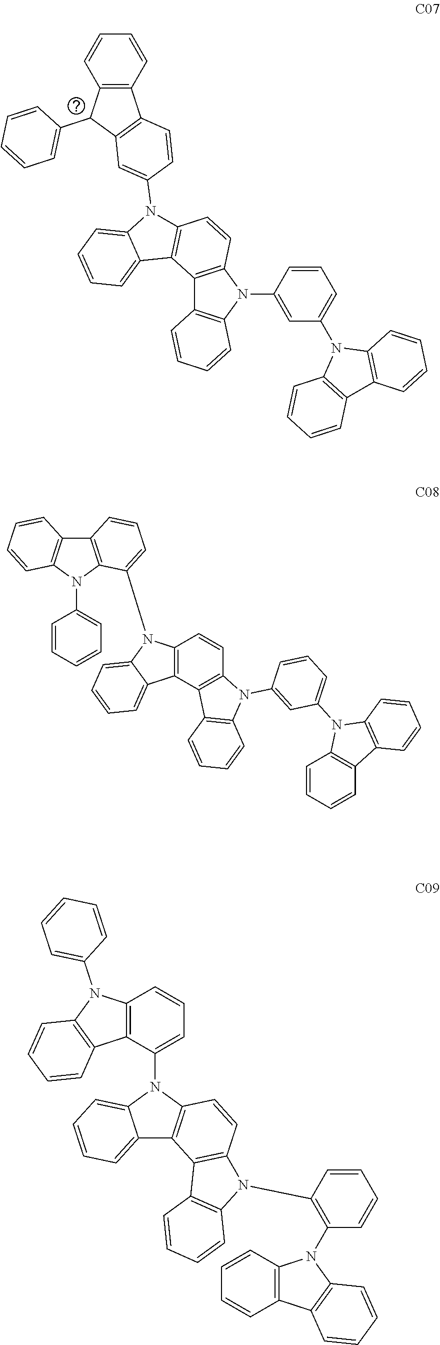

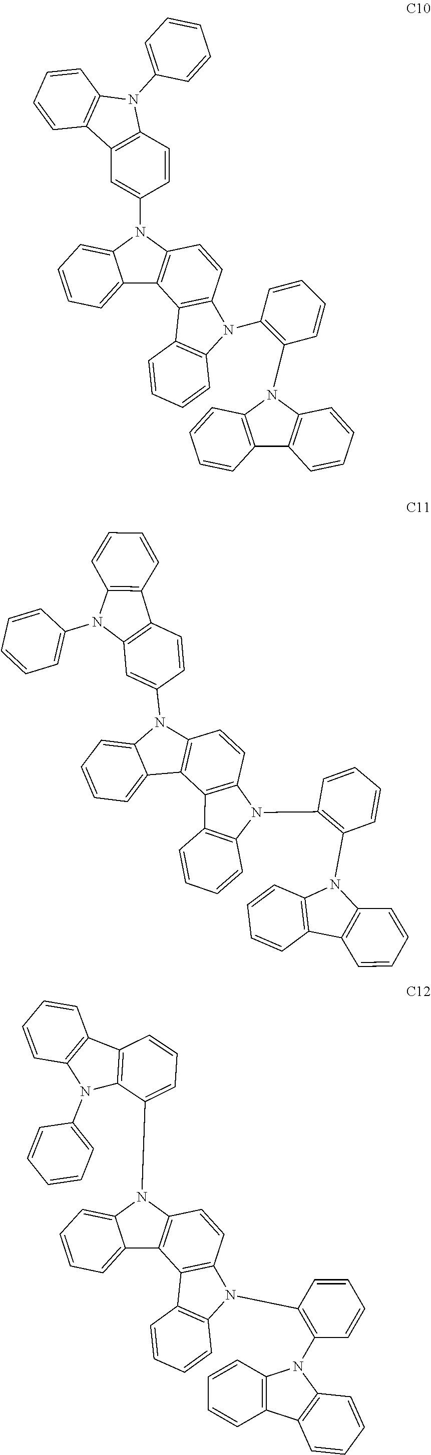

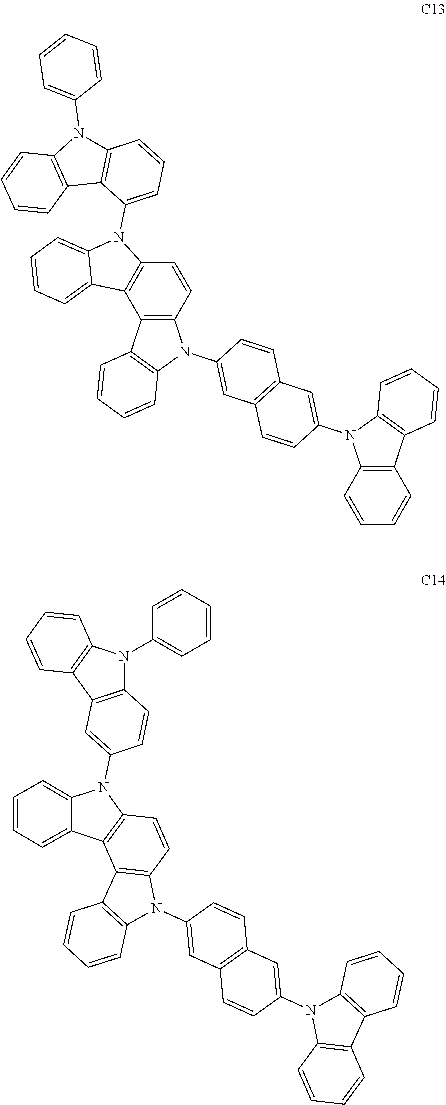

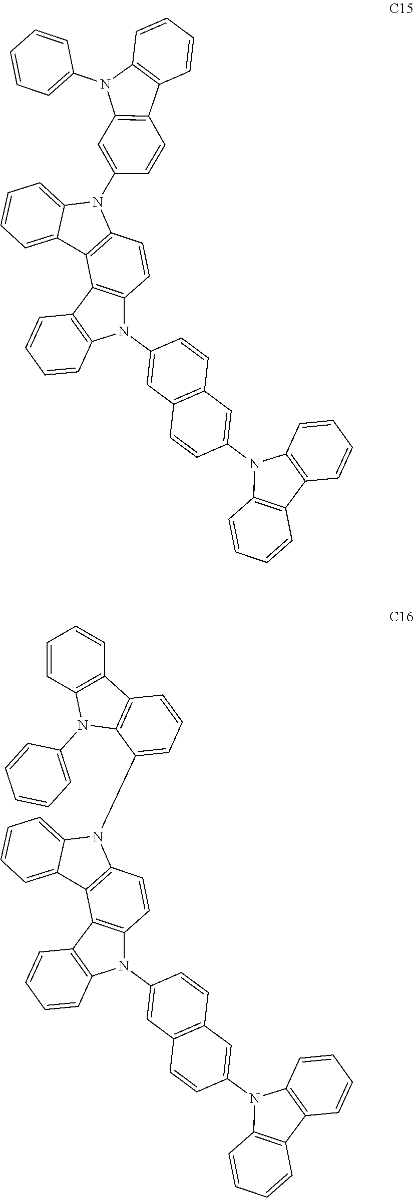

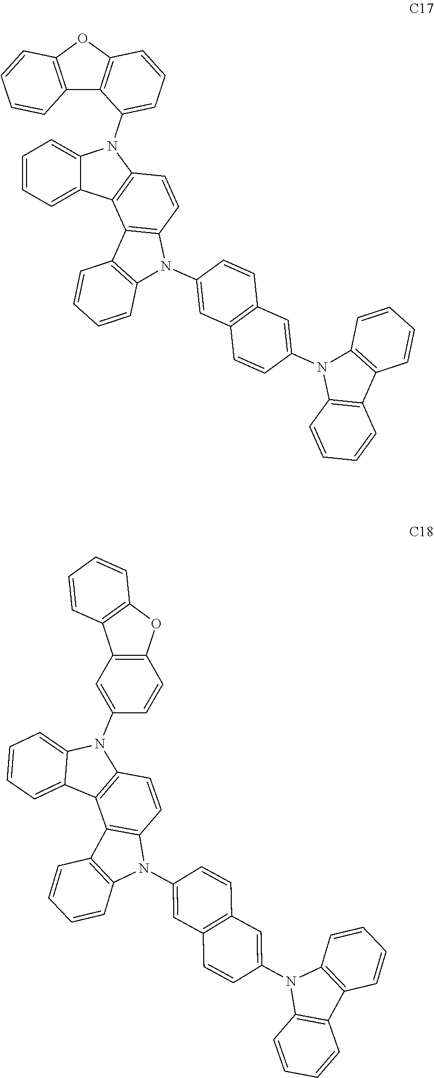

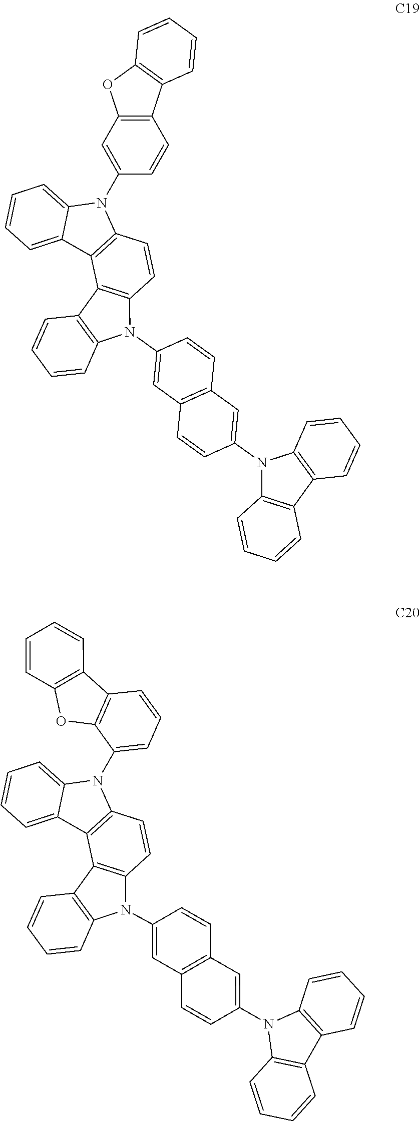

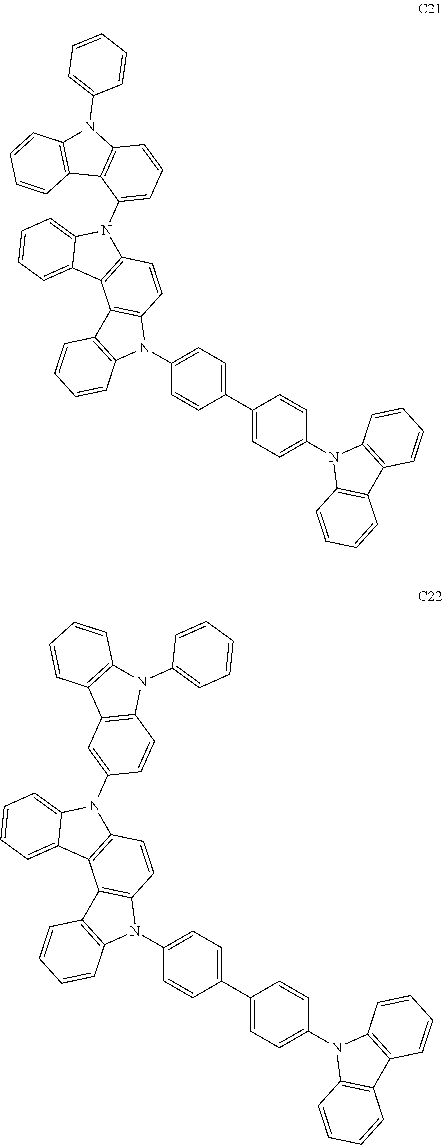

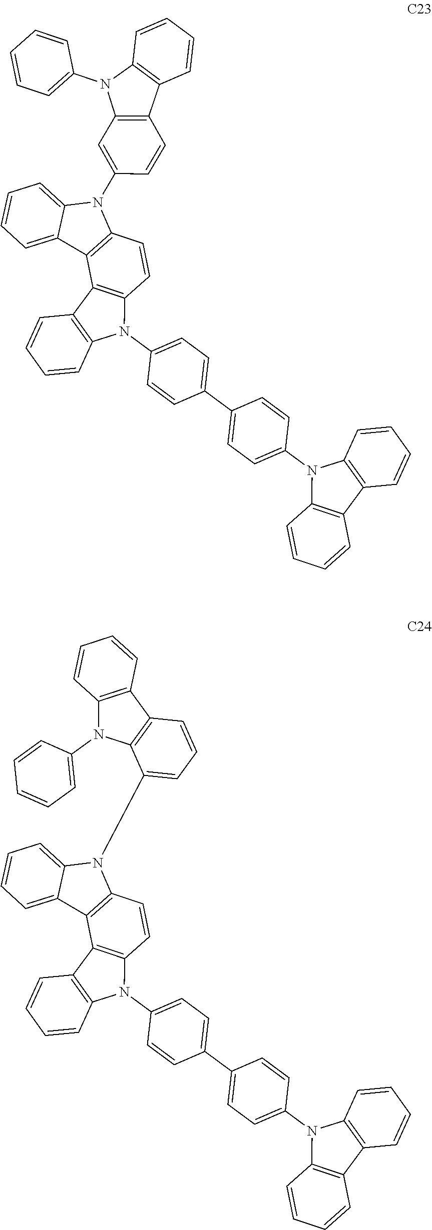

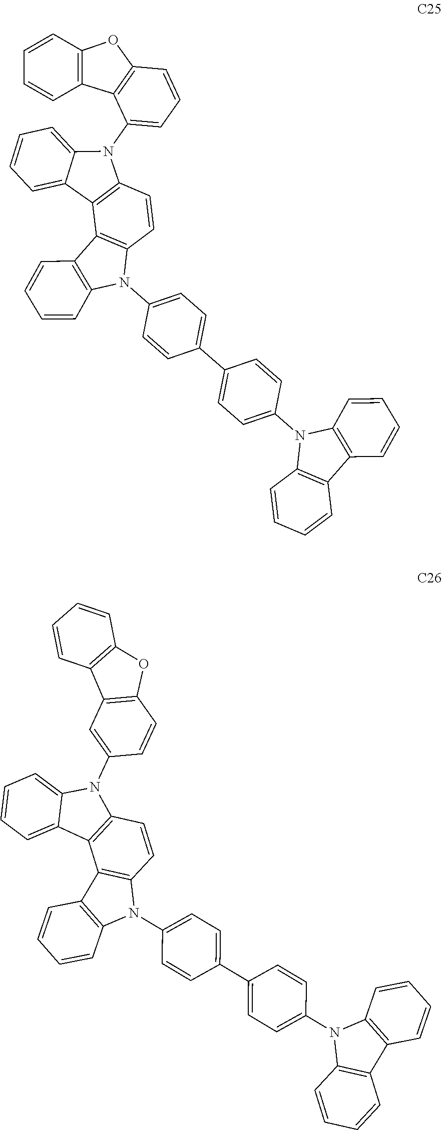

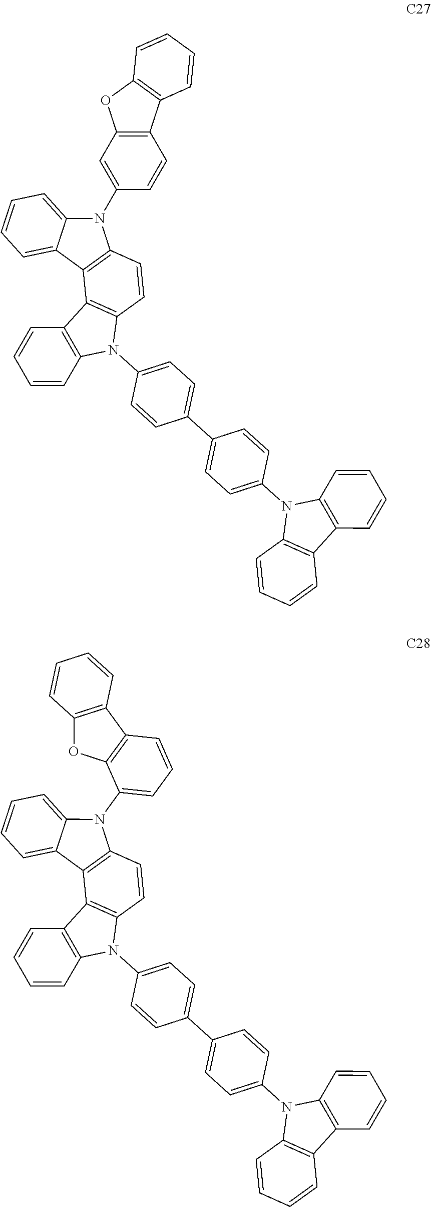

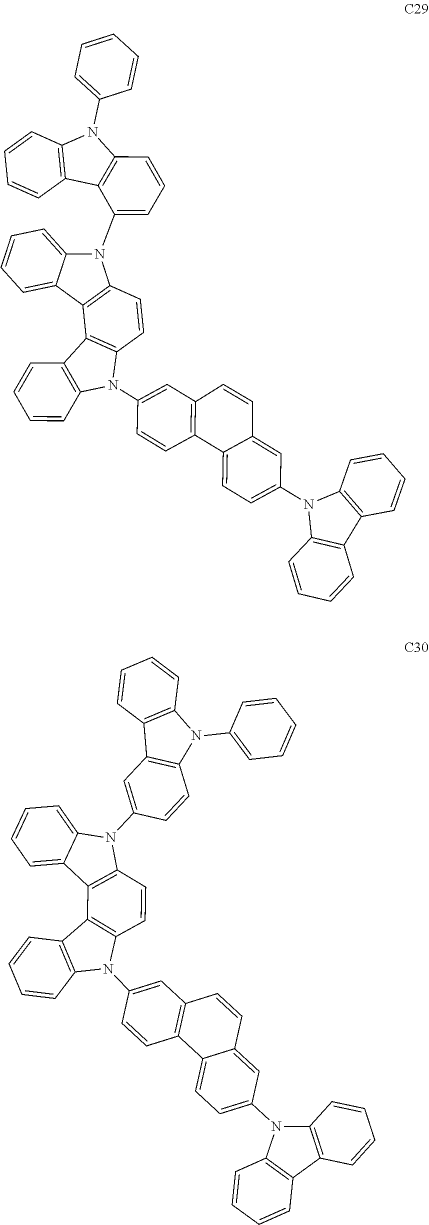

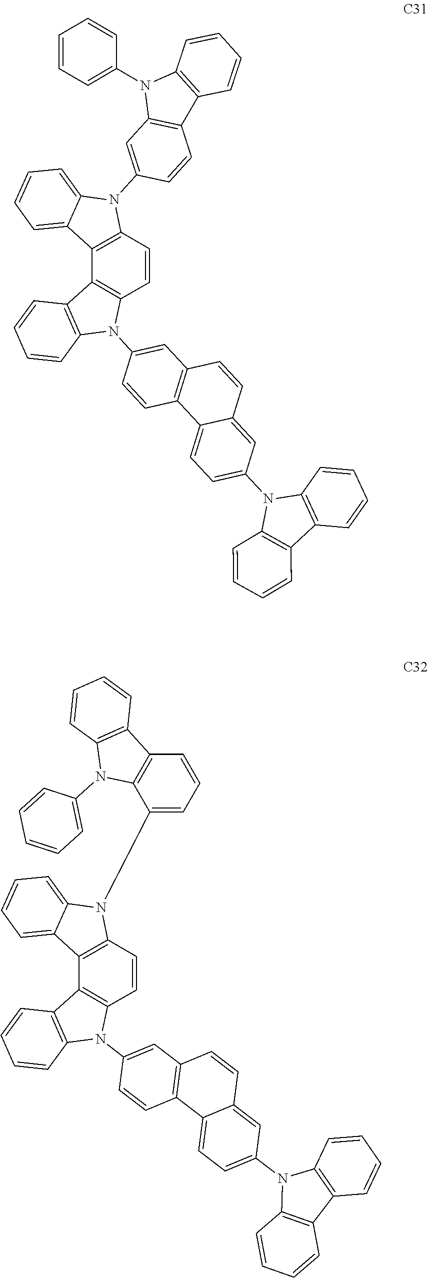

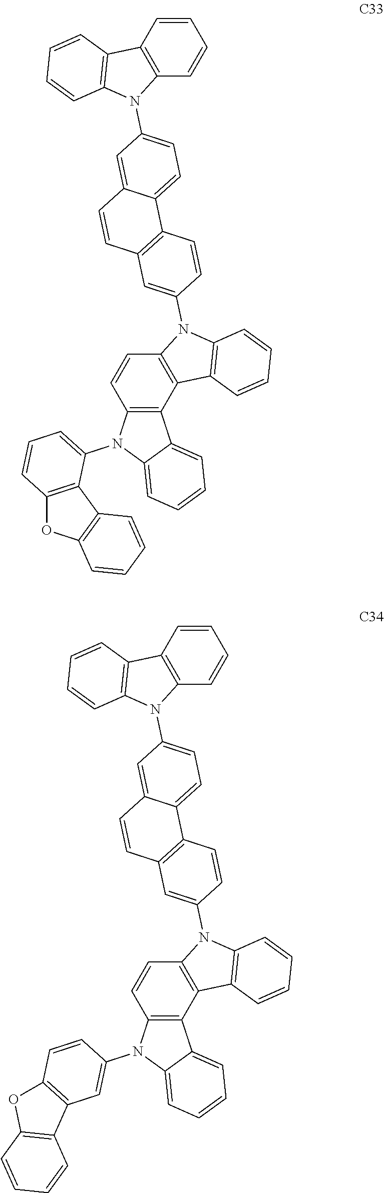

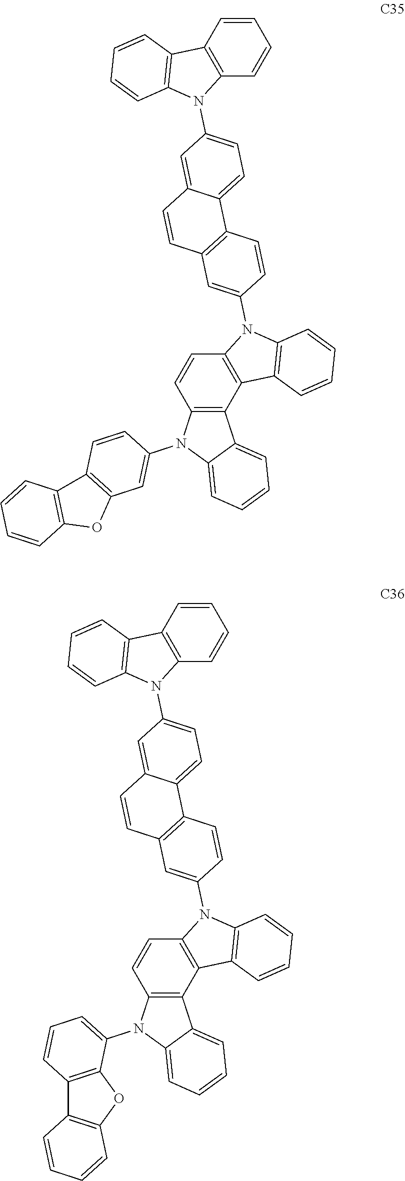

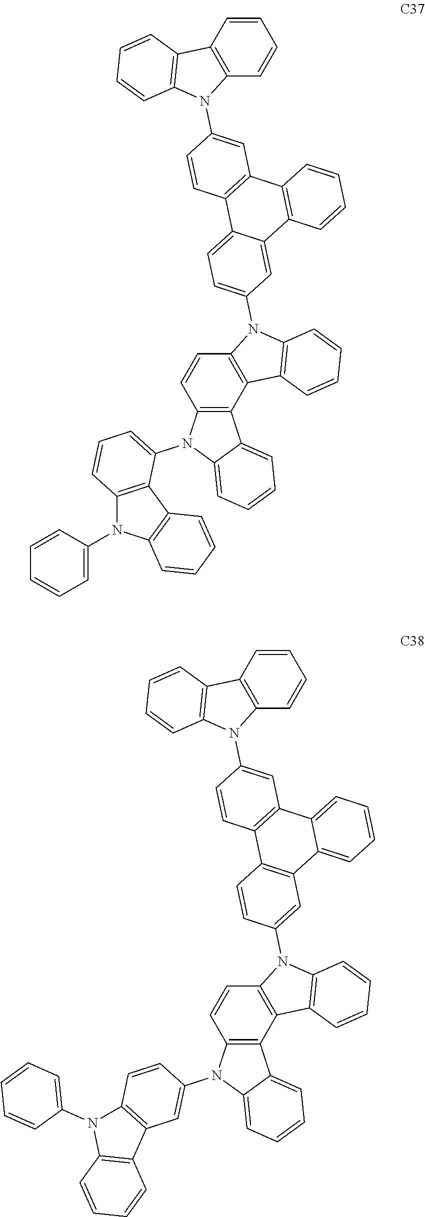

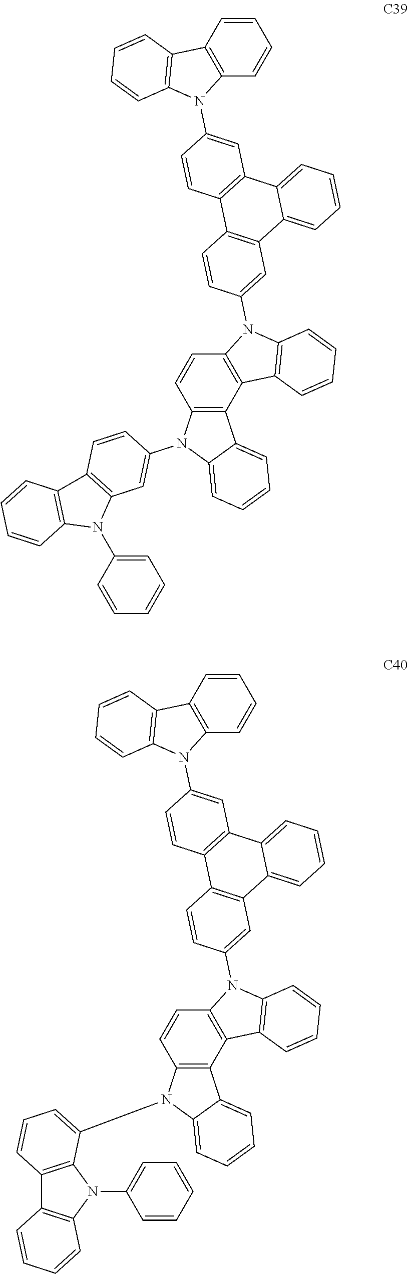

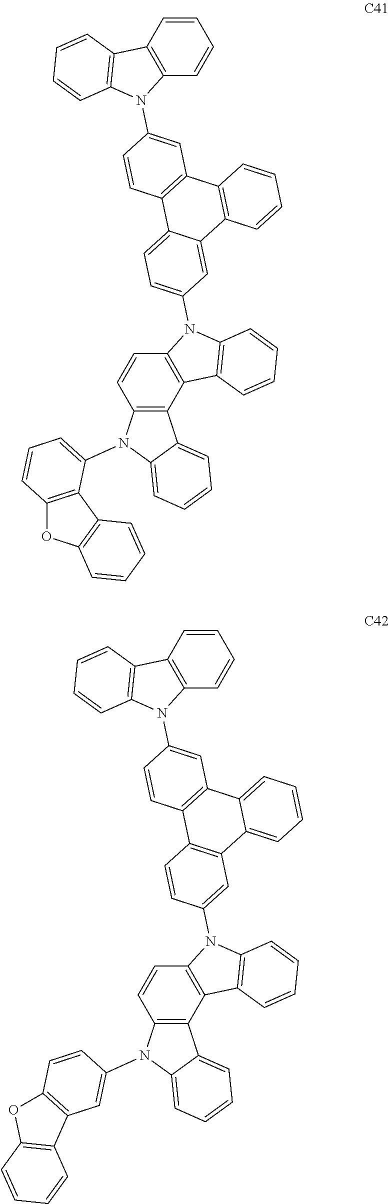

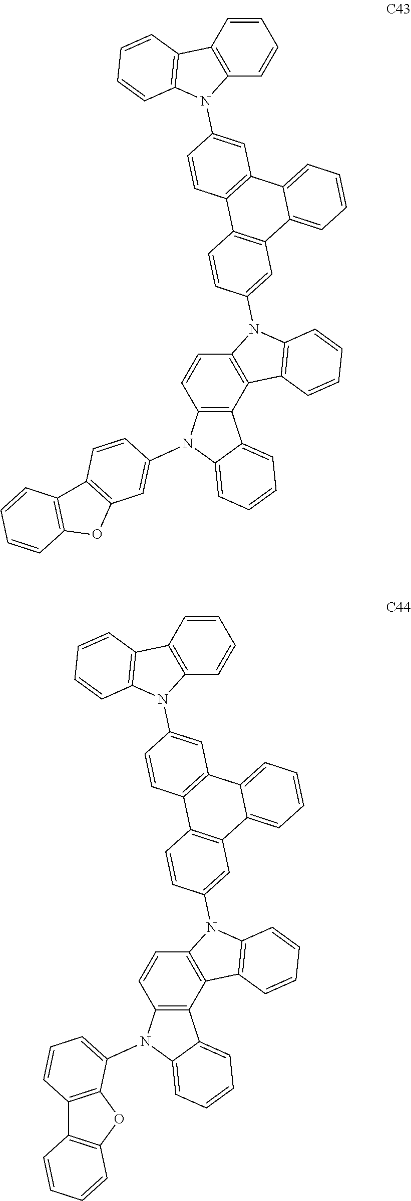

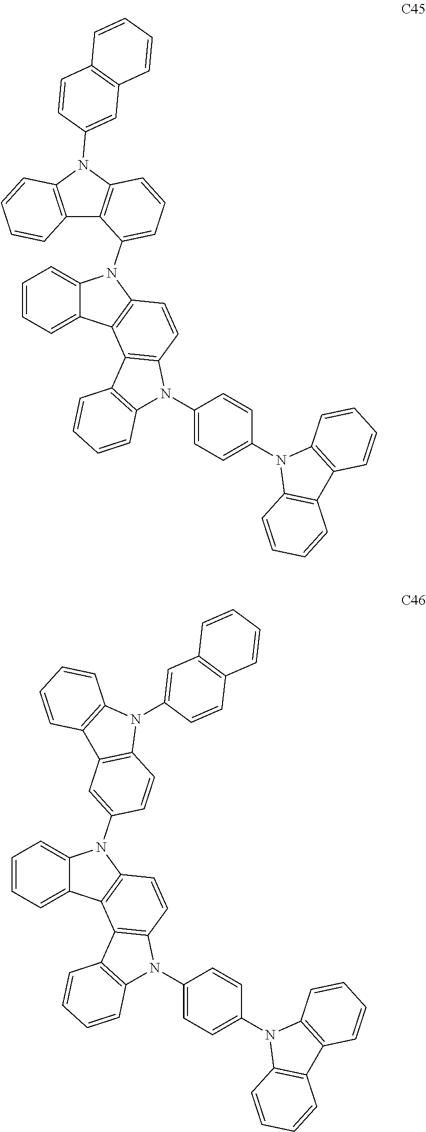

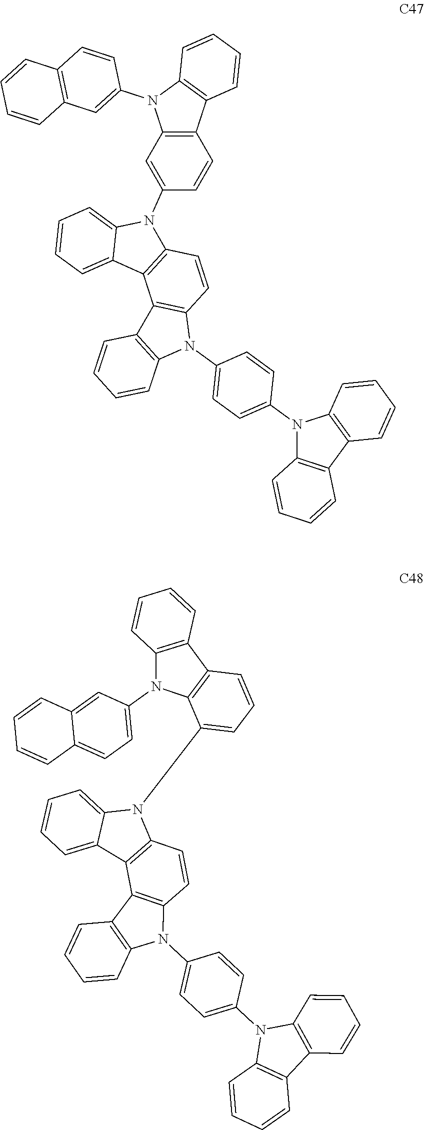

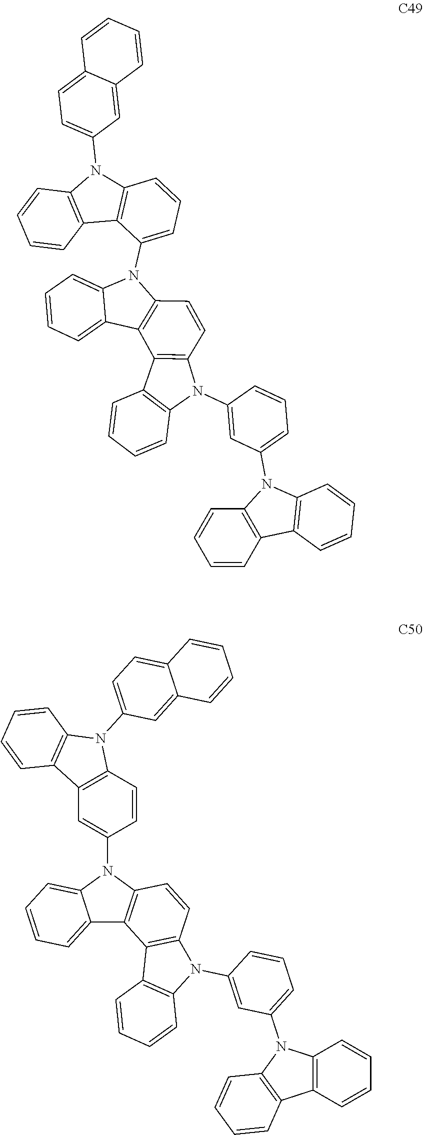

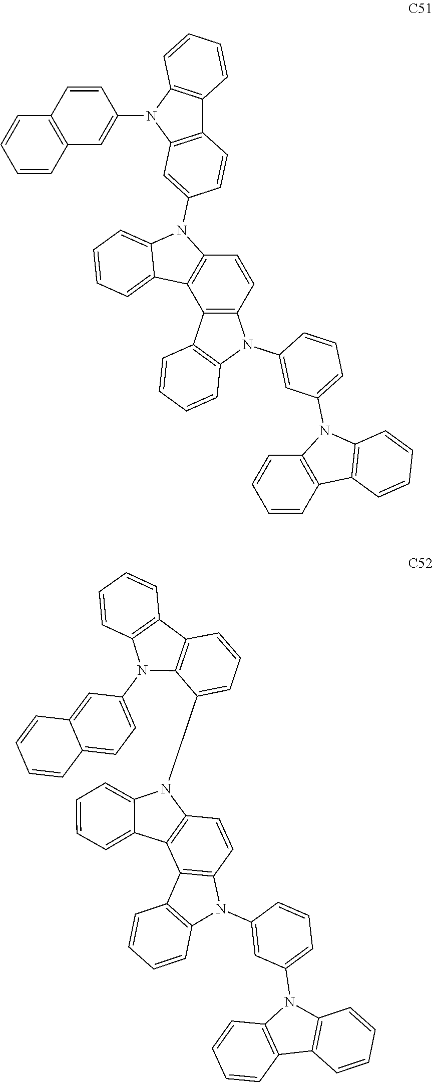

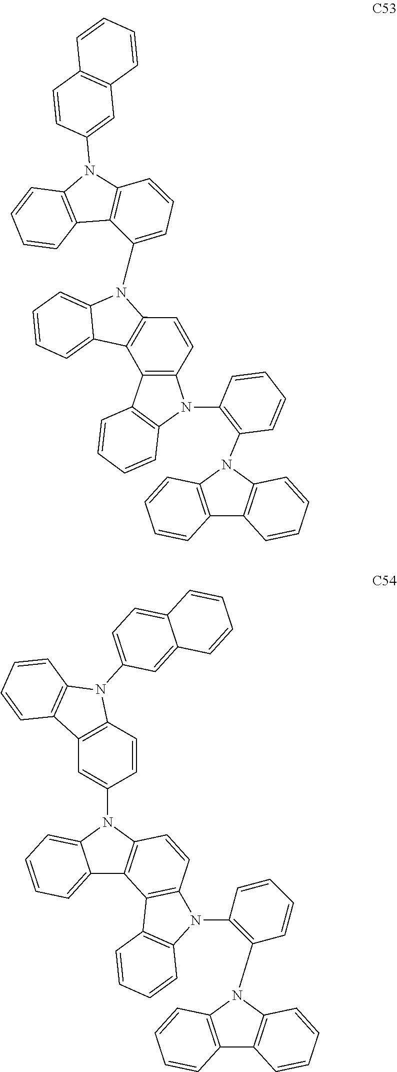

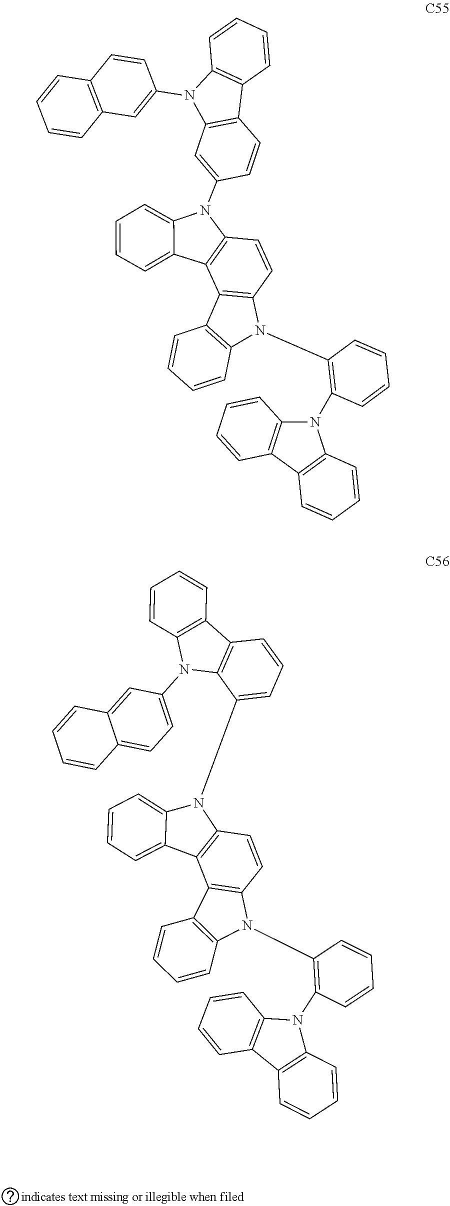

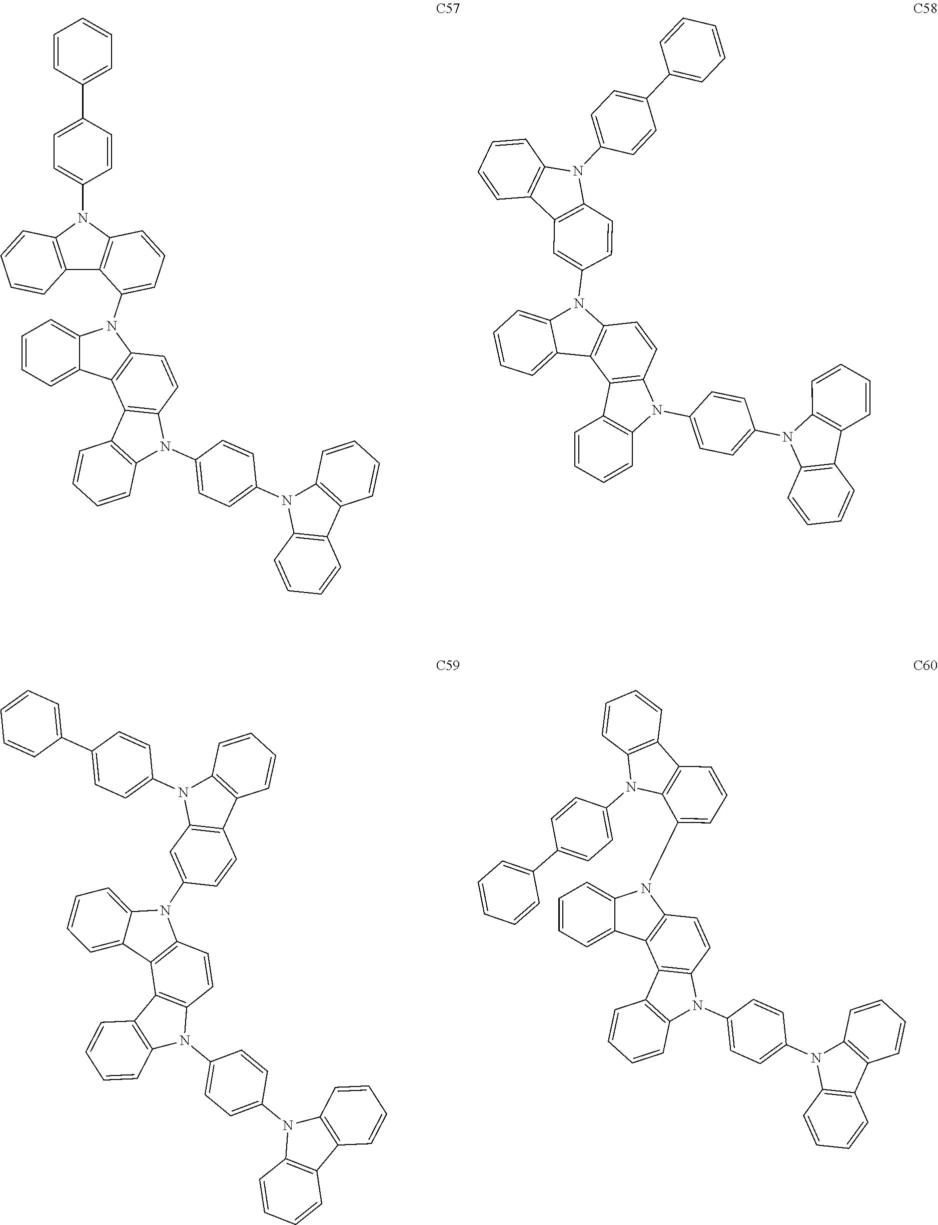

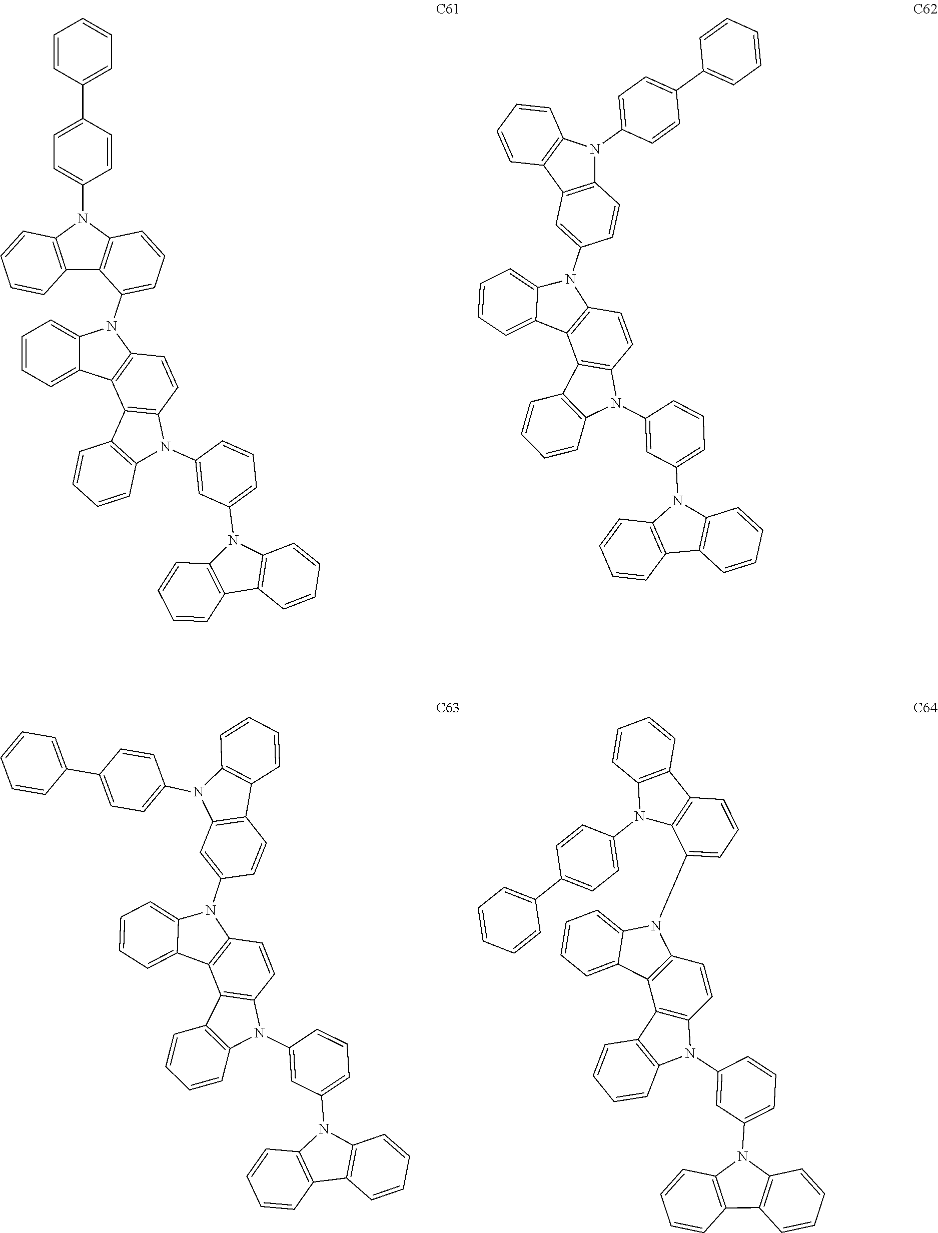

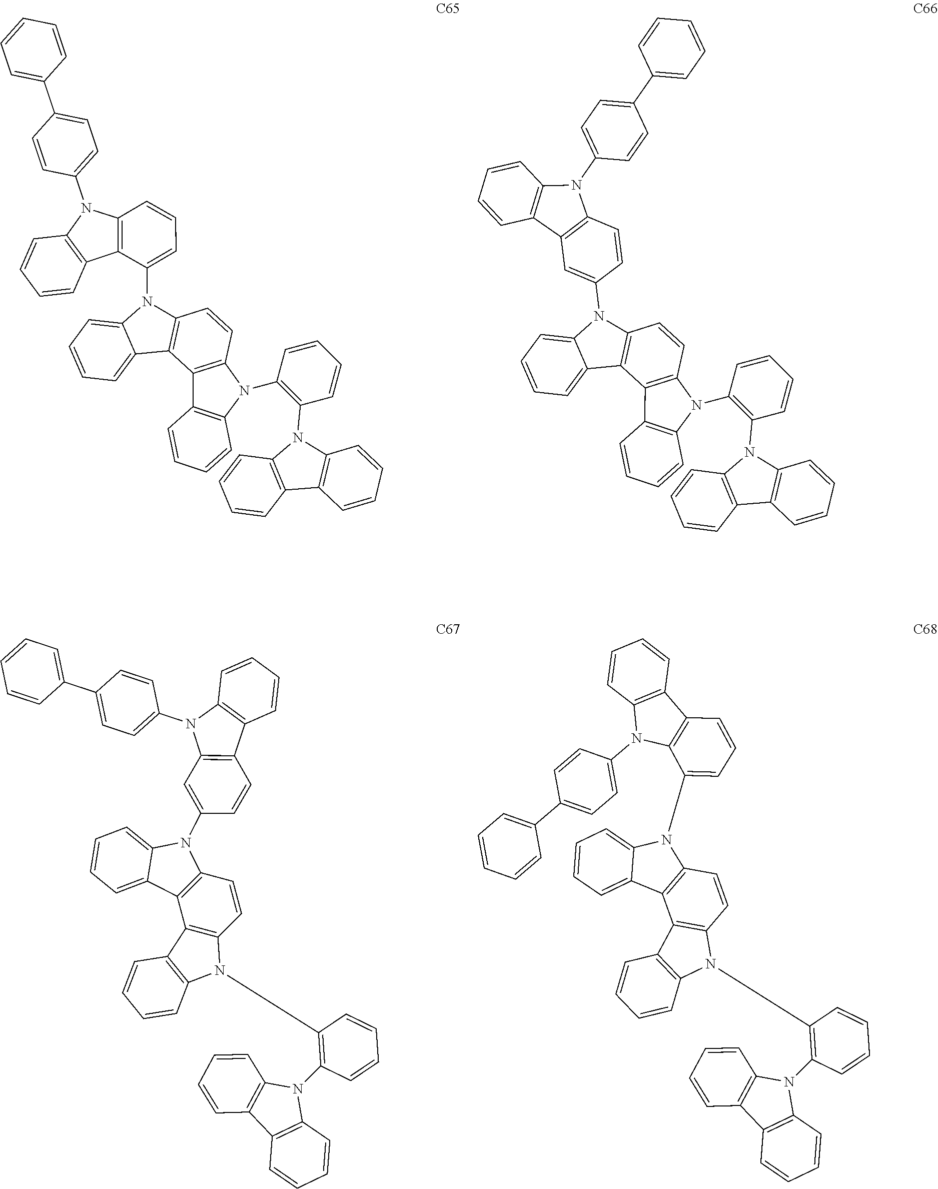

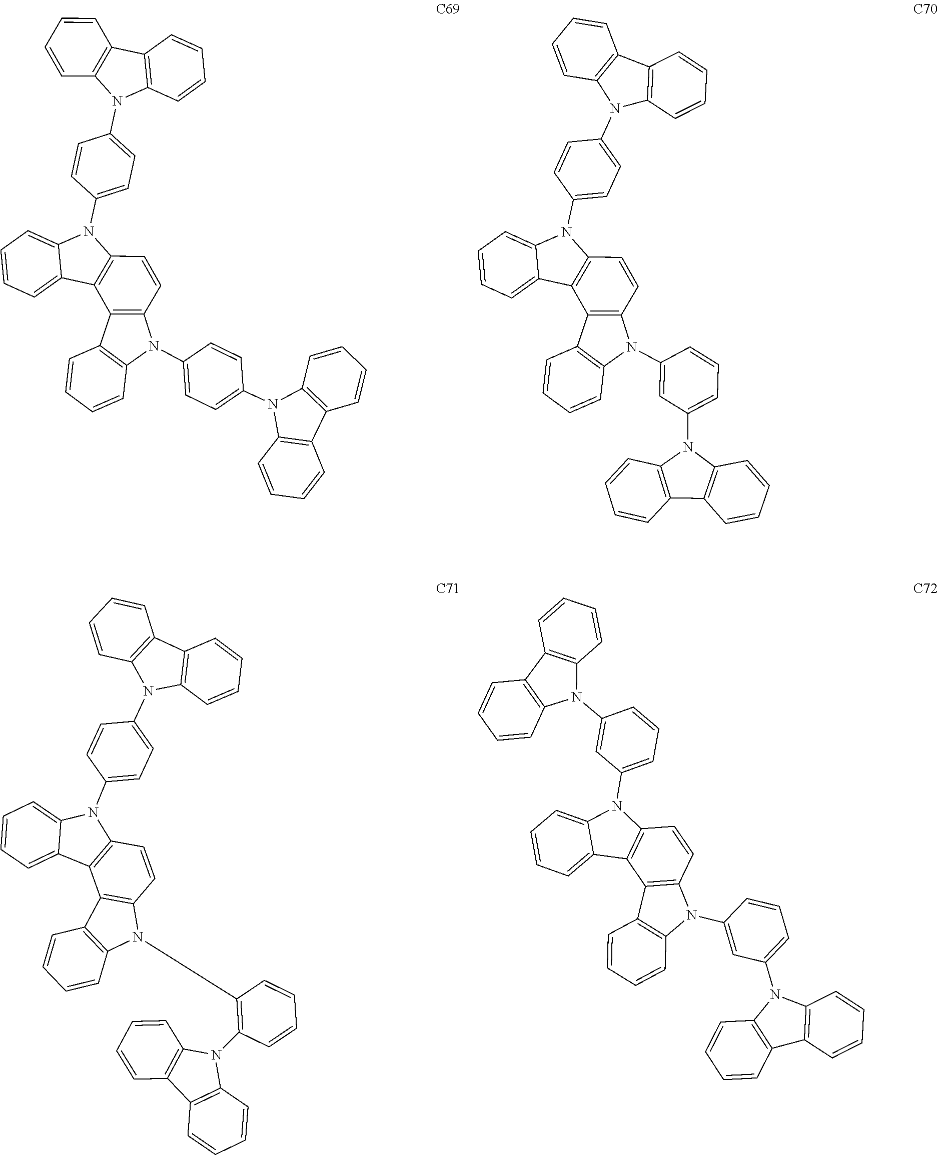

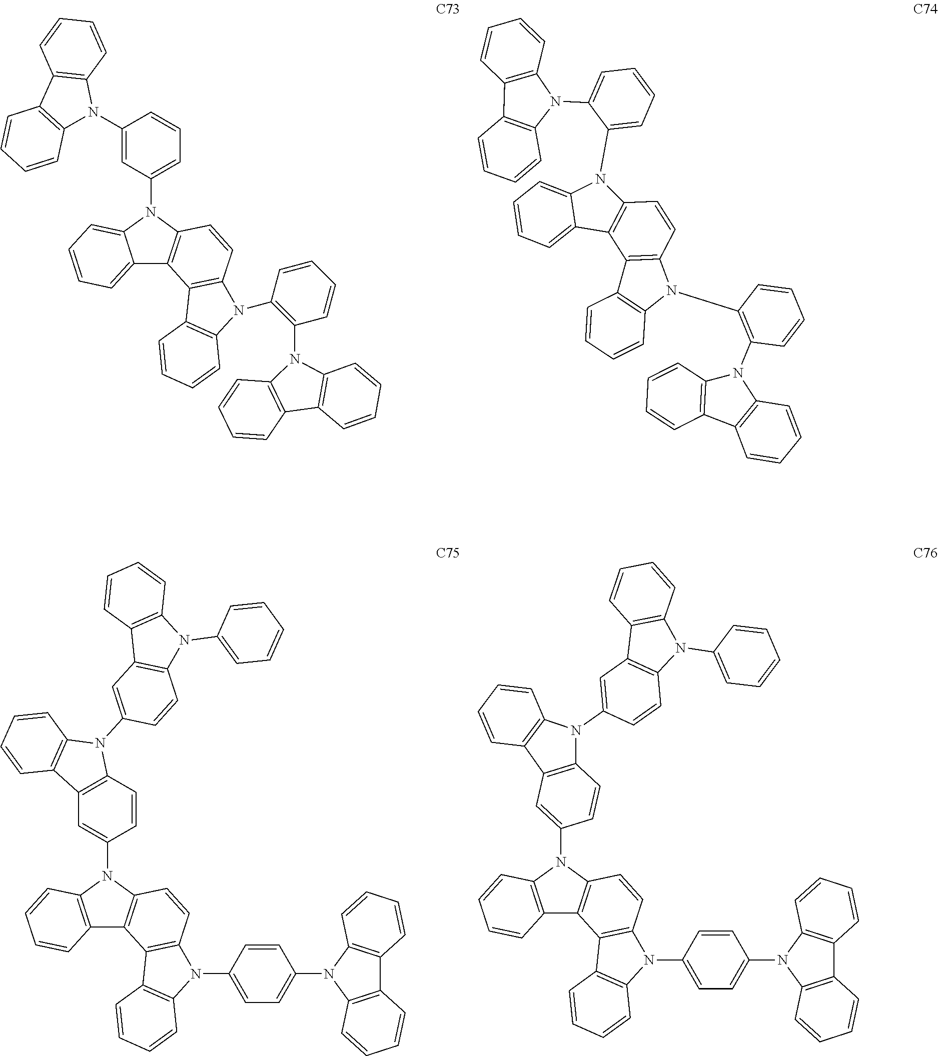

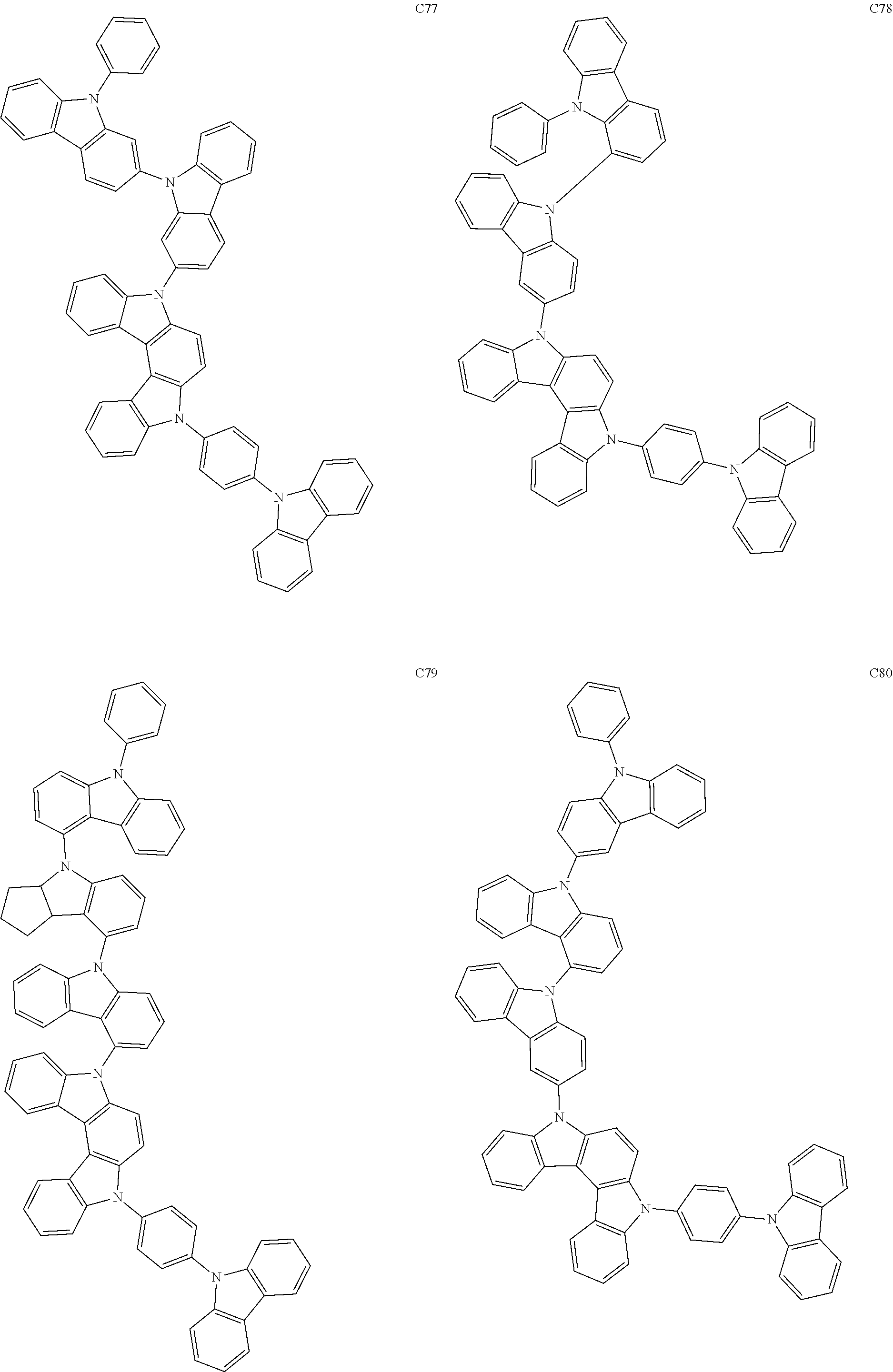

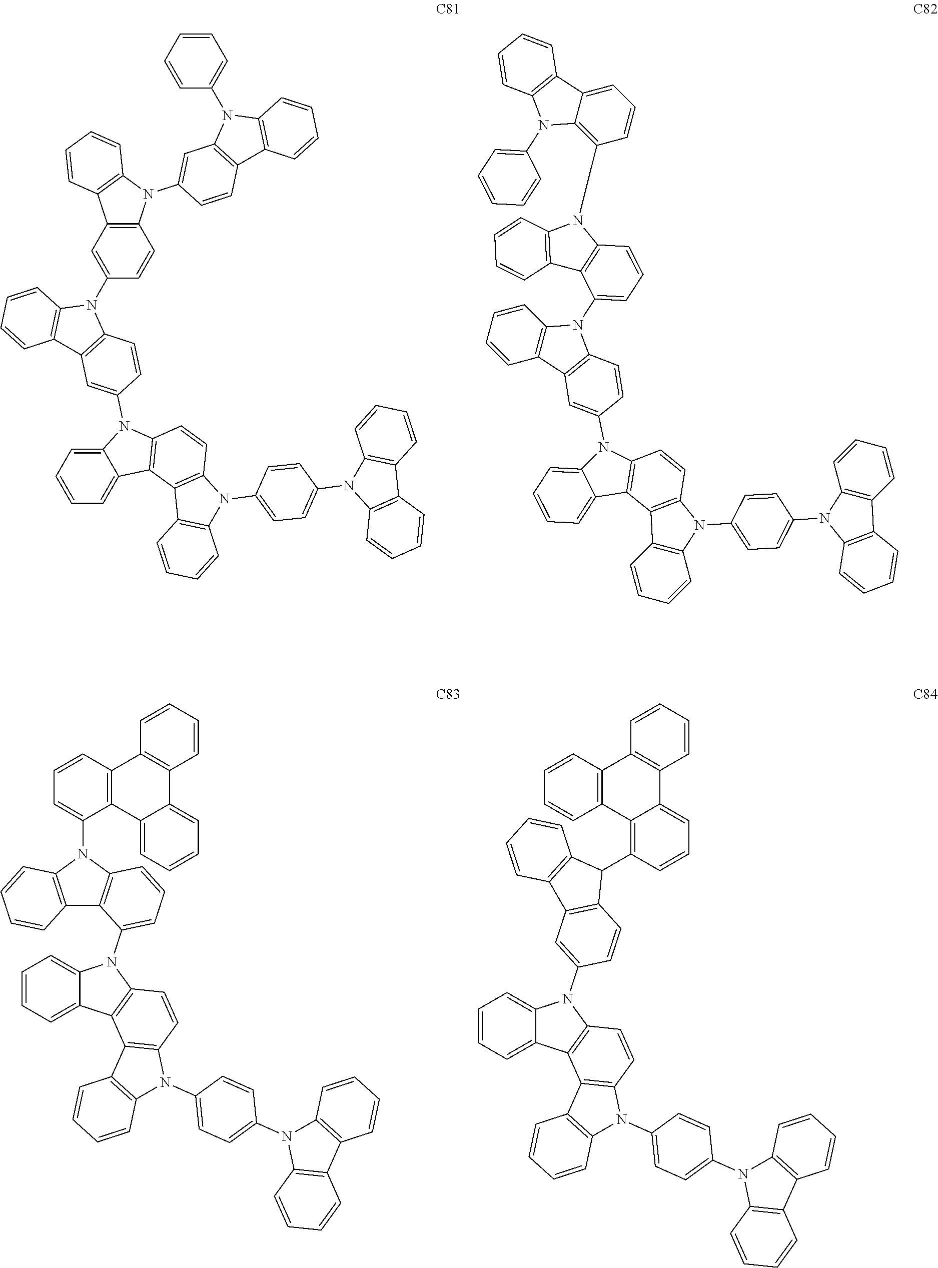

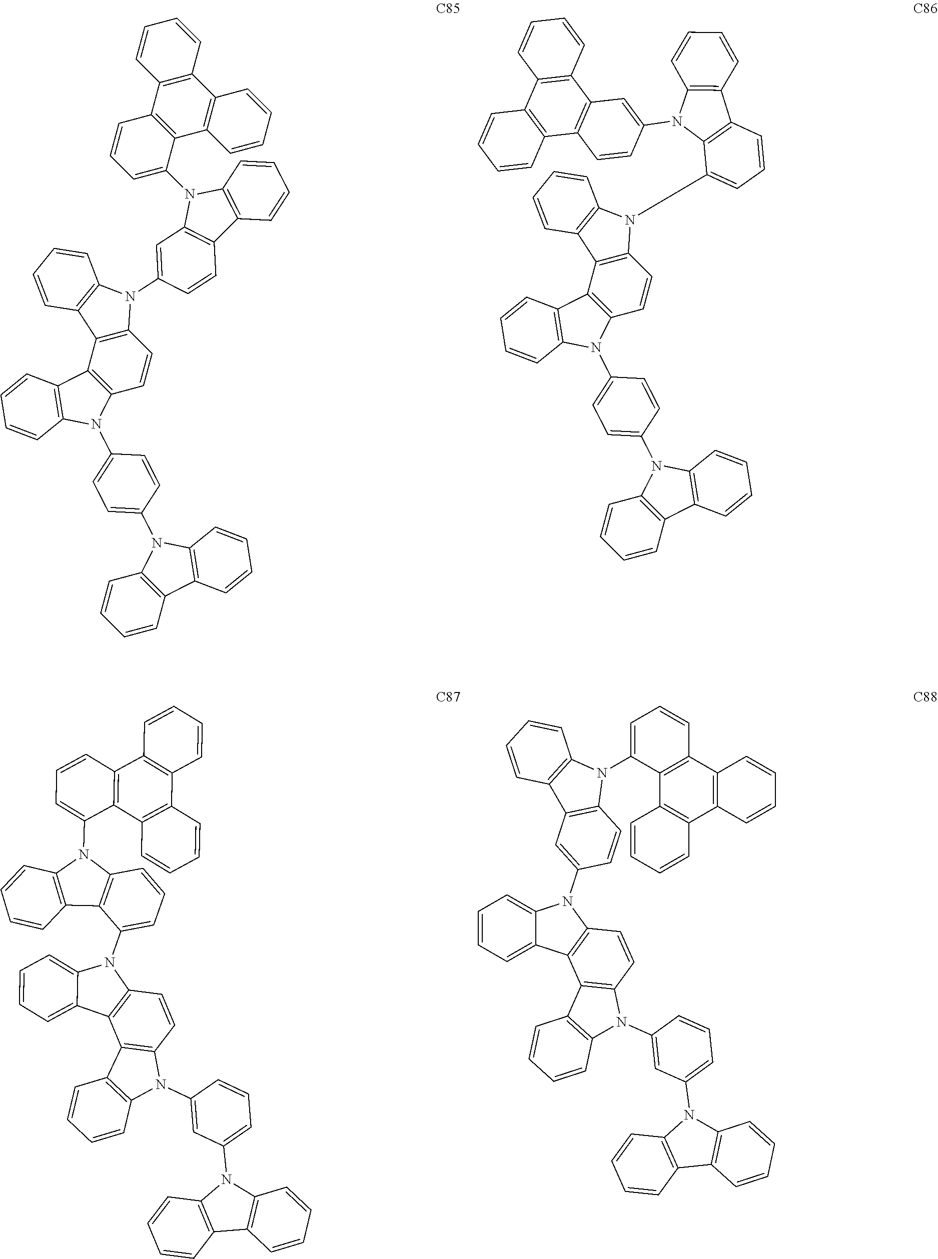

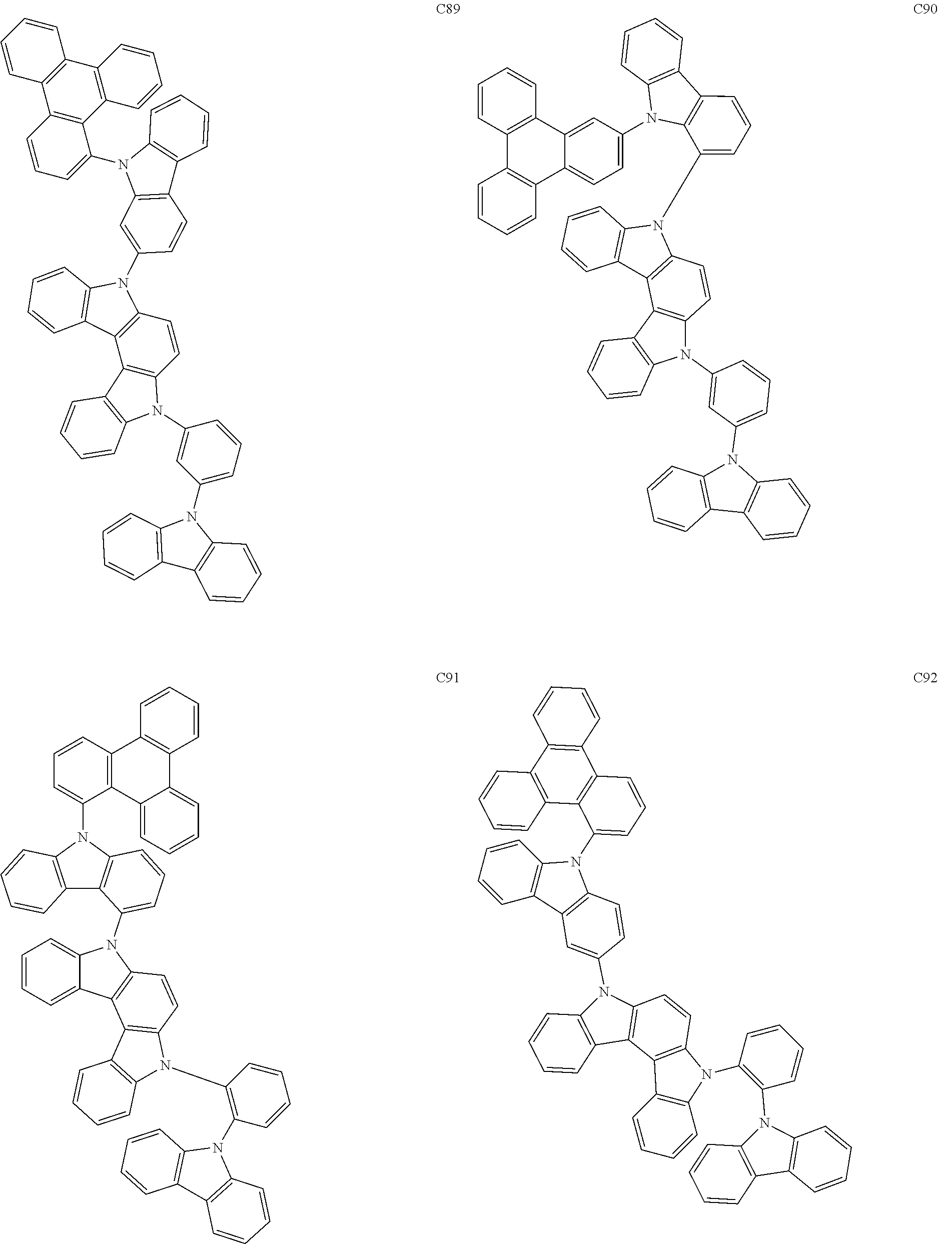

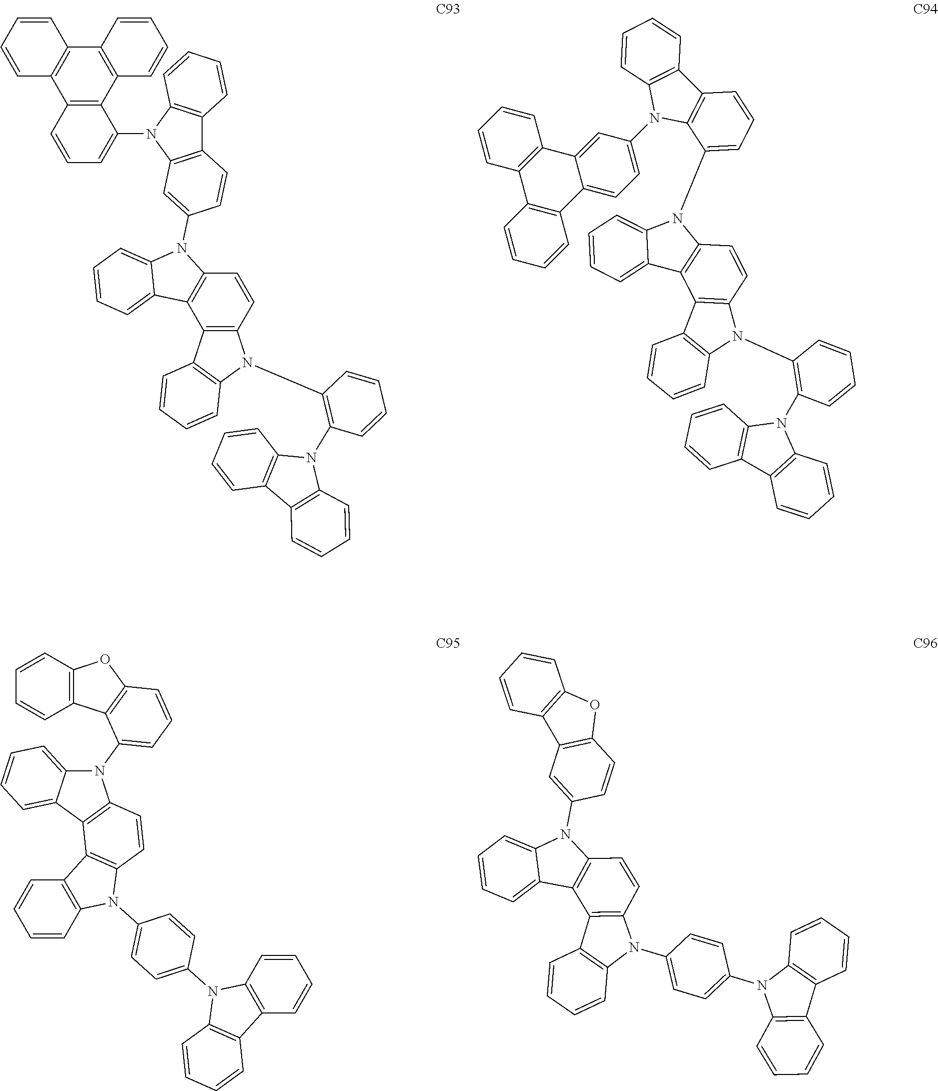

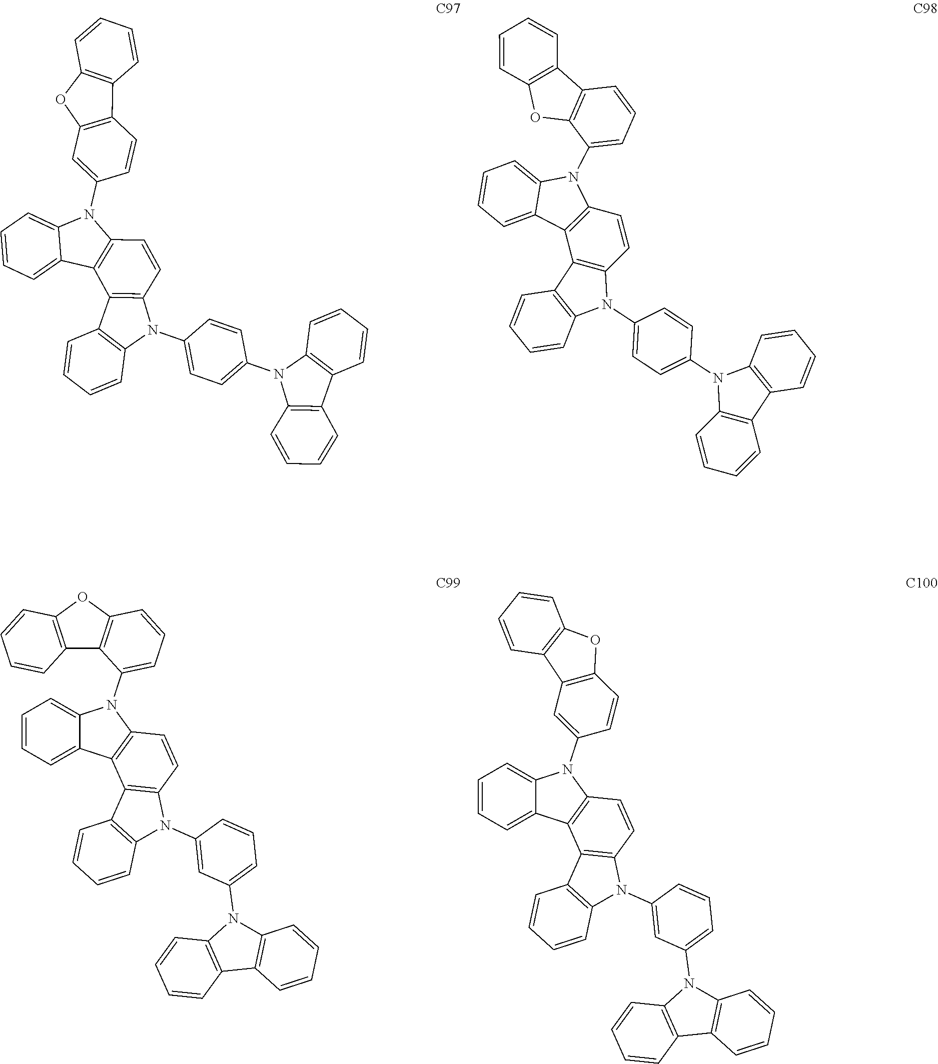

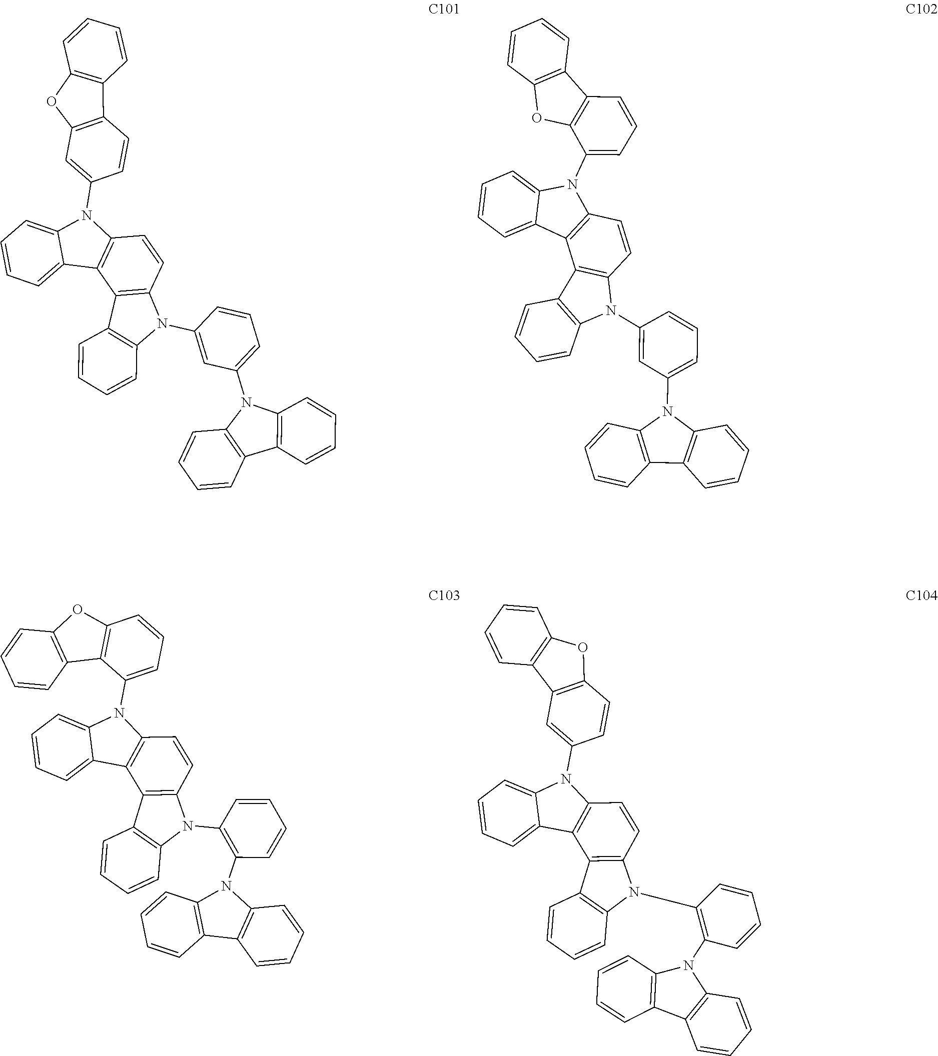

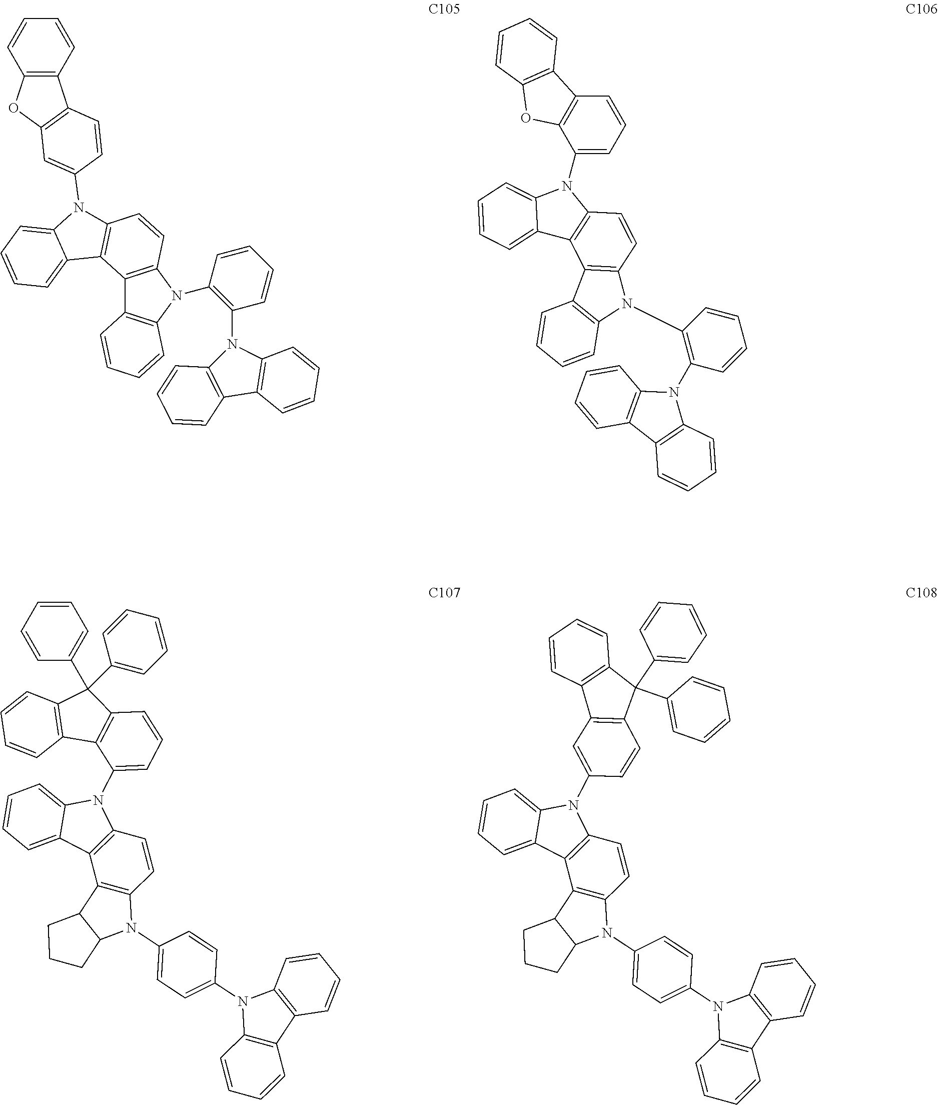

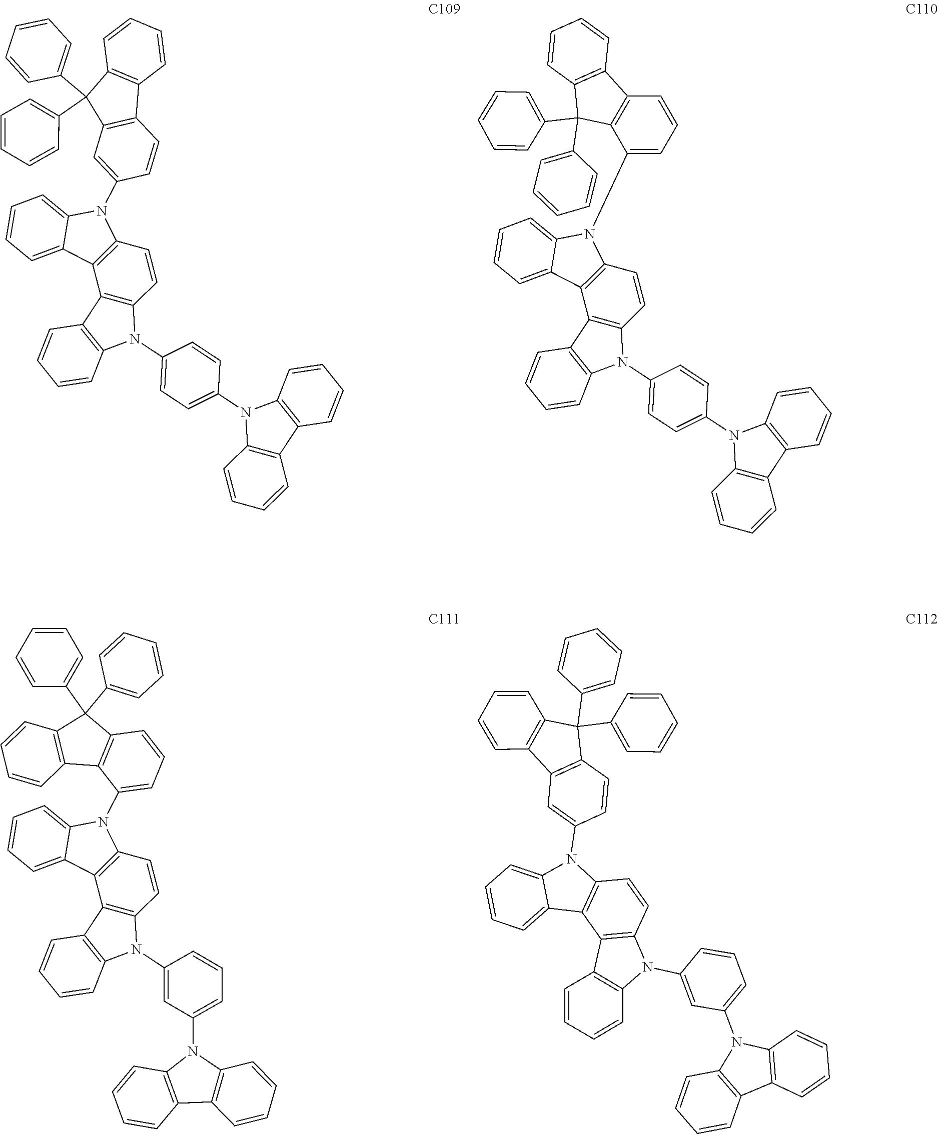

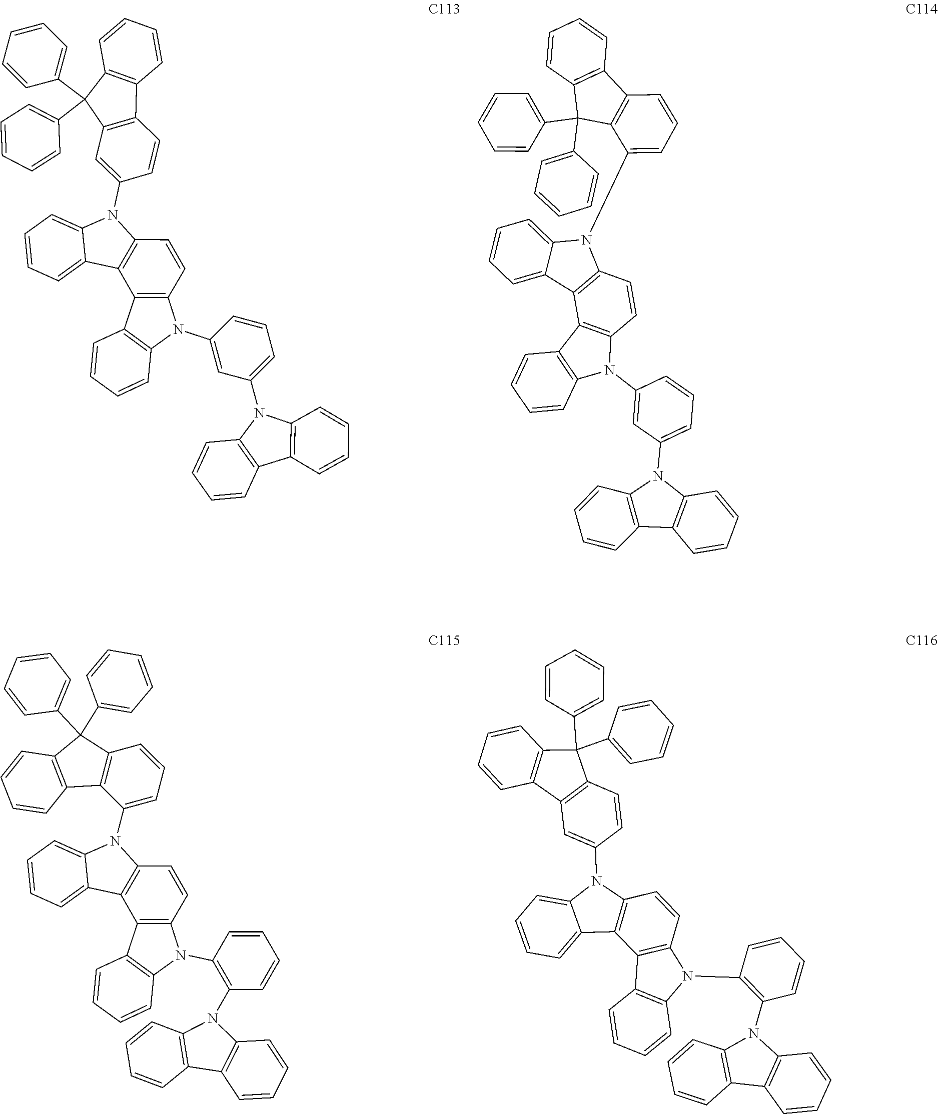

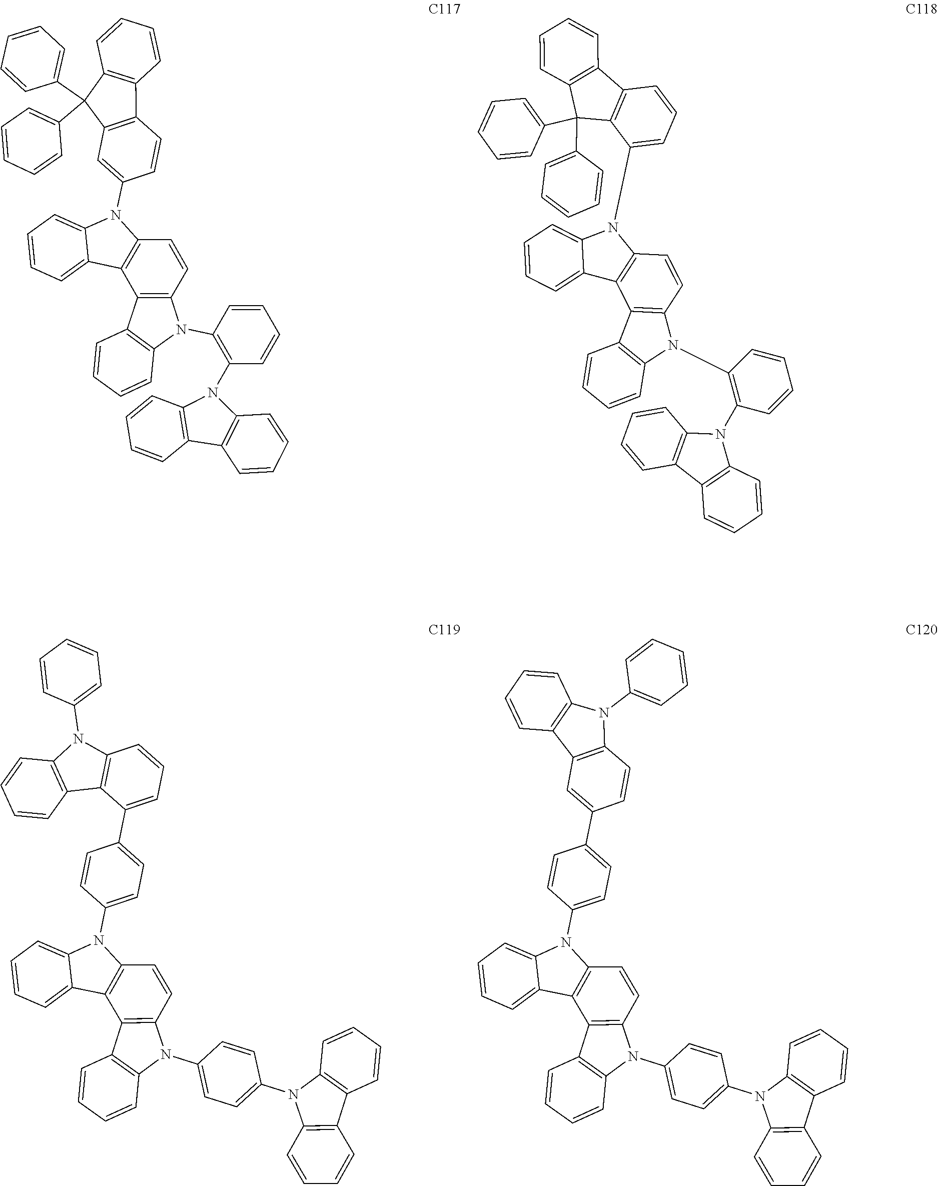

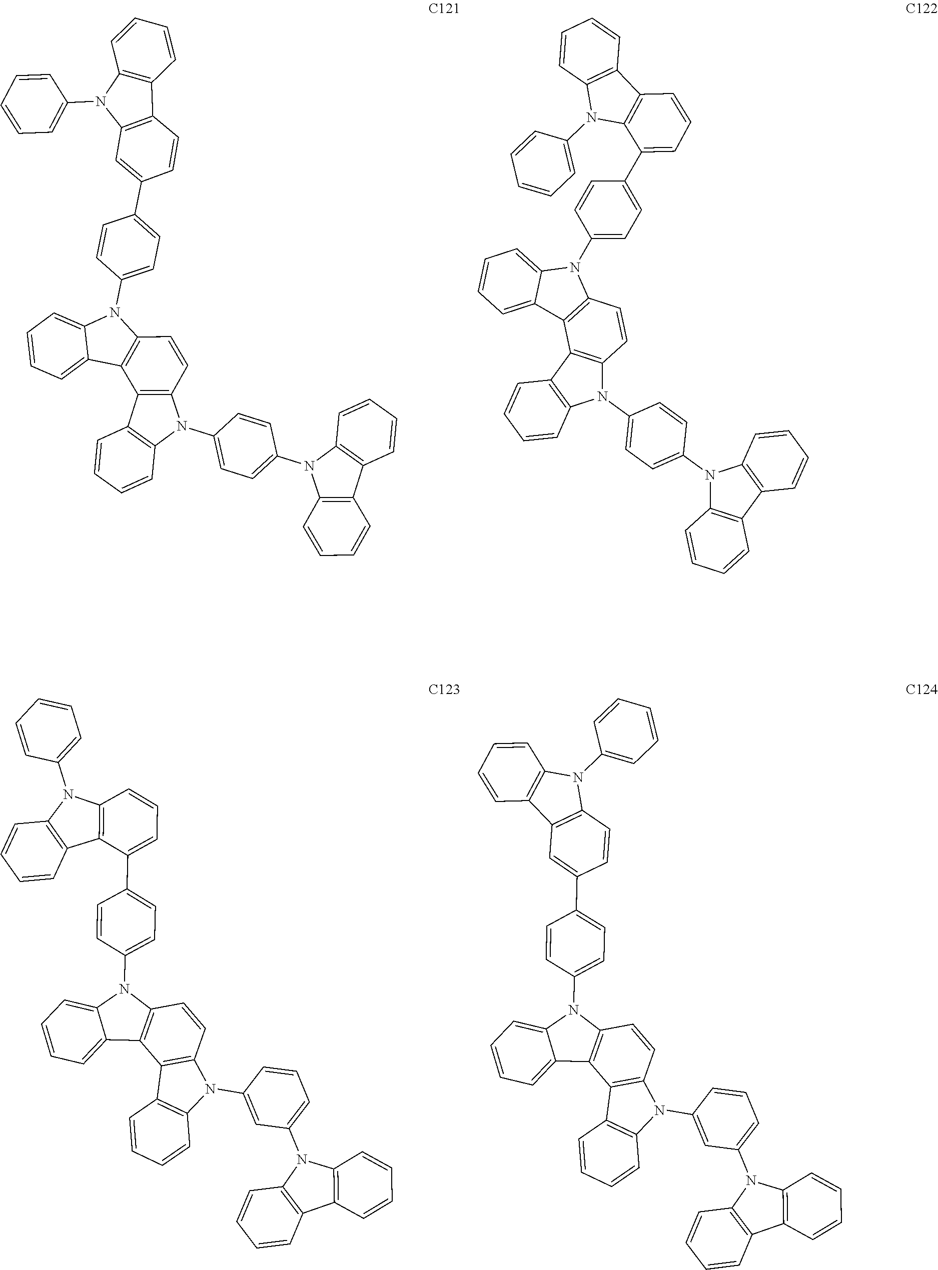

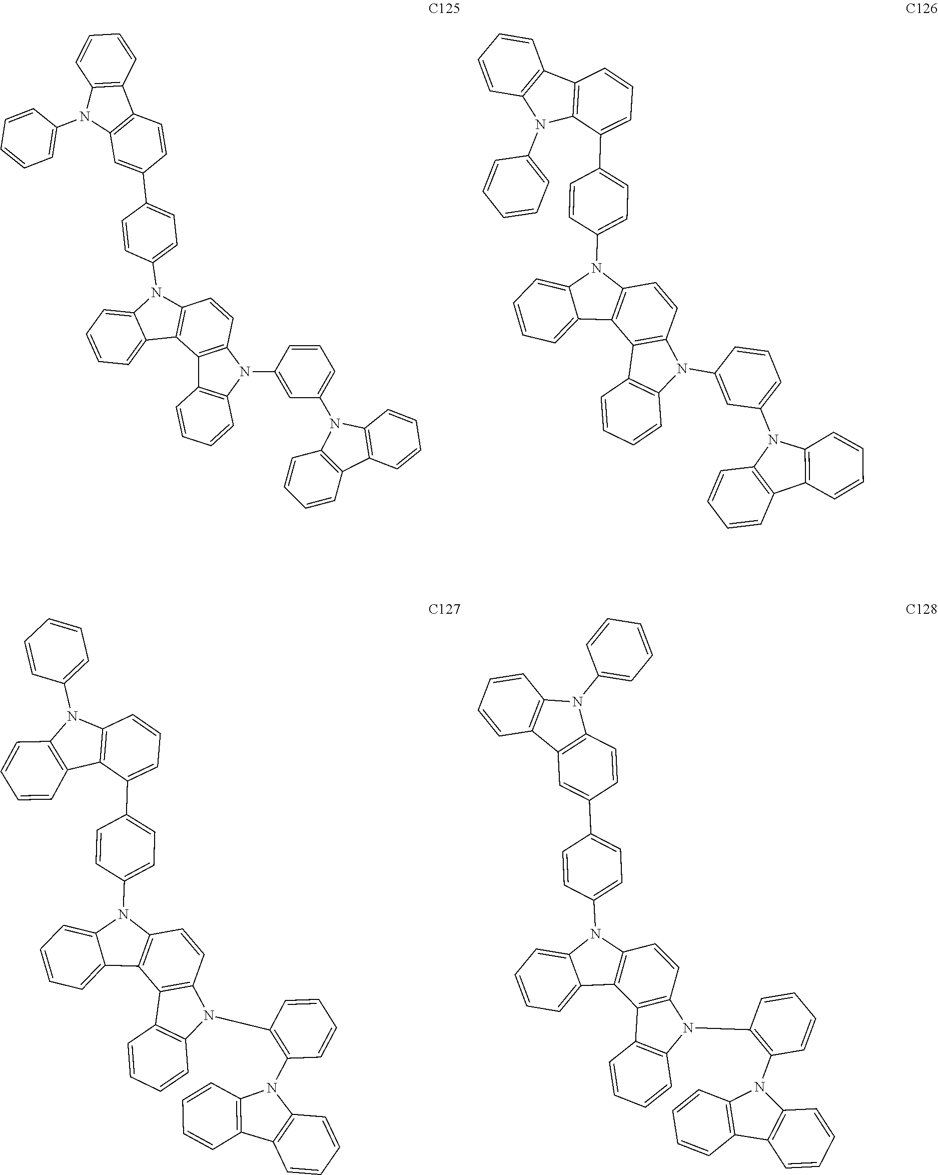

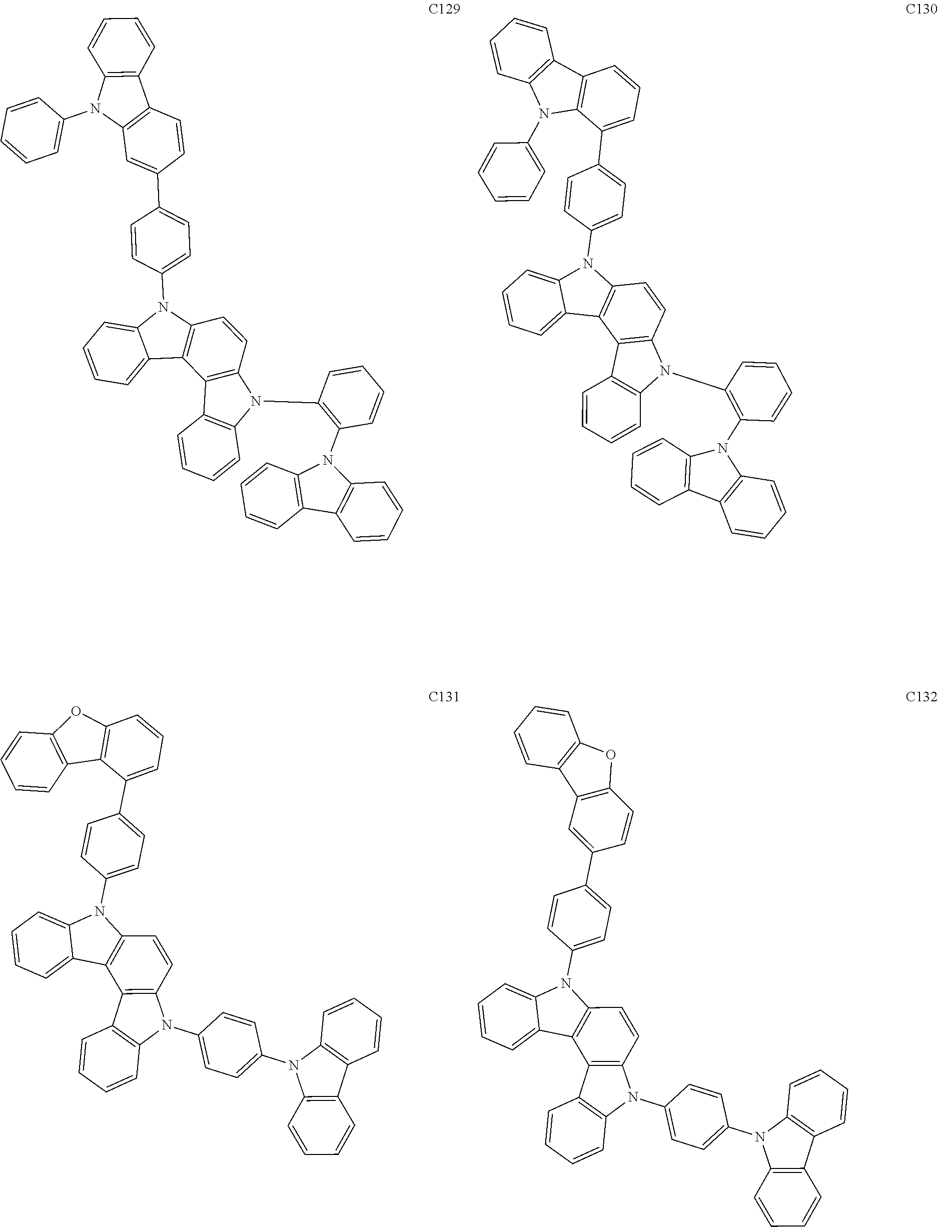

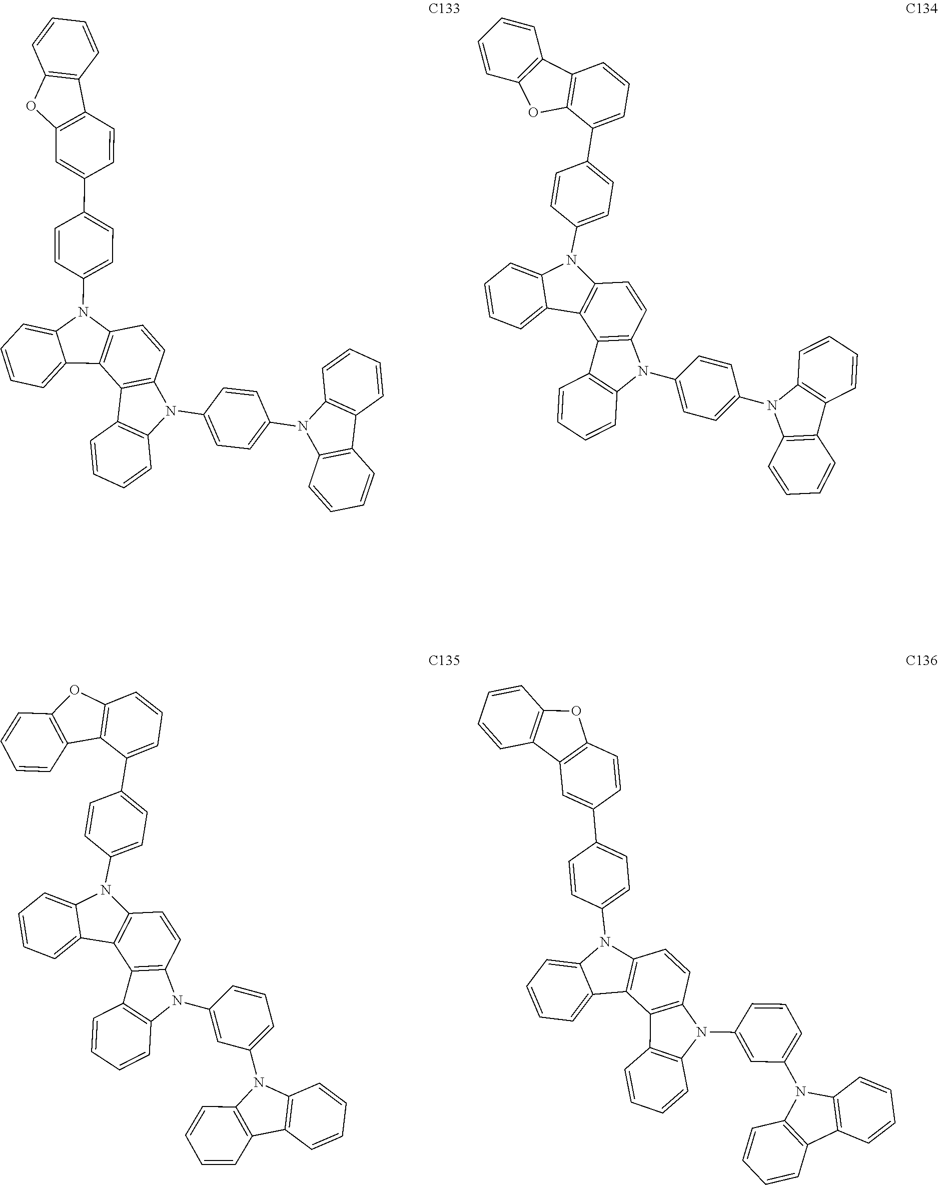

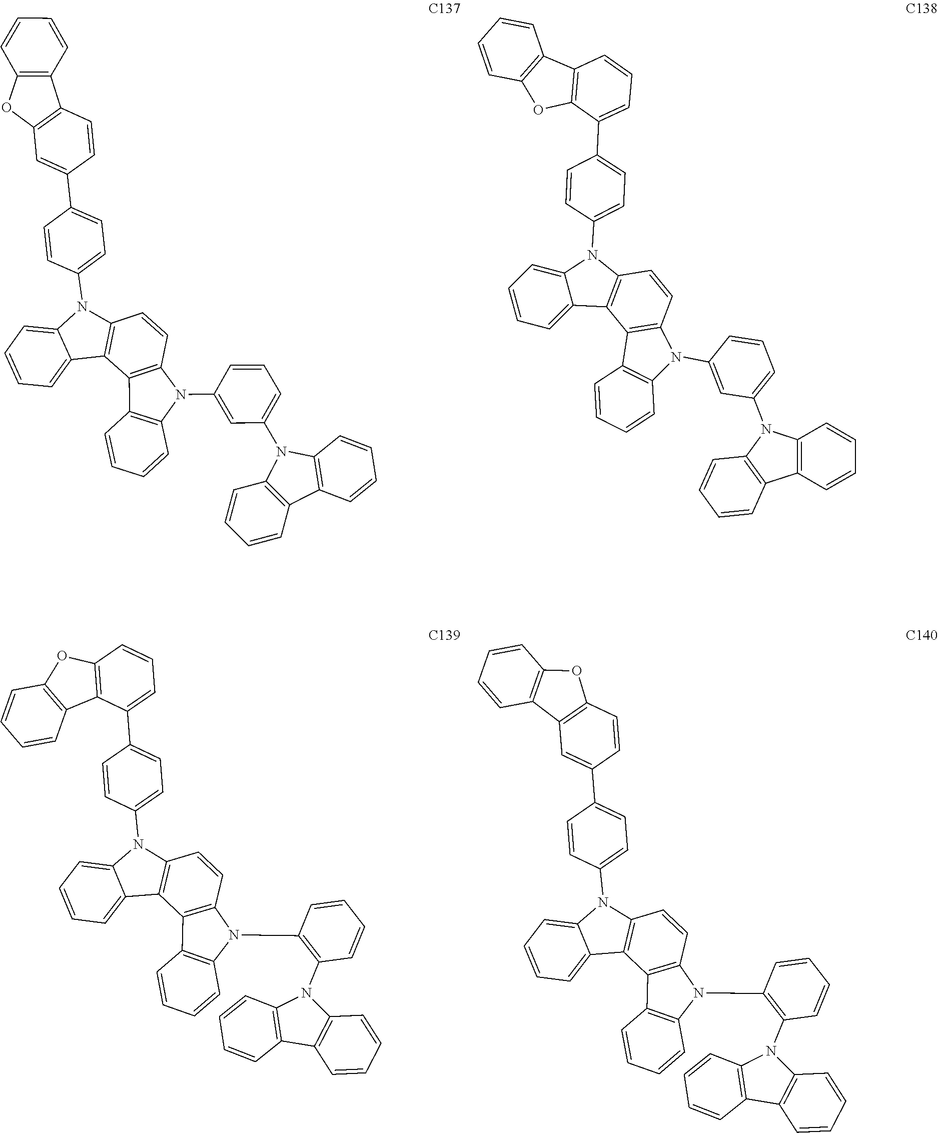

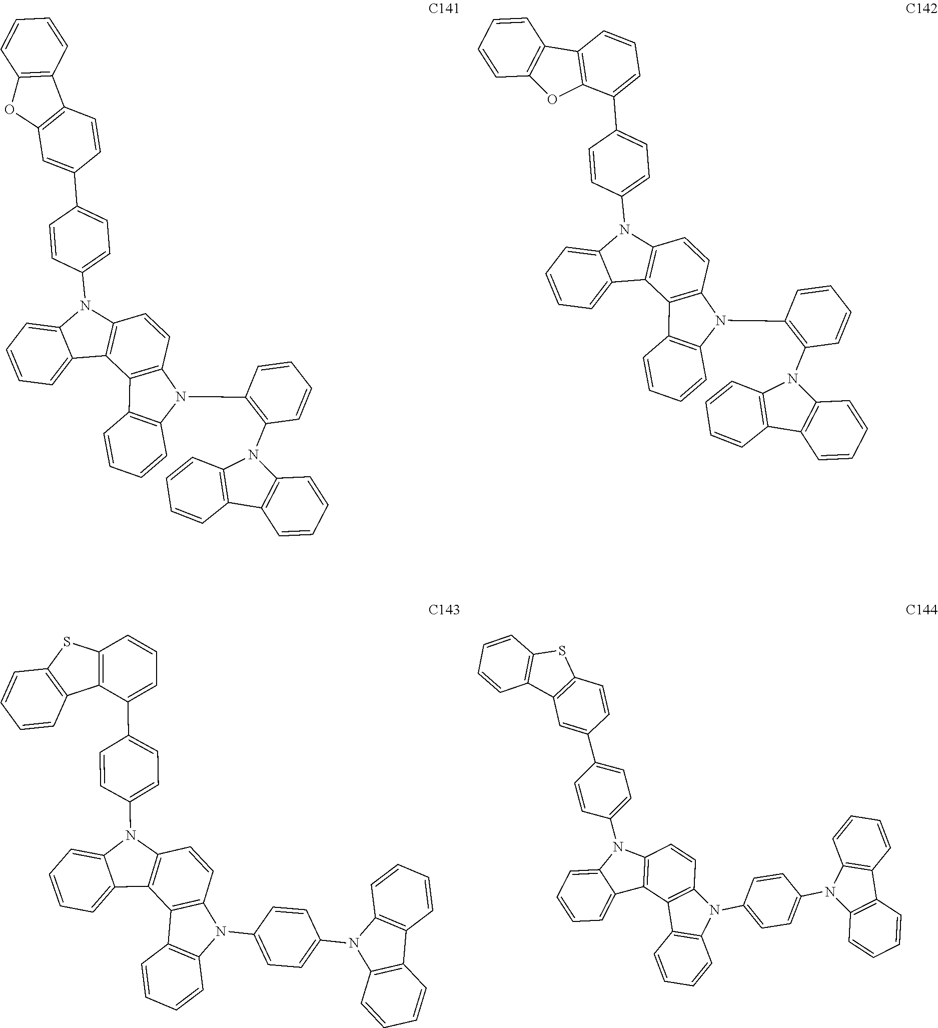

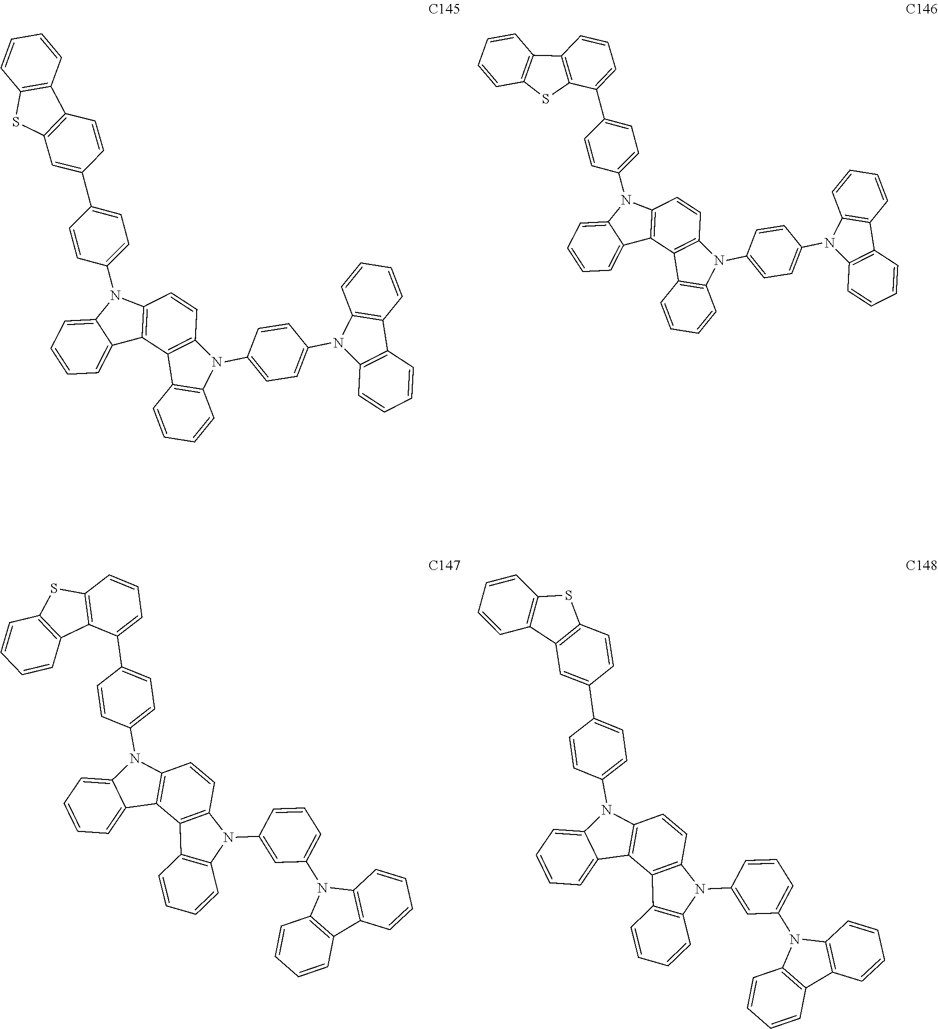

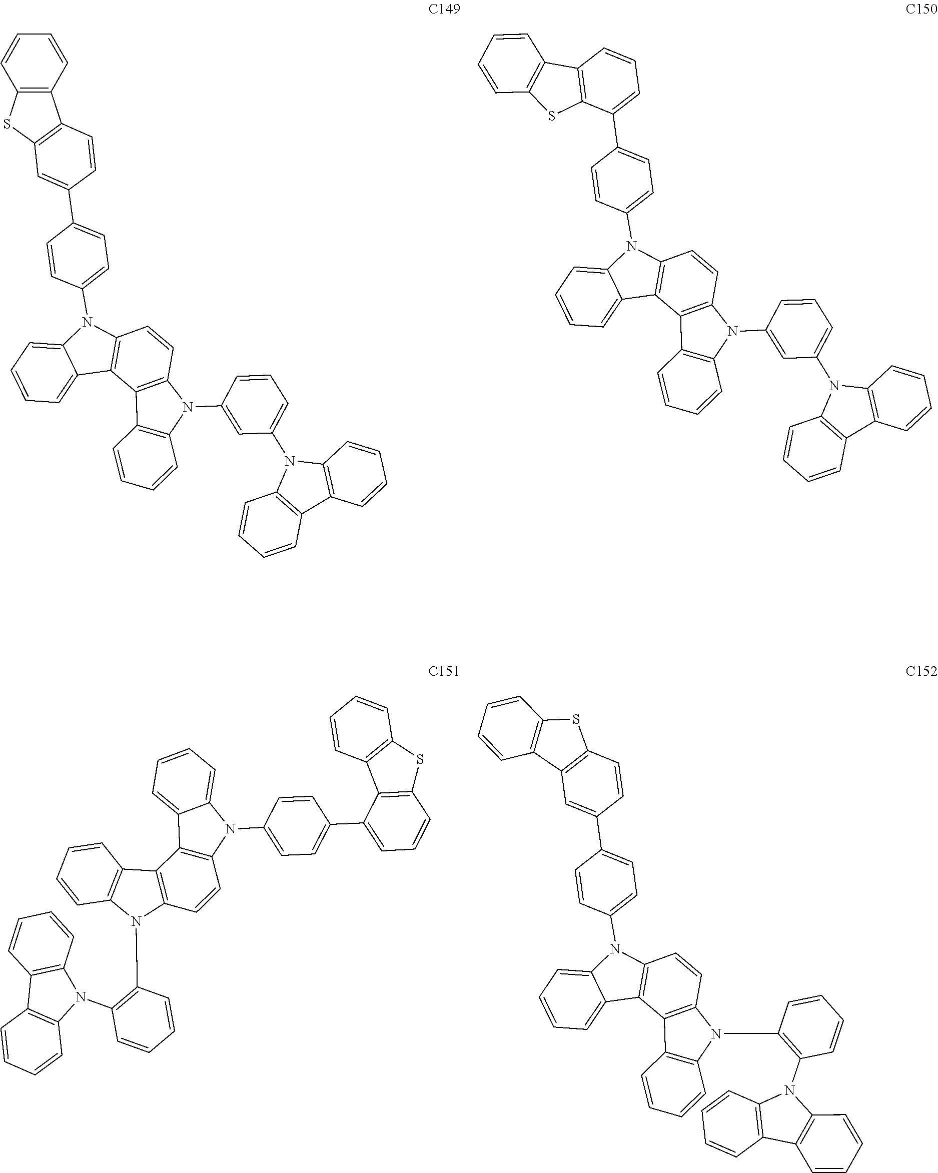

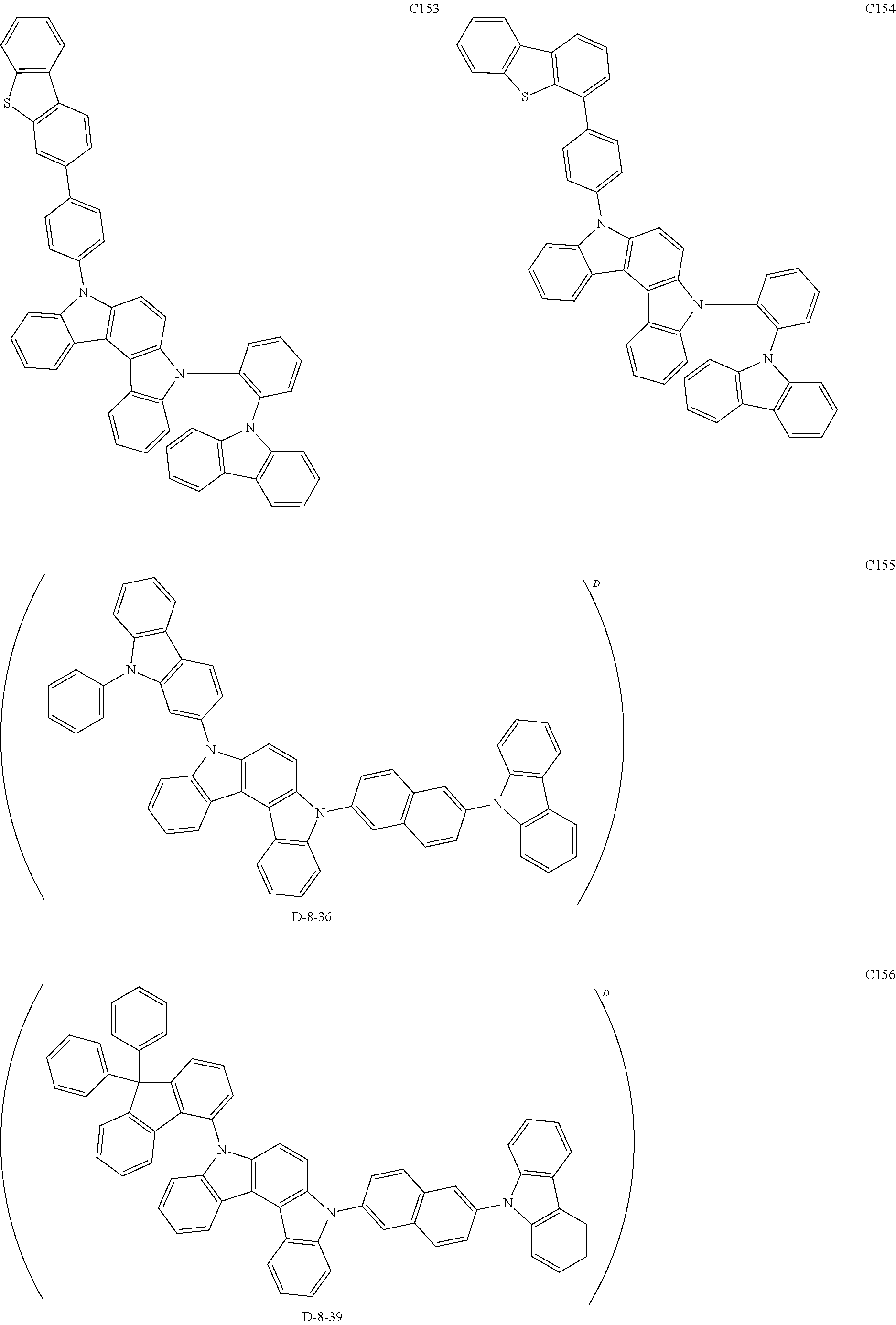

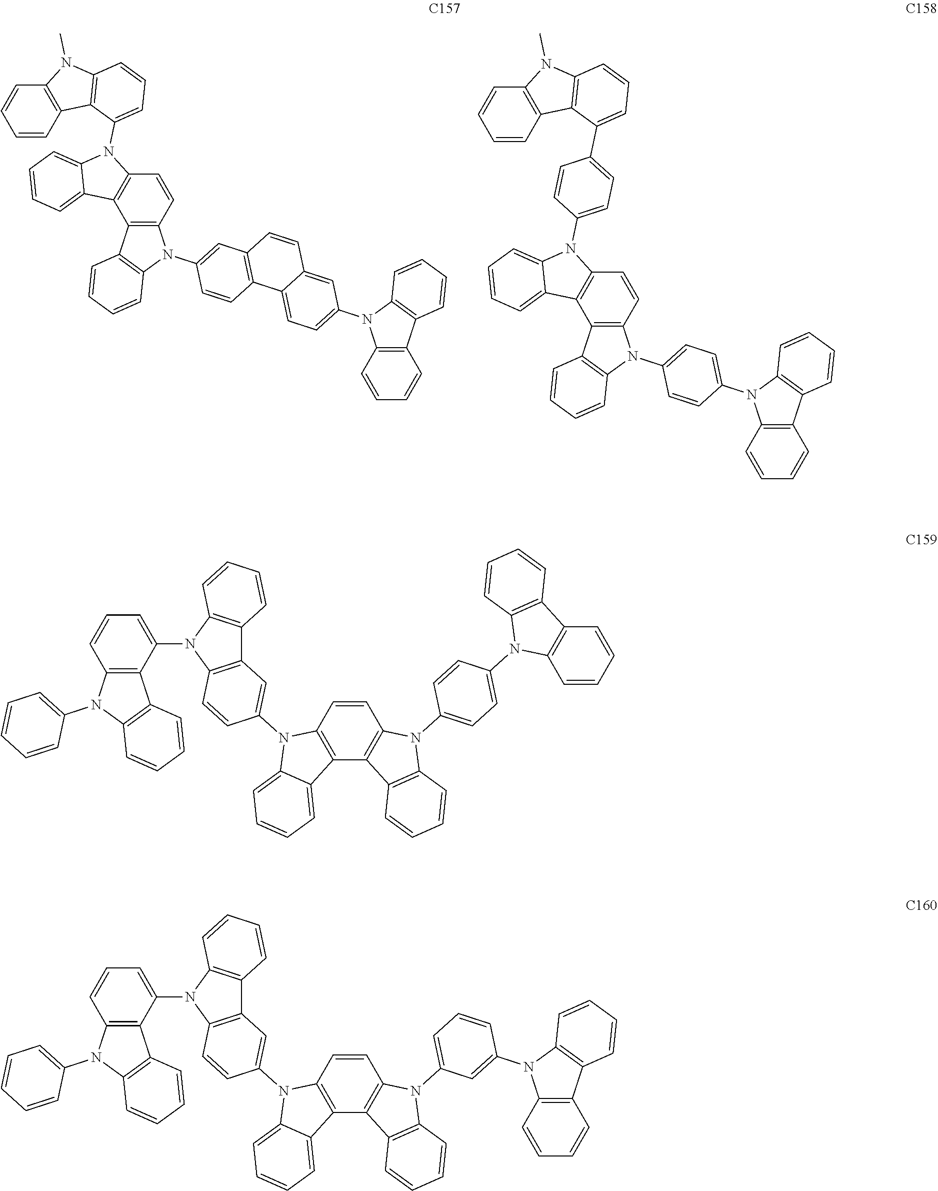

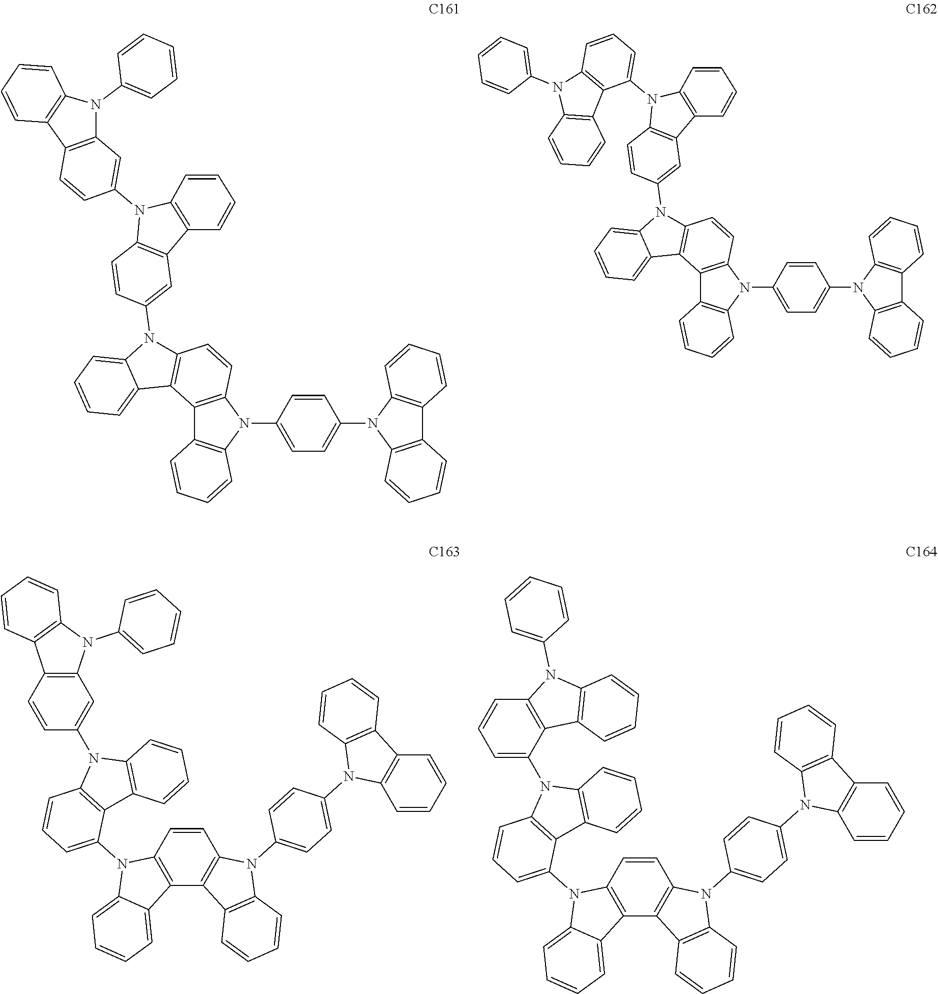

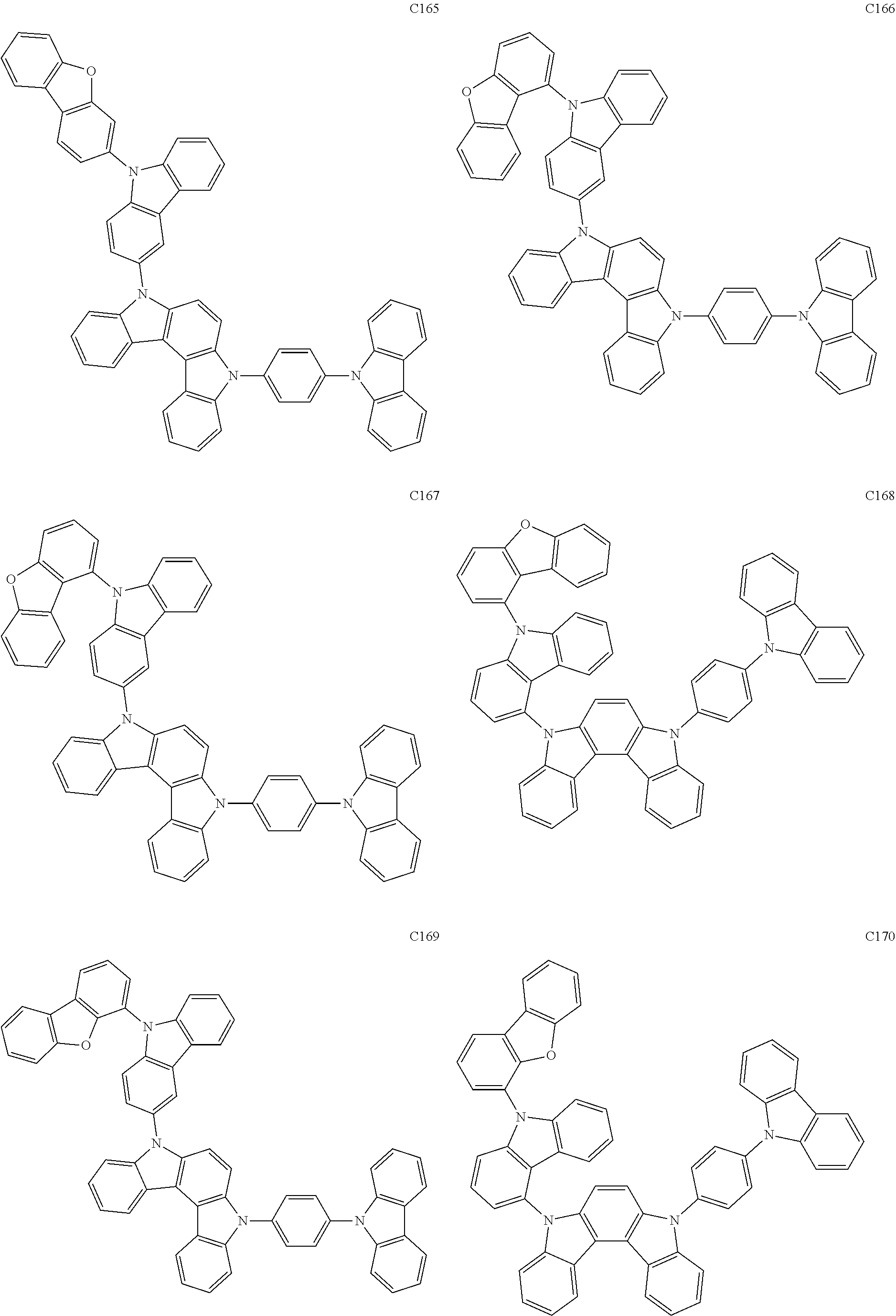

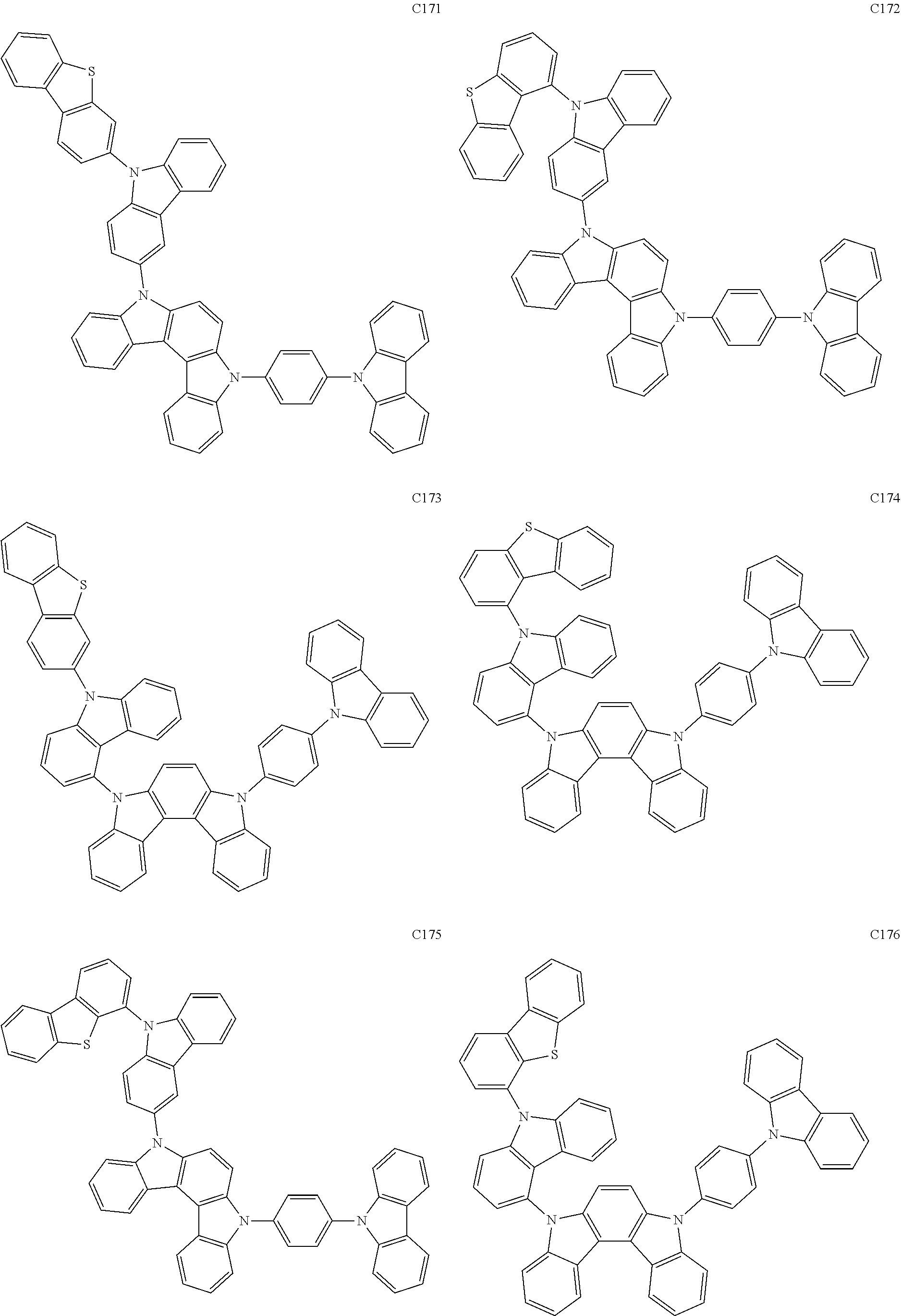

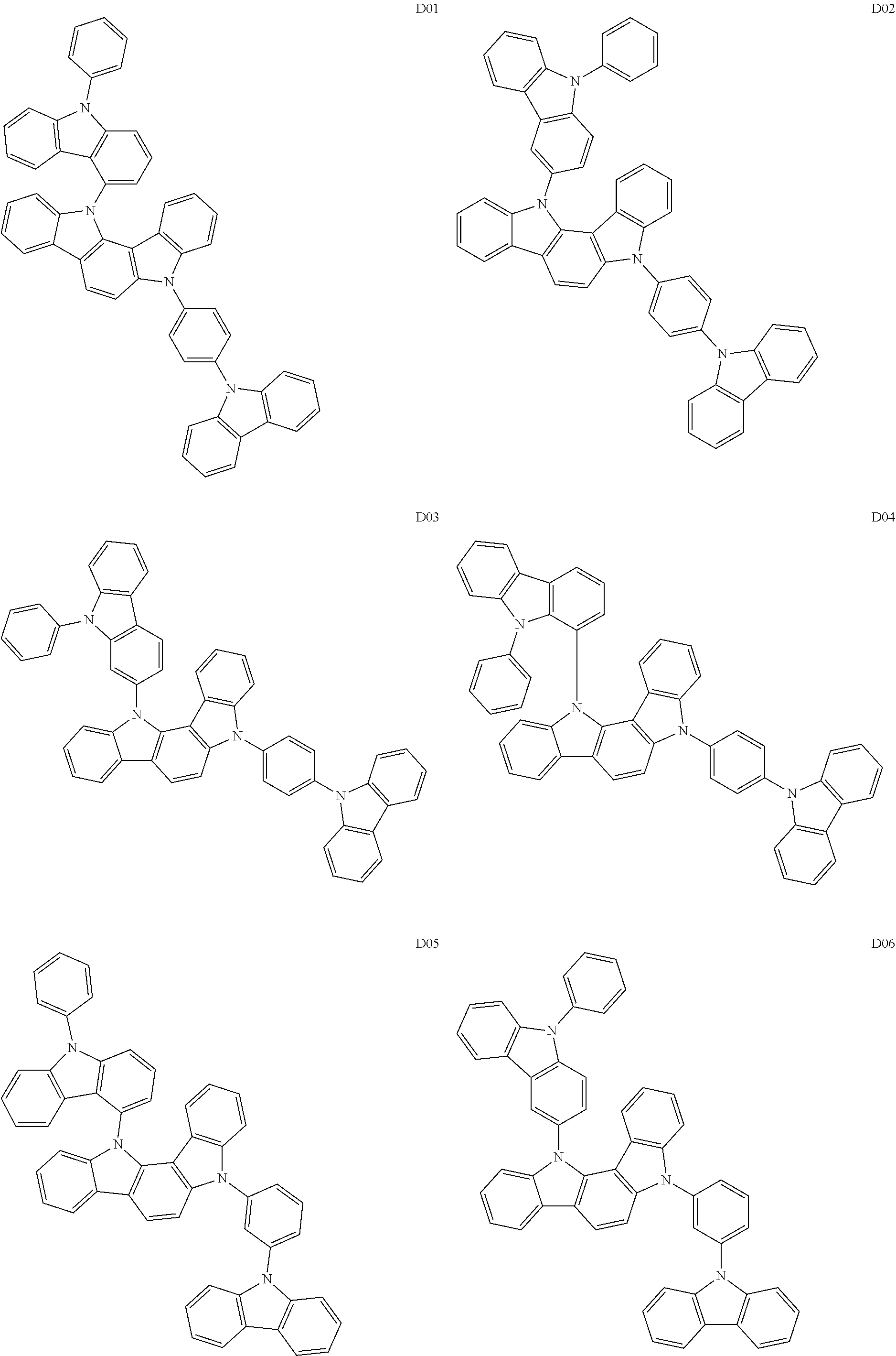

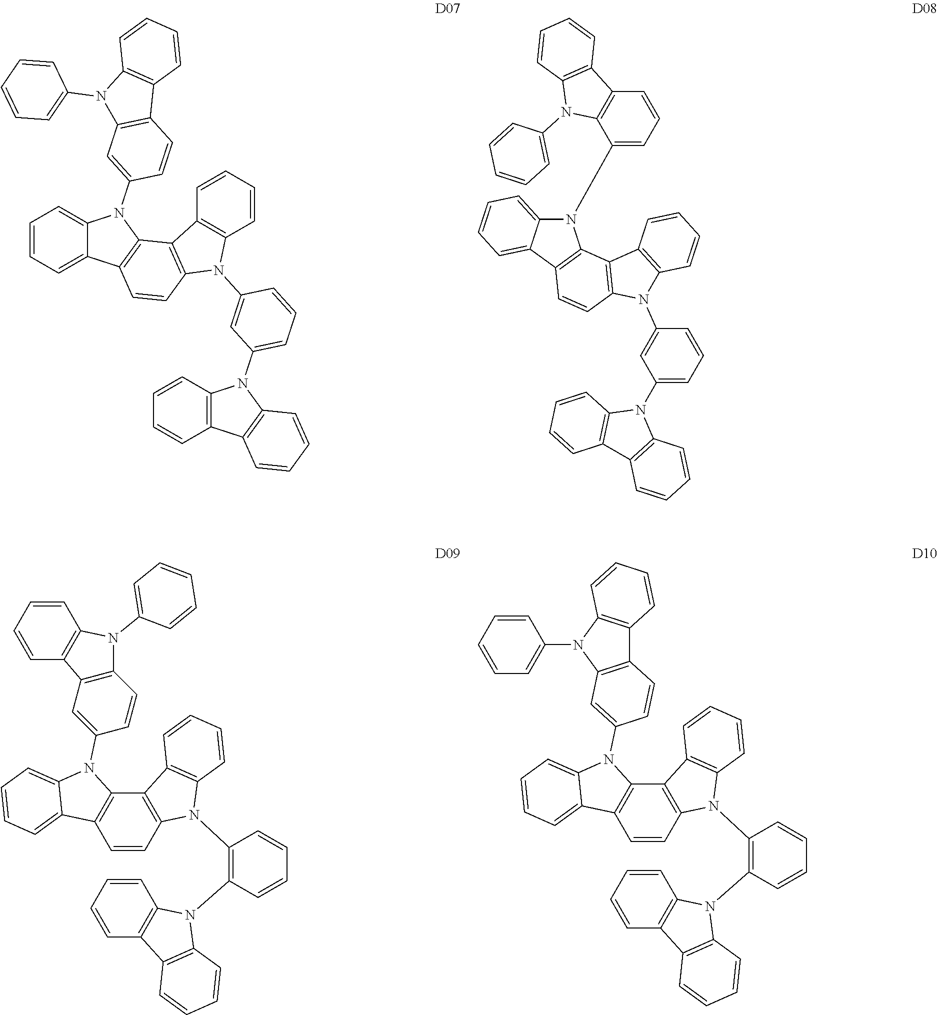

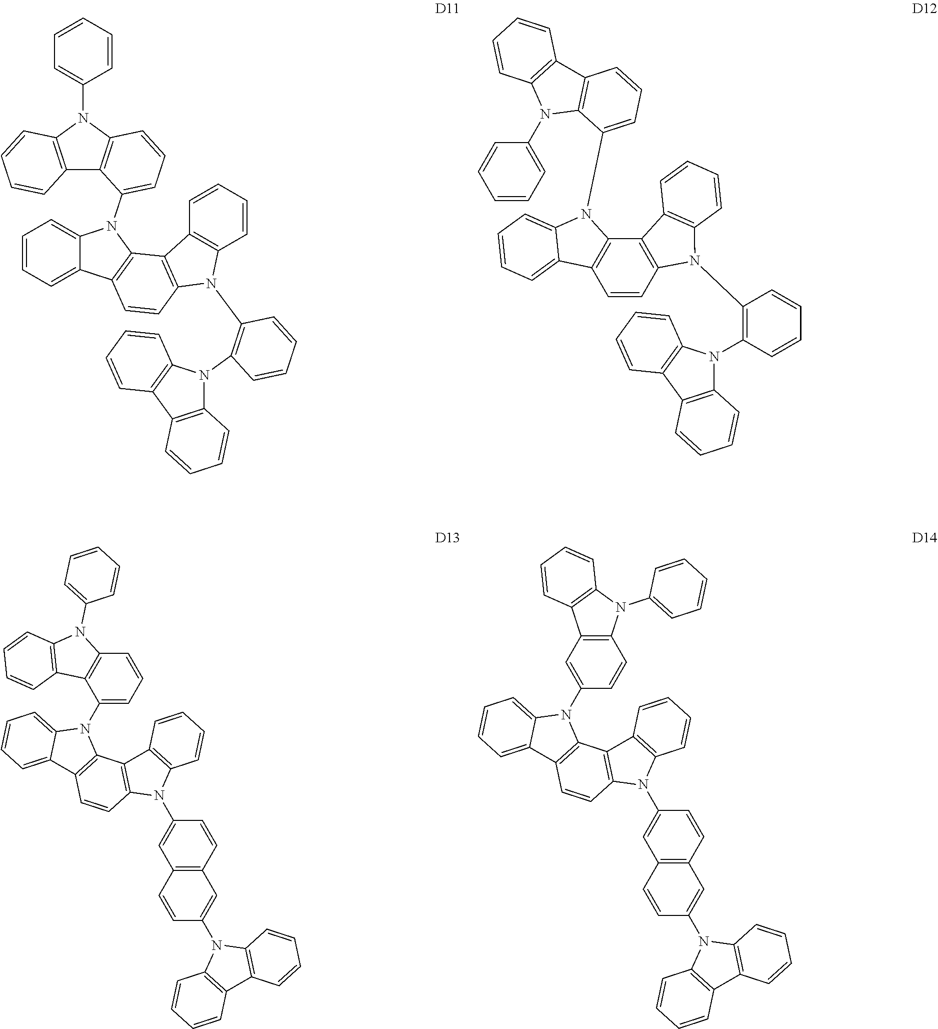

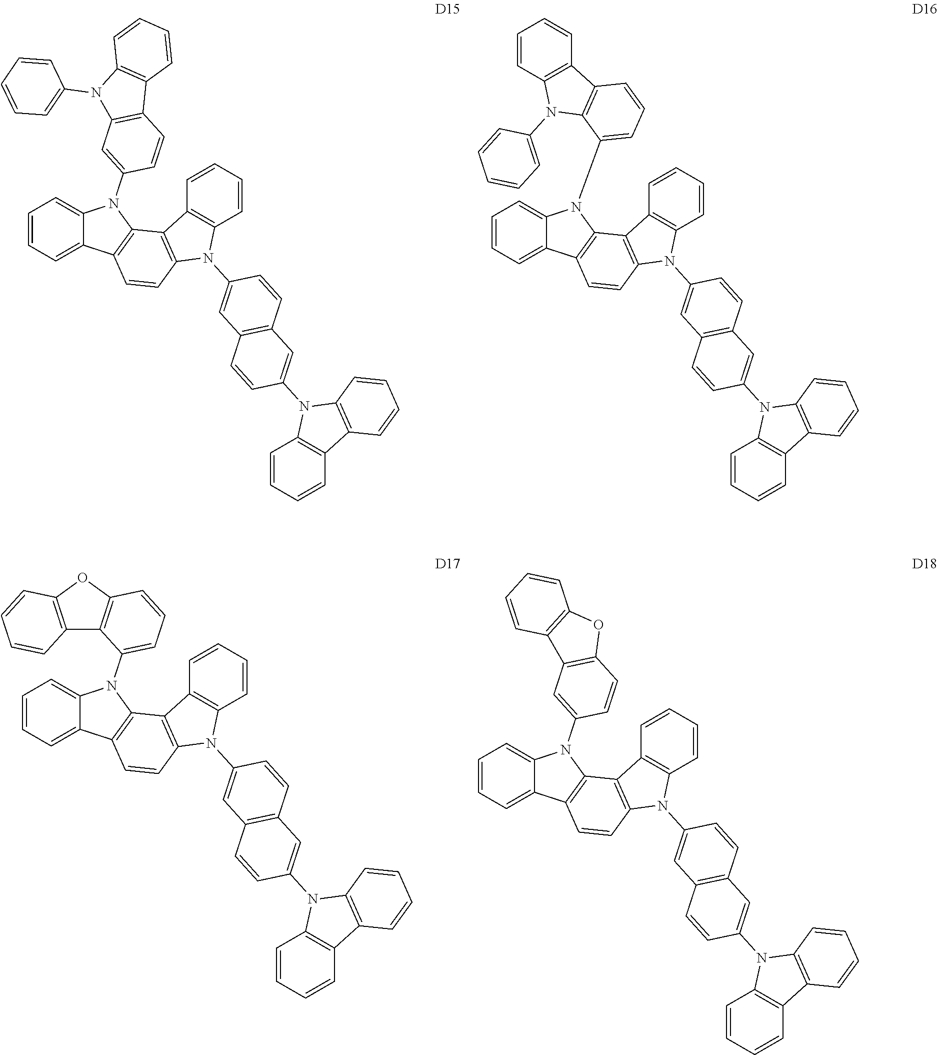

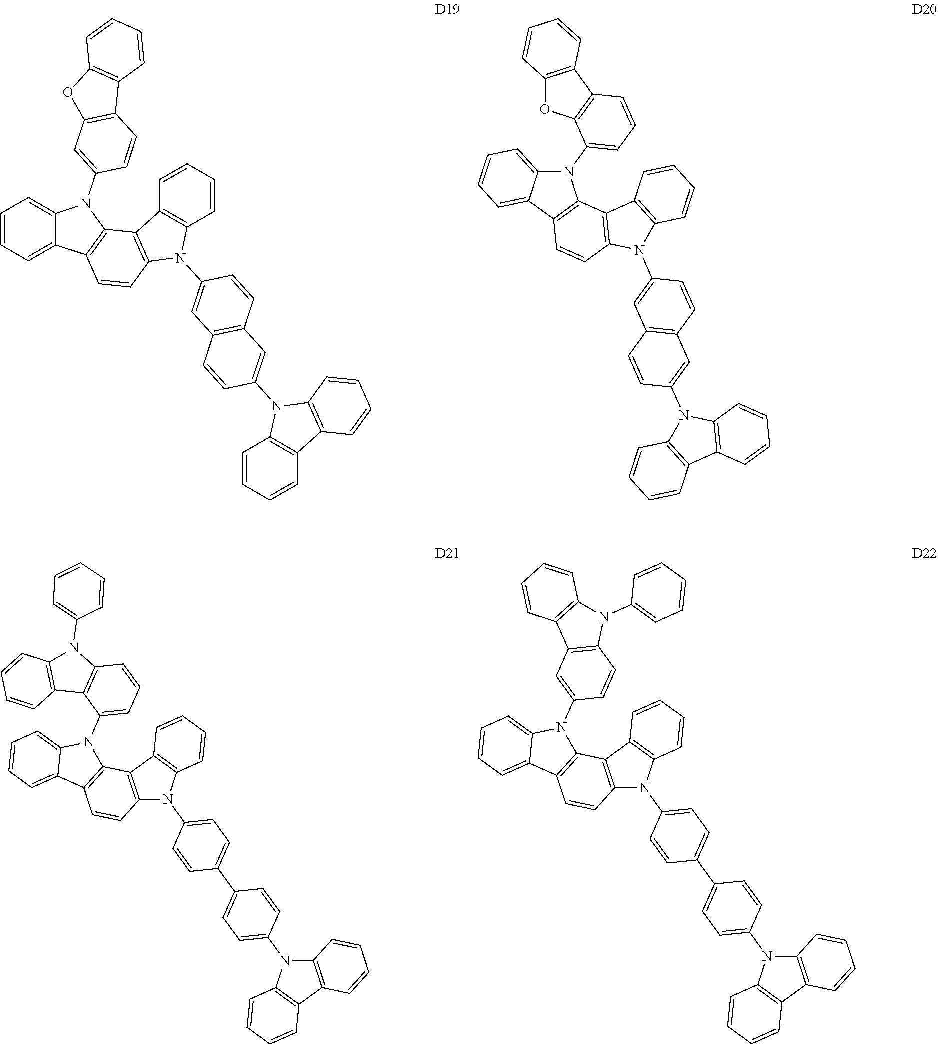

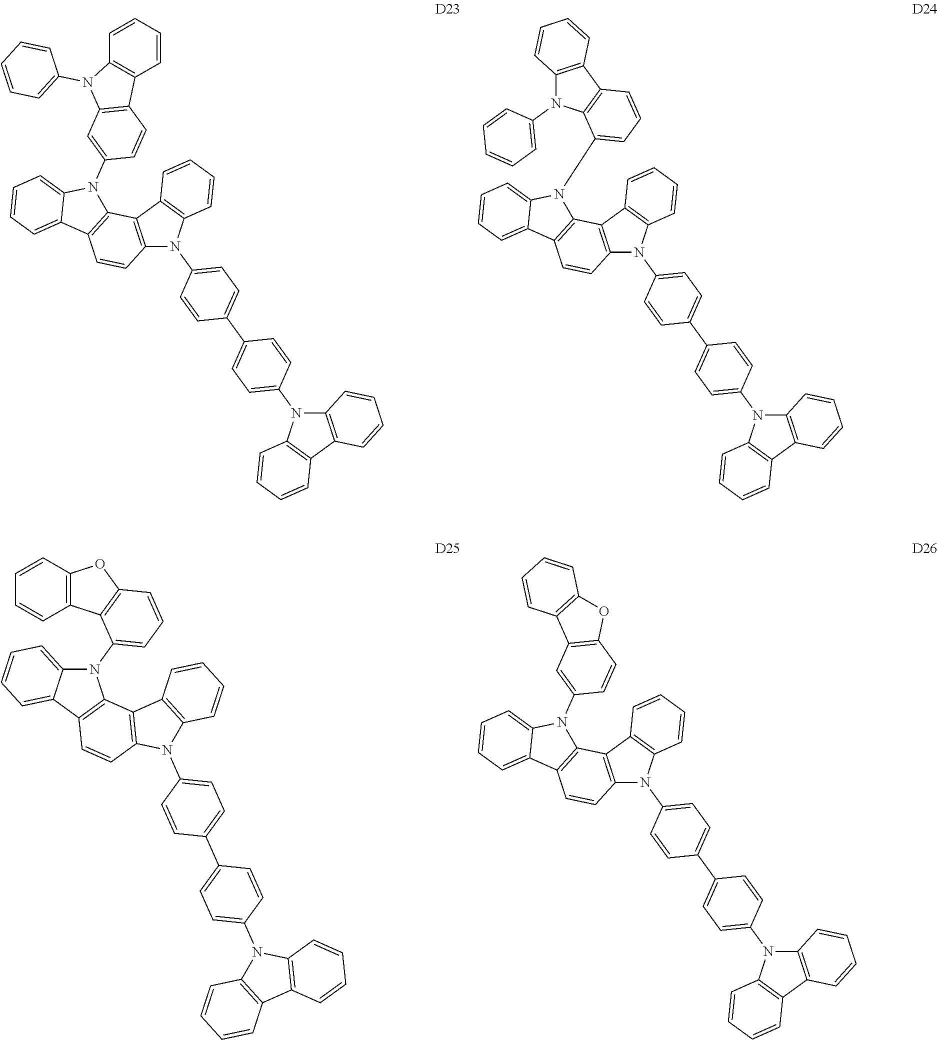

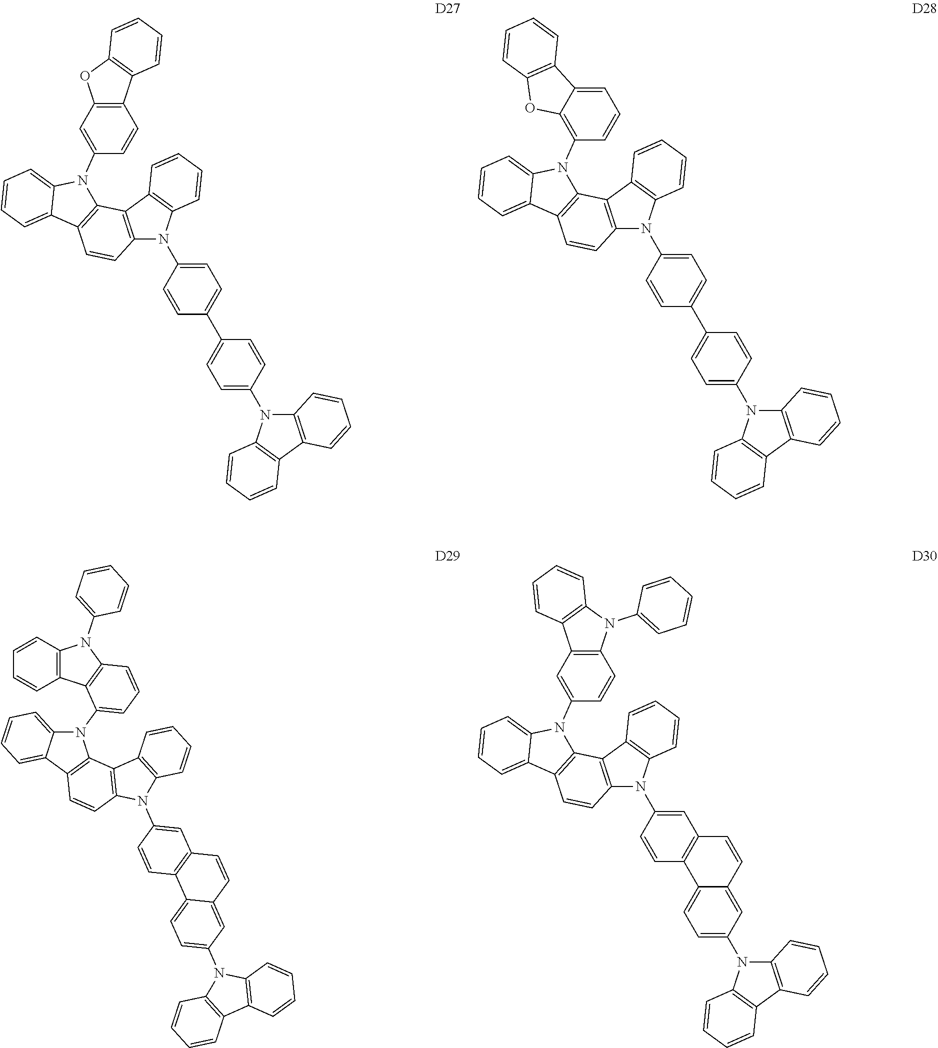

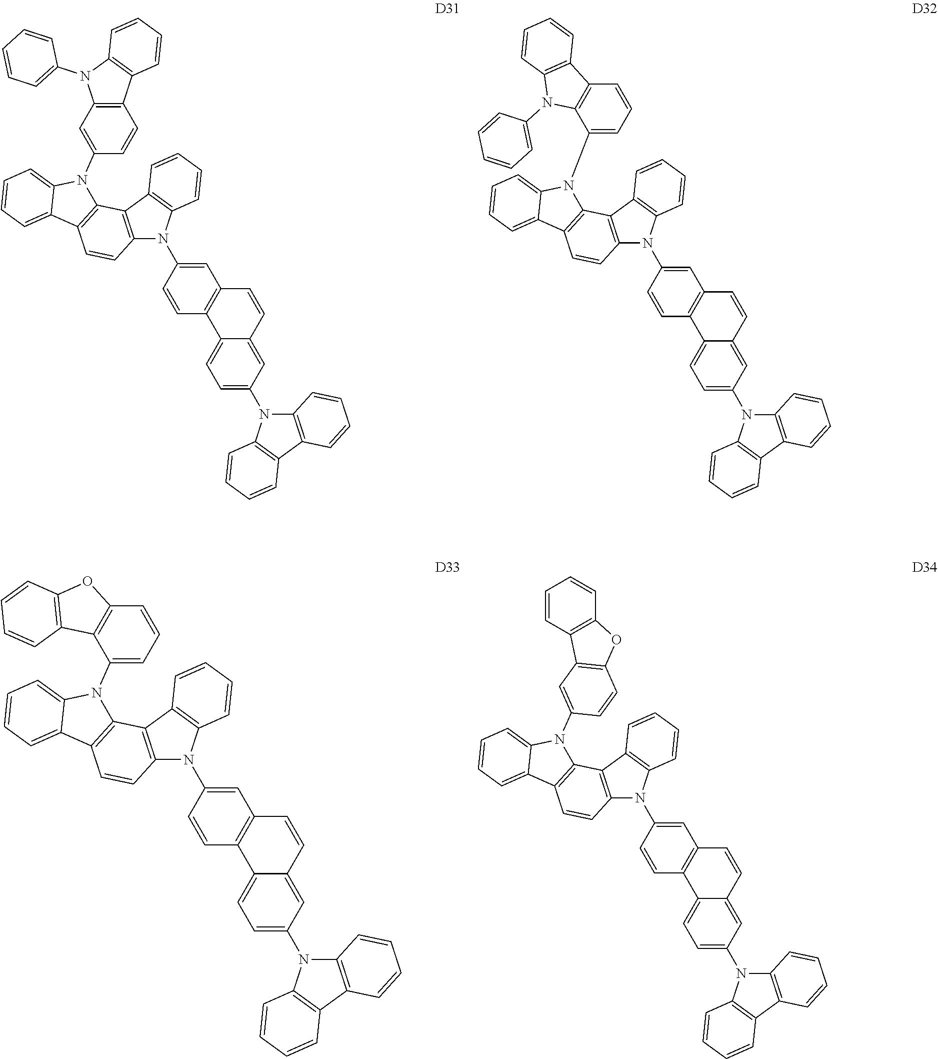

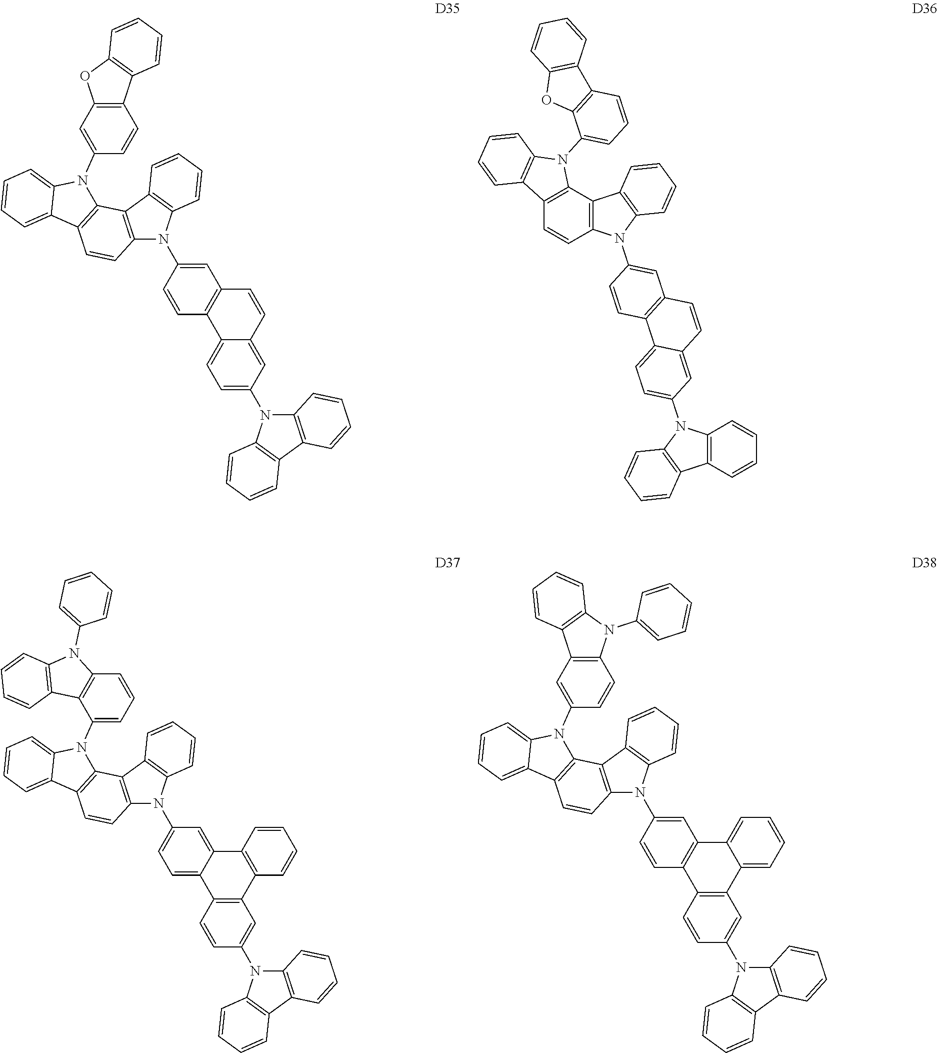

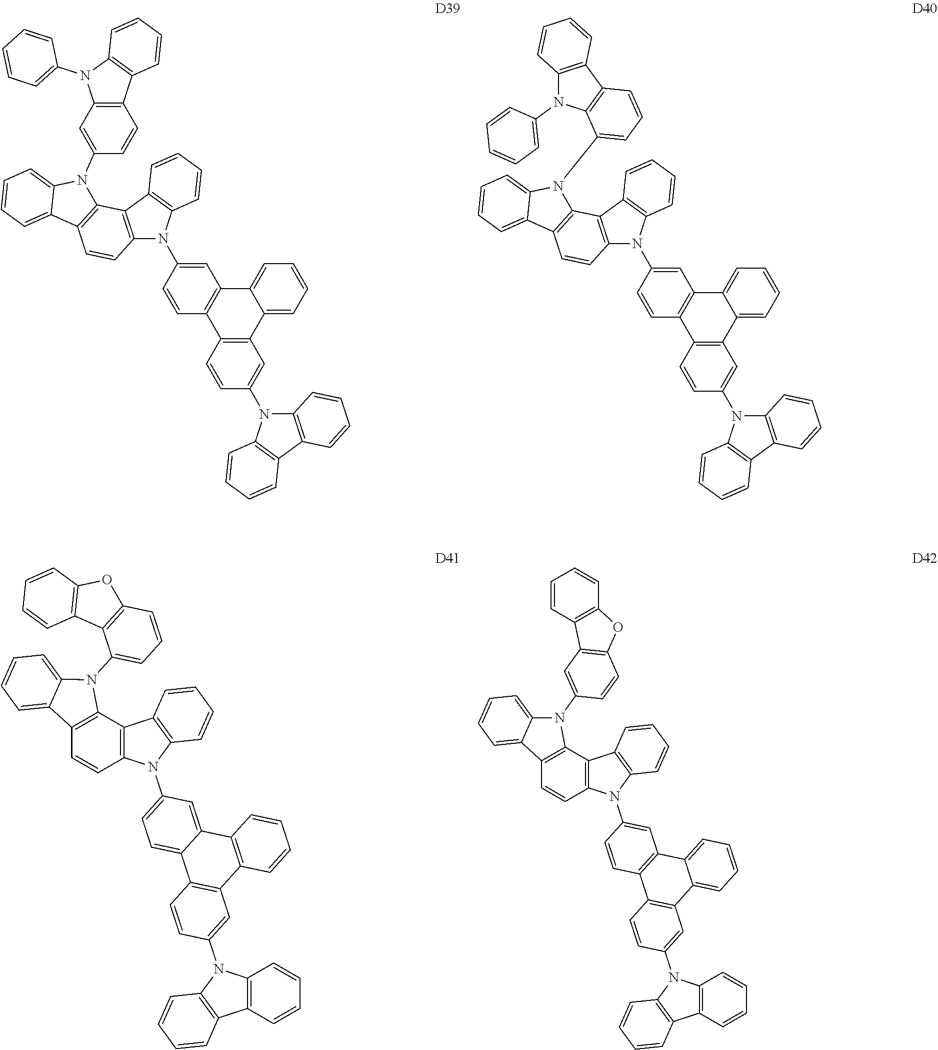

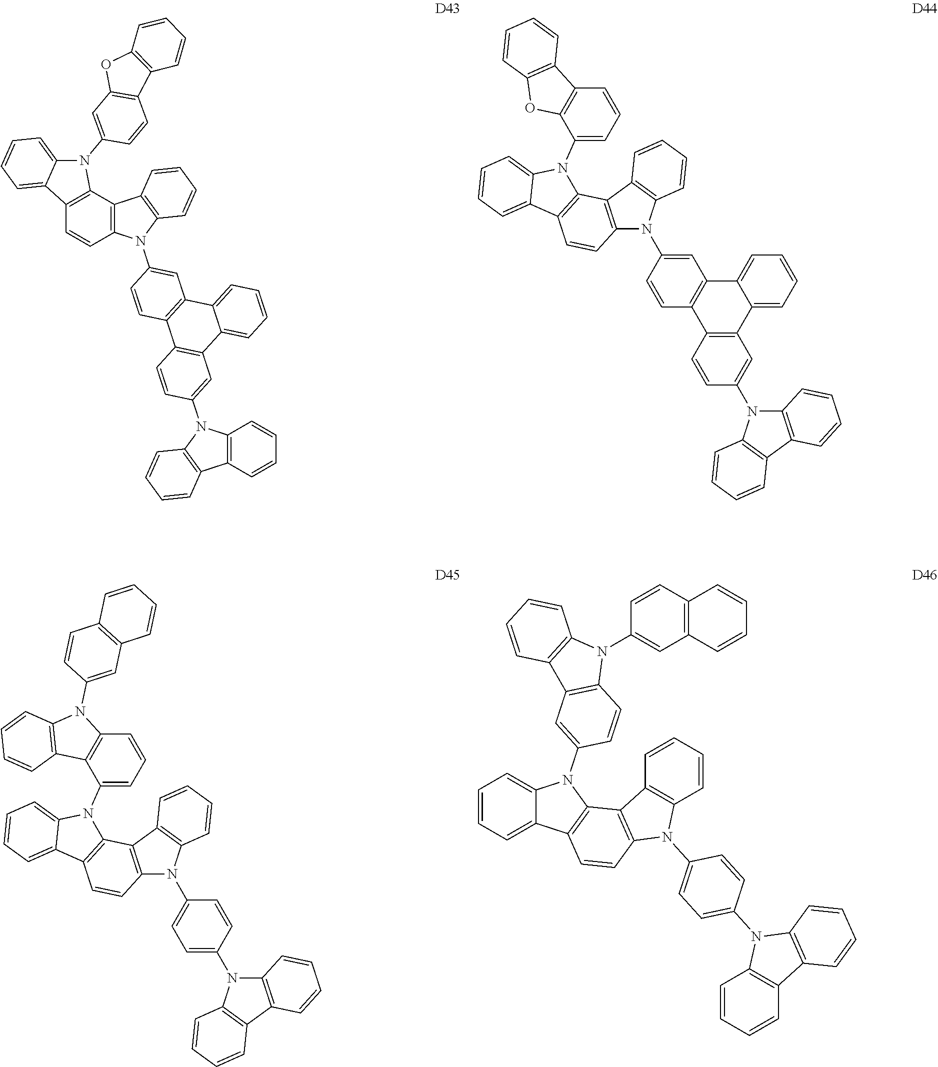

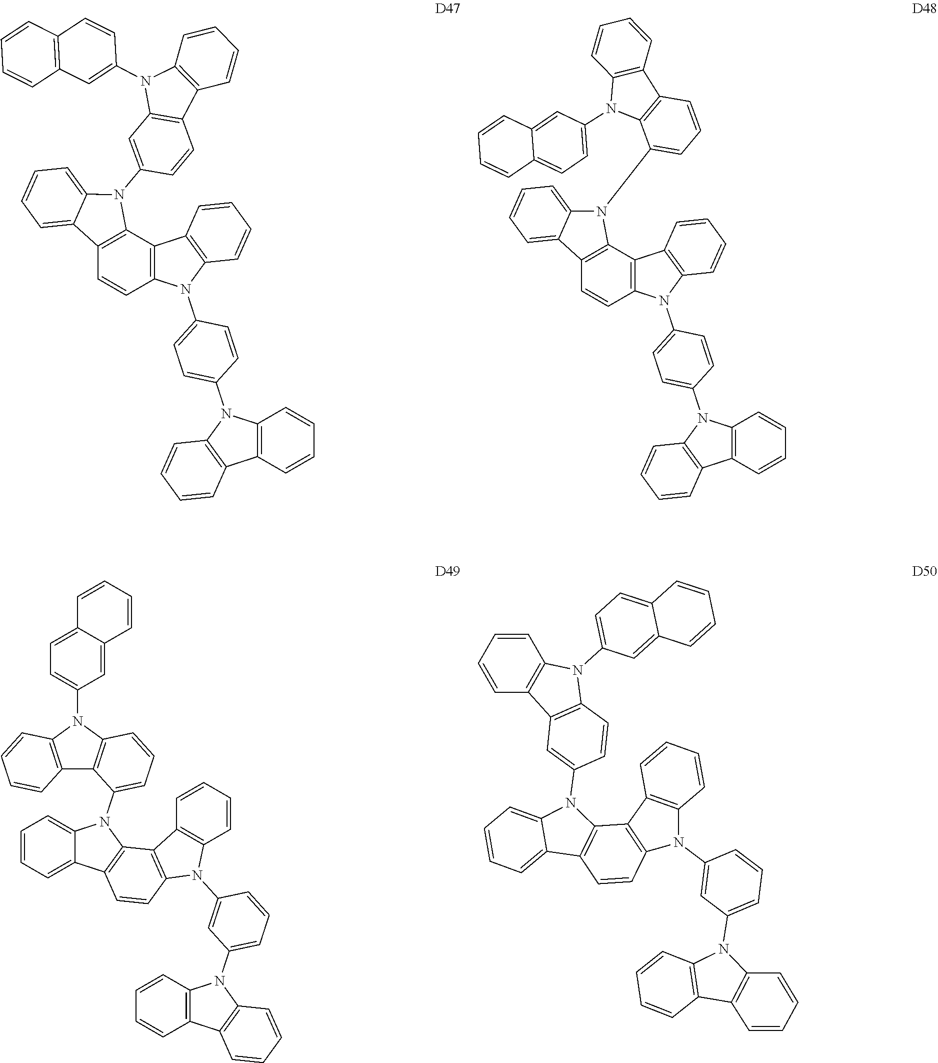

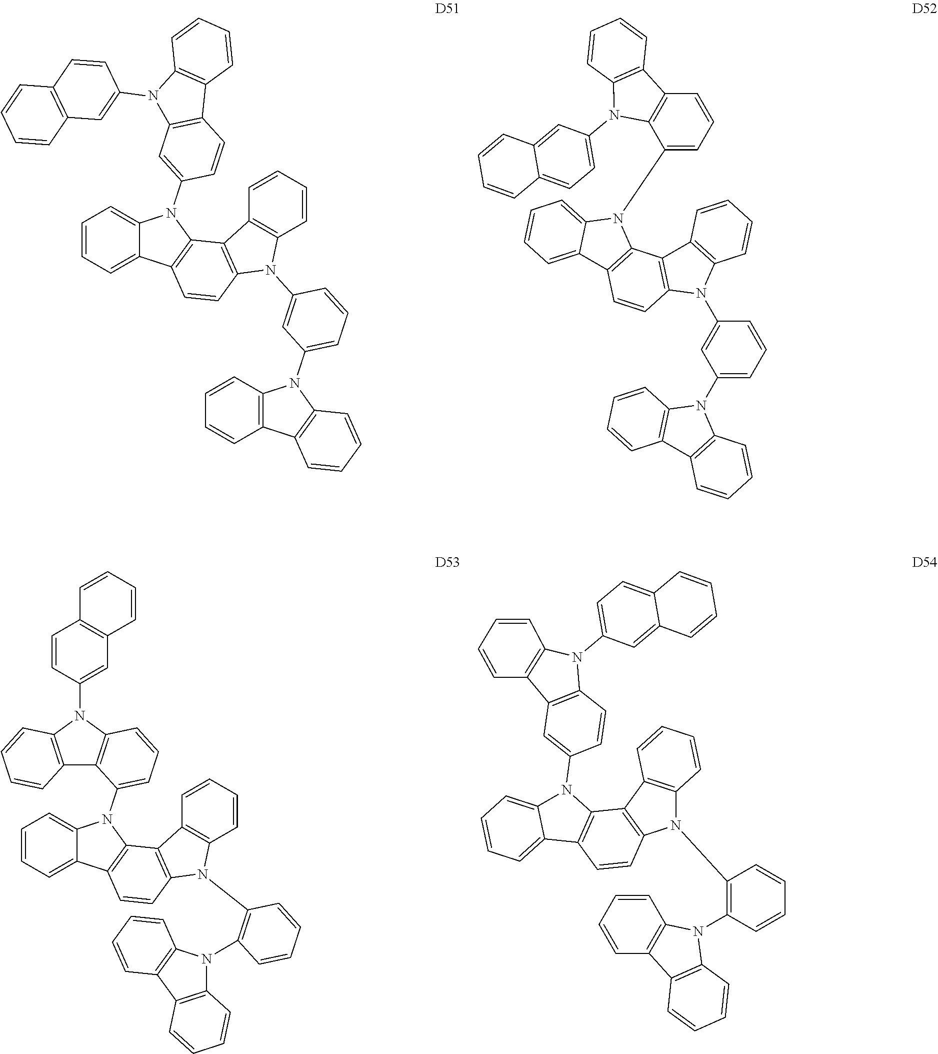

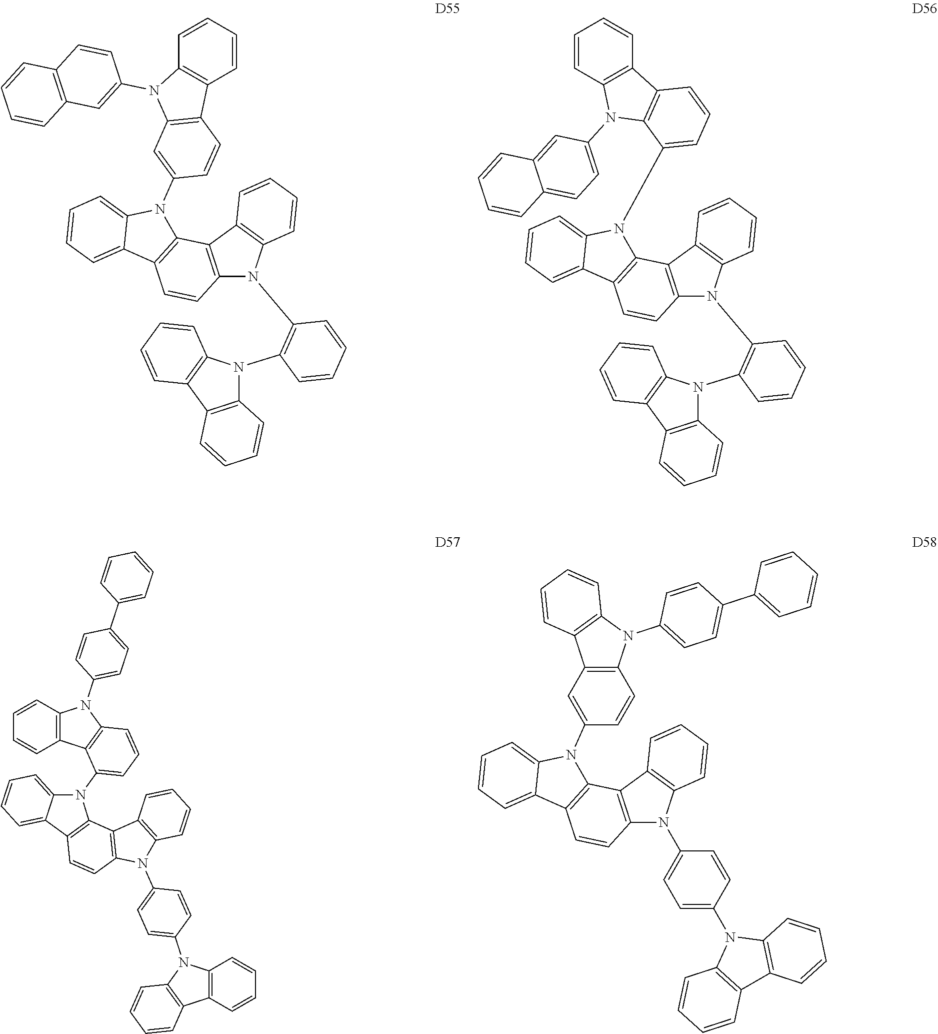

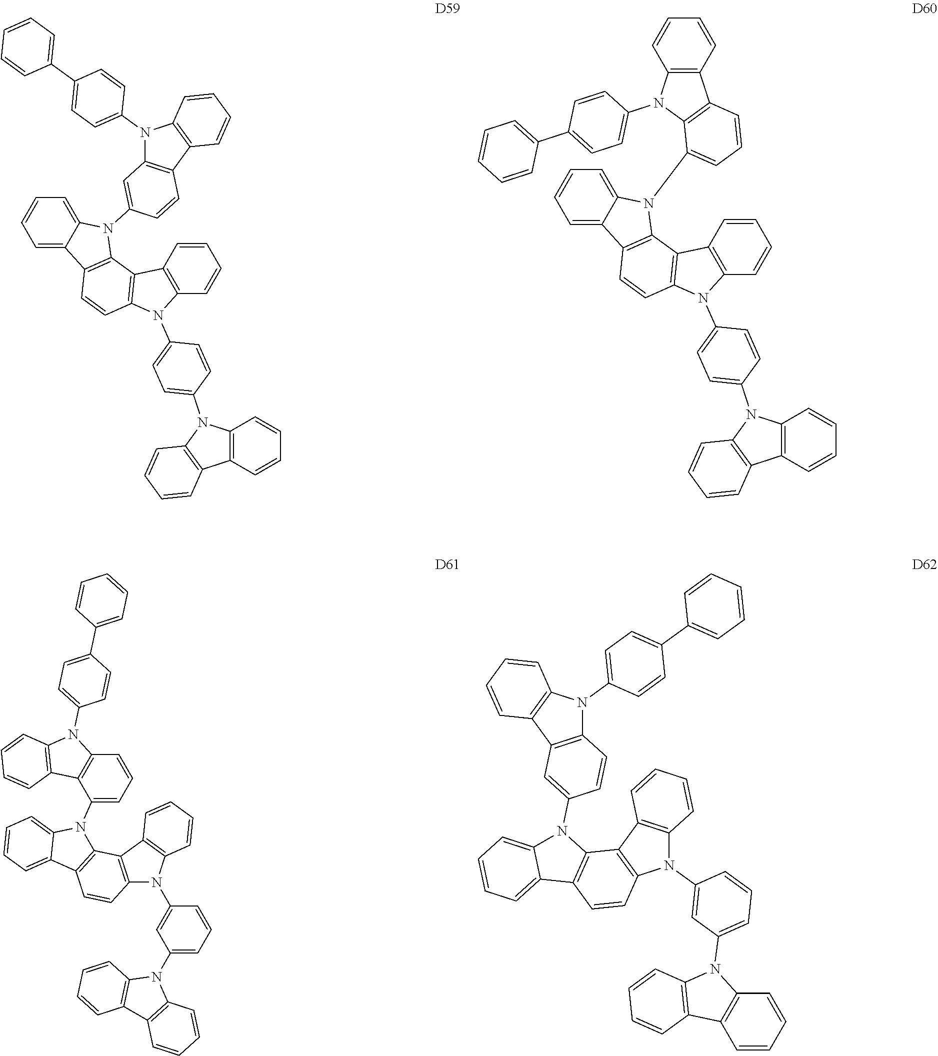

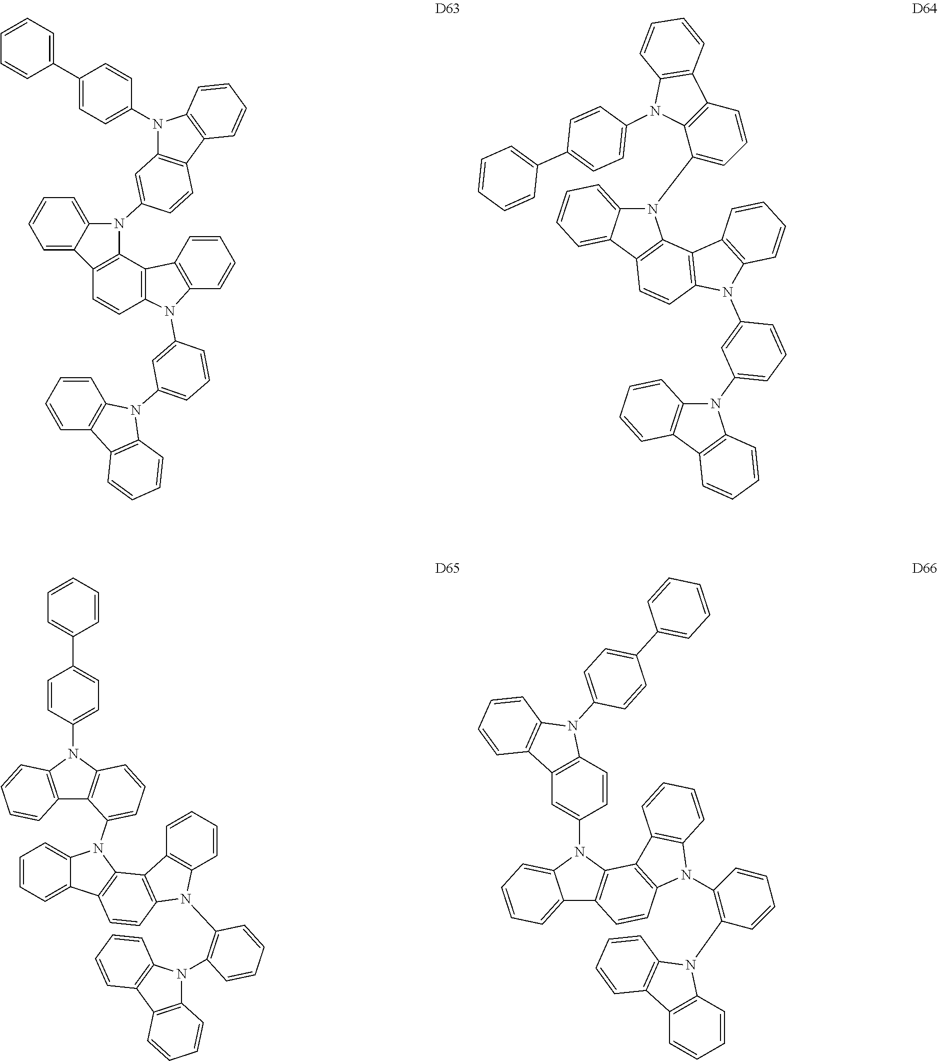

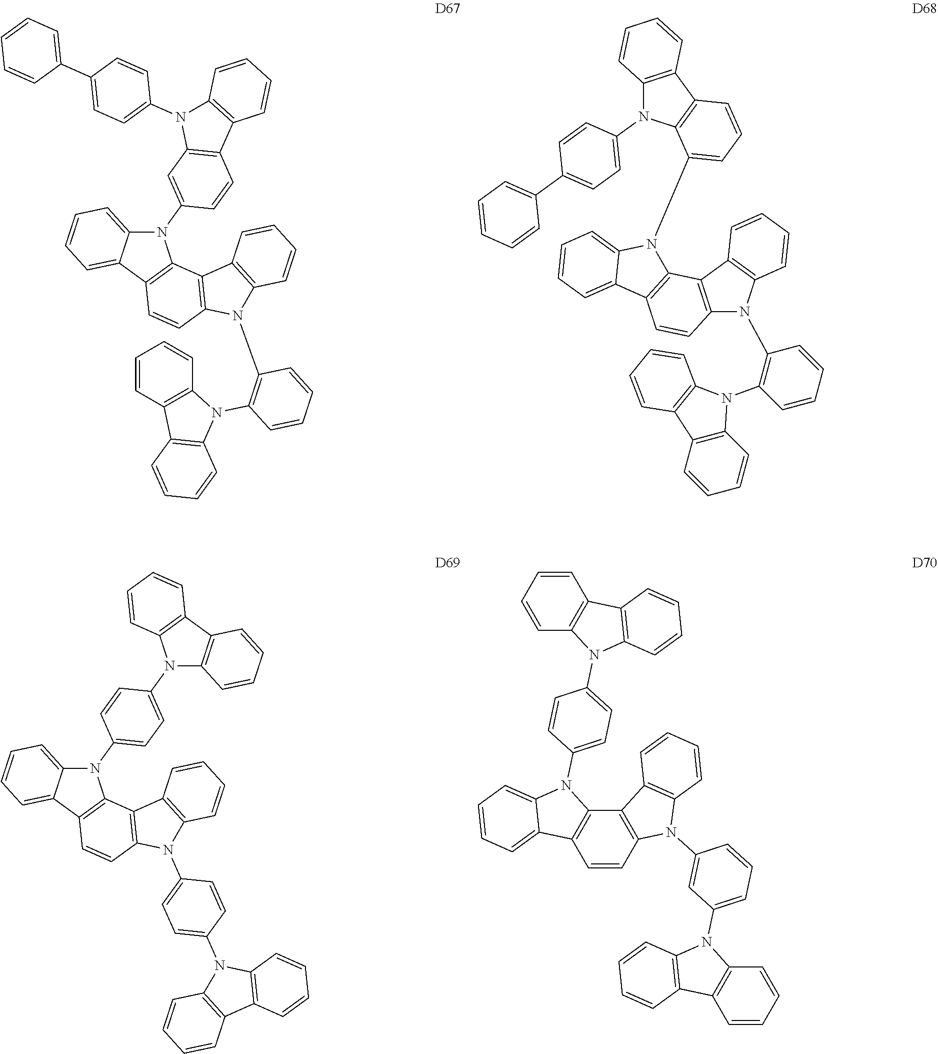

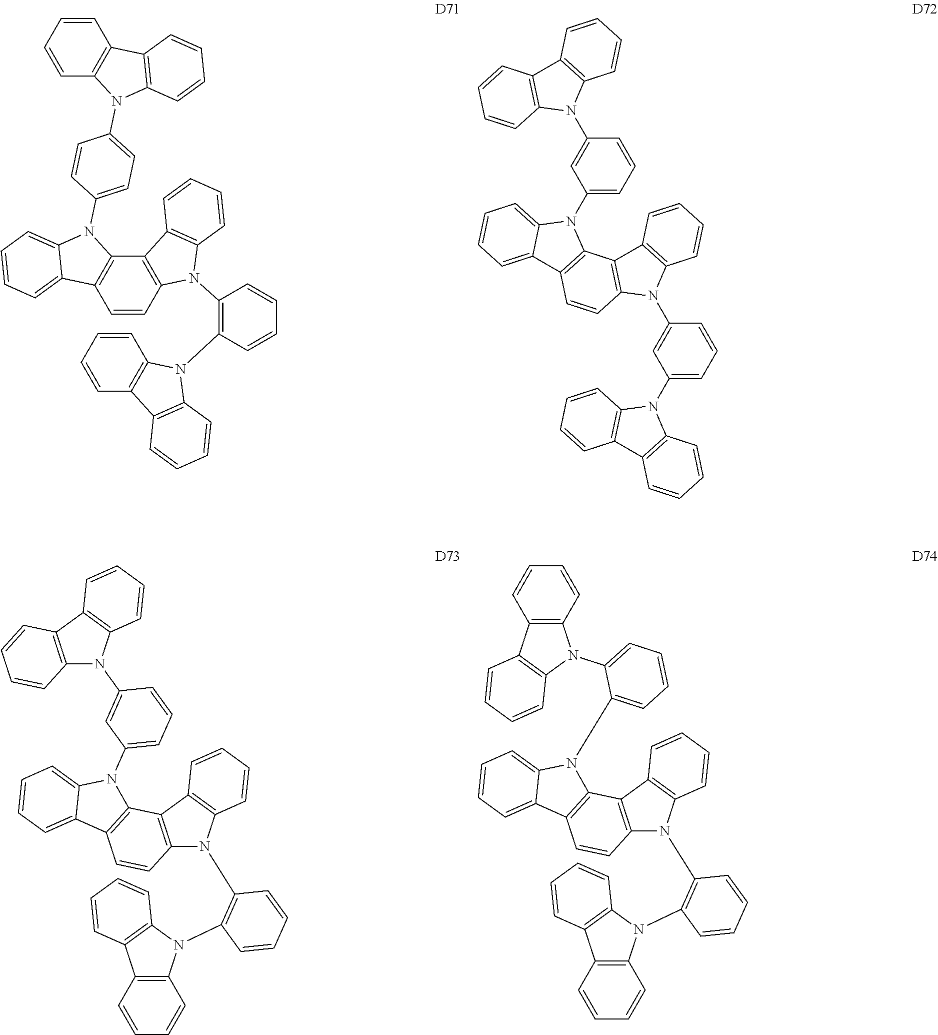

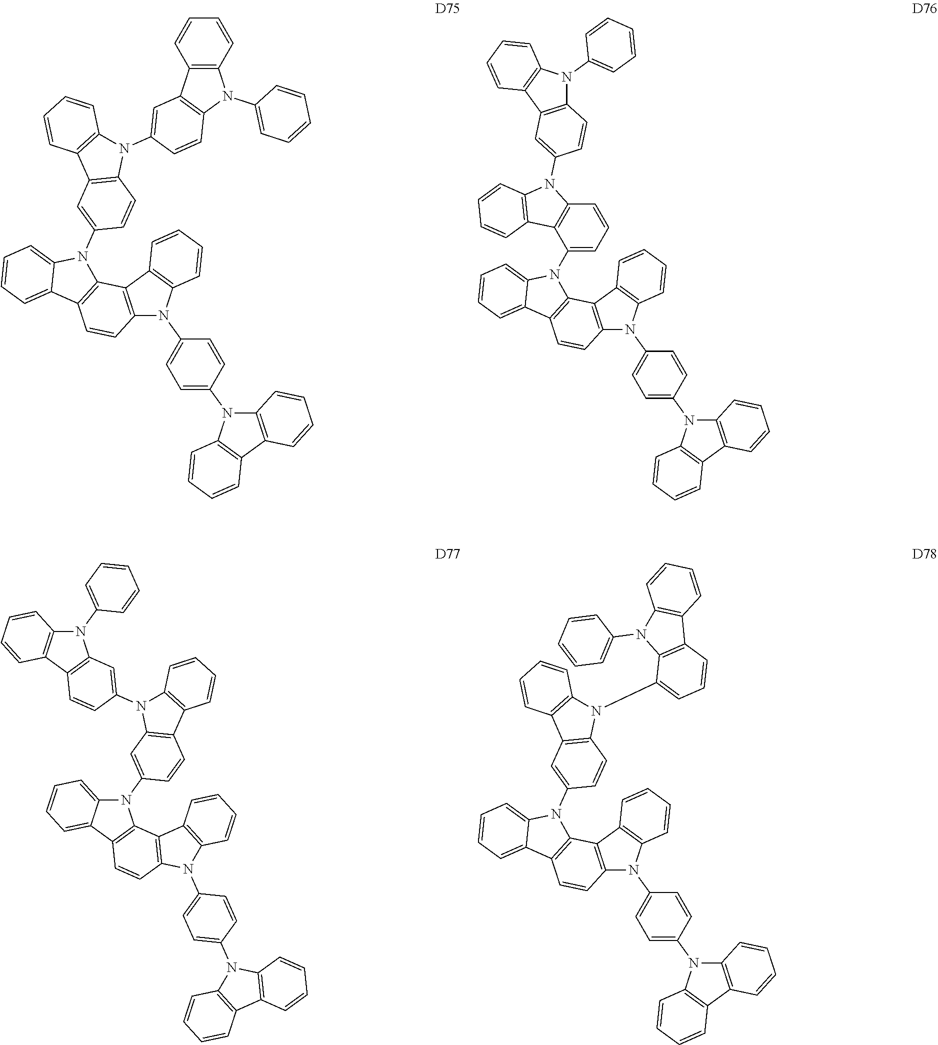

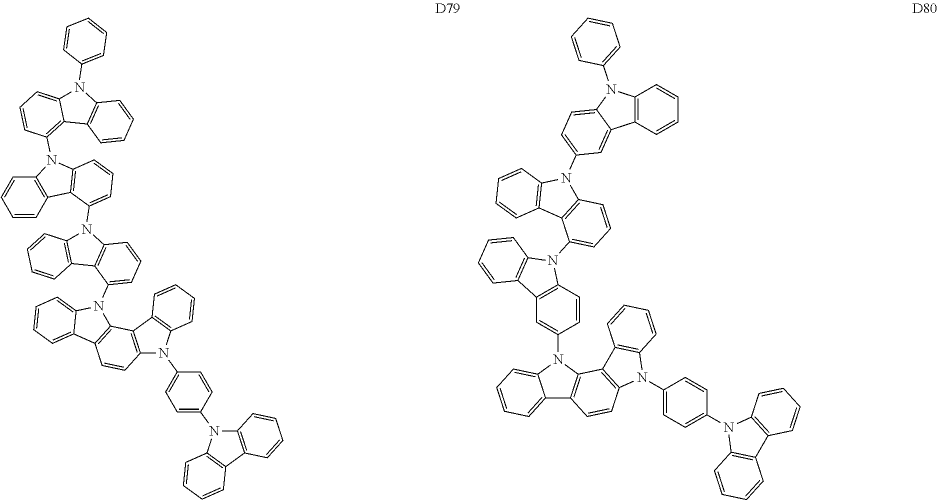

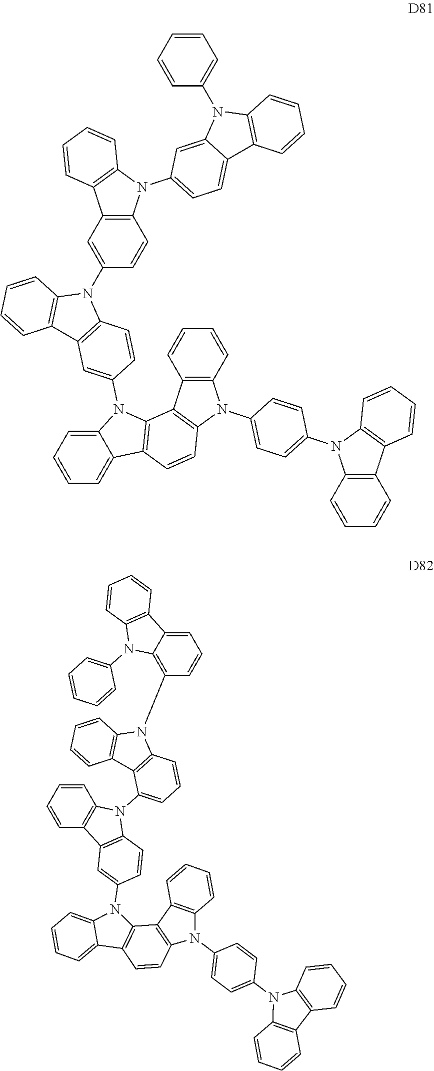

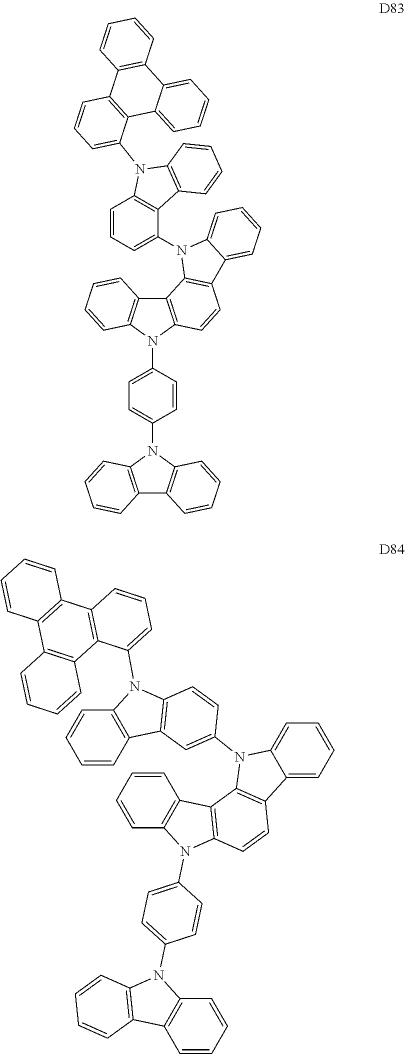

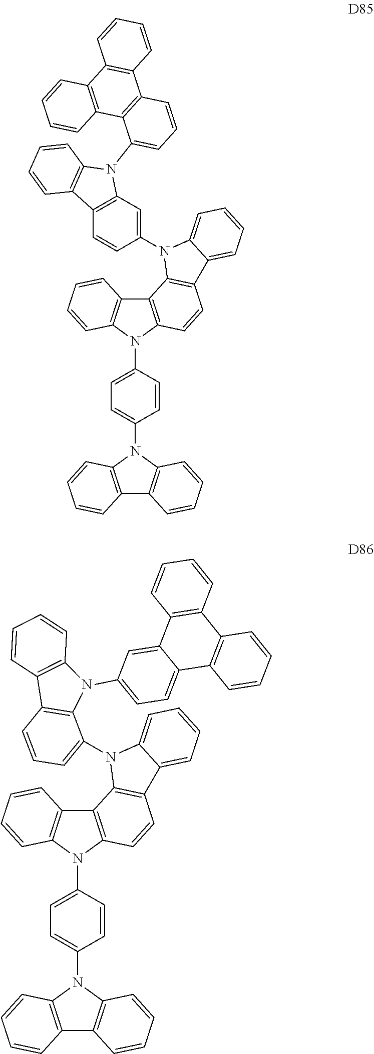

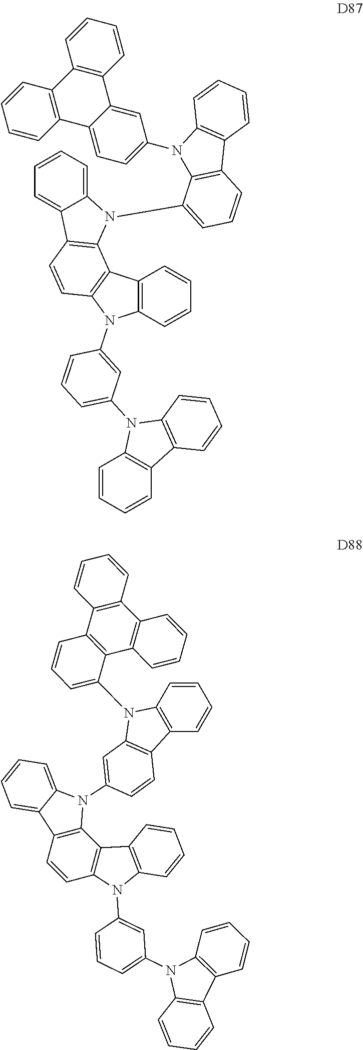

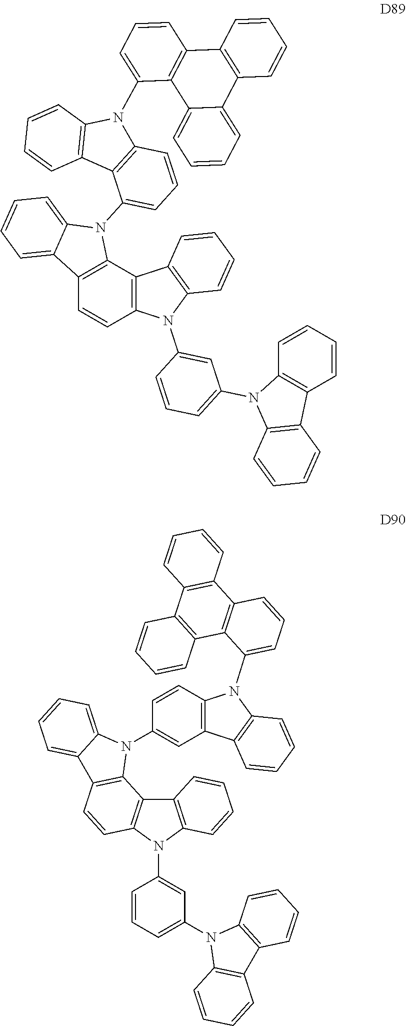

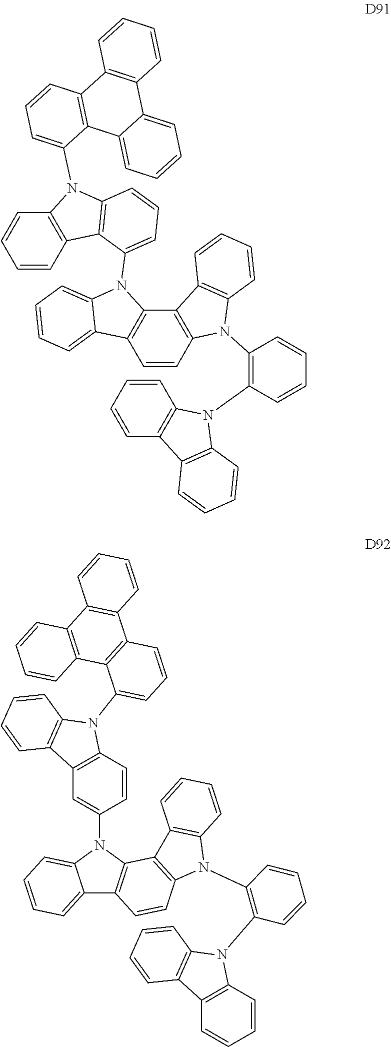

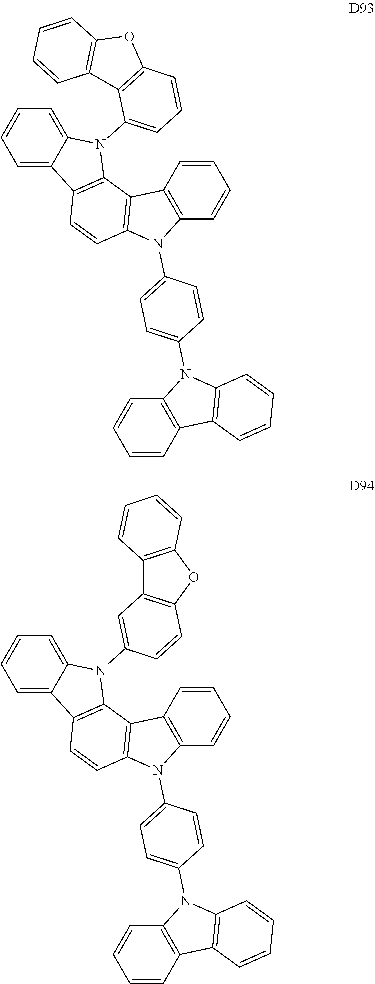

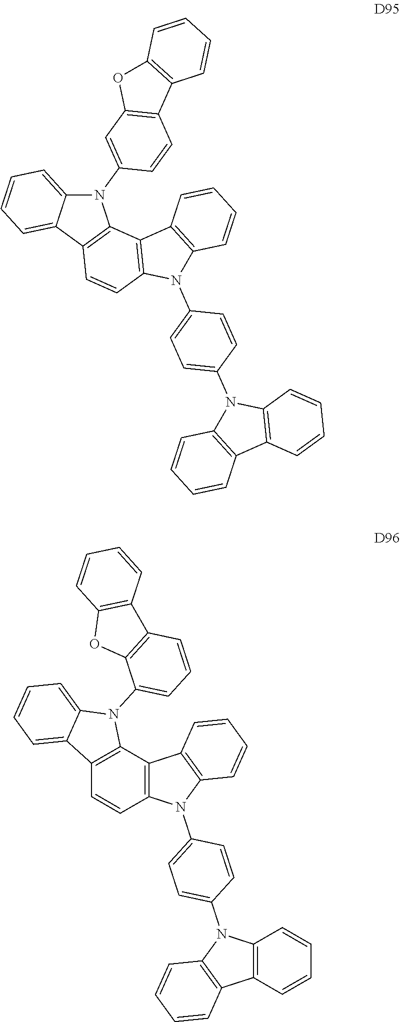

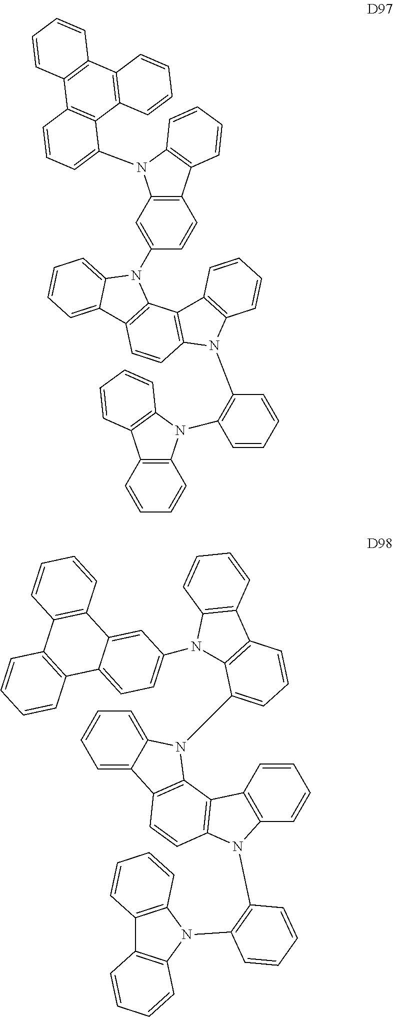

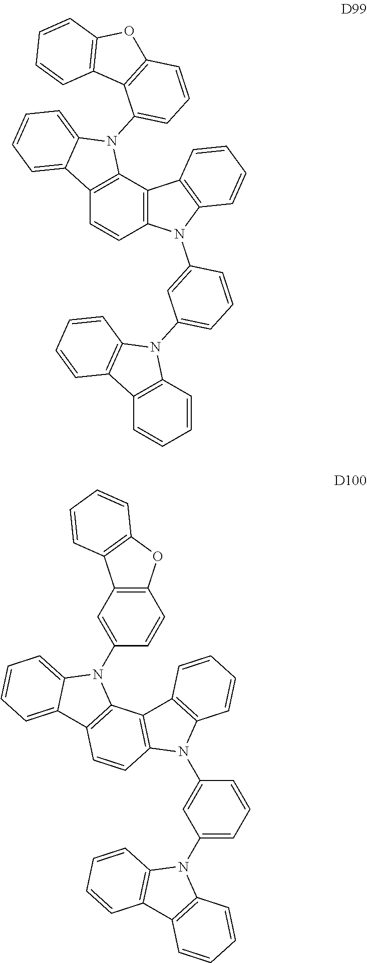

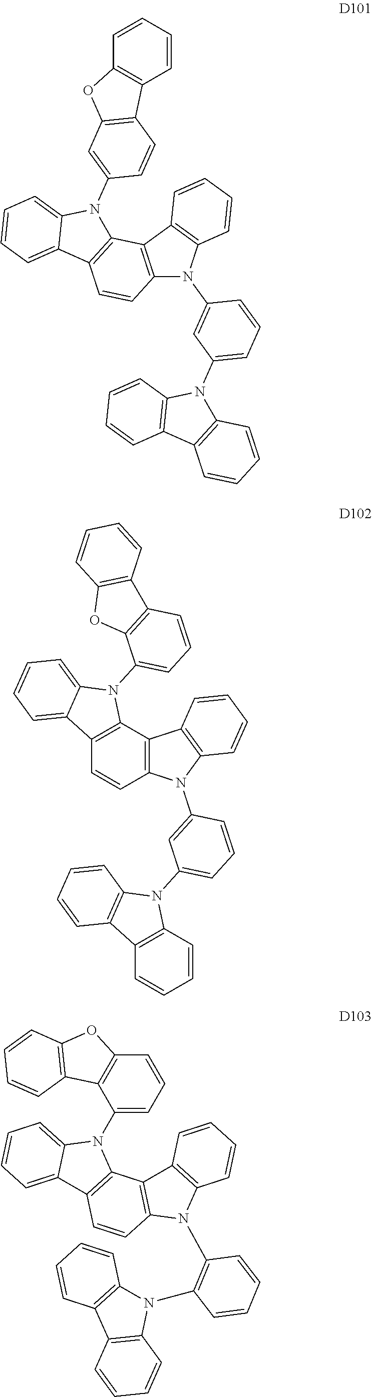

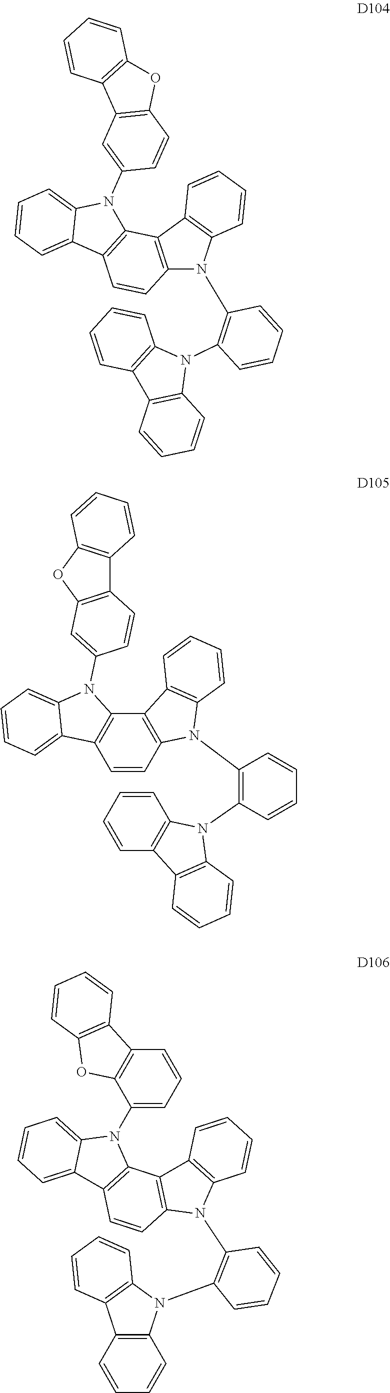

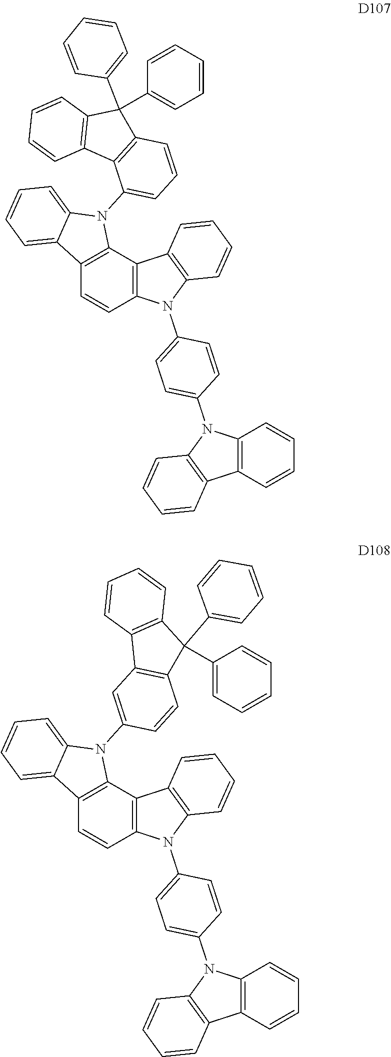

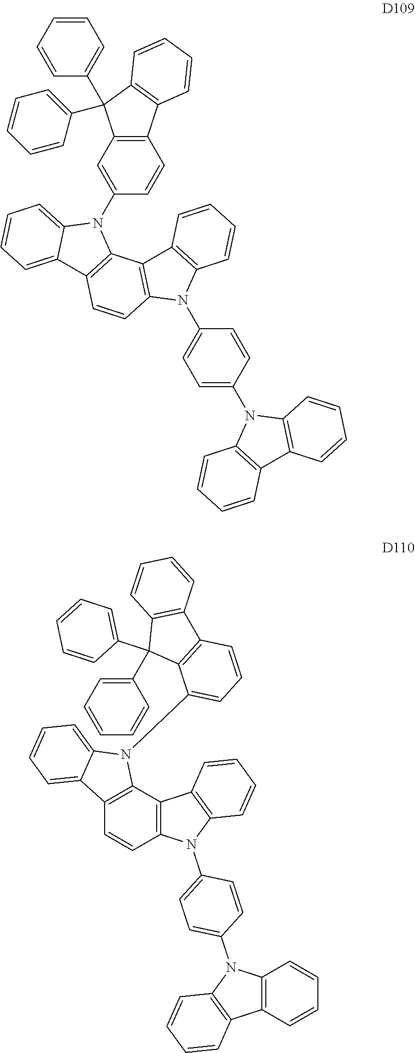

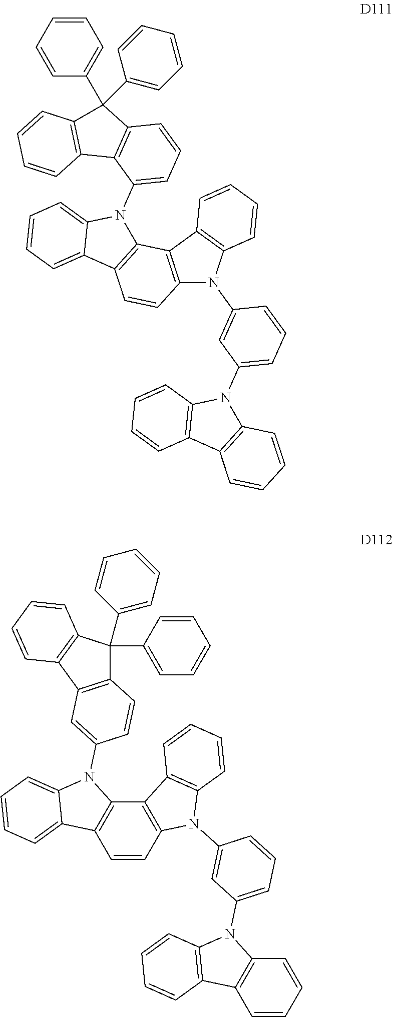

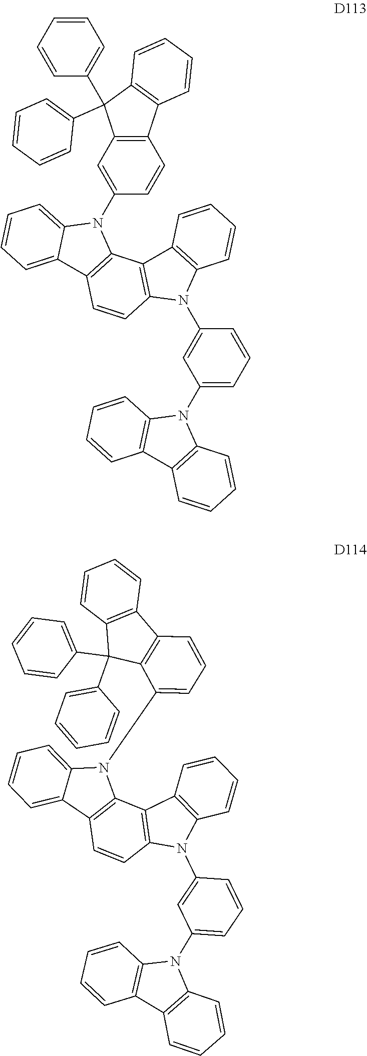

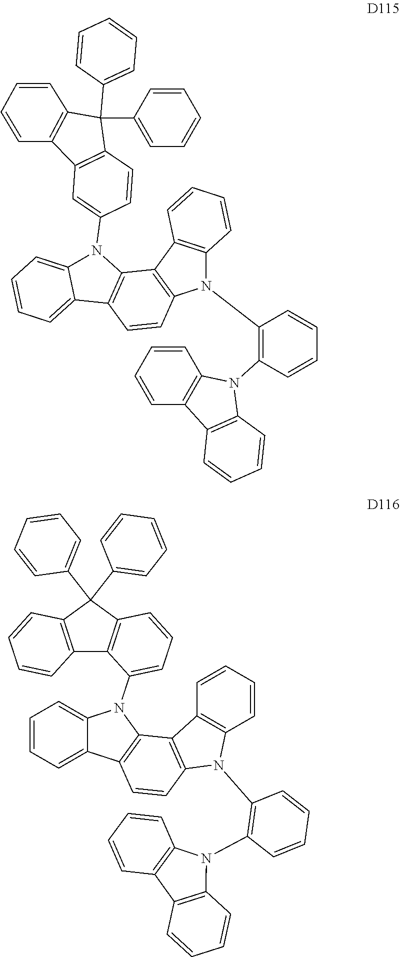

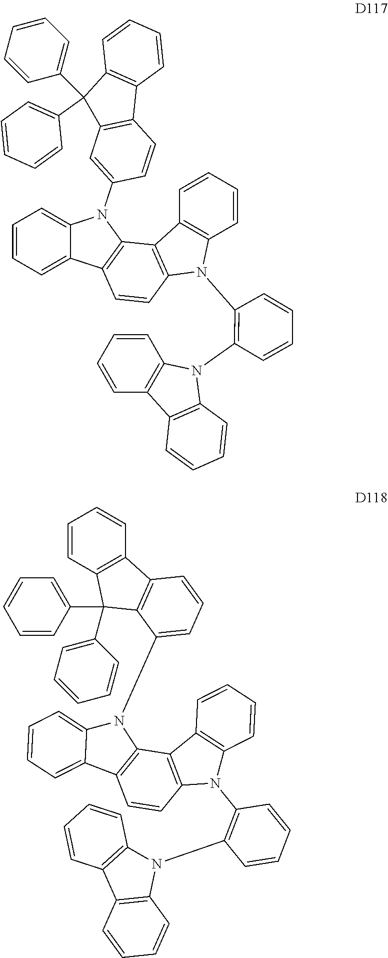

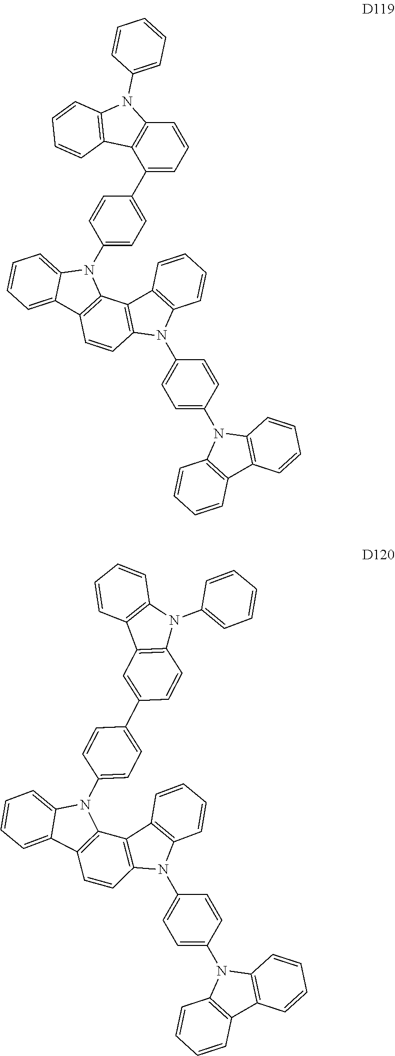

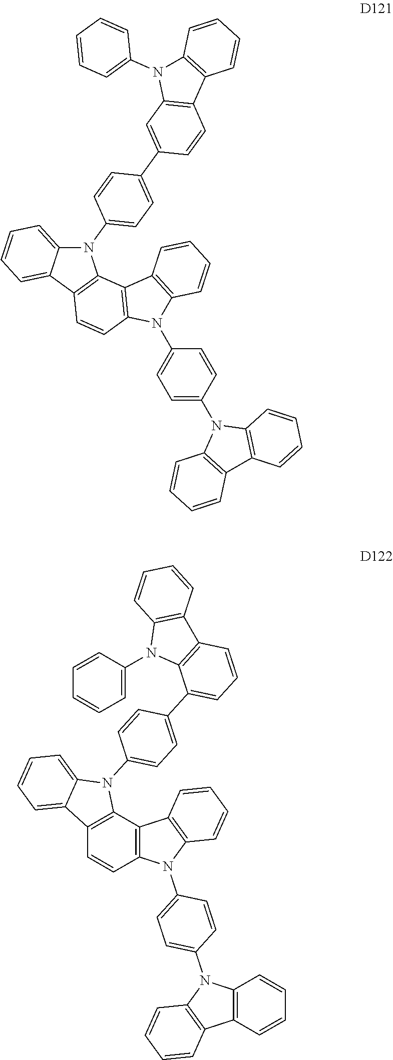

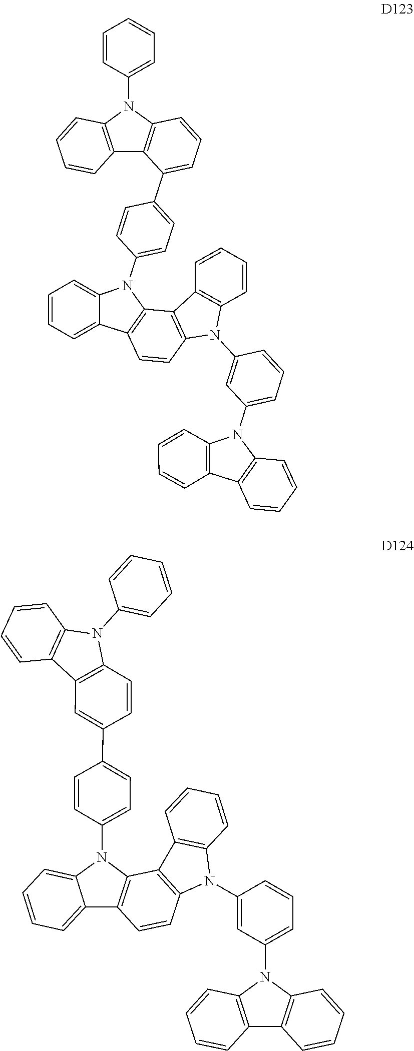

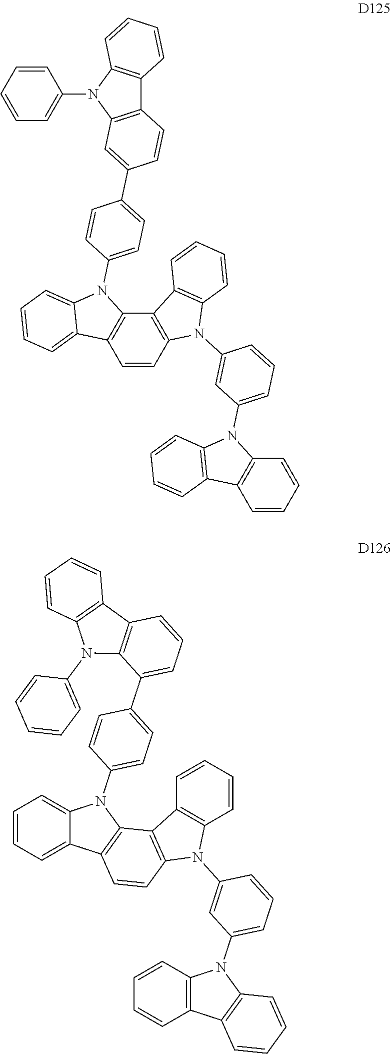

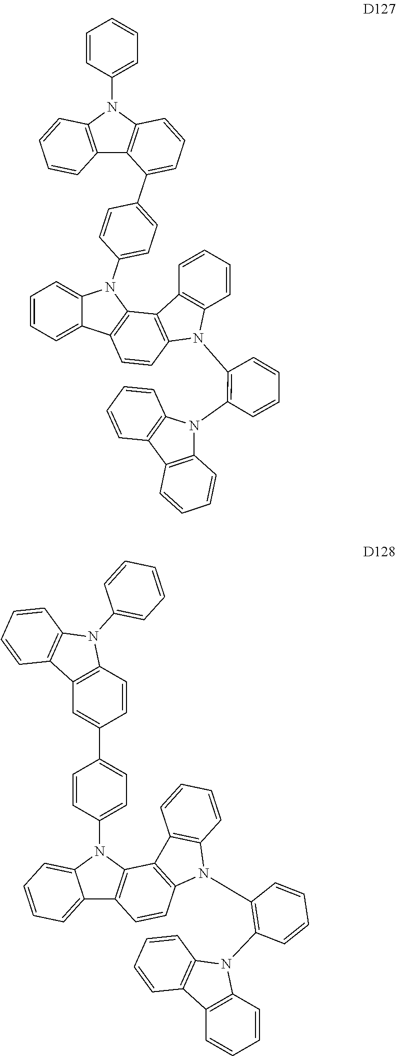

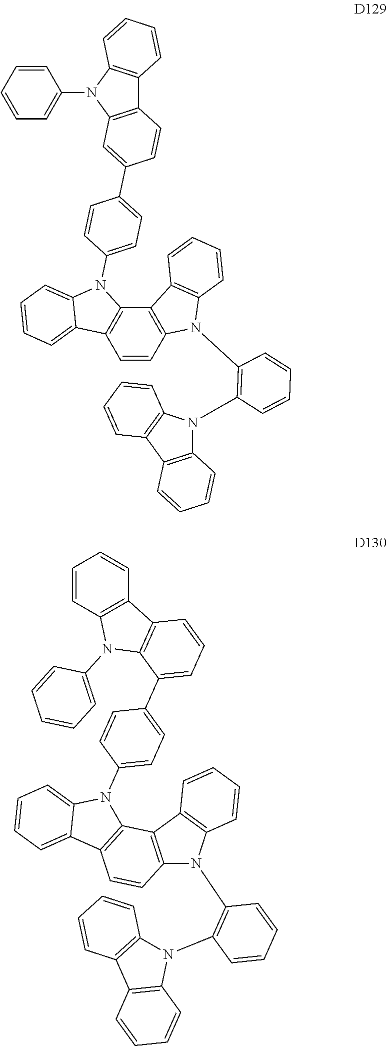

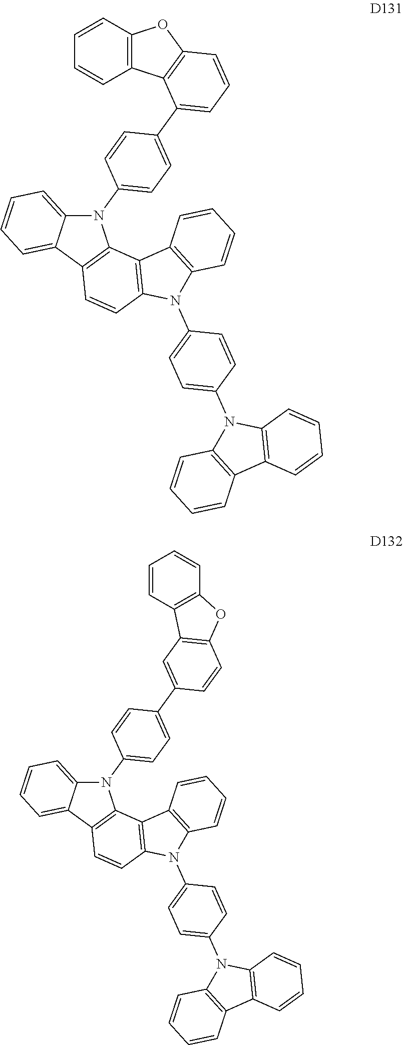

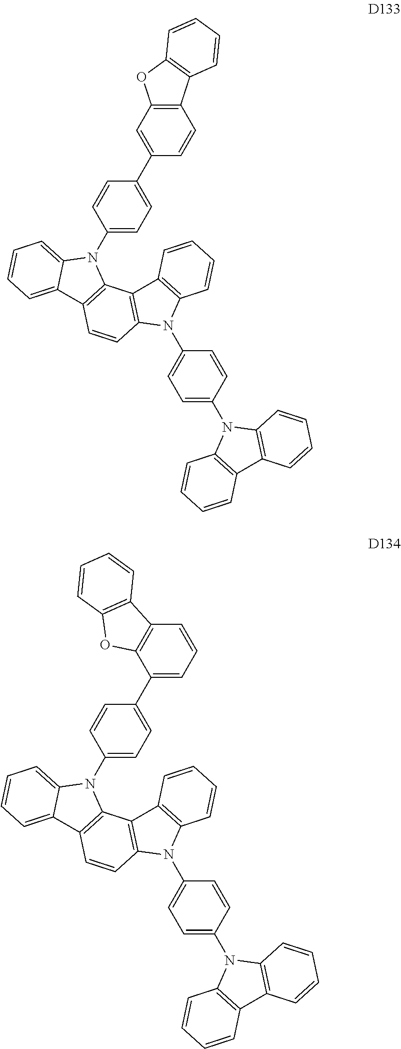

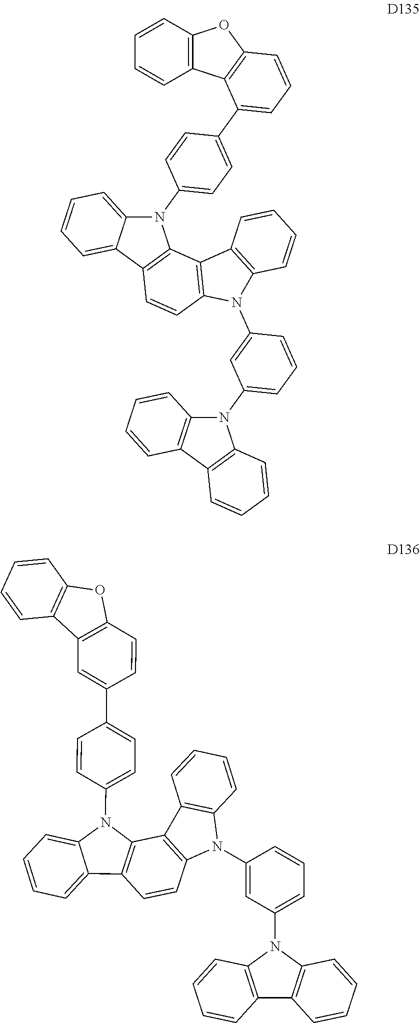

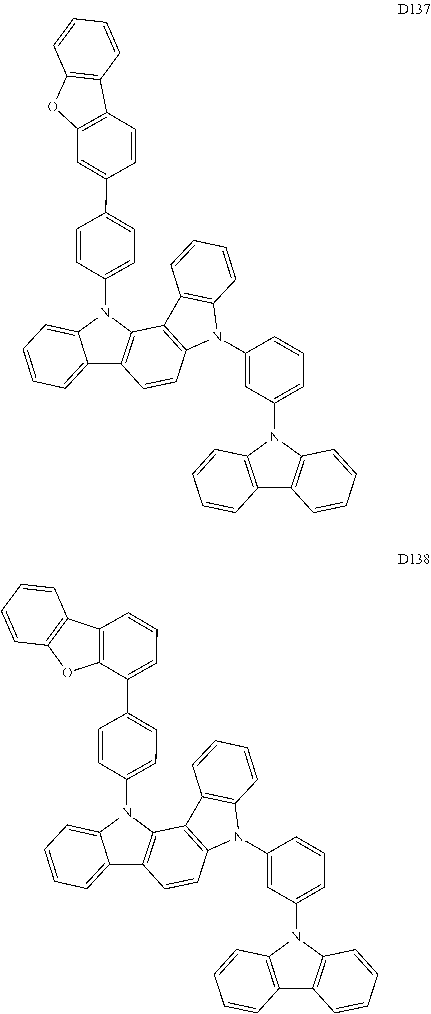

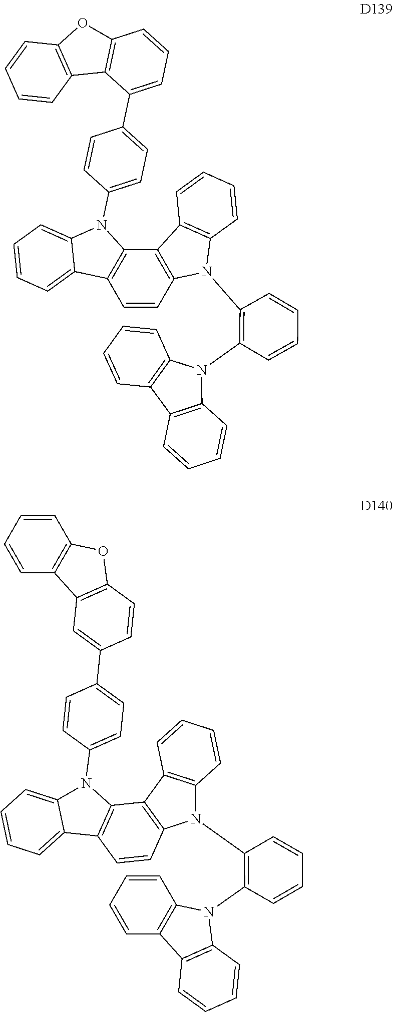

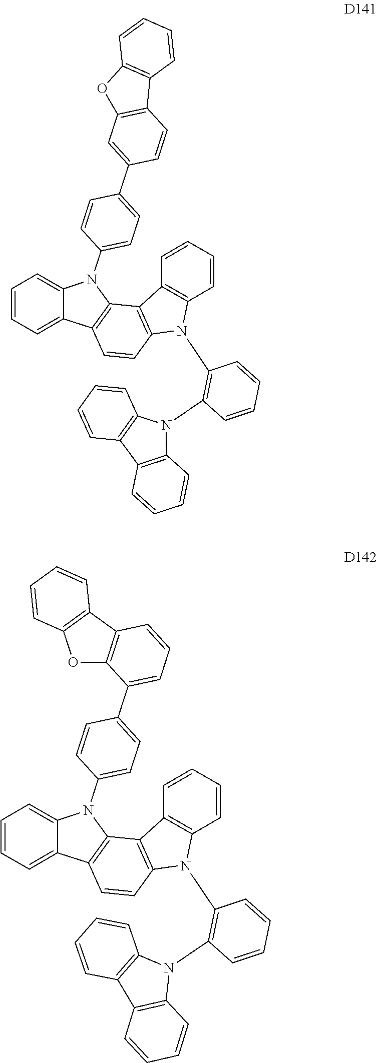

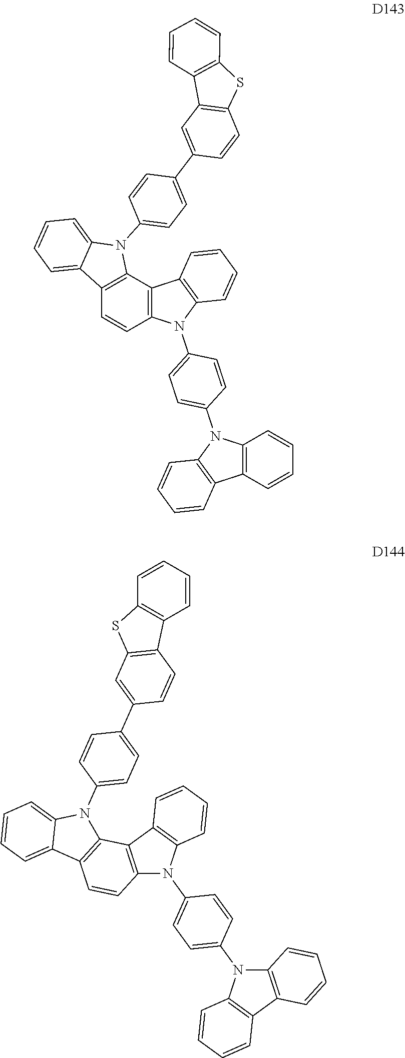

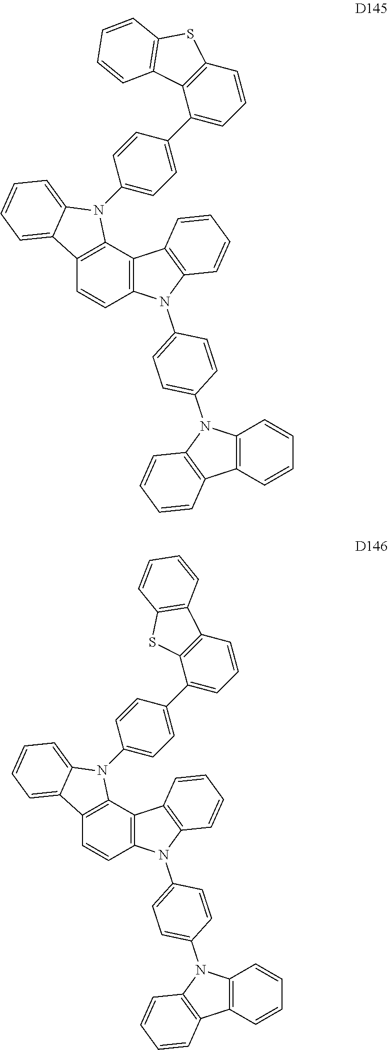

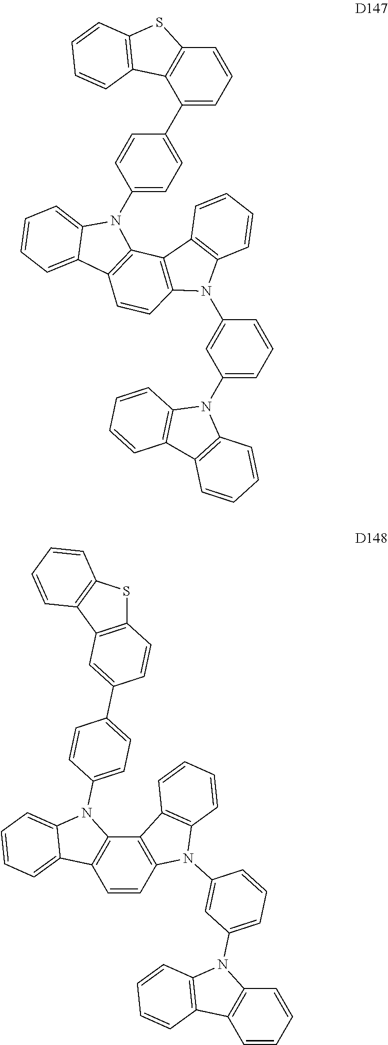

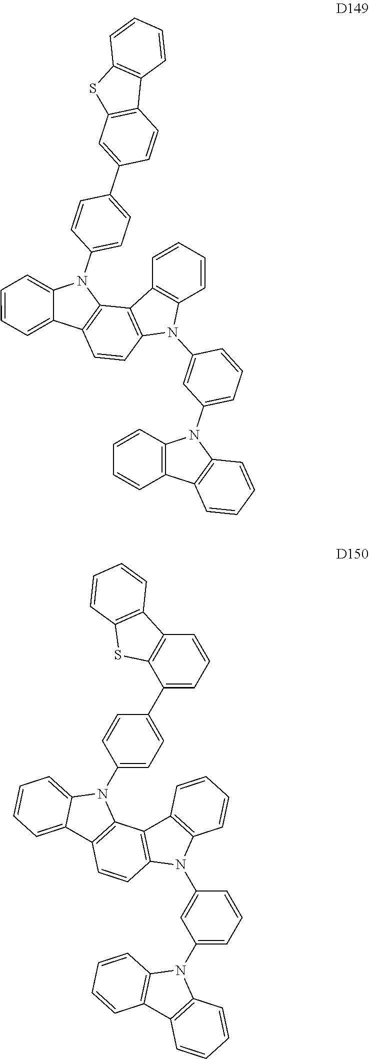

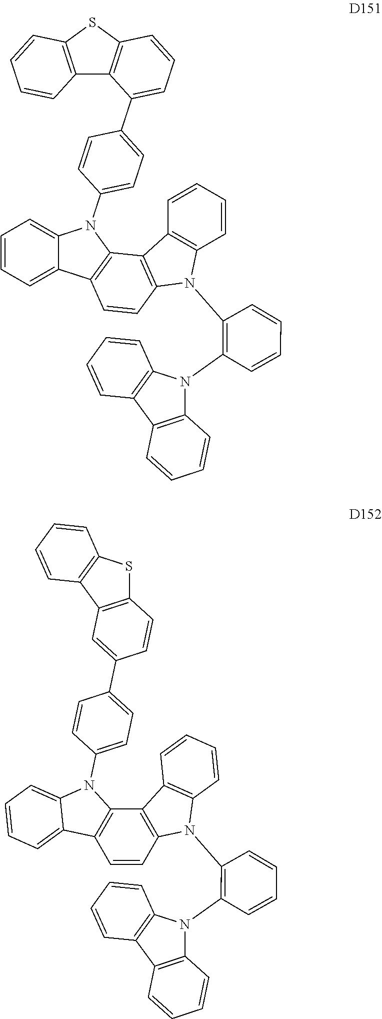

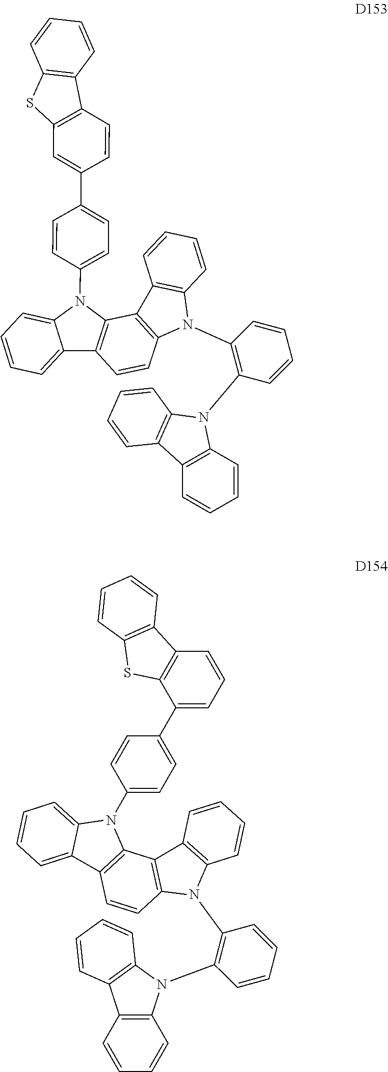

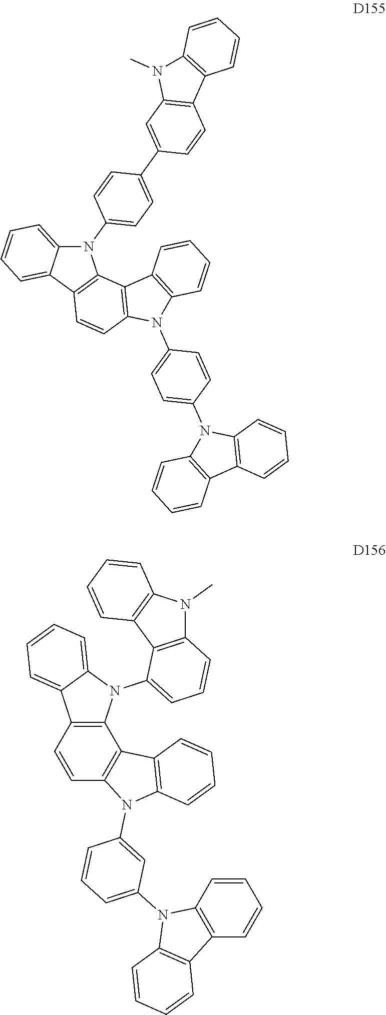

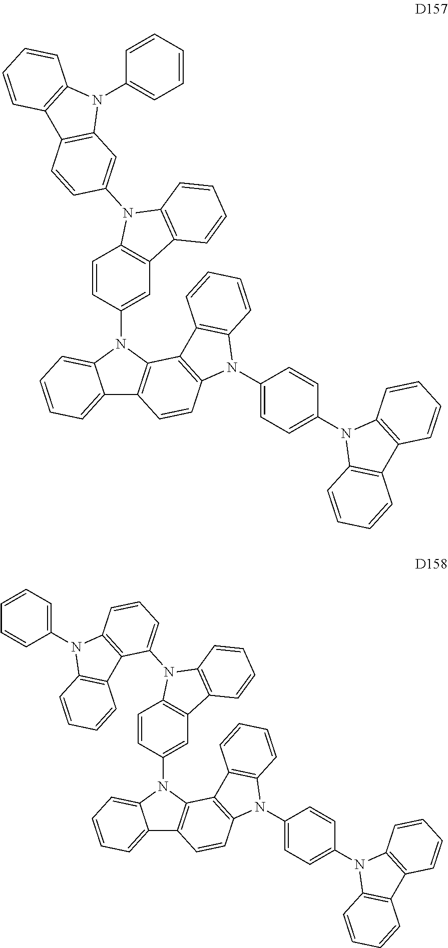

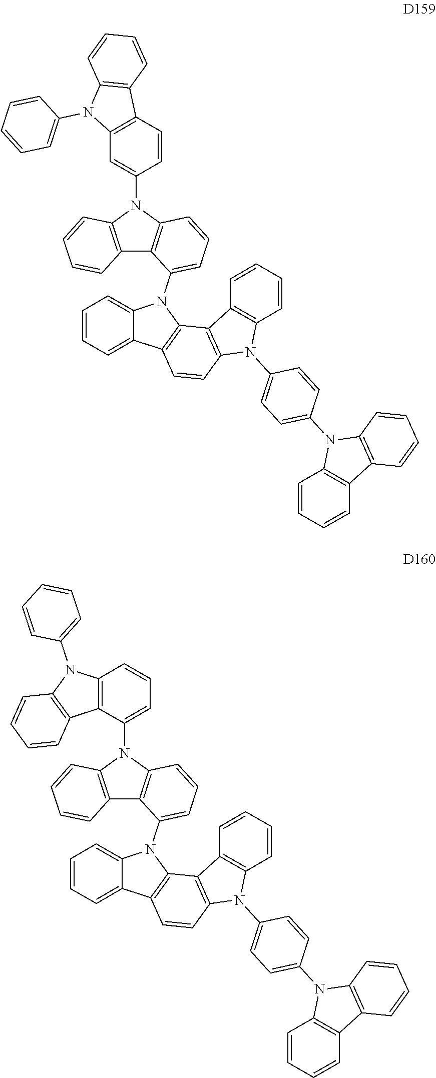

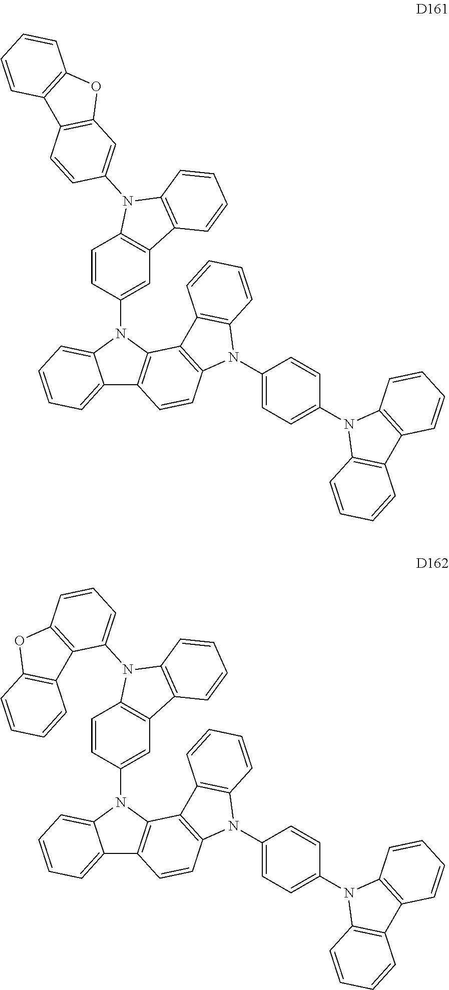

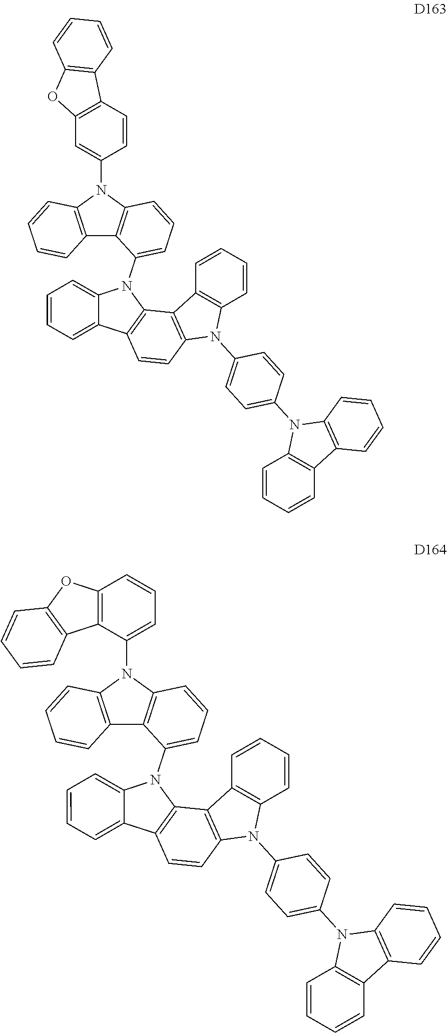

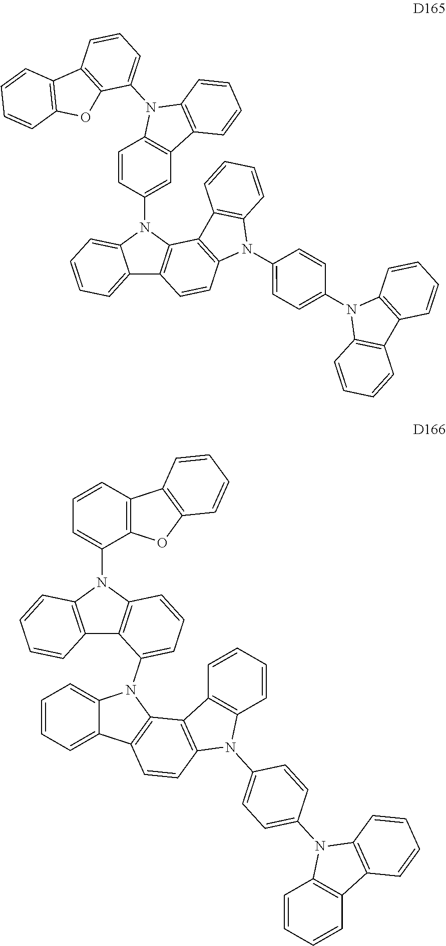

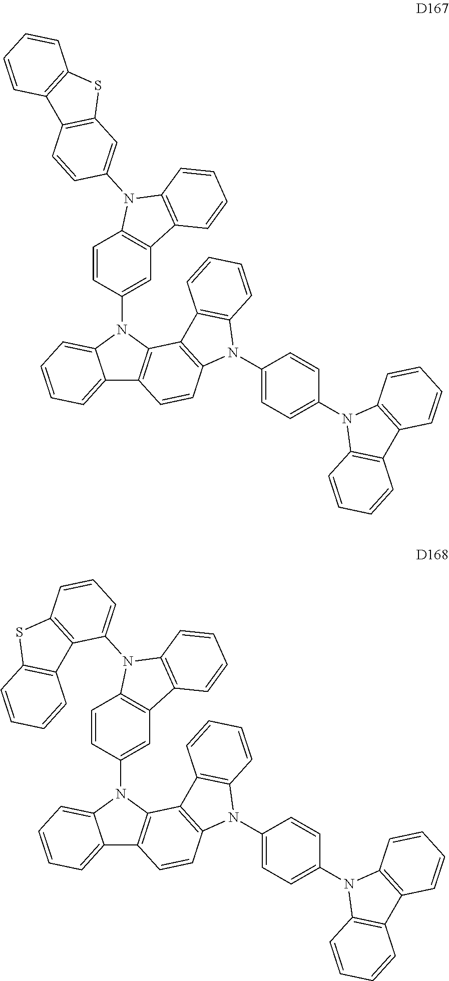

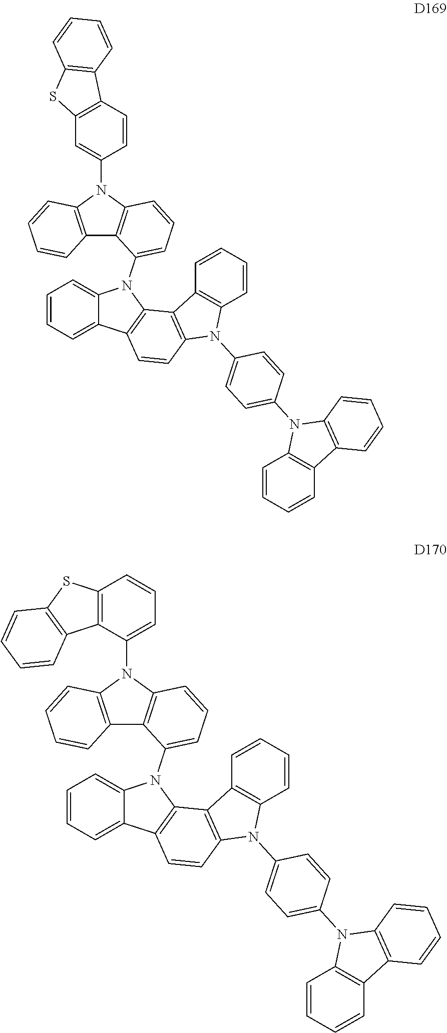

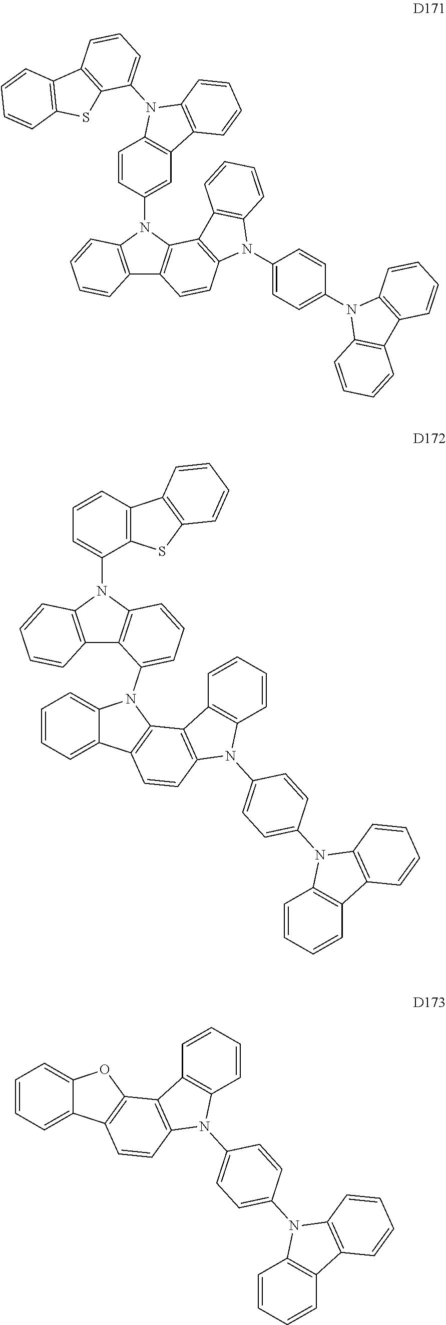

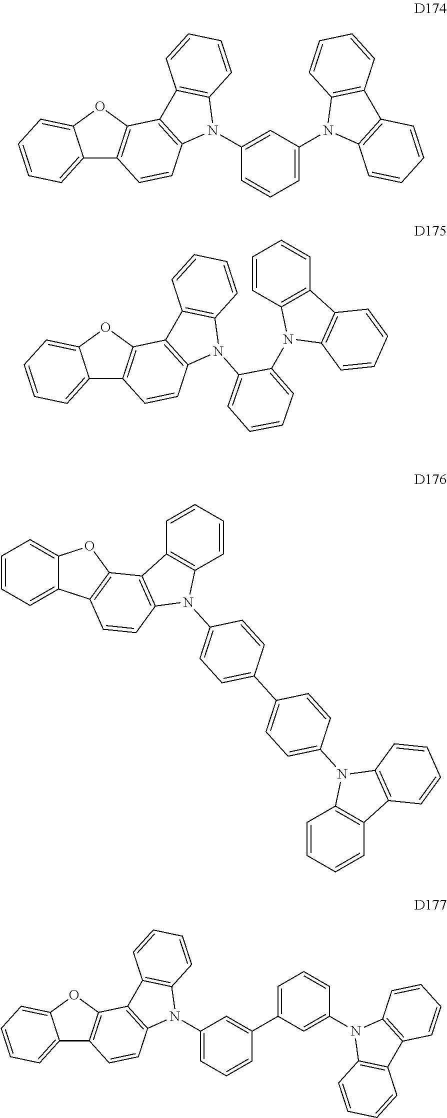

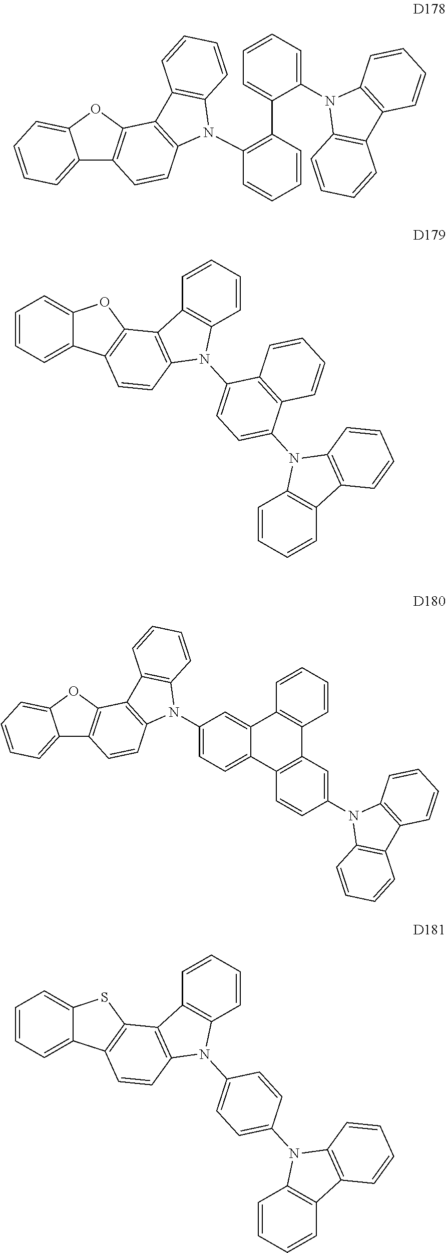

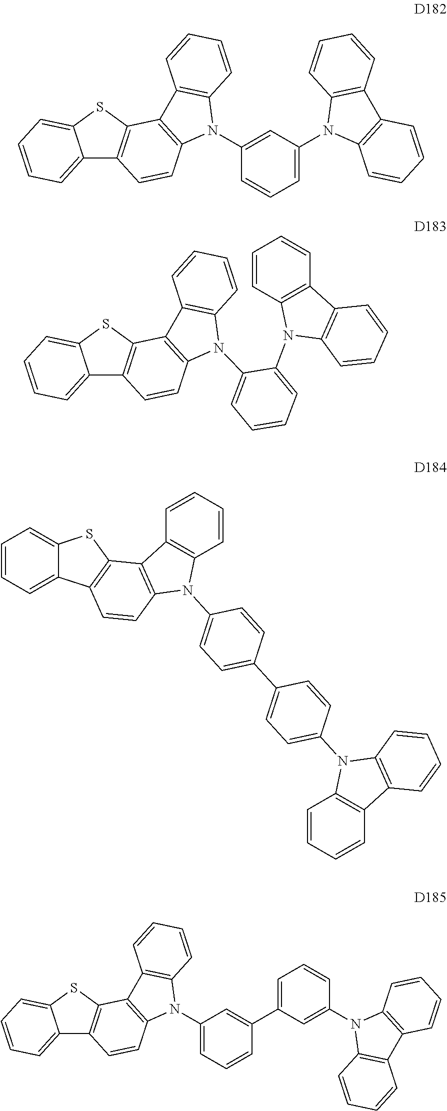

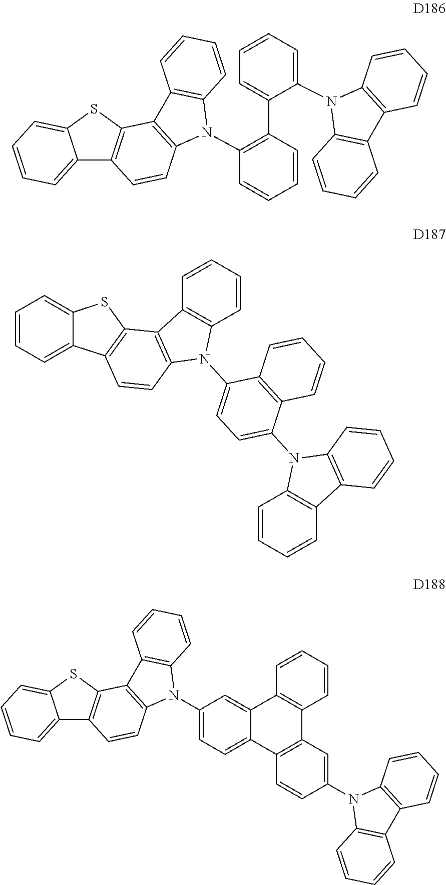

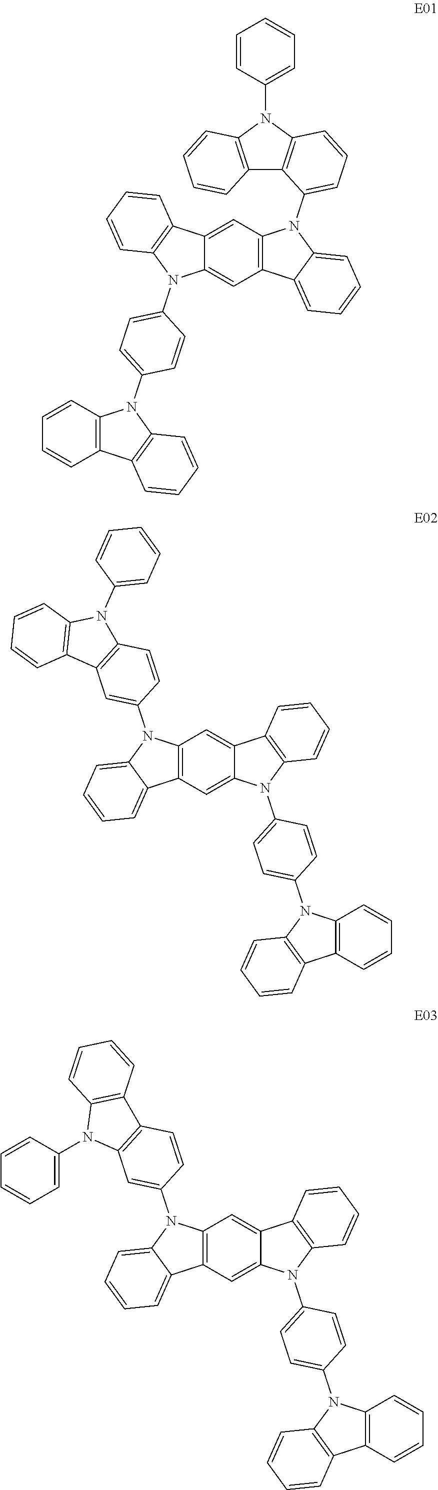

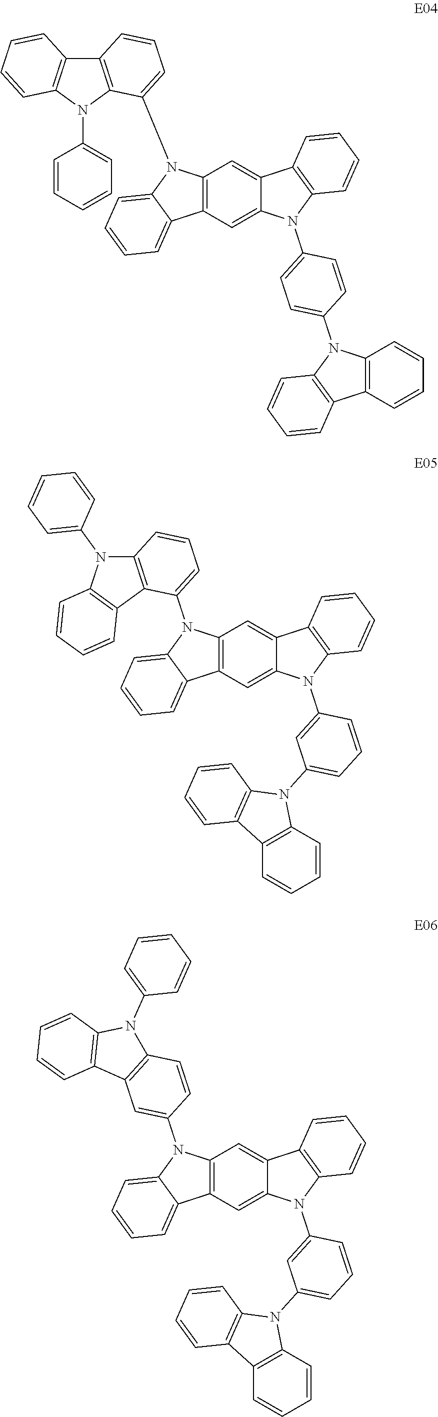

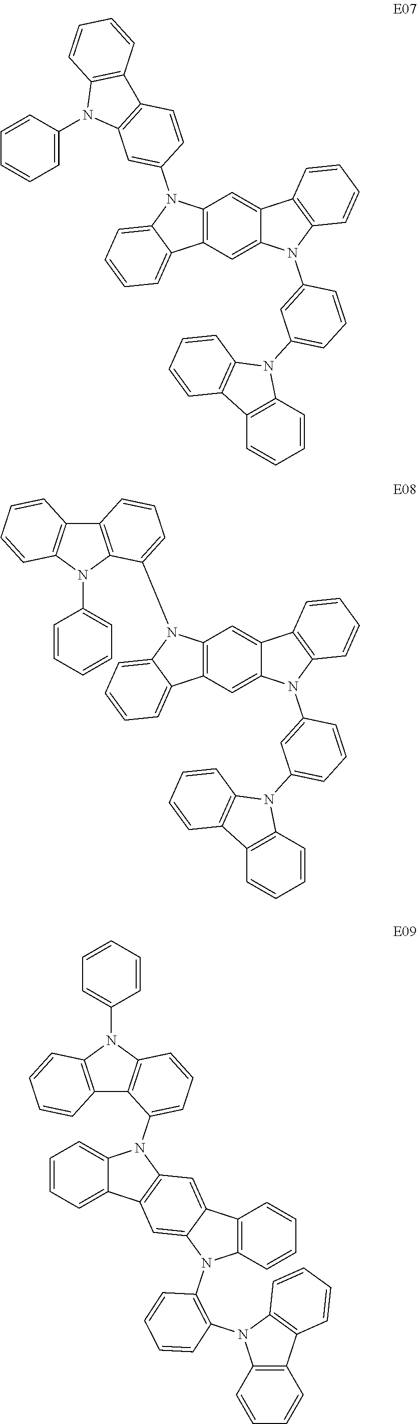

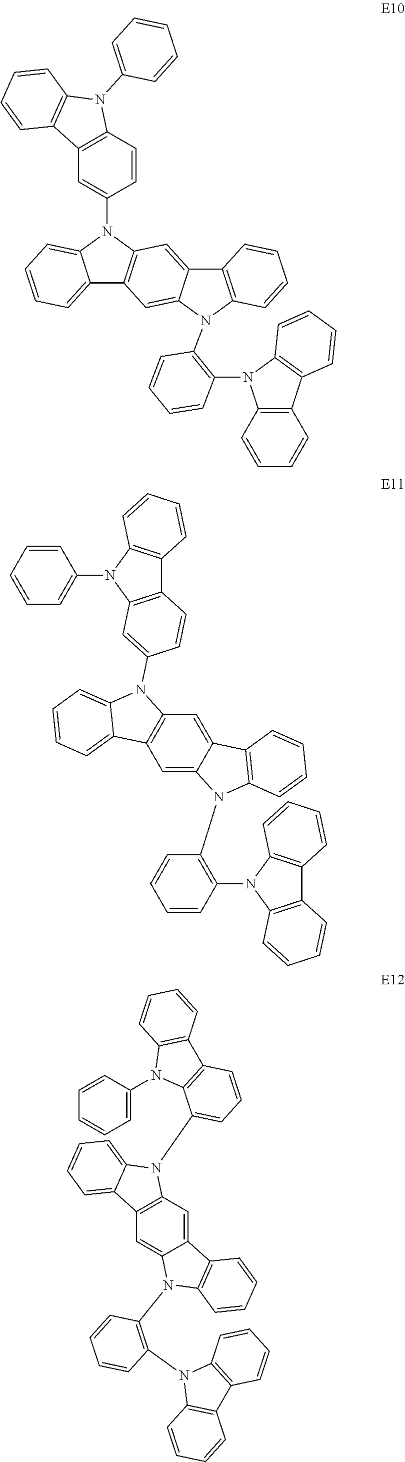

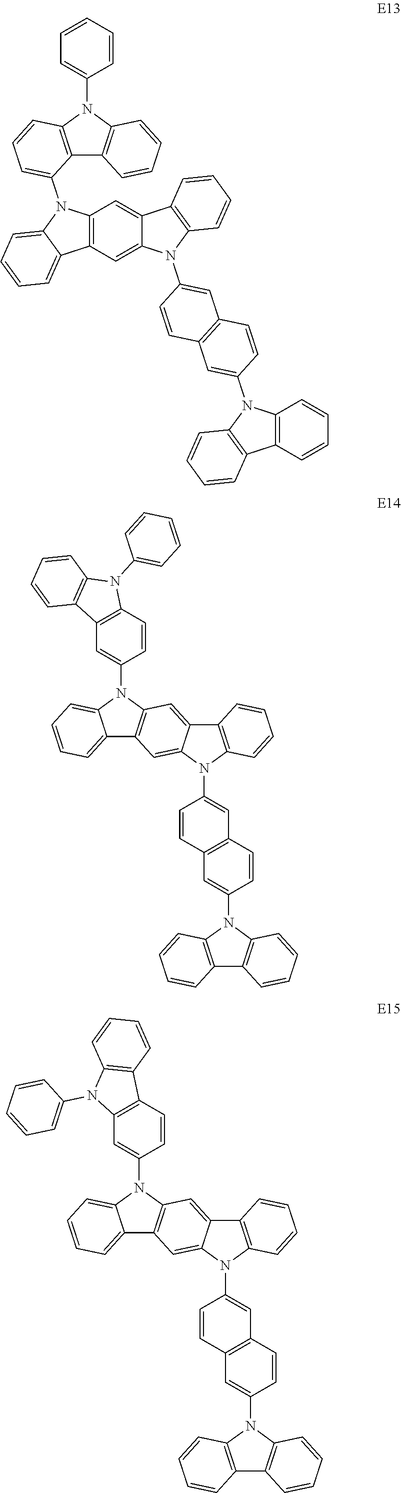

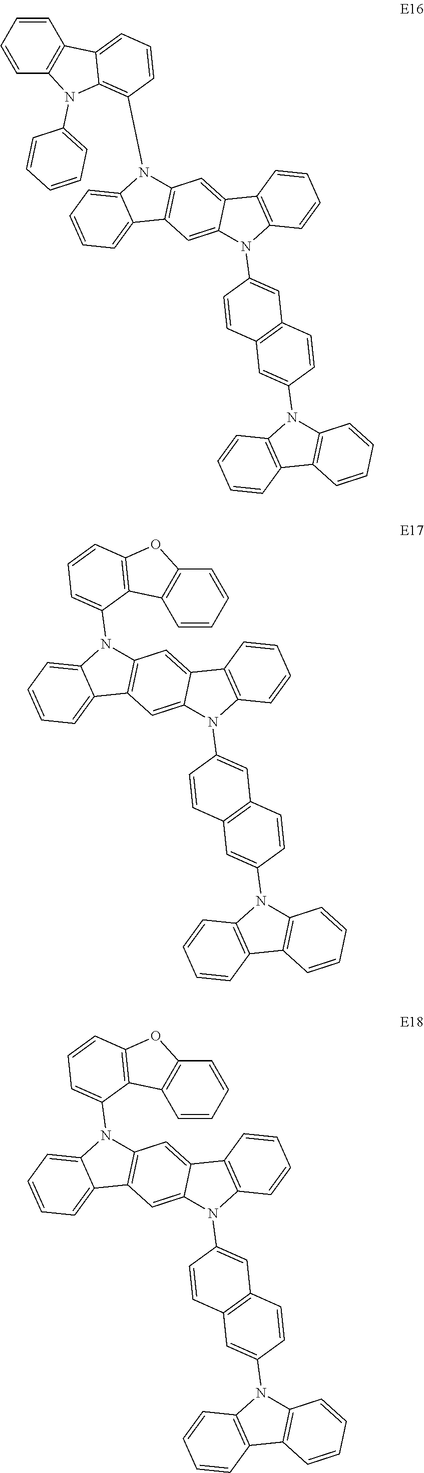

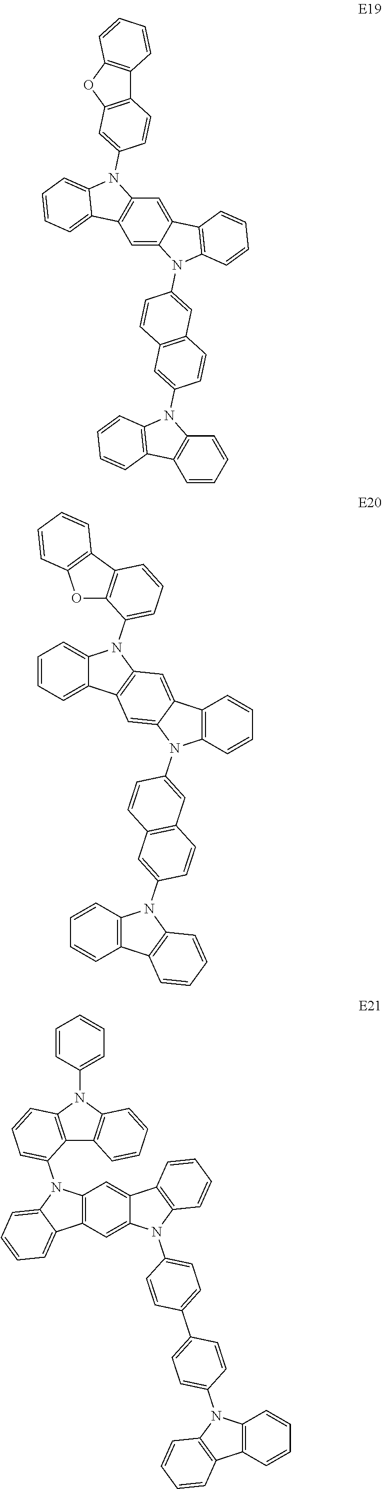

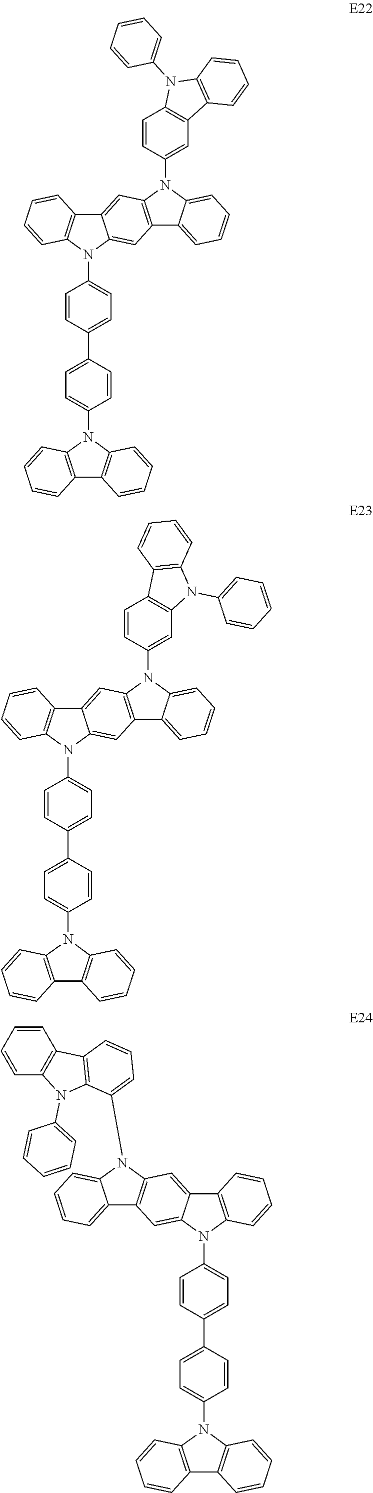

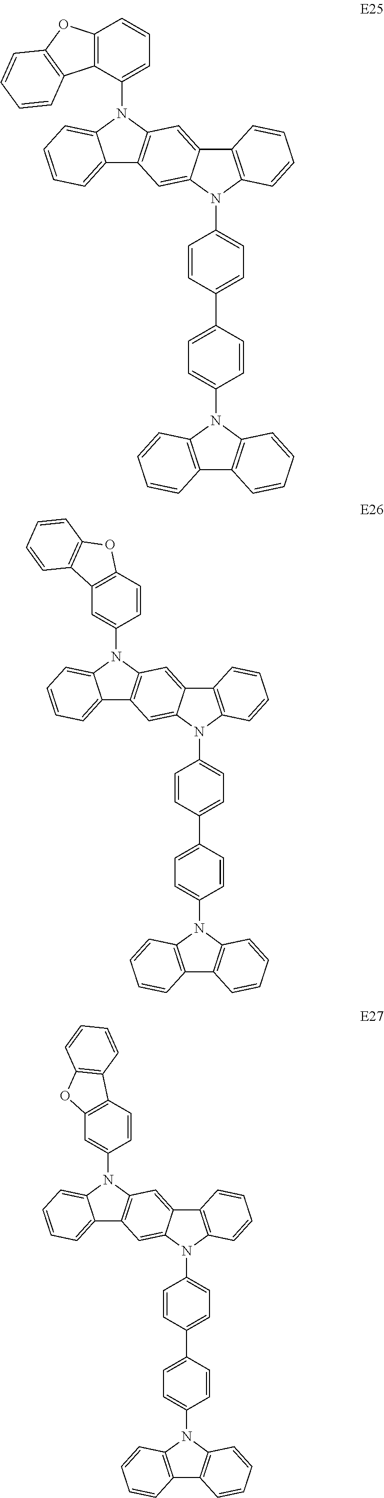

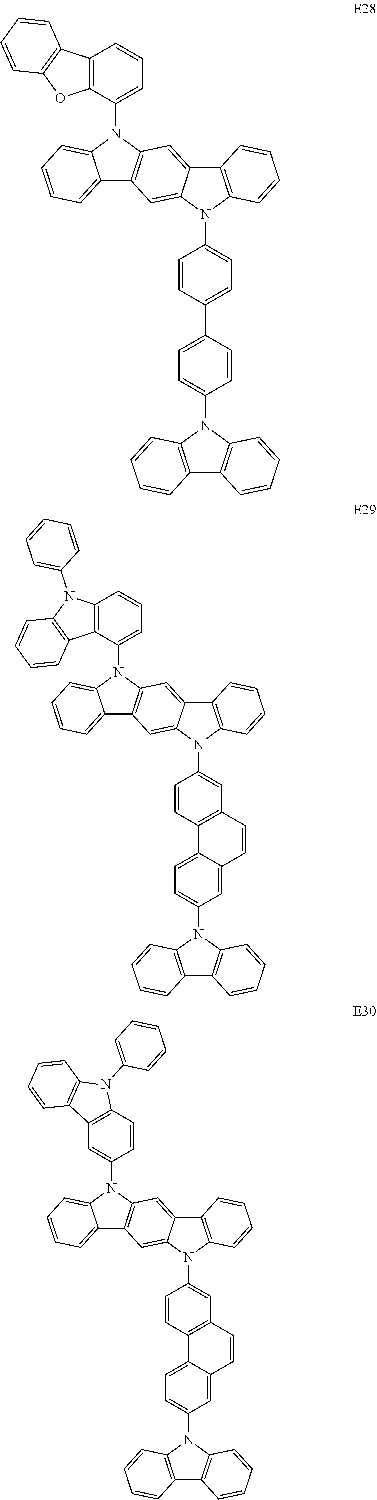

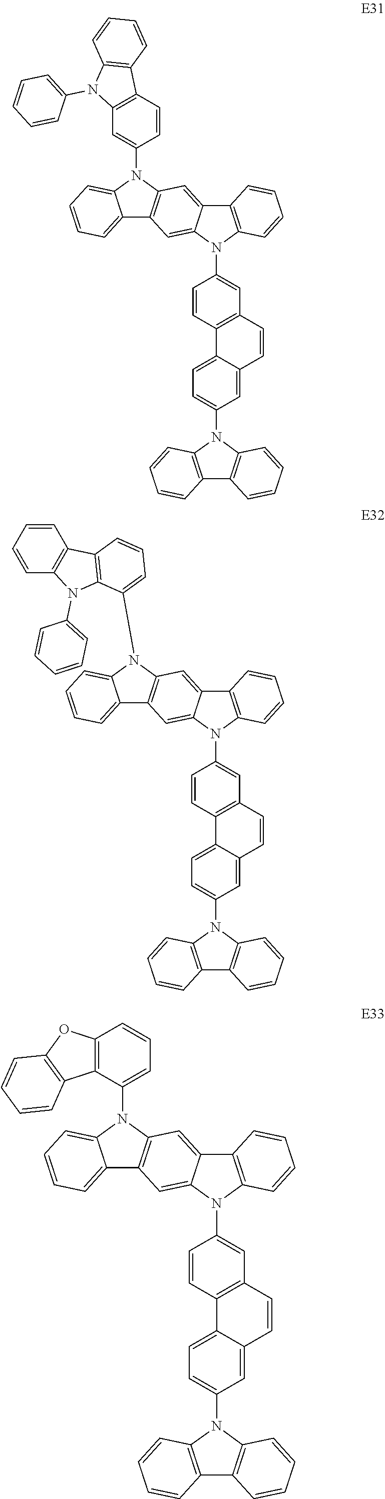

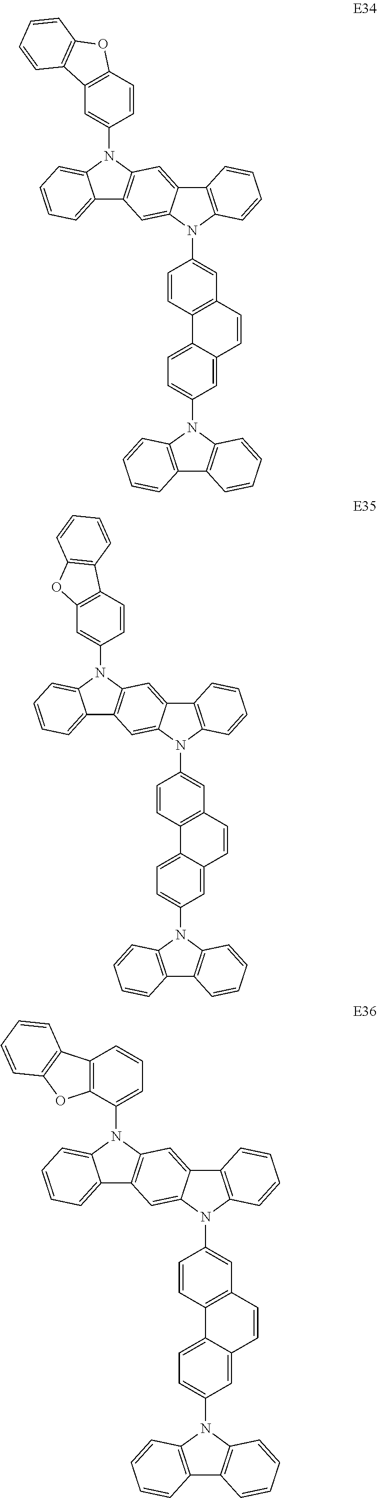

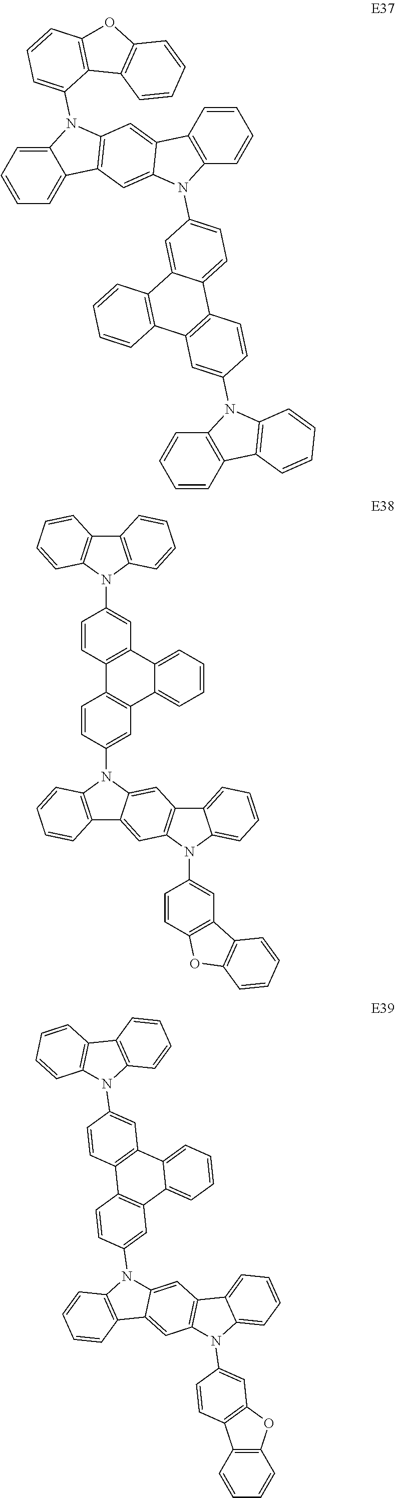

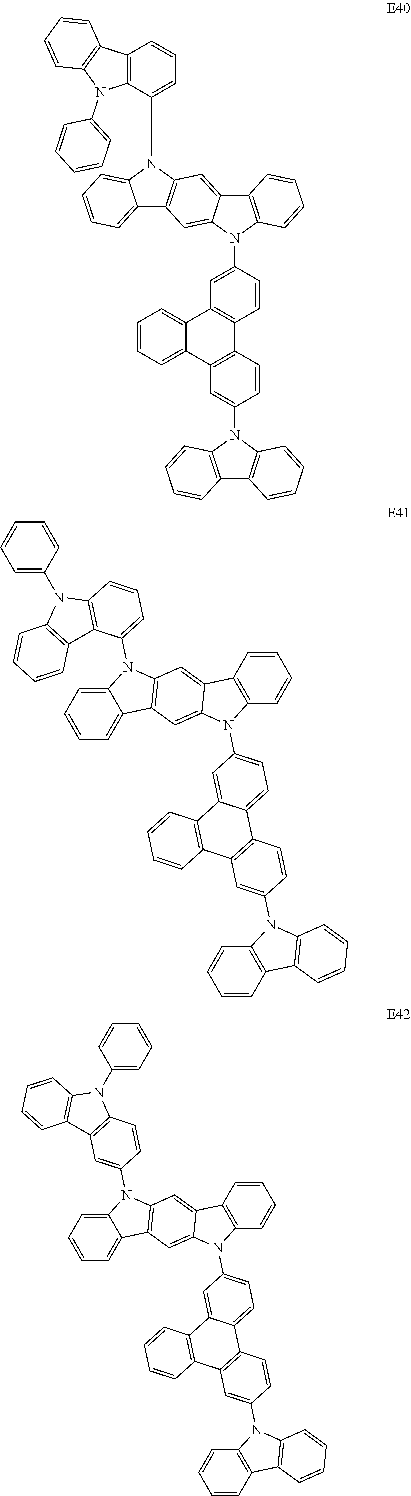

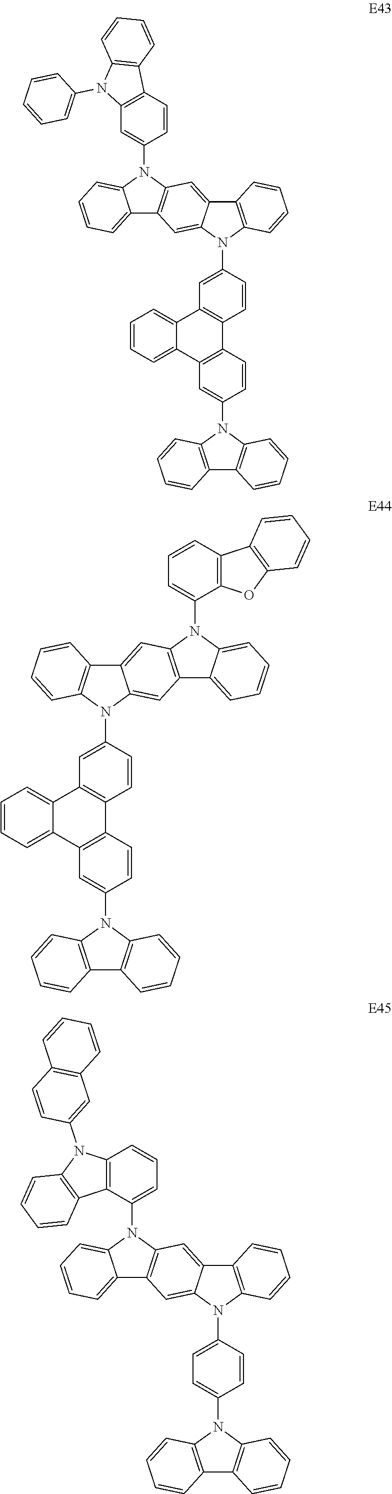

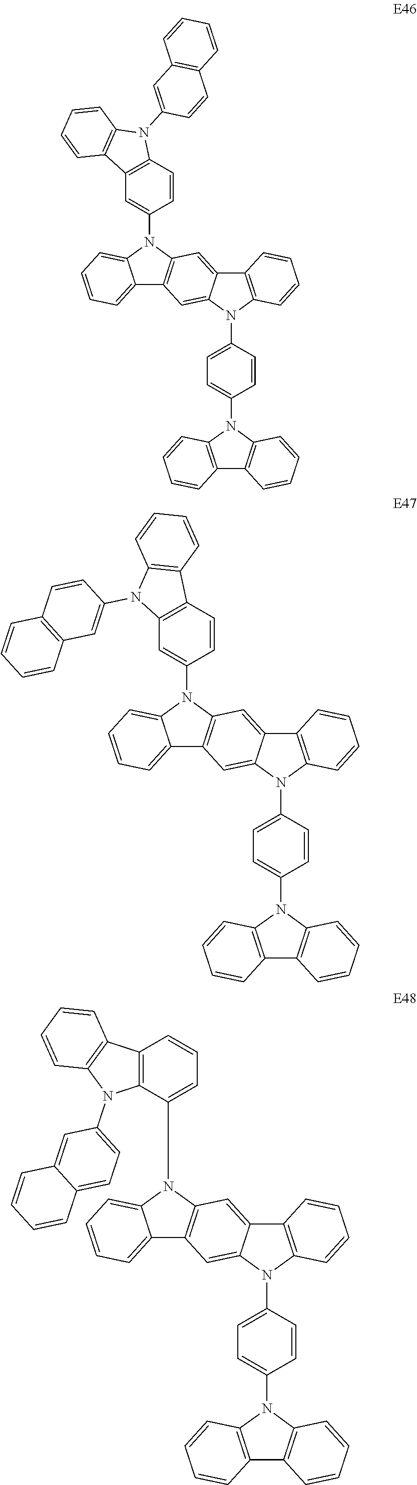

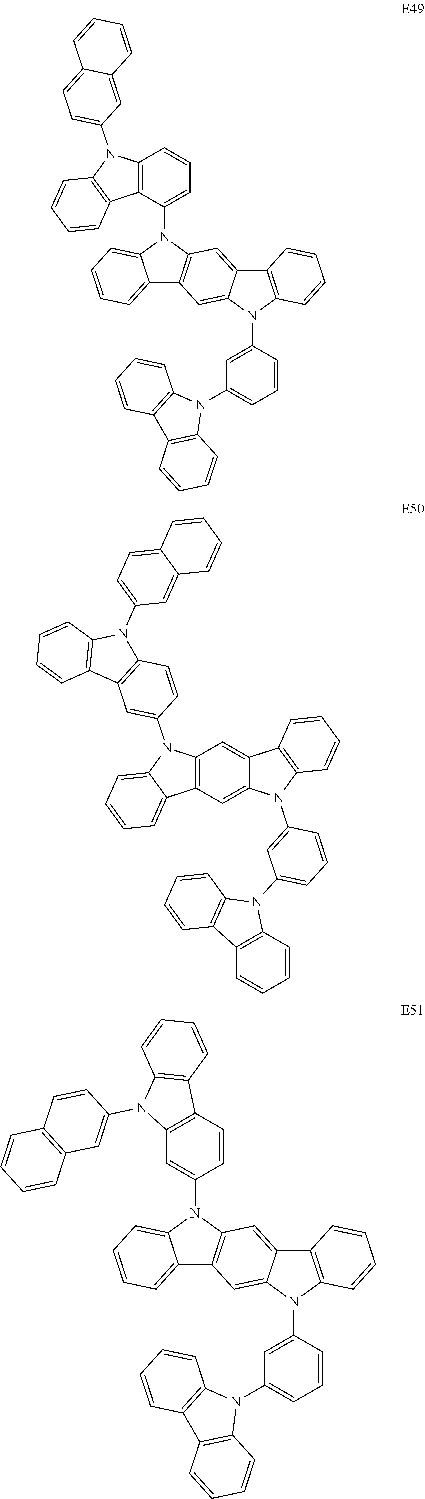

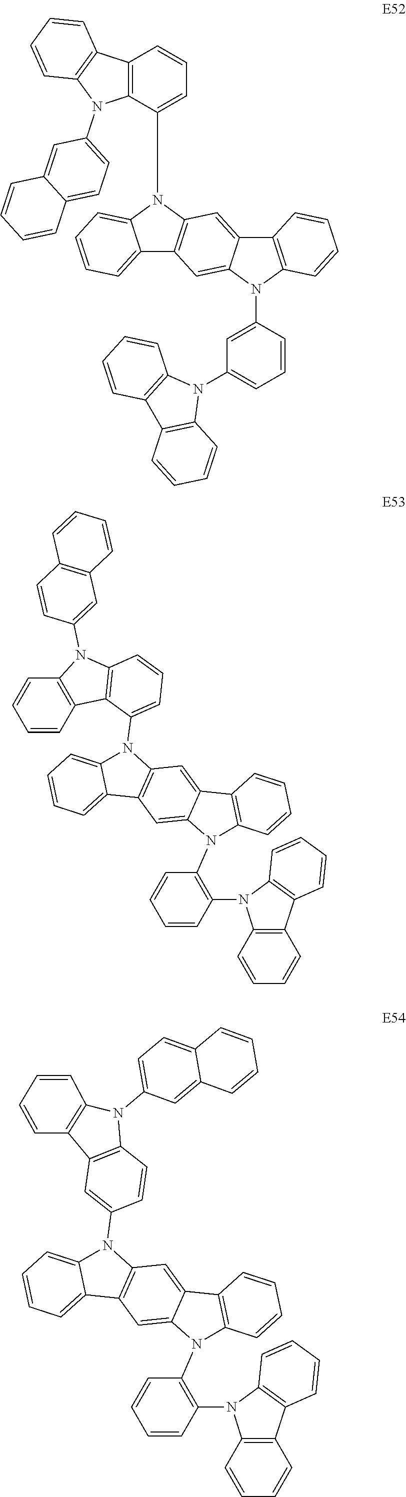

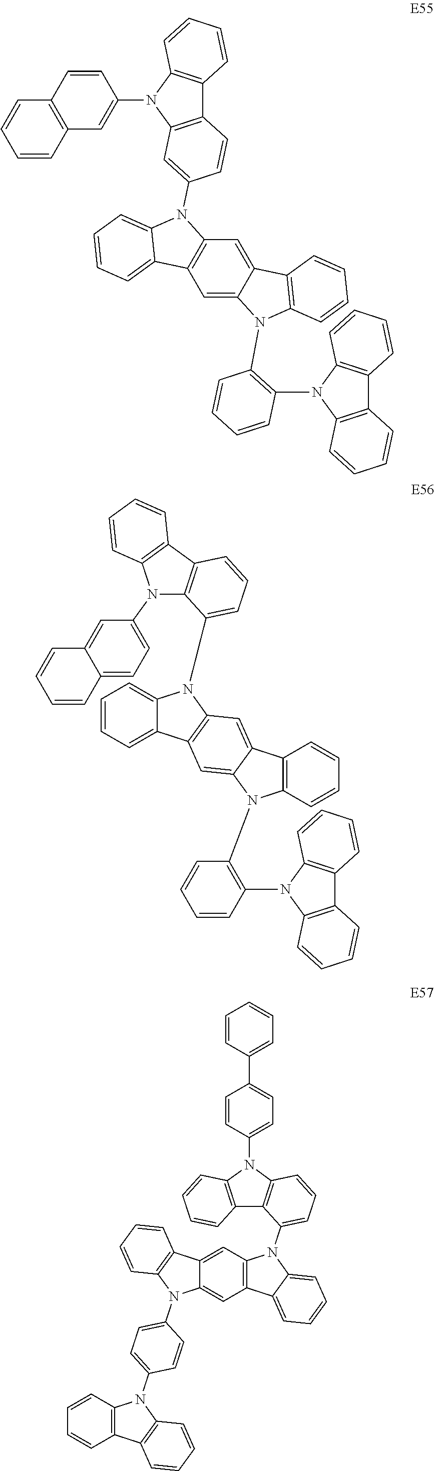

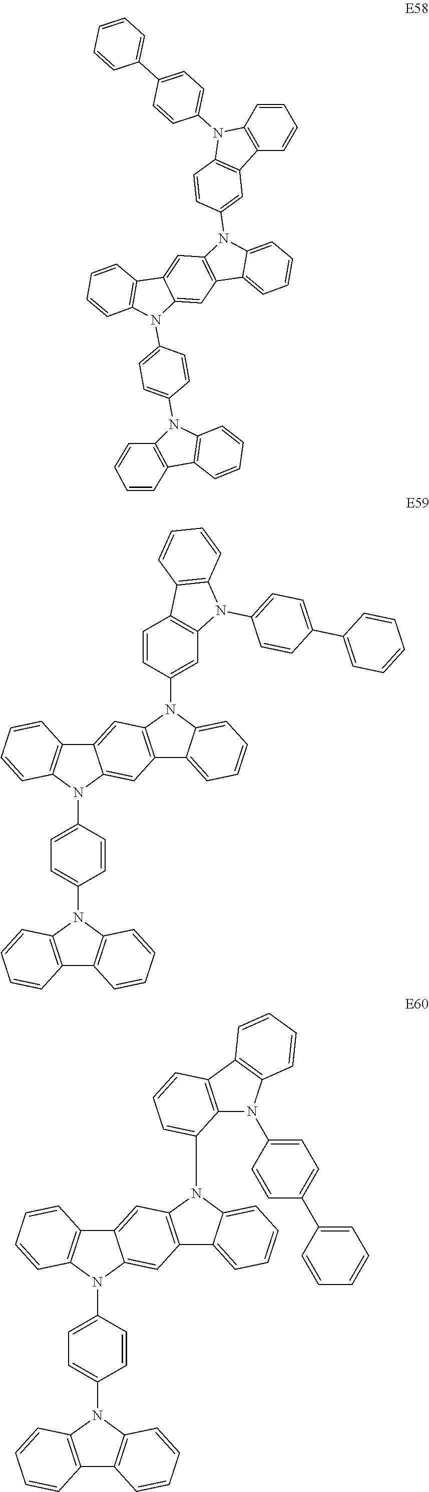

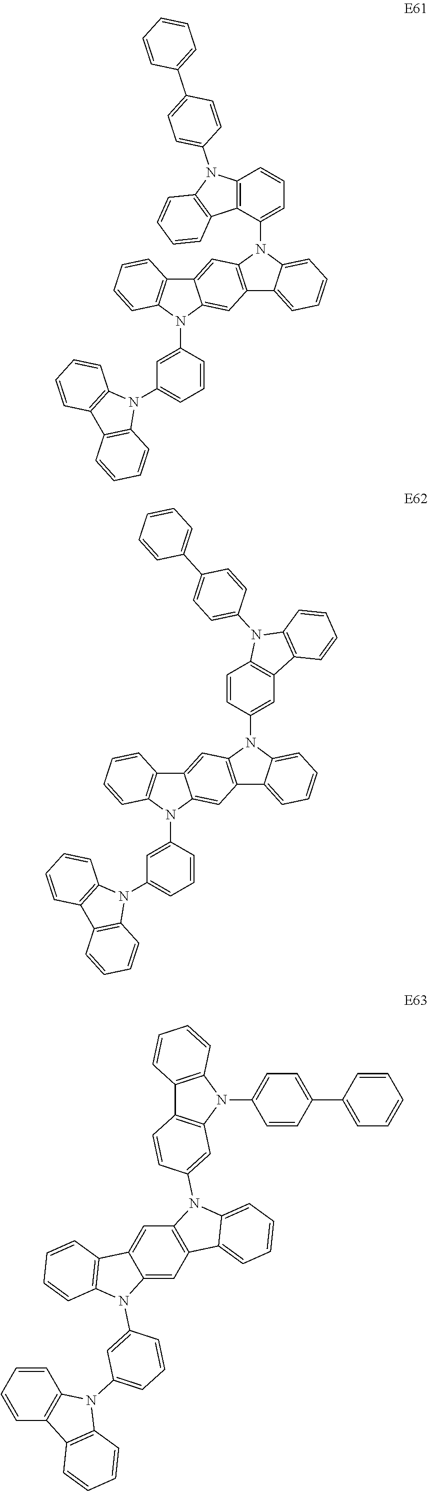

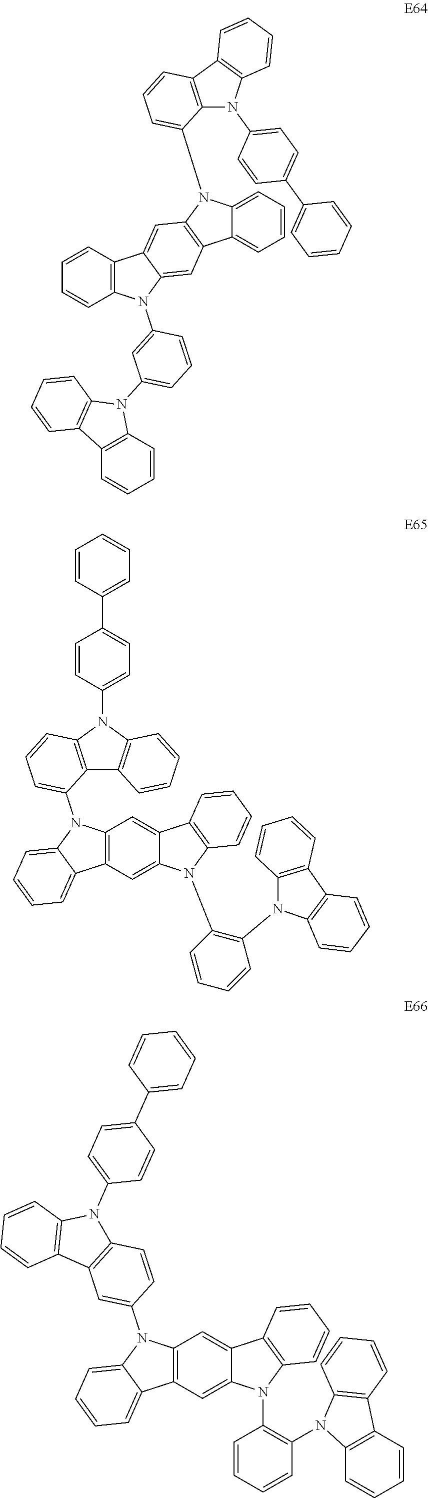

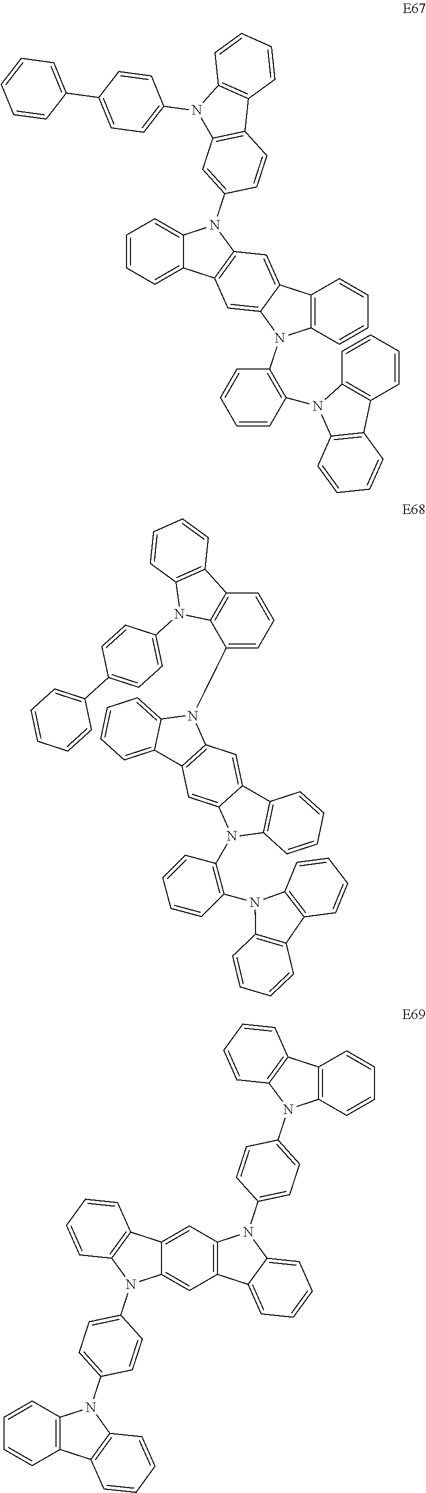

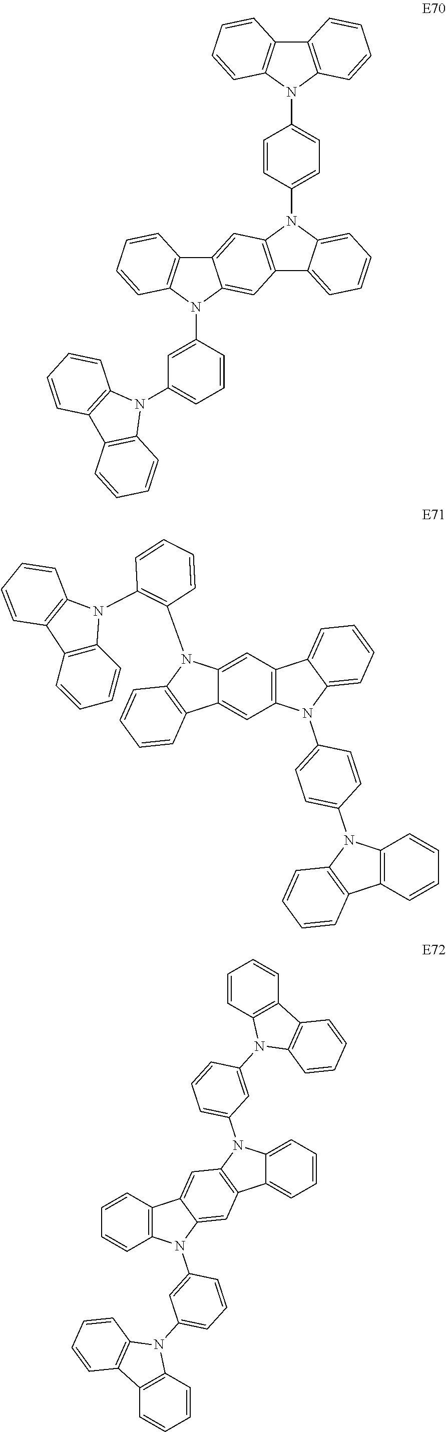

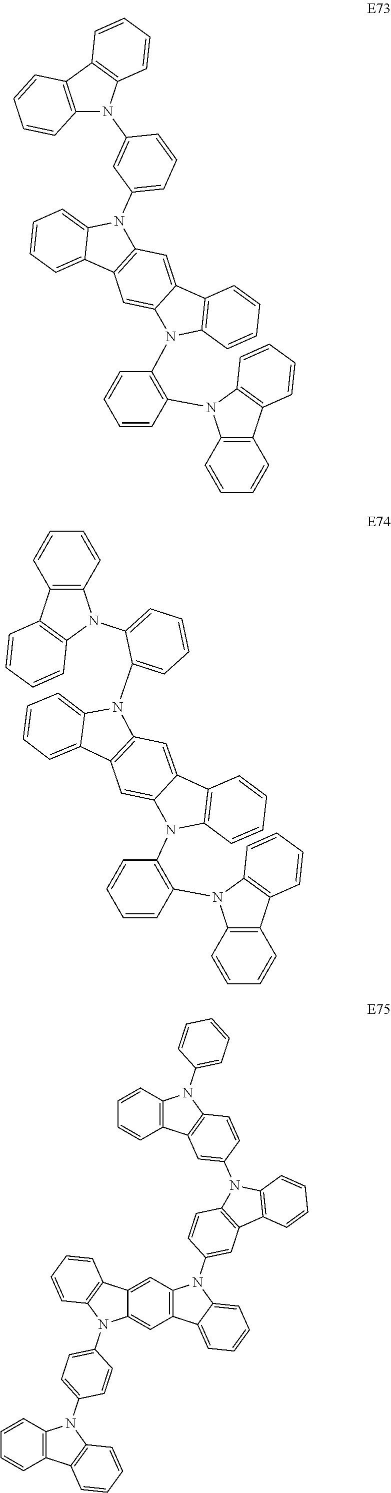

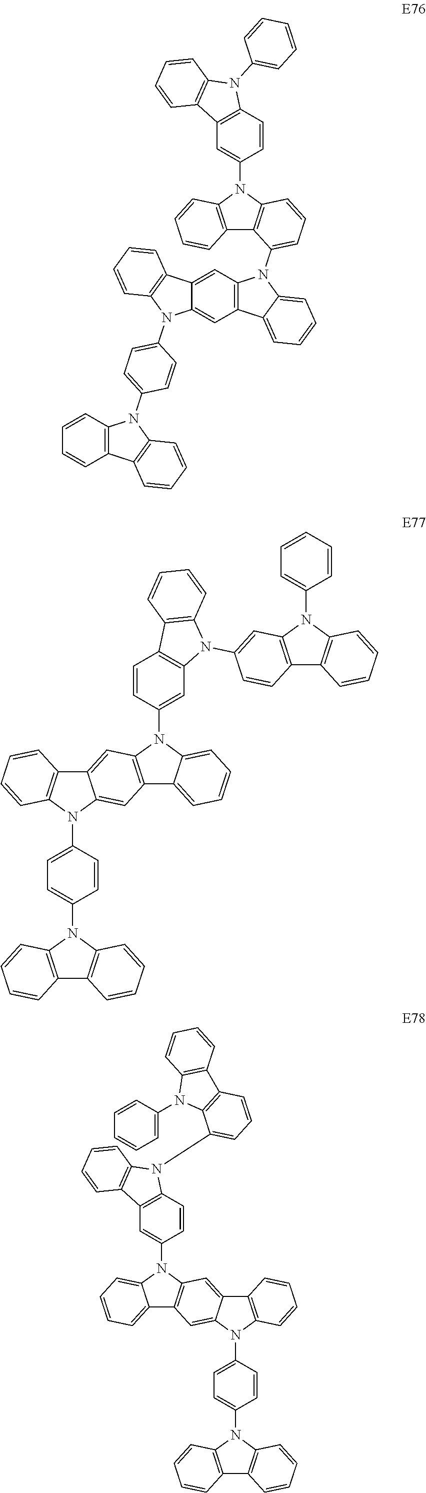

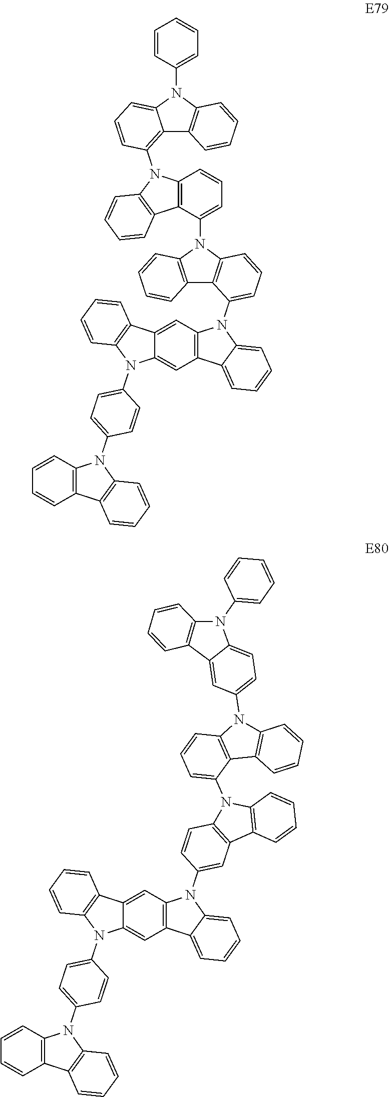

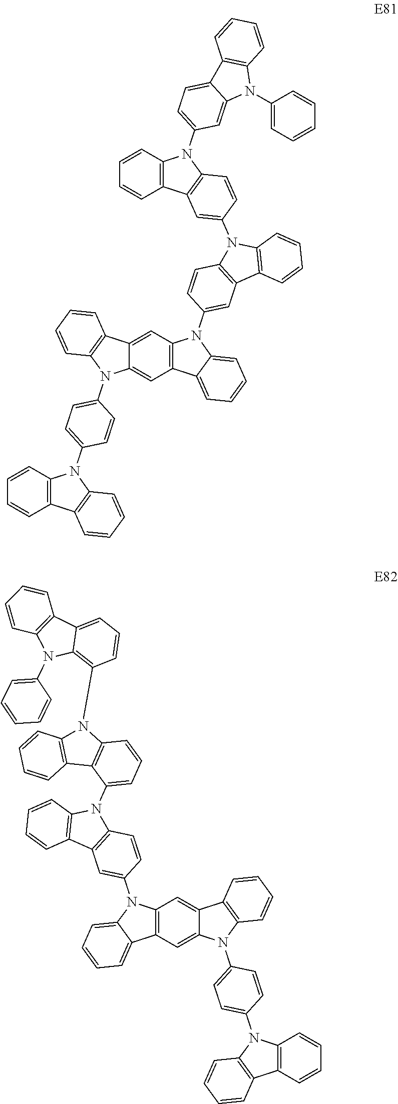

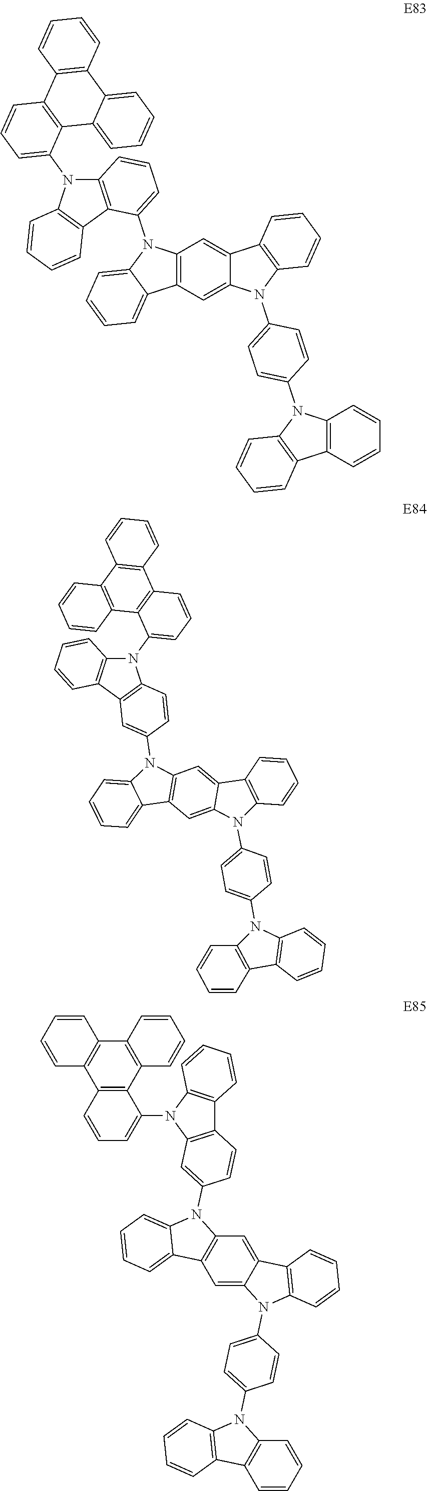

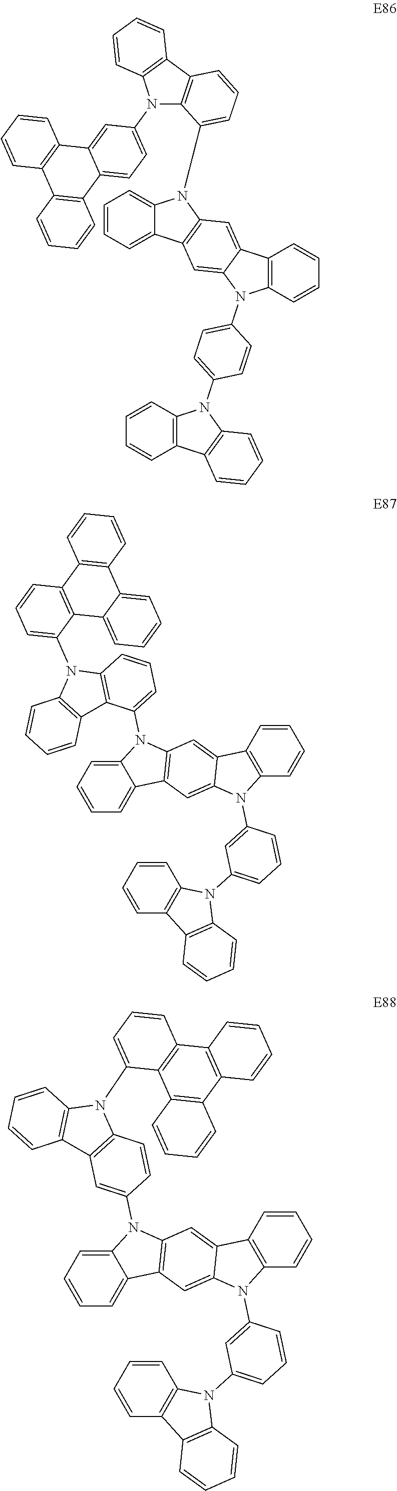

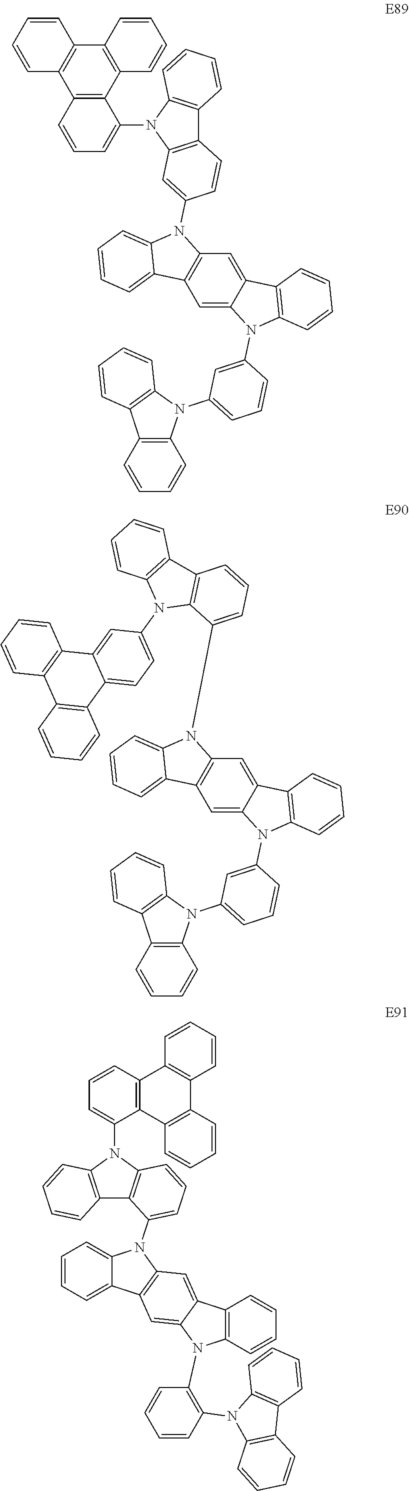

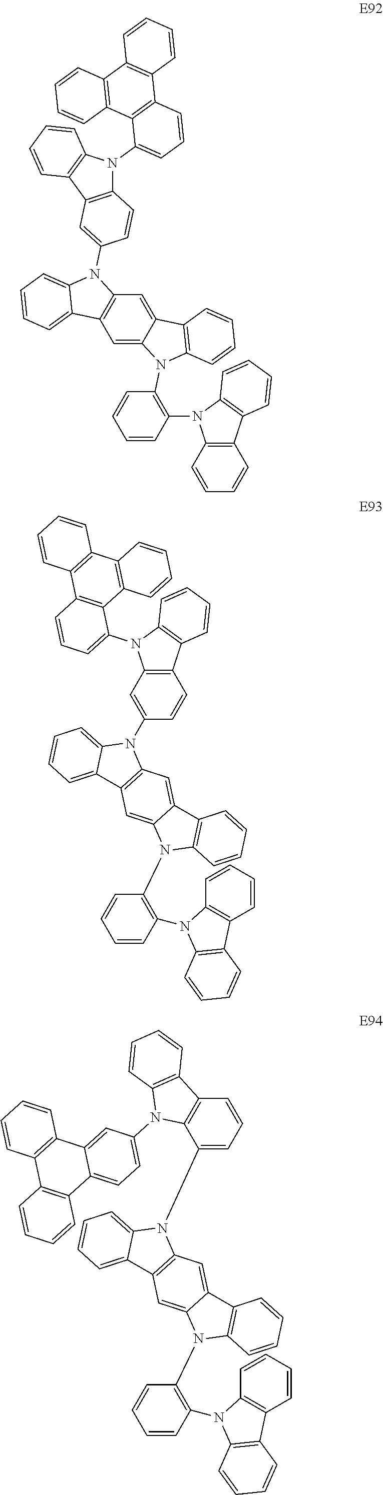

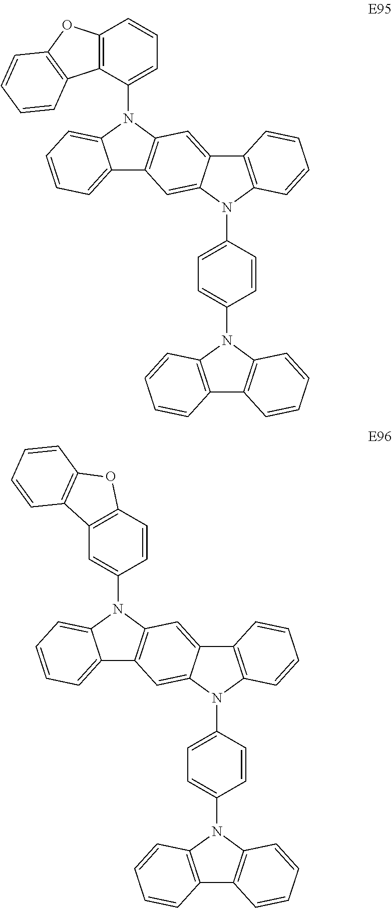

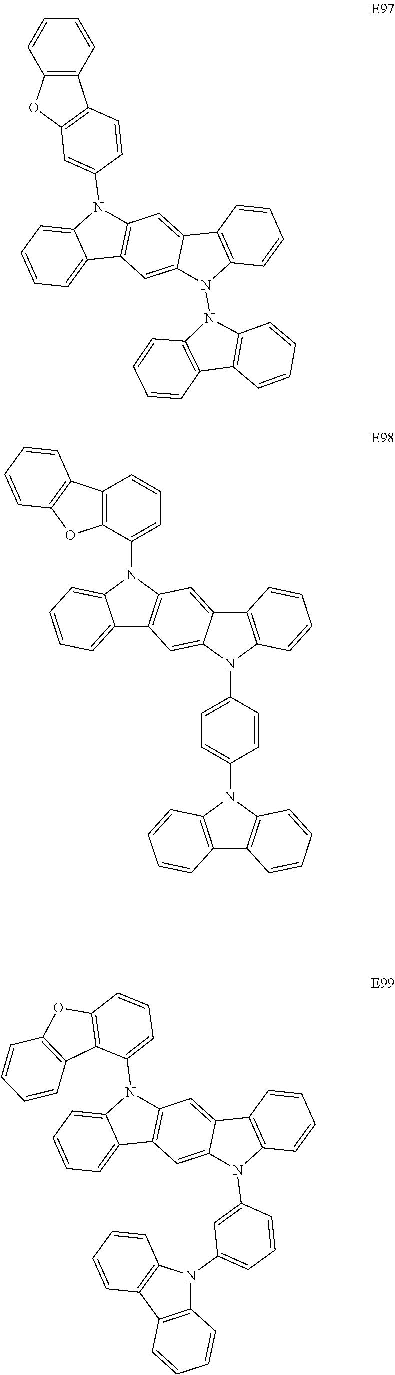

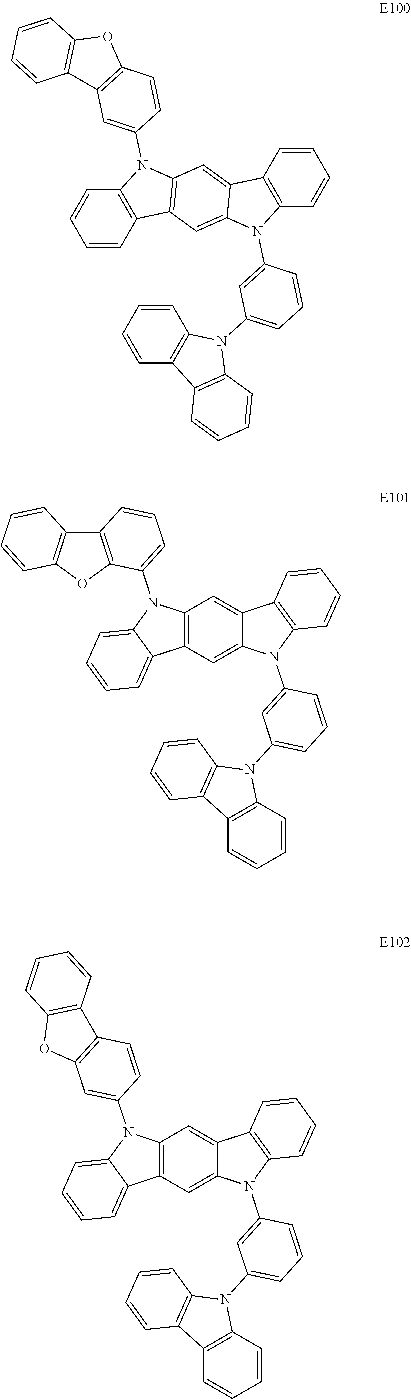

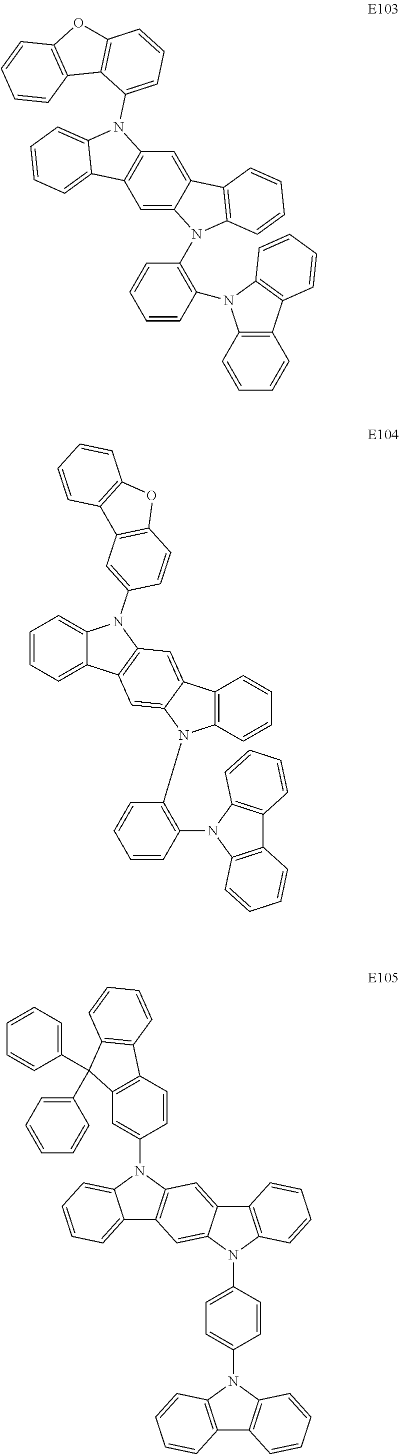

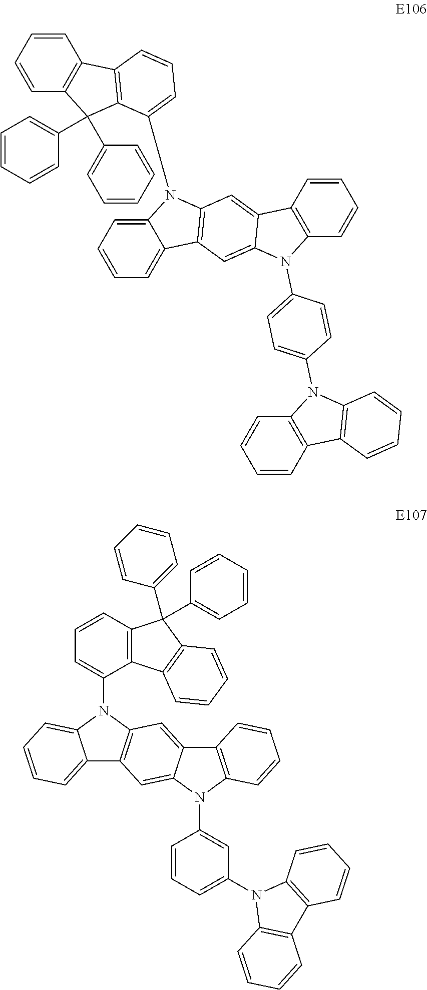

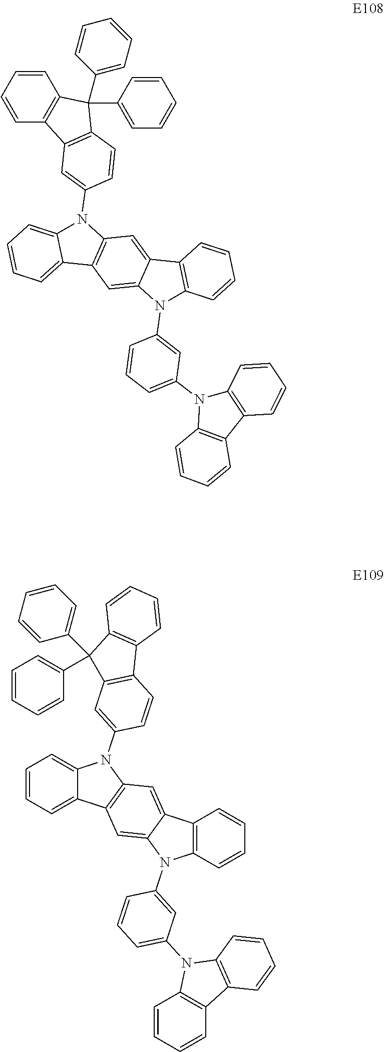

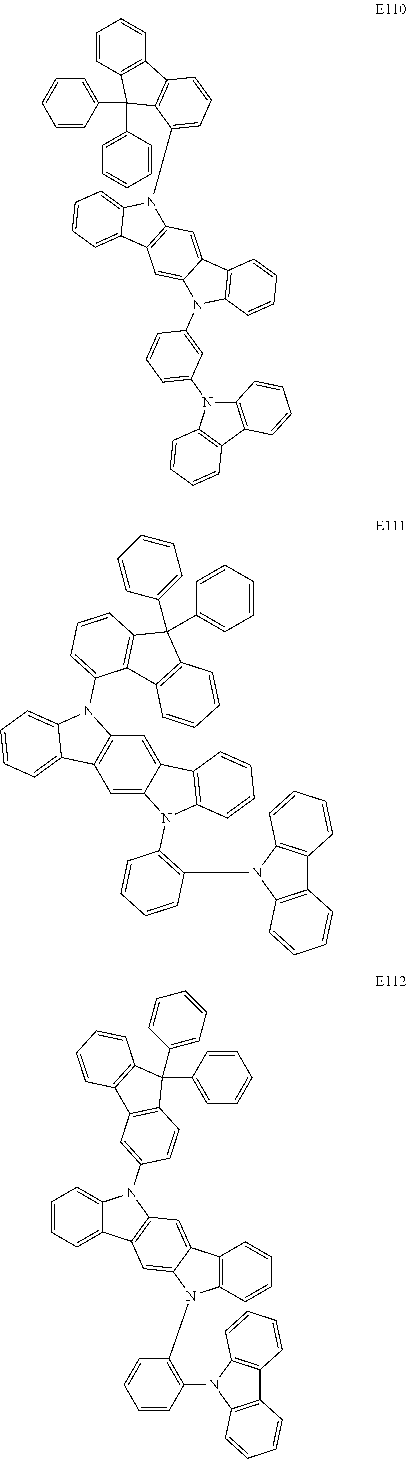

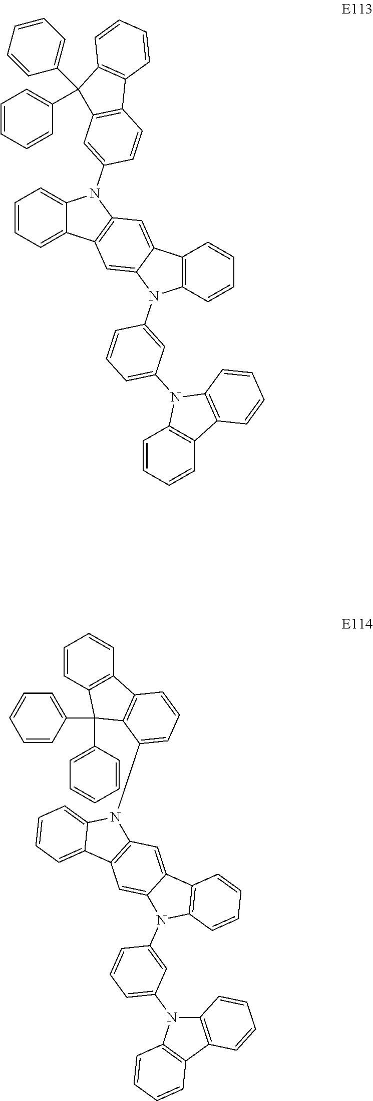

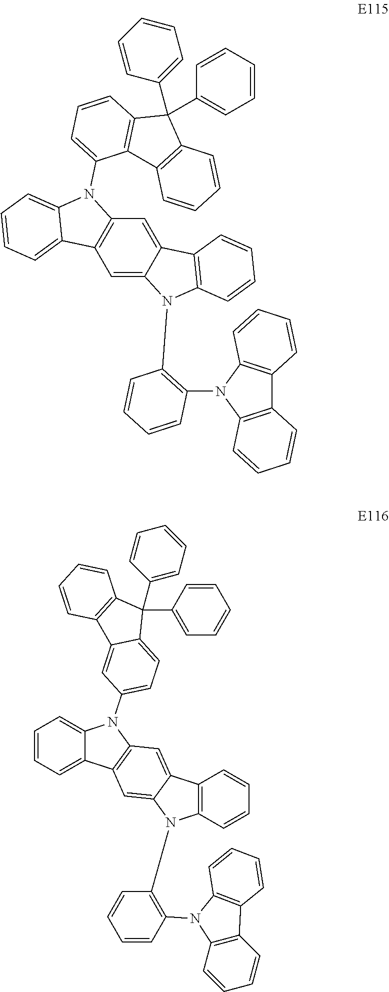

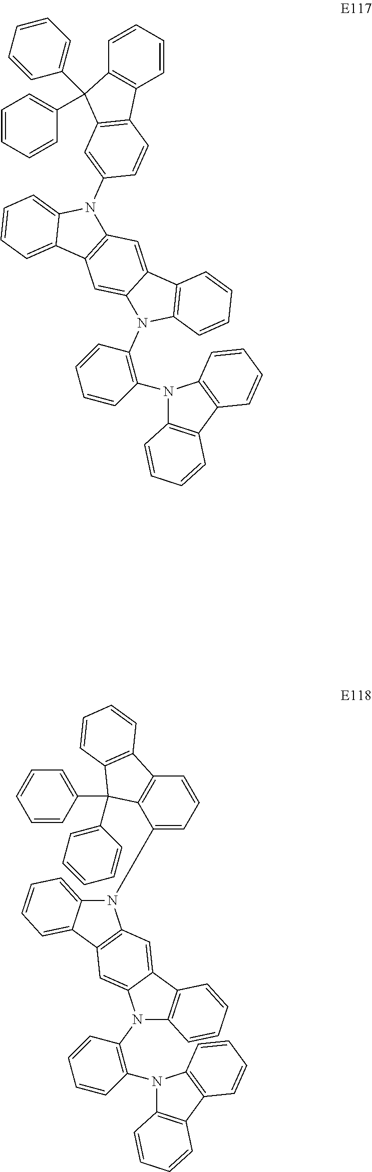

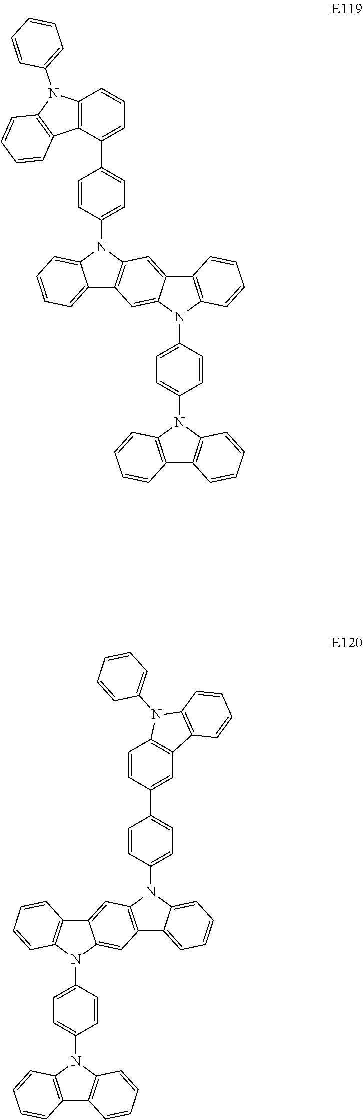

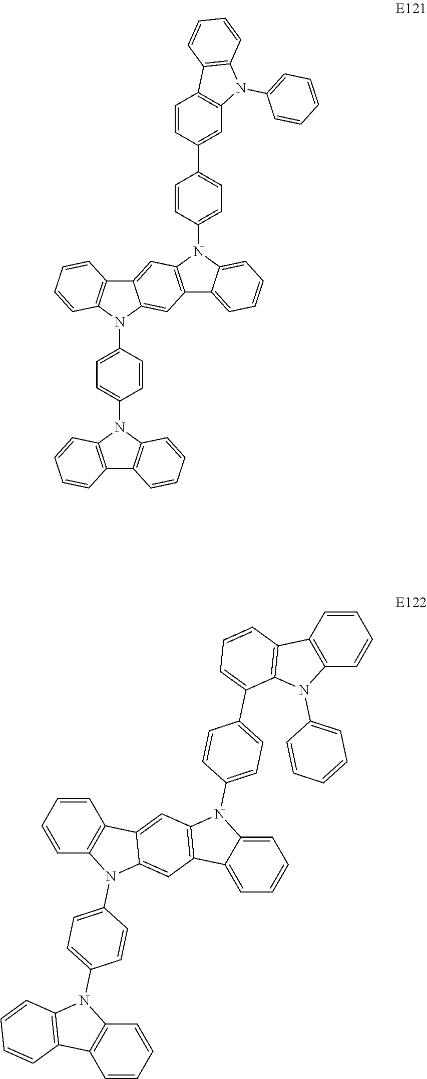

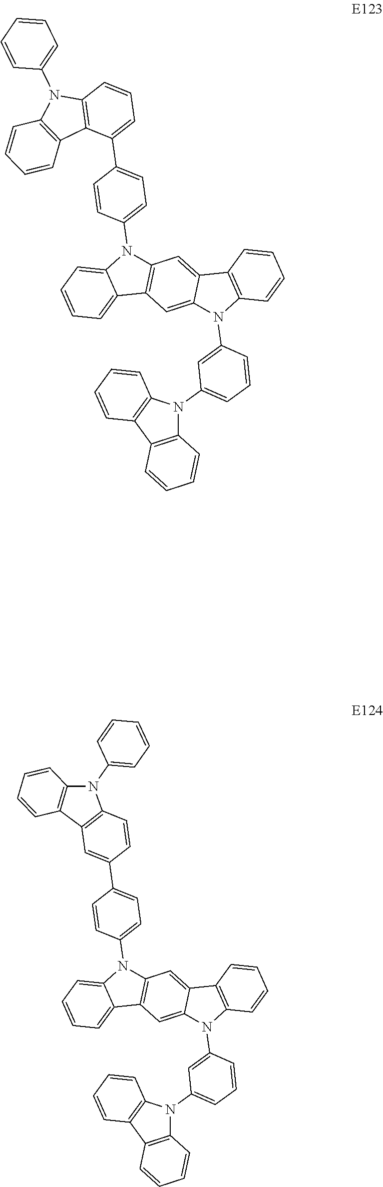

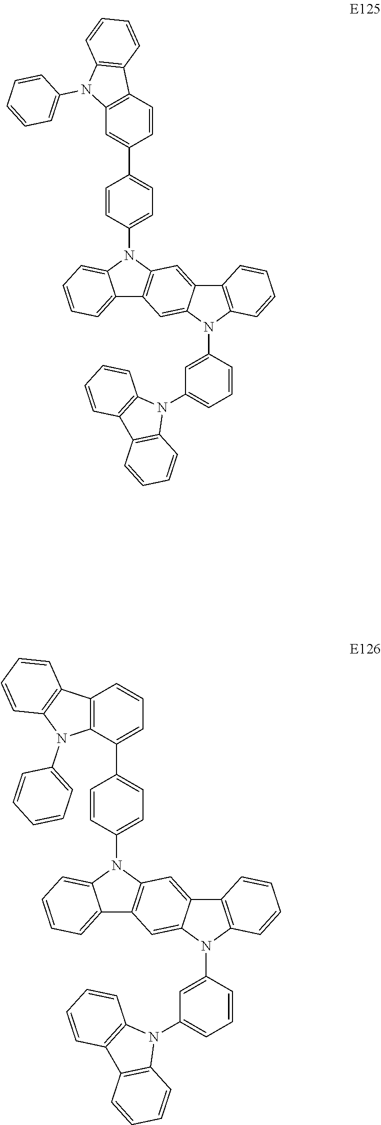

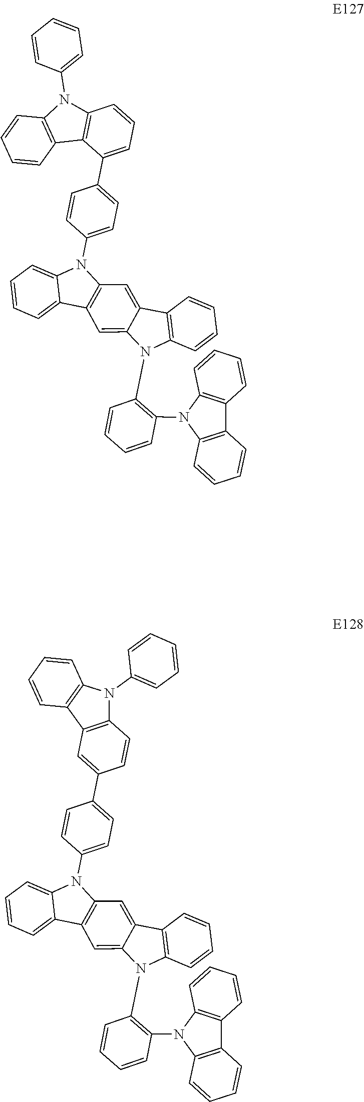

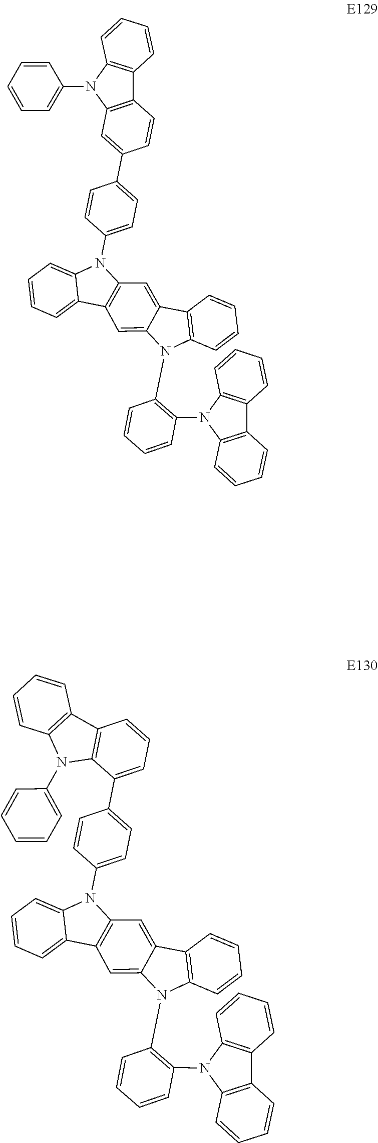

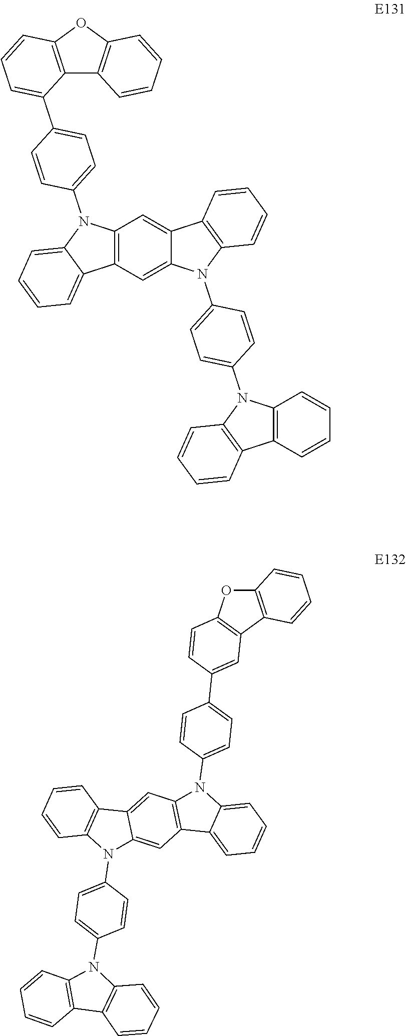

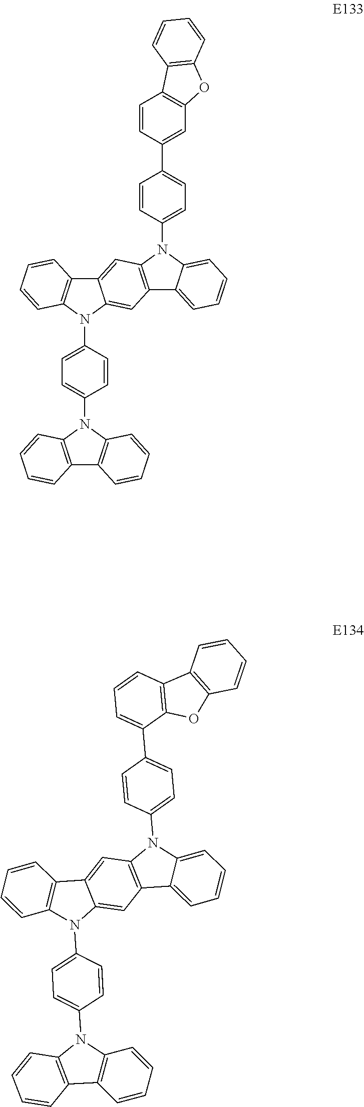

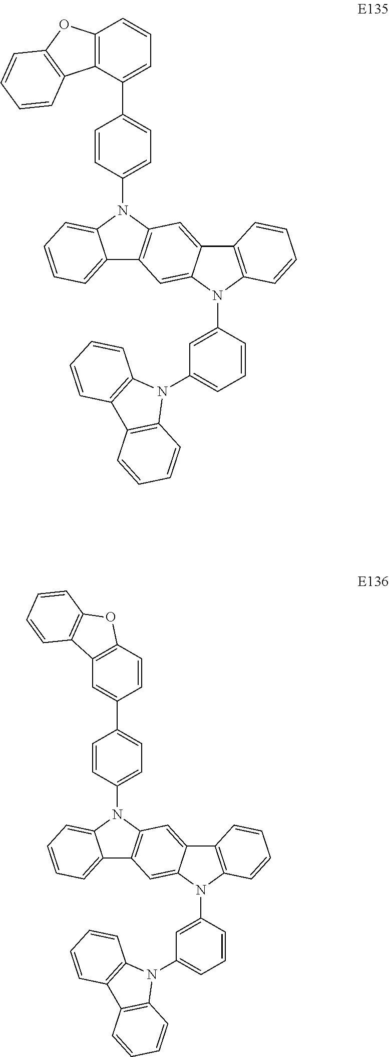

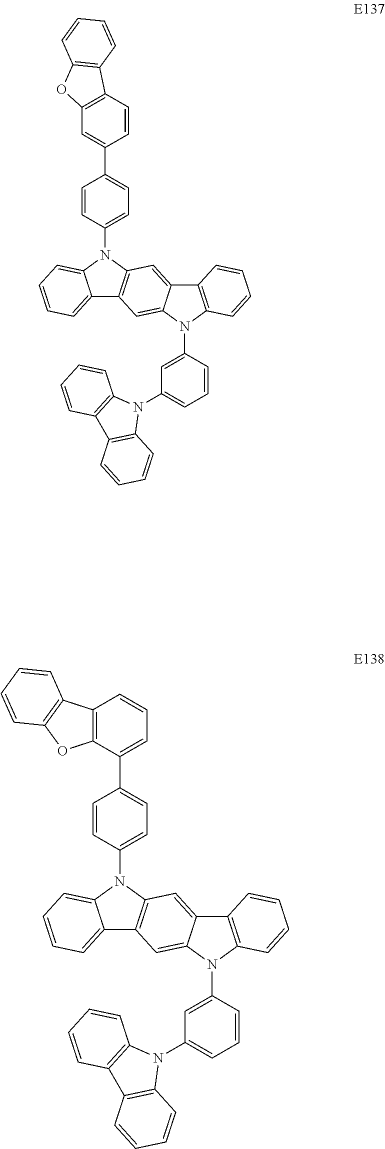

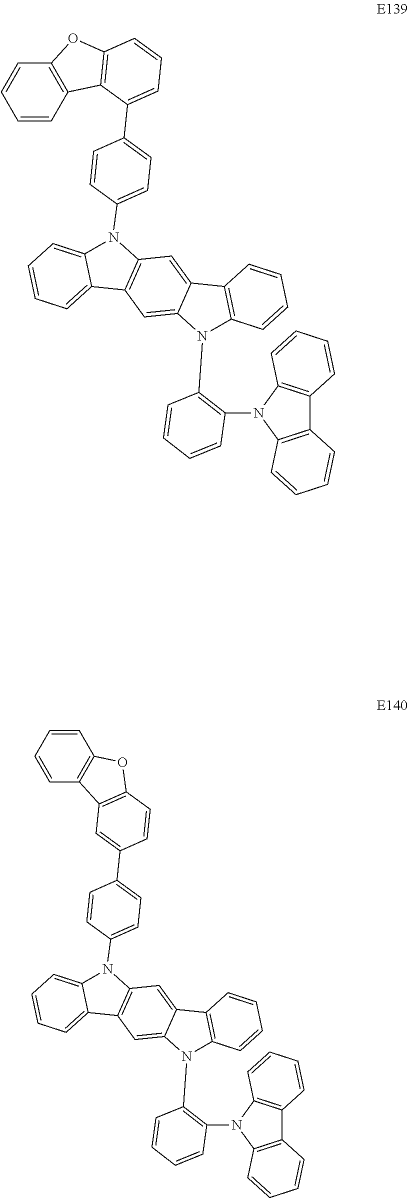

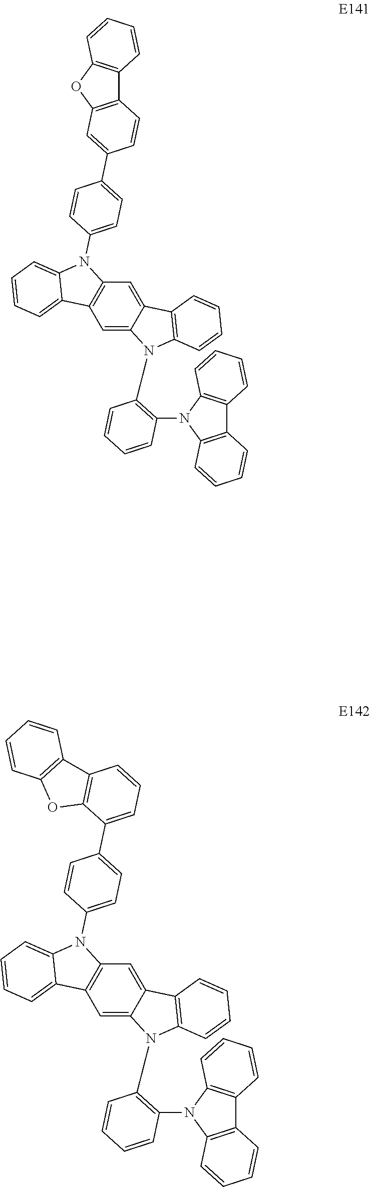

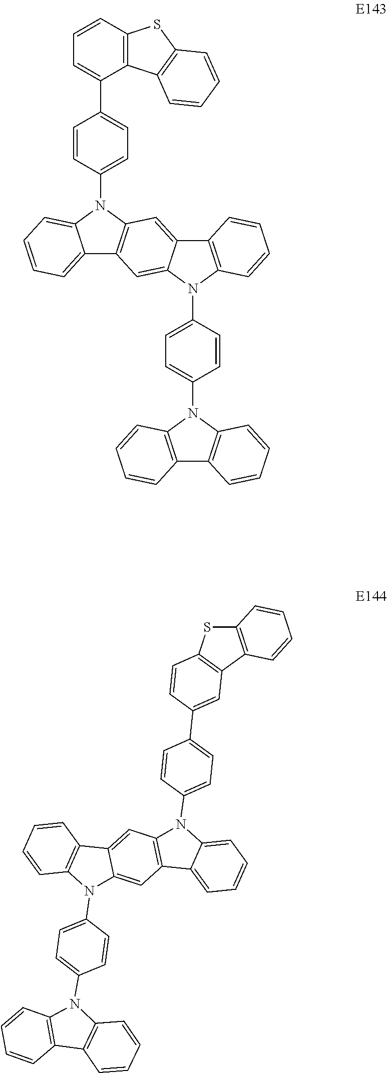

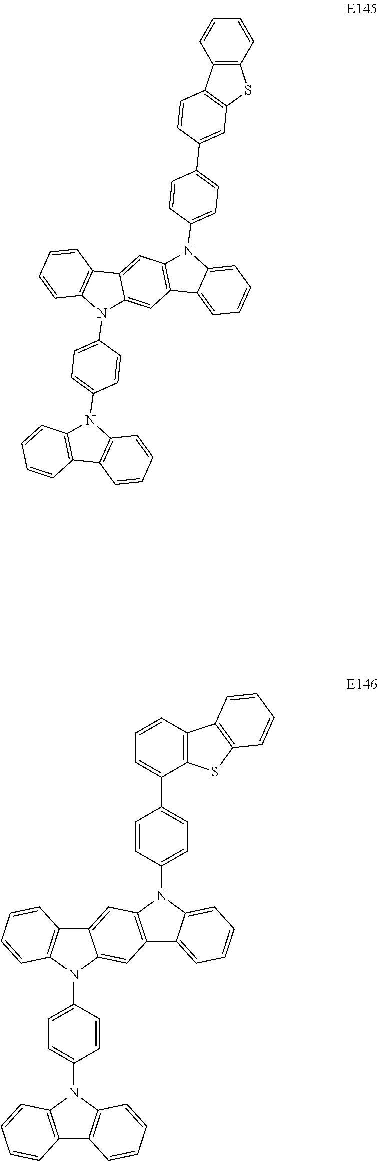

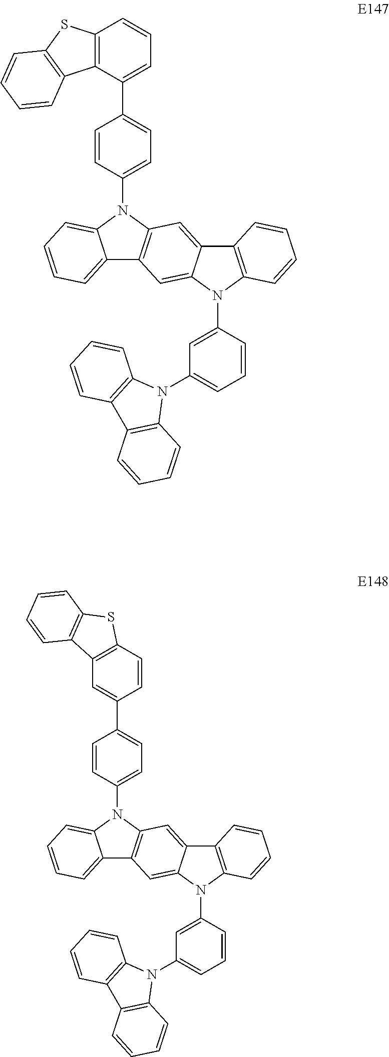

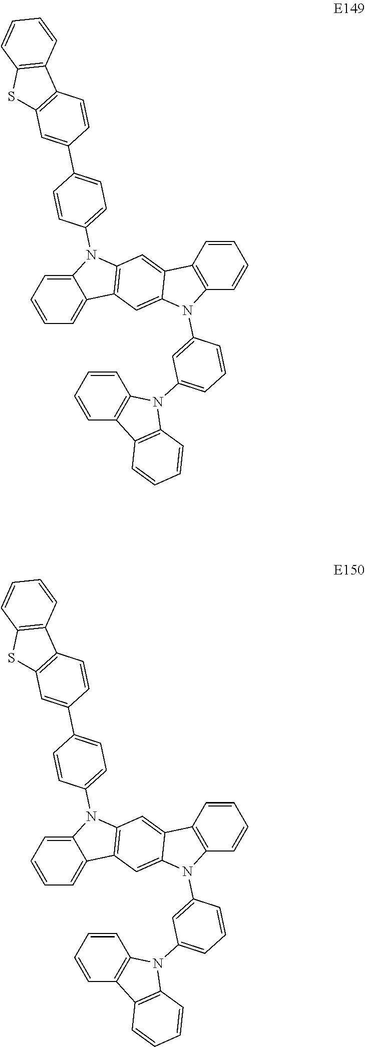

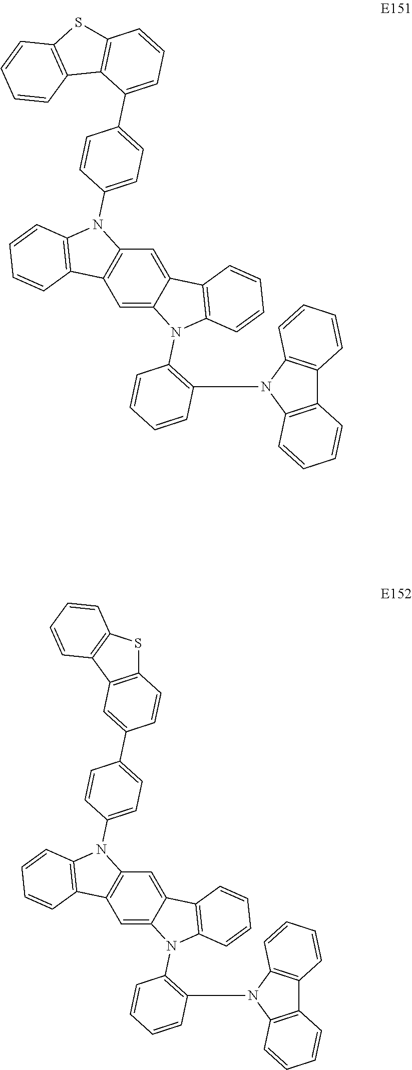

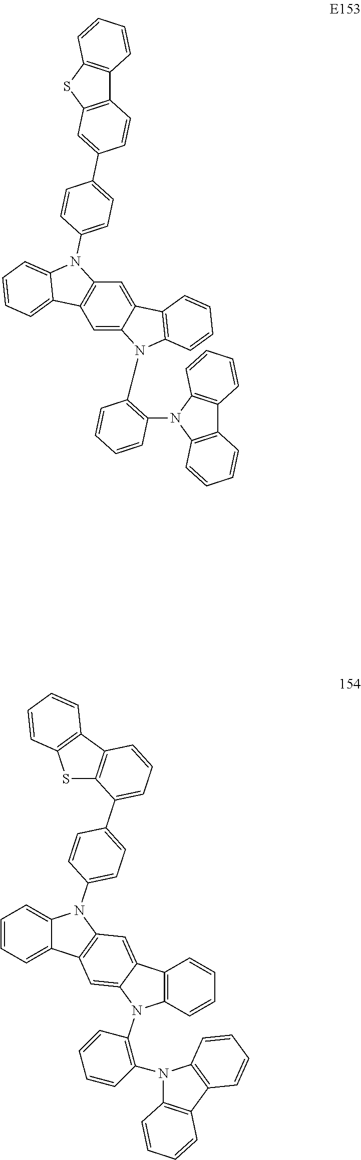

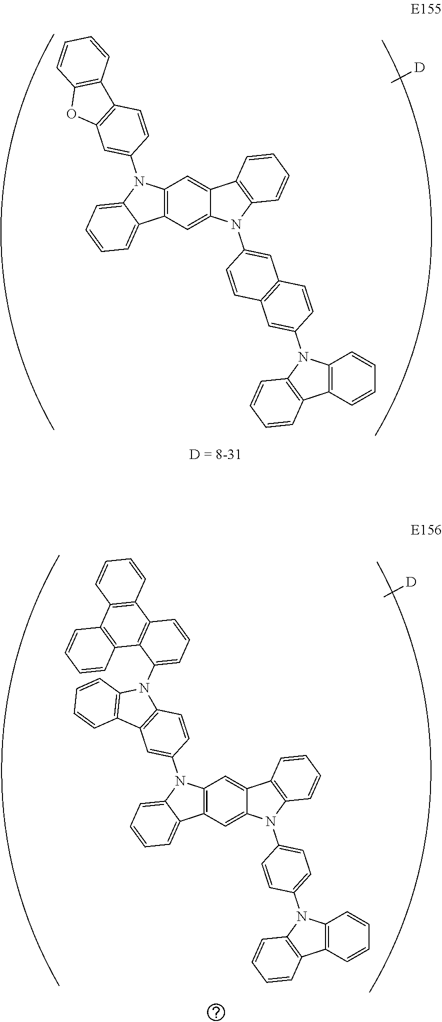

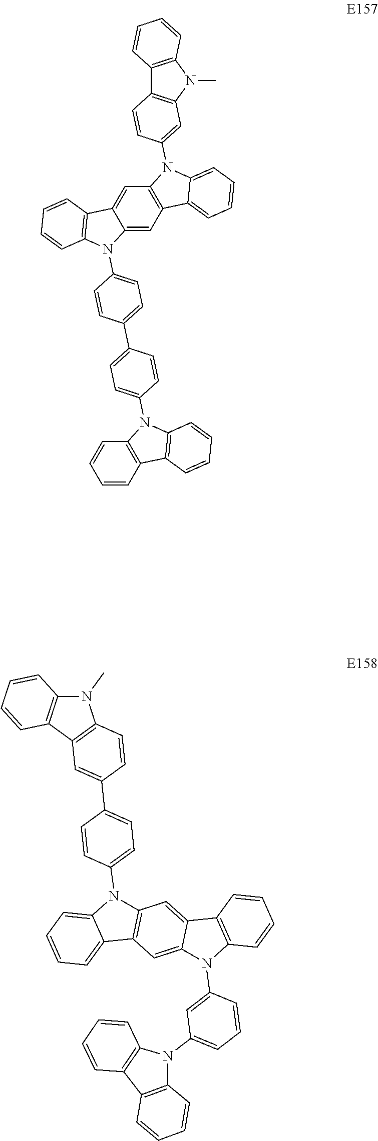

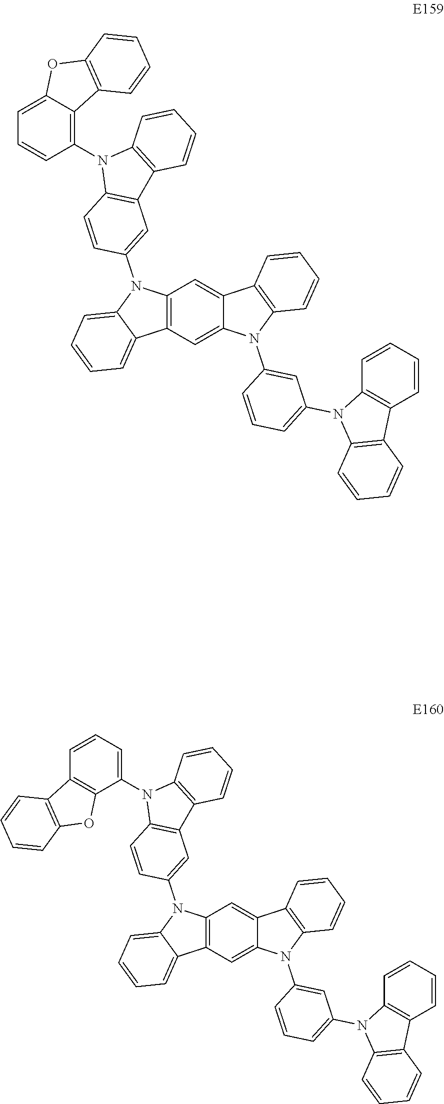

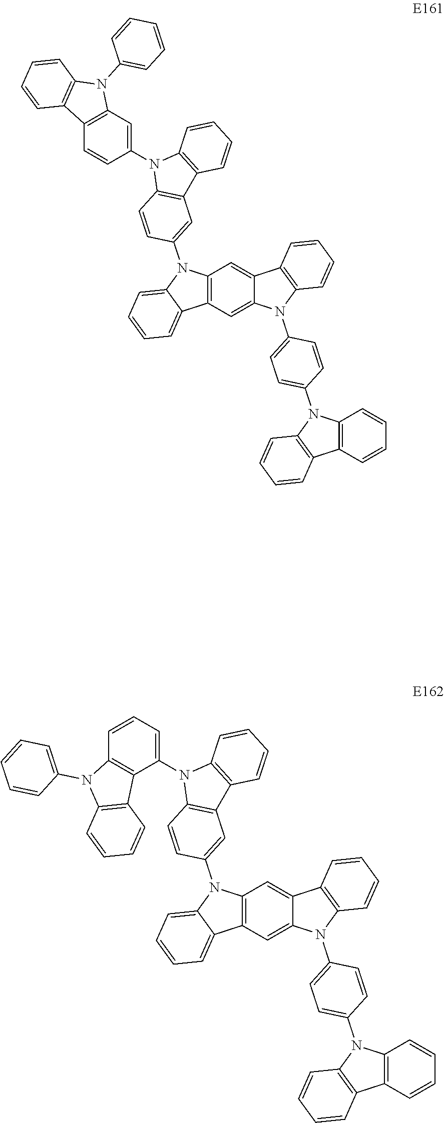

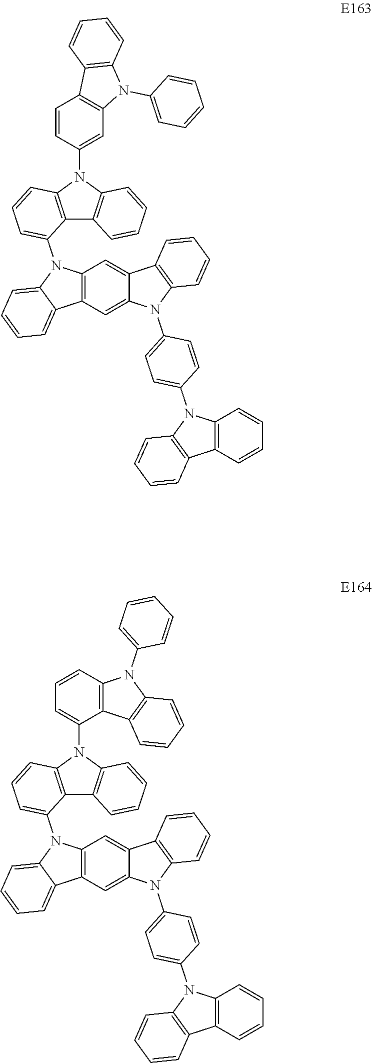

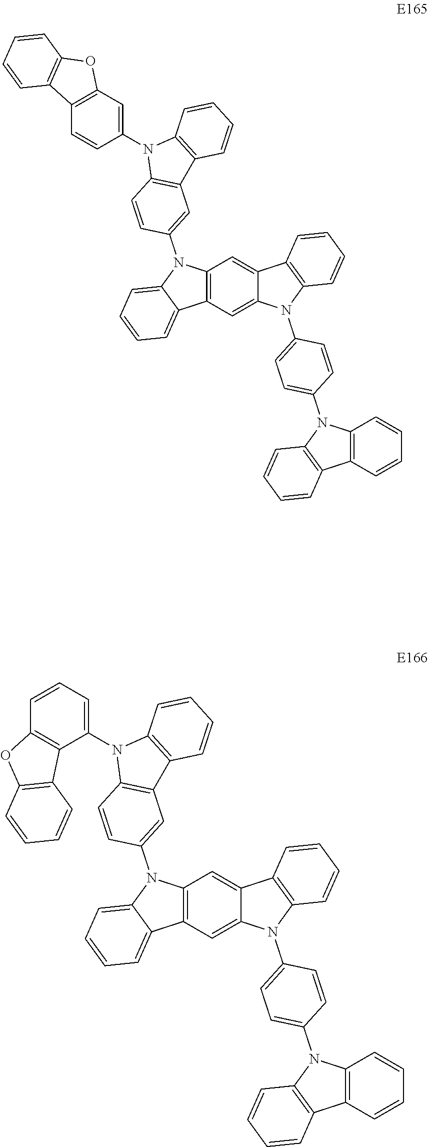

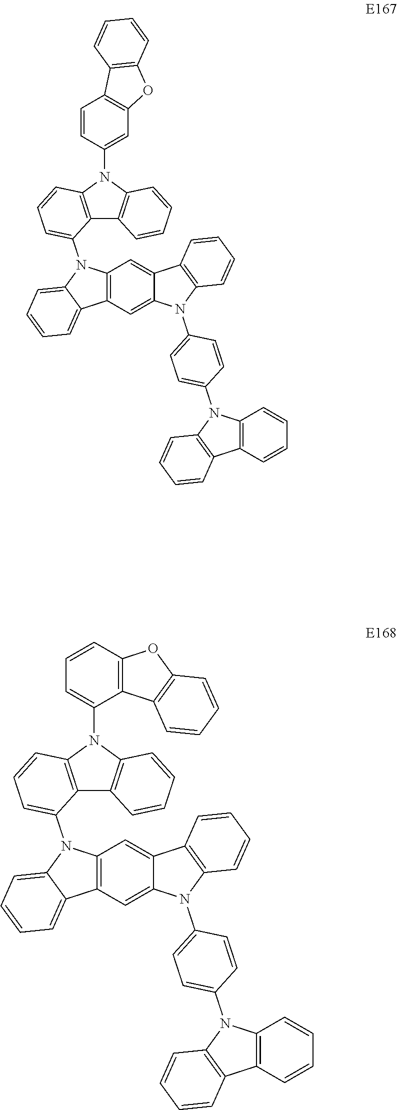

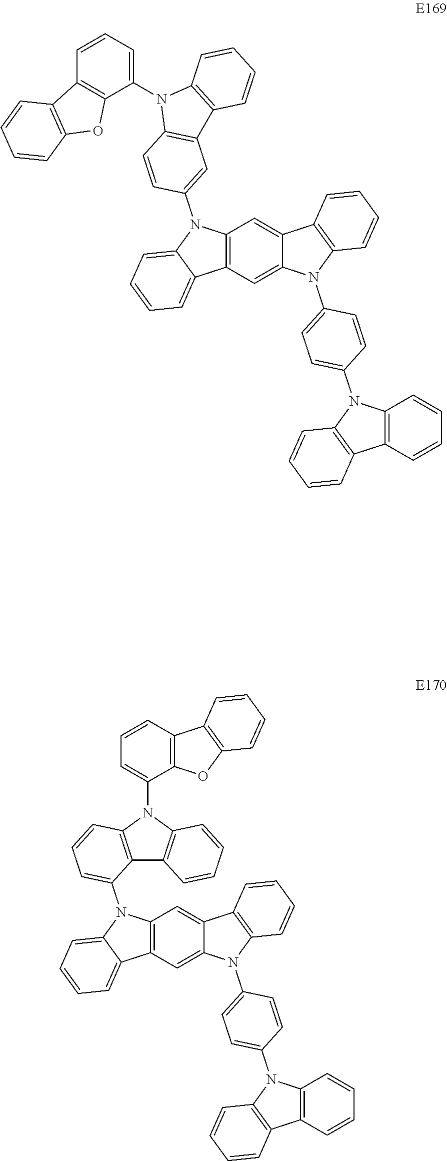

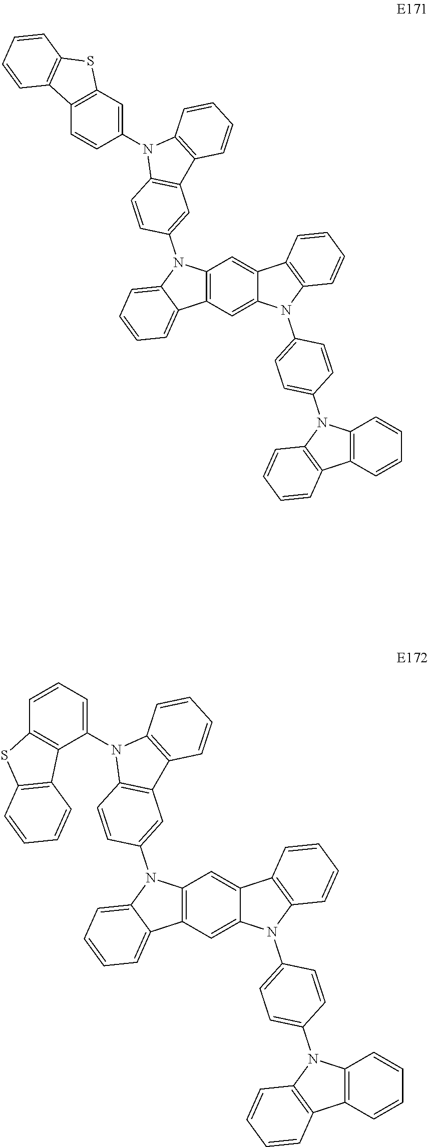

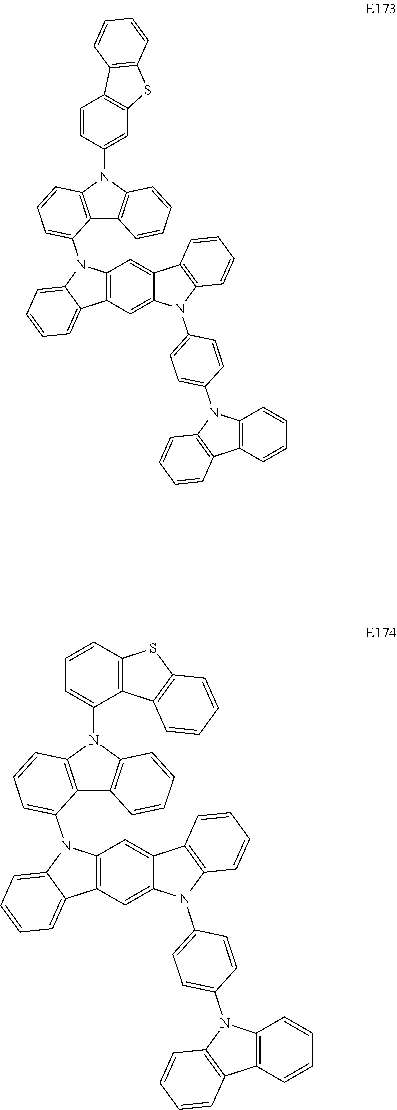

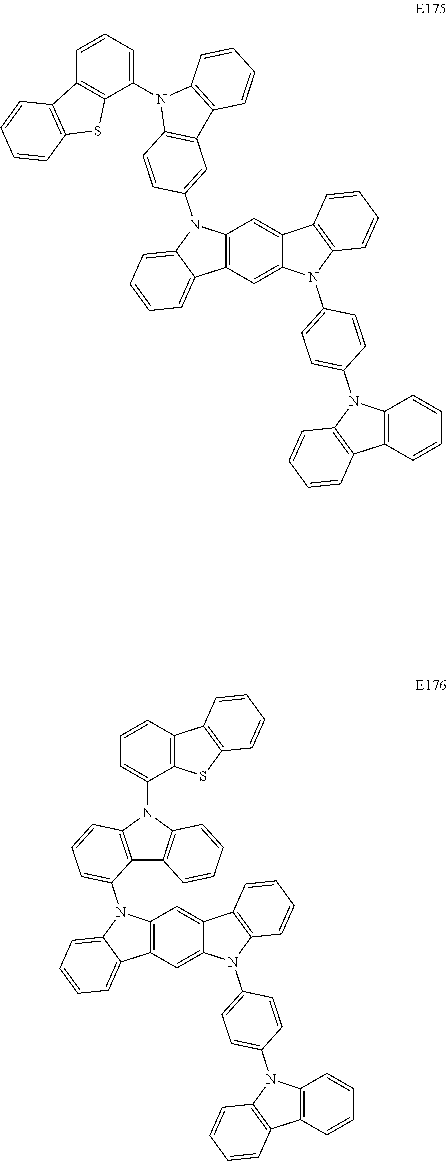

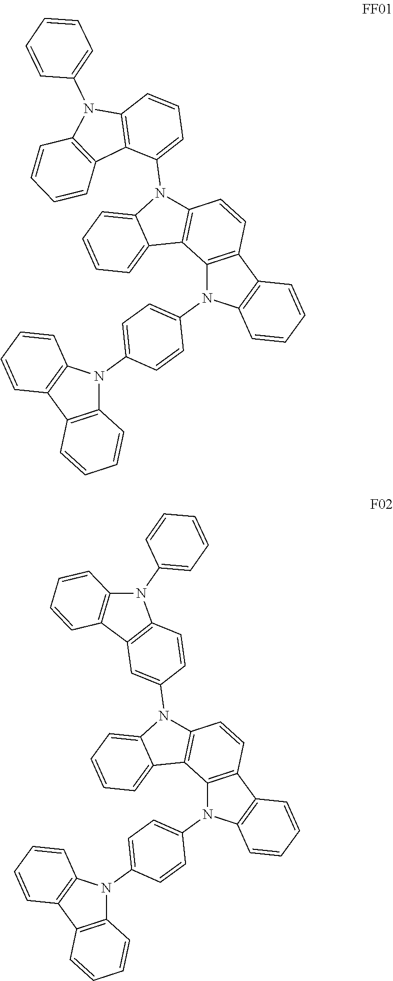

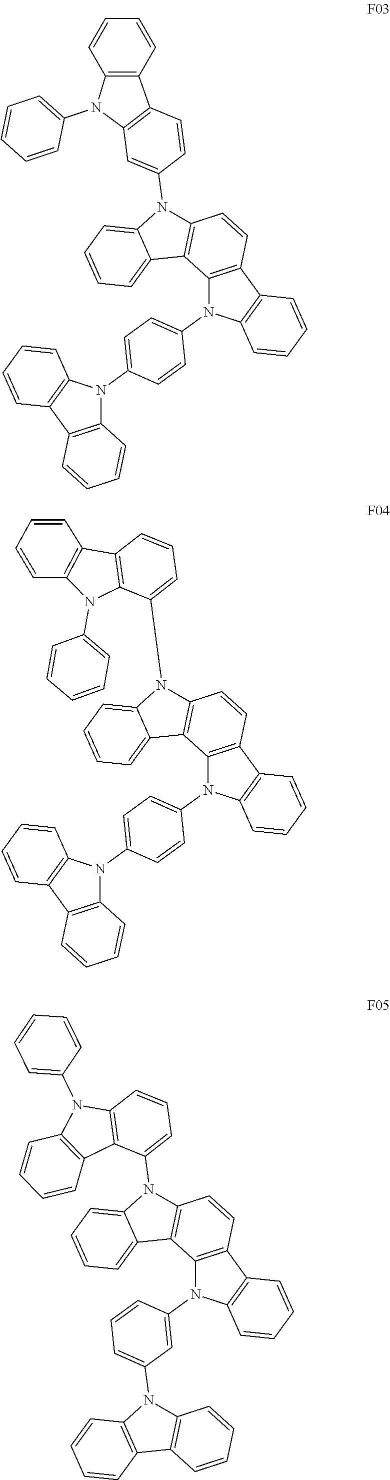

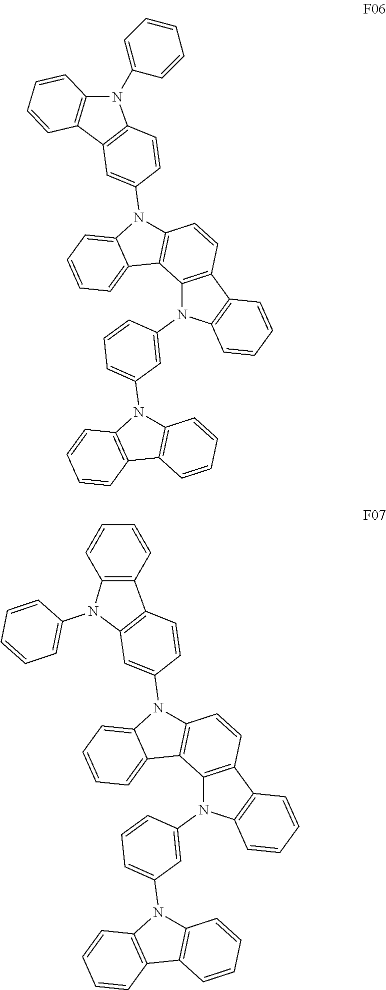

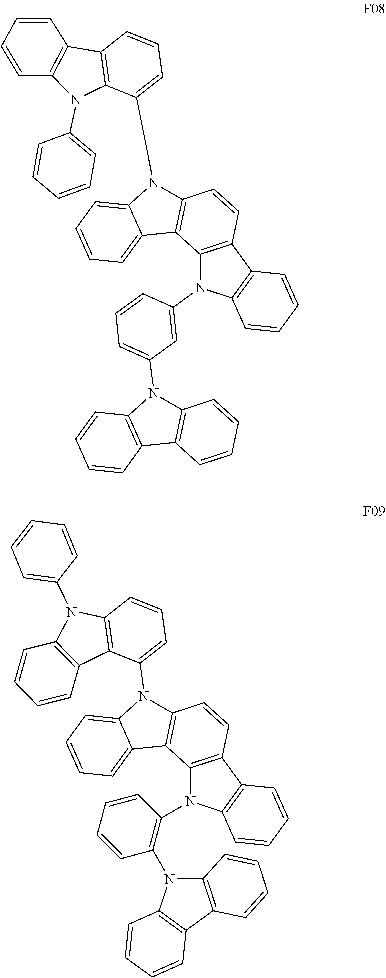

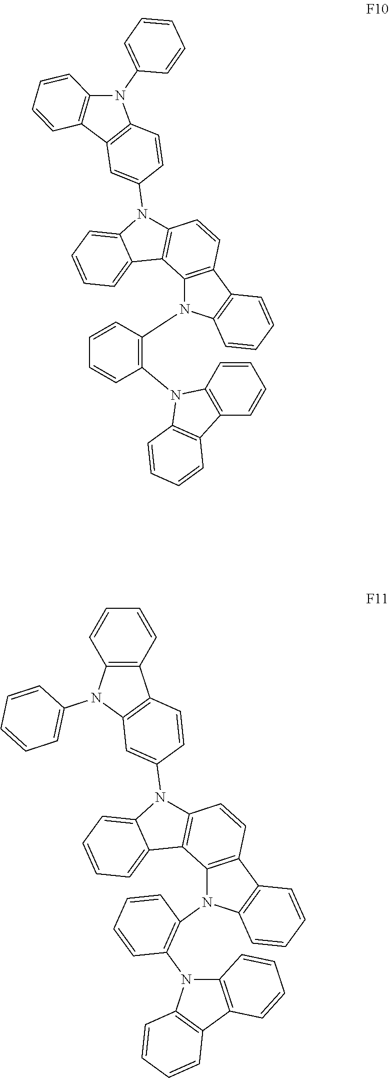

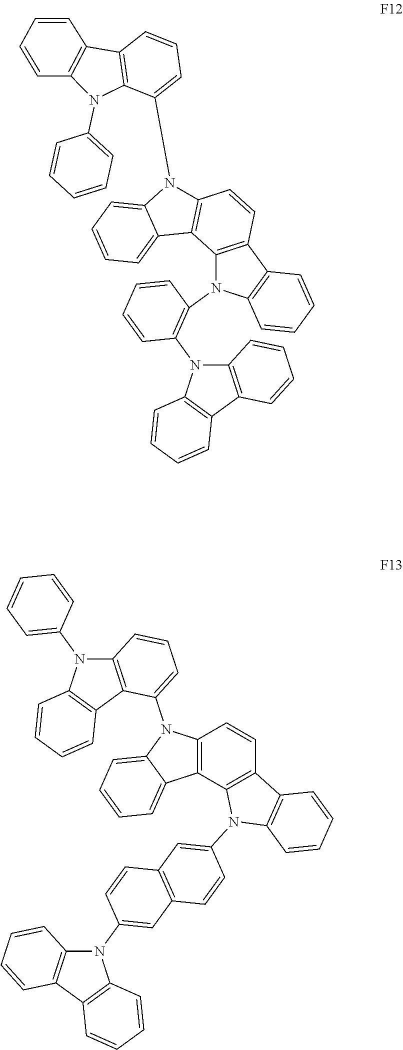

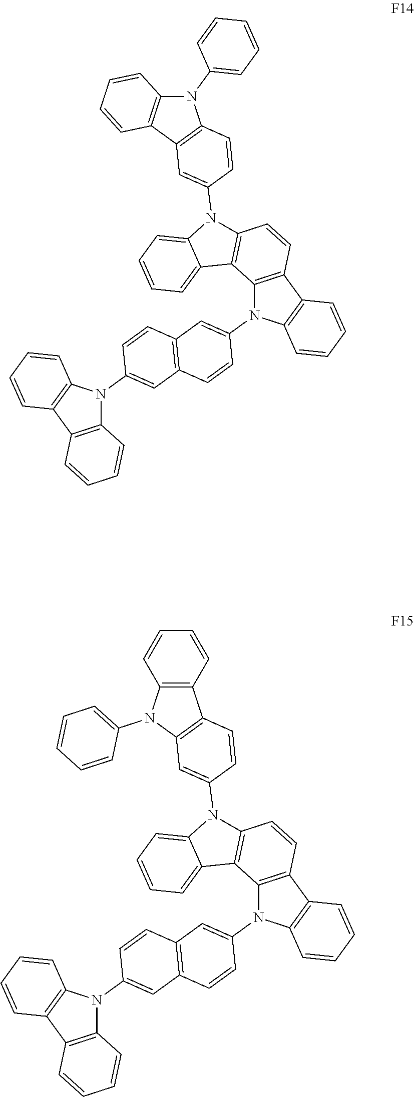

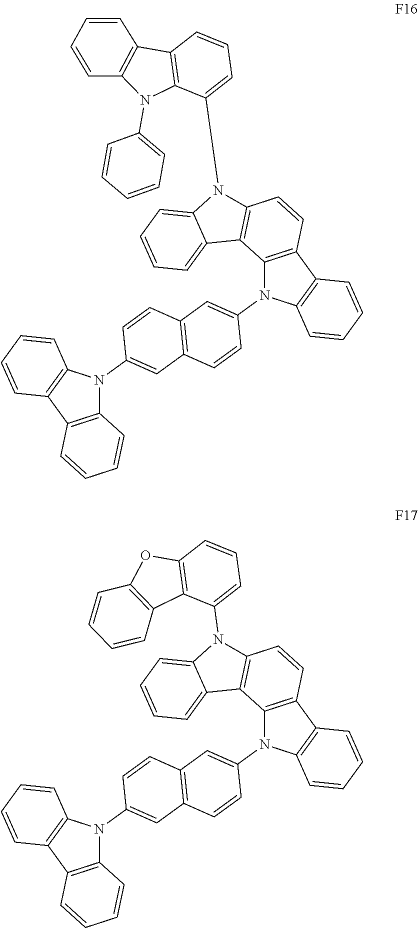

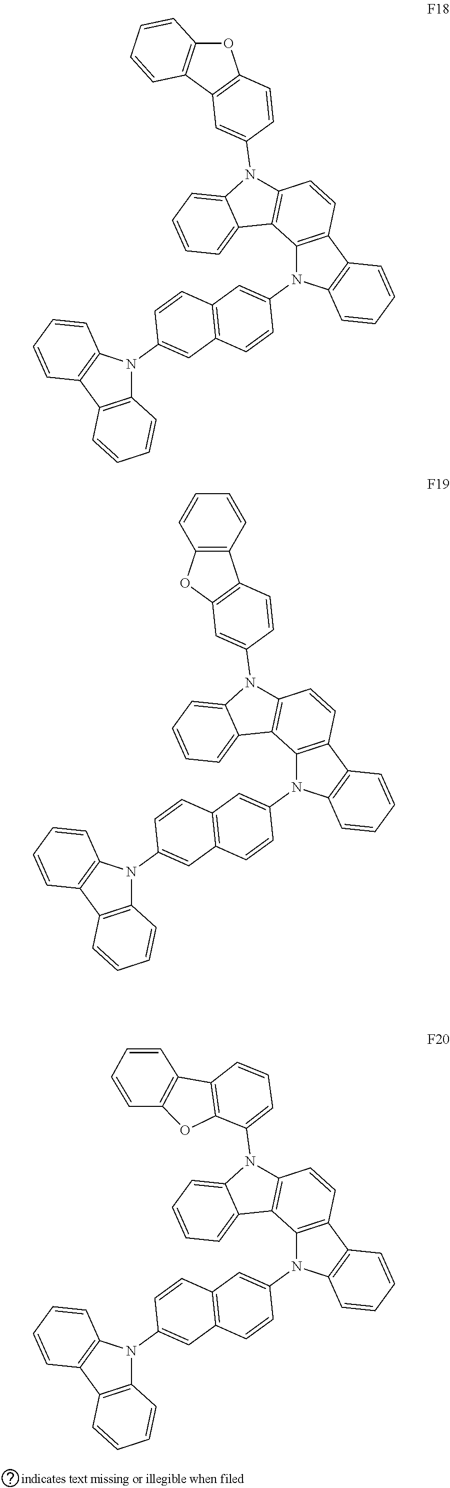

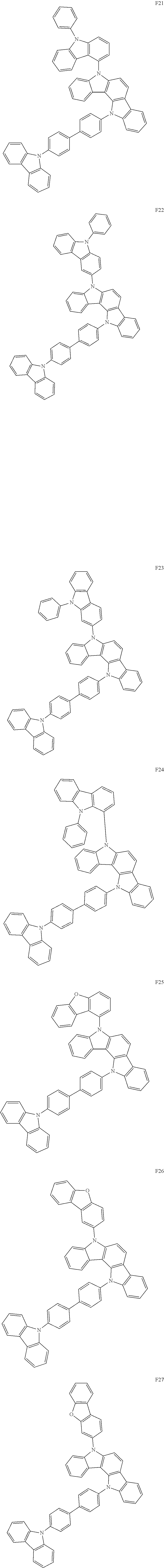

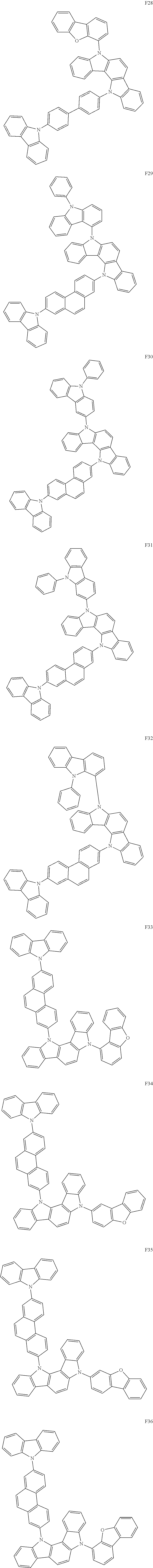

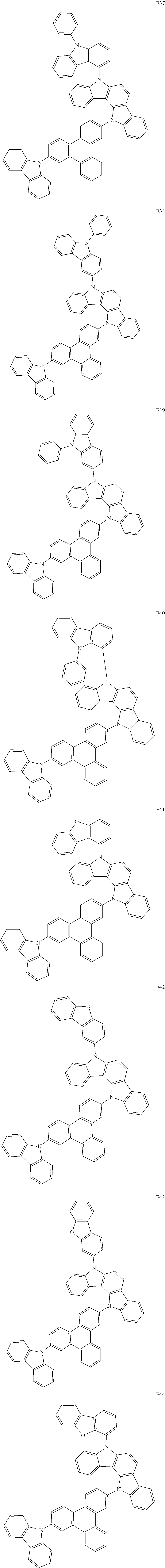

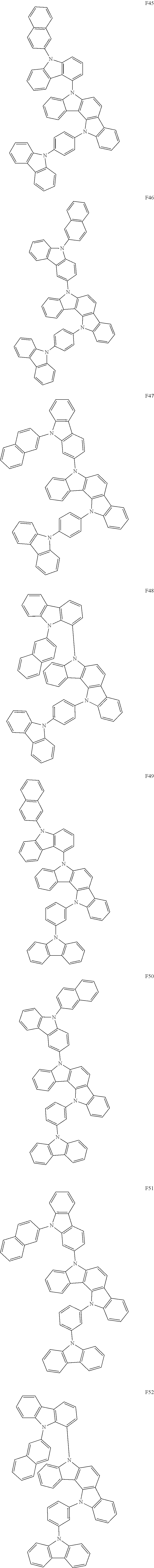

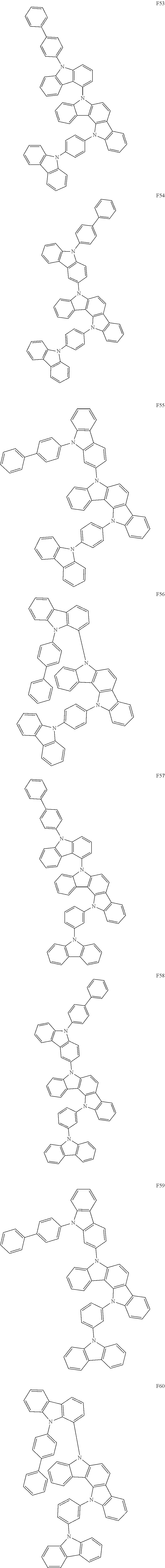

[chemical structure]

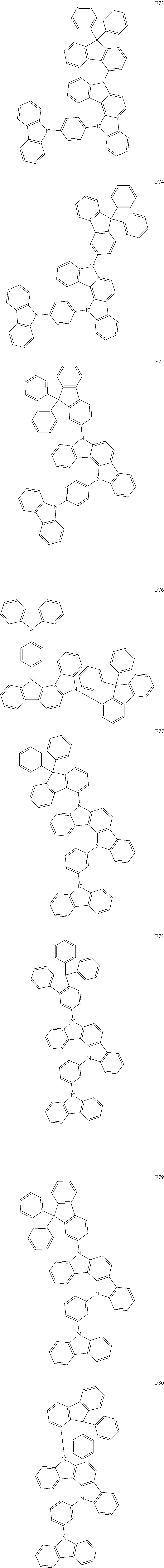

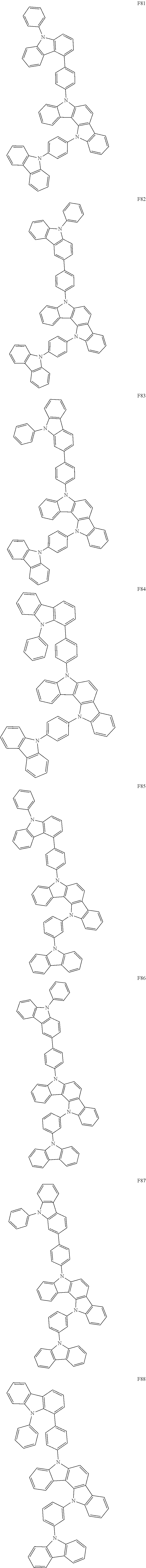

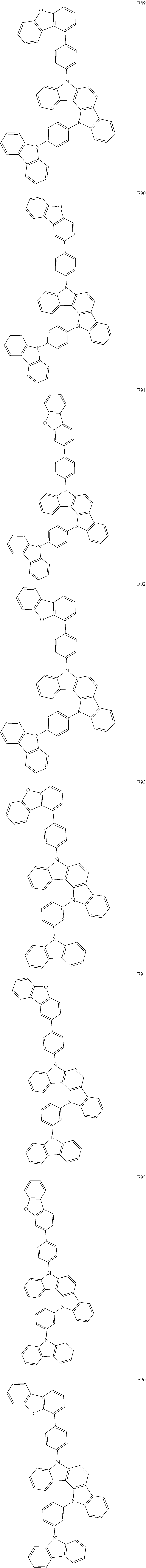

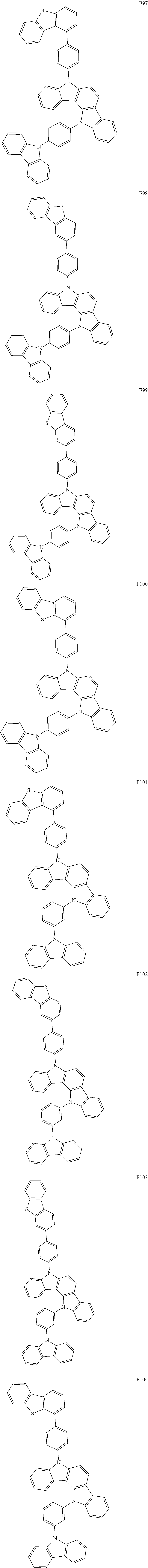

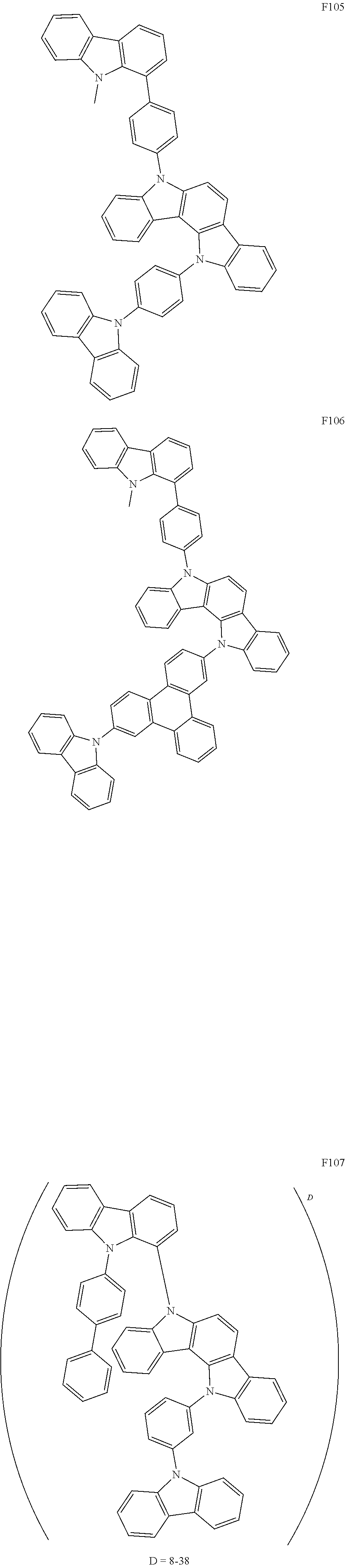

The compound of the present invention represented by the general formula (1) can be obtained by: synthesis by methods of various organic synthetic reactions established in the field of the organic synthetic chemistry including coupling reactions such as Suzuki coupling, Stille coupling, Grignard coupling, Ullmann coupling, Buchwald-Hartwig reaction, and Heck reaction, using commercially available reagents as raw materials; and then purification by using a known method such as recrystallization, column chromatography, and sublimation and purification. The method is not limited to this method.

The material for a photoelectric conversion device of the present invention preferably has an energy level of highest occupied orbital (HOMO) obtained by structural optimization calculation with a density functional calculation B3LYP/6-31G(d) of −4.3 eV or lower, more preferably within a range of −5.5 eV to −4.5 eV, and further preferably within a range of −5.2 eV to −4.8 eV.

The material for a photoelectric conversion device of the present invention preferably has an energy level of lowest unoccupied molecular orbital (LUMO) obtained by structural optimization calculation with a density functional calculation B3LYP/6-31G(d) of −2.5 eV or higher, more preferably within a range of −2.0 eV to −0.5 eV, and further preferably within a range of −1.5 eV to −0.8 eV.

In the material for a photoelectric conversion device of the present invention, a difference (absolute value) between the HOMO energy level and the LUMO energy level is preferably within a range of 2.0 eV to 5.0 eV, more preferably within a range of 2.5 eV to 4.7 eV, and further preferably within a range of 3.5 eV to 4.5 eV.

The material for a photoelectric conversion device of the present invention preferably has a hole mobility of 1×10⁻⁶ cm²/Vs or more, more preferably has a hole mobility of 1×10⁻⁴ cm²/Vs to 1×10⁻¹ cm²/Vs, and further preferably has a hole mobility of 2.2×10⁻⁴ cm²/Vs to 1×10⁻² cm²/Vs. The hole mobility can be evaluated by known methods such as a method with a FET-type transistor device, a method with a time-of-flight method, and an SCLC method.

The material for a photoelectric conversion device of the present invention is preferably amorphous. The amorphousness can be confirmed by various methods, and can be confirmed by, for example, detecting no peak in an XRD method or by detecting no endothermic peak in a DSC method.

Next, a photoelectric conversion device for imaging using the material for a photoelectric conversion device of the present invention will be described, but a structure of the photoelectric conversion device for imaging of the present invention is not limited thereto. The description will be made with reference to the drawings.

Figure is a sectional view schematically illustrating a structural example of the photoelectric conversion device for imaging of the present invention. In Figure, 1 represents an electrode, 2 represents a hole blocking layer, 3 represents a photoelectric conversion layer, 4 represents an electron blocking layer, 5 represents an electrode, and 6 represents a substrate. Note that acceptable is structure in which configuration except for the substrate is inverted from that in Figure, that is, 1 may represent the substrate, 2 may represent the electrode, 3 may represent the electron blocking layer, 4 may represent the photoelectric conversion layer, 5 may represent the hole blocking layer, and 6 may represent the electrode. The structure is not limited to the structure in Figure, and a layer can be added or omitted as necessary.

### —Electrode—

An electrode used for the photoelectric conversion device for imaging using the material for a photoelectric conversion device for imaging of the present invention has a function of trapping a hole and an electron generated in the photoelectric conversion layer. A function to let light enter the photoelectric conversion layer is also required. Thus, at least one of two electrodes is desirably transparent or semi-transparent. A material used for the electrode is not particularly limited as long as it has conductivity, and examples thereof include: conductive transparent materials, such as ITO, IZO, SnO₂, ATO (antimony-doped tin oxide), ZnO, AZO (Al-doped zinc oxide), GZO (gallium-doped zinc oxide), TiO₂, and FTO; metals, such as gold, silver, platinum, chromium, aluminum, iron, cobalt, nickel, and tungsten; inorganic conductive substances, such as copper iodide and copper sulfide; and conductive polymers, such as polythiophene, polypyrrole, and polyaniline. A plurality of these materials may be mixed to use as necessary. In addition, two or more layers thereof may be stacked.

### —Photoelectric Conversion Layer—

The photoelectric conversion layer is a layer in which a hole and an electrode are generated by charge separation of an exciton generated by the incident light. The photoelectric conversion layer may be formed with a single photoelectric converting material, or may be formed by combination with a P-type organic semiconductor material being a hole transport material and an N-type organic semiconductor material being an electron transport material. Two or more kinds of the P-type organic semiconductor may be used, and two or more kinds of the N-type organic semiconductor may be used. One or more kinds of these P-type organic semiconductor and/or N-type organic semiconductor desirably use a dye material having a function of absorbing light with a desired wavelength in the visible region. As the P-type organic semiconductor material being the hole transport material, the compound of the present invention represented by the general formula (1) can be used.

The P-type organic semiconductor material may be any material having a hole transportability. The material represented by the general formula (1) is preferably used, but another P-type organic semiconductor material may be used. In addition, two or more kinds of the material represented by the general formula (1) may be mixed to use. Furthermore, the compound represented by the general formula (1) and another P-type organic semiconductor material may be mixed to use.

The another P-type organic semiconductor material may be any material having the hole transportability, and for example, usable are: compounds having a fused polycyclic aromatic group such as naphthalene, anthracene, phenanthrene, pyrene, chrysene, naphthacene, triphenylene, perylene, fluoranthene, fluorene, and indene; compounds having a n-excess aromatic group such as a cyclopentadiene derivative, a furan derivative, a thiophene derivative, a pyrrole derivative, a benzofuran derivative, a dibenzothiophene derivative, a dinaphthothienothiophene derivative, an indole derivative, a pyrazoline derivative, a dibenzofuran derivative, a dibenzothiophene derivative, a carbazole derivative, and an indolocarbazole; an aromatic amine derivative, a styrylamine derivative, a benzidine derivative, a porphyrin derivative, a phthalocyanine derivative, and a quinacridone derivative.

As the other P-type organic semiconductor material, a polymer P-type organic semiconductor material may be used. Specific examples thereof include a polyphenylene-vinylene derivative, a polyparaphenylene derivative, a polyfluorene derivative, a polyvinylcarbazole derivative, and a polythiophene derivative. Further, two or more kinds of compounds selected from the compound represented by the general formula (1), the P-type organic semiconductor material, and the polymer P-type organic semiconductor material may be mixed to use.

The N-type organic semiconductor material may be any material having the electron transportability, and examples thereof include naphthalenetetracarboxylic diimide and perylenetetracarboxylic diimide, fullerenes, and azole derivatives such as imidazole, thiazole, thiadiazole, oxazole, oxadiazole, and triazole. Two or more kinds of materials selected from the N-type organic semiconductor materials may be mixed to use.

### —Electron Blocking Layer—

The electron blocking layer is provided in order to inhibit a dark current generated by injecting an electron from one electrode into the photoelectric conversion layer when a bias voltage is applied between the two electrodes. The electron blocking layer also has a function of hole transportation for transporting a hole generated by charge separation in the photoelectric conversion layer toward the electrode. A single layer or multiple layers of the electron blocking layer can be disposed as necessary. For the electron blocking layer, a P-type organic semiconductor material being the hole transport material can be used. The P-type organic semiconductor material may be any material having the hole transportability. Although the compound represented by the general formula (1) is preferably used, another P-type organic semiconductor material may be used. The compound represented by the general formula (1) and another P-type organic semiconductor material may be mixed to use. The other P-type organic semiconductor material may be any material having the hole transportability, and specific examples thereof include compounds exemplified as the other P-type organic semiconductor material in the section of the photoelectric conversion layer.

In addition, as the other P-type organic semiconductor material, a polymer P-type organic semiconductor material may be used. Specific examples thereof include compounds exemplified as the polymer P-type organic semiconductor material in the section of the photoelectric conversion layer. Two or more kinds of materials selected from the compound of the present invention represented by the general formula (1), the P-type organic semiconductor material, and the polymer P-type organic semiconductor material may be mixed to use.

### —Hole Blocking Layer—

The hole blocking layer is provided in order to inhibit a dark current generated by injecting a hole from one electrode into the photoelectric conversion layer when a bias voltage is applied between the two electrodes. The hole blocking layer also has a function of electron transportation for transporting an electron generated by charge separation in the photoelectric conversion layer toward the electrode. A single layer or multiple layers of the hole blocking layer can be disposed as necessary. For the hole blocking layer, the N-type organic semiconductor material having the electron transportability can be used.

The N-type organic semiconductor material may be any material having the electron transportability, and examples thereof include: polycyclic aromatic multivalent carboxylic anhydride or imidized products thereof, such as naphthalenetetracarboxylic diimide and perylenetetracarboxylic diimide; fullerenes, such as C60 and C70; azole derivatives, such as imidazole, thiazole, thiadiazole, oxazole, oxadiazole, and triazole; a tris(8-quinolinolate)aluminum (III) derivative, a phosphine oxide derivative, a nitro-substituted fluorene derivative, a diphenylquinone derivative, a thiopyran dioxide derivative, a carbodiimide, a fluorenylidene methane derivative, an anthraquinodimethane derivative and an anthrone derivative, a bipyridine derivative, a quinoline derivative, and an indolocarbazole derivative. Two or more kinds of these N-type organic semiconductor materials may be mixed to use.

Hydrogen in the material for a photoelectric conversion device of the present invention may be deuterium. That is, a part or all of hydrogens on the aromatic rings in the general formula (1) and hydrogen of the substituents may be deuterium.

Furthermore, a part or all of hydrogens in a compound used as the N-type organic semiconductor material and the P-type organic semiconductor material may be deuterium.

A method for producing a film of each layer in producing the photoelectric conversion device for imaging of the present invention is not particularly limited. The photoelectric conversion device may be produced by any one of dry process and wet process. The organic layer containing the material for a photoelectric conversion device of the present invention may be a plurality of the layers as necessary.

The photoelectric conversion device for imaging of the present application exhibits a current value in a dark place of preferably 5.0×10⁻¹⁰ A/cm² or less, more preferably within a range of 1.0×10⁻¹² A/cm² to 5.0×⁻¹⁰ A/cm², and further preferably within a range of 1.0×10⁻¹² A/cm² to 4.5×10⁻¹⁰ A/cm under the measurement condition described in Example 1 of the present application. The photoelectric conversion device for imaging of the present application exhibits a contrast ratio of preferably 6.0×10² or more, more preferably 6.5×10² or more, and further preferably 7.0×10² or more under the measurement condition described in Example 1 of the present application.

### EXAMPLES

Hereinafter, the present invention will be described in more detail with Examples, but the present invention is not limited to these Examples.

### Calculation Example

### Calculation of HOMO and LUMO

Calculated were energy levels of HOMO and LUMO and a difference in energy of HOMO and LUMO of the above compounds A06, A28, A133, B01, B95, C07, C144, and E101. The calculation was performed by using a density functional theory (DFT), using Gaussian as a calculation program, and with structural optimization calculation of a density functional calculation B3LYP/6-31G(d). Table 1 shows the results. It can be mentioned that any of the materials for the photoelectric conversion device for imaging of the present invention has preferable HOMO and LUMO values.

As comparative compounds an energy value of H1, H2, H3 and H4 HOMO, and LUMO, and the difference in energy of HOMO and LUMO were calculated in the same manner to above compounds. Table 1 shows the results.

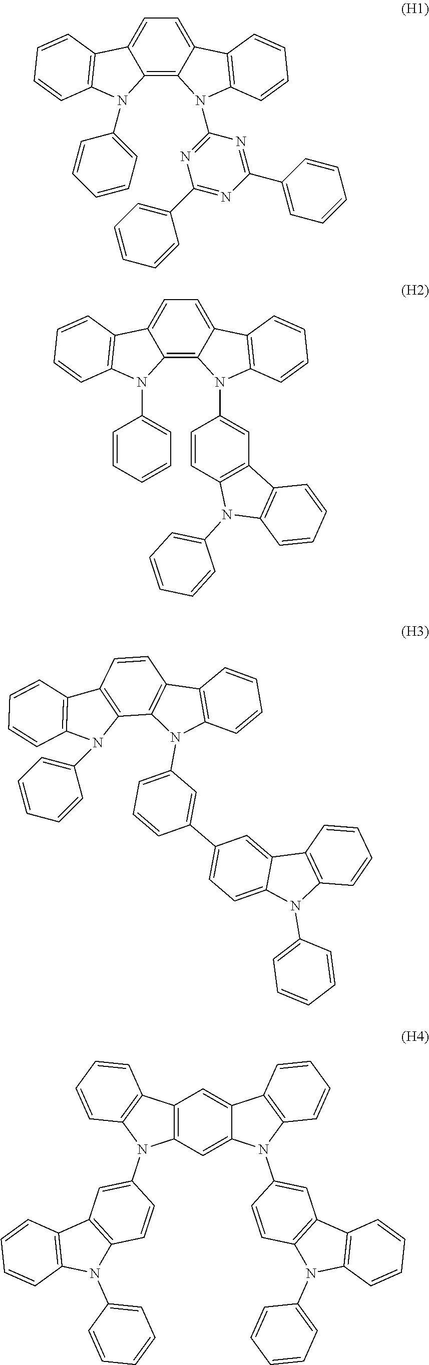

TABLE 1

| Compound | HOMO[eV] | LUMO[eV] | Energy difference[eV] |
|---|---|---|---|
| A06 | −5.1 | −1.0 | 4.1 |
| A28 | −5.2 | −1.2 | 3.9 |
| A133 | −5.2 | −1.3 | 3.9 |
| B01 | −5.0 | −0.9 | 4.1 |
| B95 | −5.1 | −1.3 | 3.8 |
| C07 | −4.9 | −1.0 | 3.9 |
| C144 | −5.0 | −1.1 | 3.9 |
| E101 | −4.9 | −1.2 | 3.8 |
| H1 | −5.3 | −1.9 | 3.4 |
| H2 | −5.0 | −0.9 | 4.1 |
| H3 | −5.1 | −0.8 | 4.2 |
| H4 | −4.7 | −0.9 | 3.8 |

A synthesis example of the compound A06 will be described below as a representative example. The other compounds were also synthesized by a similar method.

### Synthesis Example 1 (Synthesis of Intermediate R3)

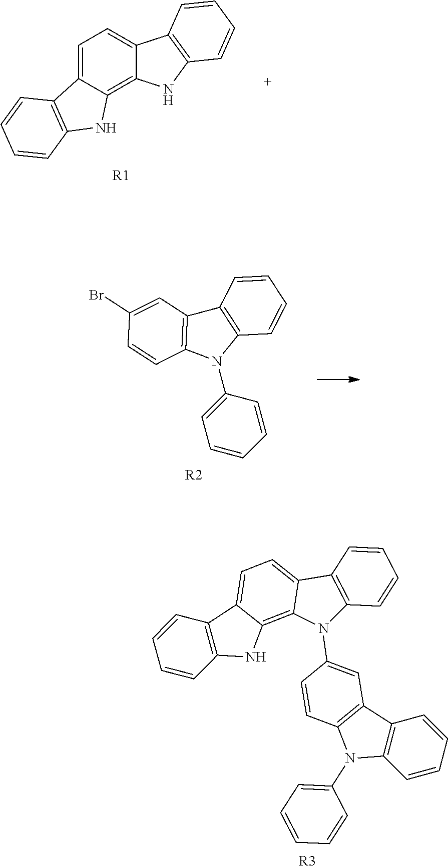

Into a three-necked 500-ml flask with degassed and nitrogen-replenished, R1 (19.5 mmol), R2 (19.5 mmol), copper iodide (2 mmol), and potassium carbonate (39.0 mmol) were fed, 50 ml of dehydrated dioxane was added thereinto, and then the mixture was stirred at 120 ° C for 6 hours. The mixture was cooled to a room temperature, then an inorganic substance was removed by filtration, 300 ml of water and 300 ml of dichloromethane were added into the filtrate and transferred to a separatory funnel, and separation into an organic layer and an aqueous layer was performed. The organic layer was washed three times with 200 ml of water, the obtained organic layer was dehydrated with magnesium sulfate, and then concentrated under a reduced pressure. The obtained residue was purified by column chromatography to obtain R3 (pale yellow solid). The yield quantity was 5.3 g, and the yield rate was 54.6%.

### Synthesis Example 2 (Synthesis of Compound A06)

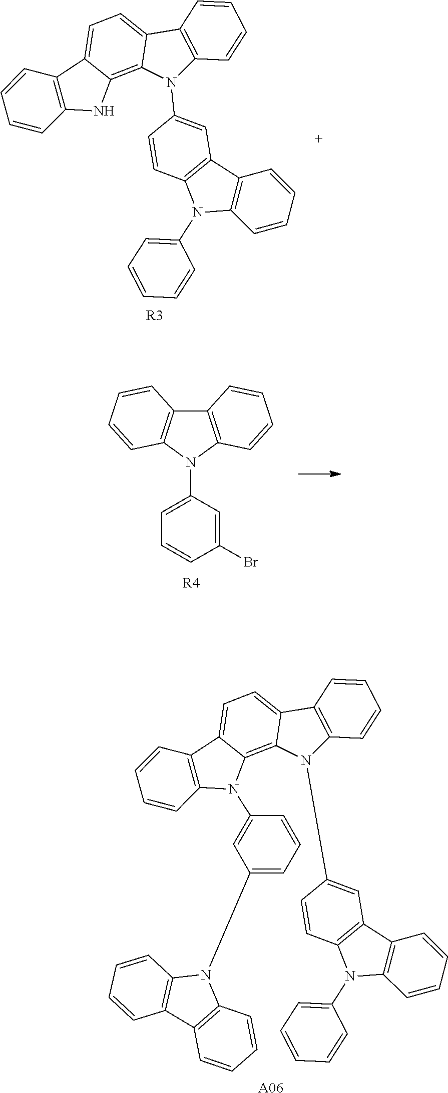

Into a three-necked 500-ml flask with degassed and nitrogen-replenished, R3 (10.0 mmol) synthesized in Synthesis Example 1, R4 (12.1 mmol), copper iodide (1.0 mmol), and potassium carbonate (20.1 mol) were fed, 50 ml of dimethylimidazolidinone was added thereinto, and then the mixture was stirred at 180 ° C for 8 hours. The mixture was cooled to a room temperature, then an inorganic substance was removed by filtration, 200 ml of water and 200 ml of dichloromethane were added into the filtrate and transferred to a separatory funnel, and separation into an organic layer and an aqueous layer was performed. The organic layer was washed three times with 200 ml of water, the obtained organic layer was dehydrated with magnesium sulfate, and then concentrated under a reduced pressure. The obtained residue was purified by column chromatography to obtain A06 (pale yellow solid). The yield quantity was 6.0 g, and the yield rate was 80.8%. The obtained solid was evaluated by an XRD method but no peak was detected. Thus, this compound was found to be amorphous. (APCI-TOFMS, m/z=739[M+H]⁺)

### Example of Physical Properties Evaluation

On a glass substrate on which a transparent electrode composed of ITO with 110 nm in film thickness was formed, the compound A06 was produced to a film as an organic layer by a vacuum deposition method under a condition that a film thickness was approximately 3 μm. Subsequently, charge mobility was measured by a time-of-flight method using a device in which aluminum (Al) was formed with 70 nm in thickness as an electrode, and as a result, the hole mobility was 1.5×10⁻⁴ cm²/Vs.

The hole mobilities were evaluated in the same procedure as above except that A28, A133, B01, B95, C07, C144, E101, H1, H2, H3, and H4 were used instead of the compound A06. Table 2 shows the results.

TABLE 2

| Compound | Hole mobility [cm²/Vs] |
|---|---|
| A06 | 2.5 × 10⁻⁴ |
| A28 | 5.8 × 10⁻⁴ |
| A133 | 6.0 × 10⁻⁴ |
| B01 | 4.5 × 10⁻⁴ |
| B95 | 2.4 × 10⁻³ |
| C07 | 3.3 × 10⁻⁴ |
| C144 | 1.1 × 10⁻³ |
| E101 | 6.1 × 10⁻⁴ |
| H1 | 4.0 × 10⁻⁵ |
| H2 | 3.0 × 10⁻⁵ |
| H3 | 1.0 × 10⁻⁴ |
| H4 | 6.0 × 10⁻⁵ |

### Example 1

On an electrode composed of ITO with 70 nm in film thickness formed on a glass substrate, a 10-nm film of the compound A06 was formed with a vacuum degree of 4.0×10⁻⁵ Pa as an electron blocking layer. Then, 2Ph-BTBT, F6-SubPc-OC6F5, and fullerene (C60) were co-deposited at a deposition rate ratio of 4:4:2 with 200 nm to form a film as a photoelectric conversion layer. Subsequently, 10-nm of dpy-NDI was deposited to form a hole blocking layer. Finally, an aluminum film was formed with 70 nm in thickness as an electrode to produce a photoelectric conversion device. A current in a dark place (dark current) was 3.3×10⁻¹⁰ A/cm² with the electrodes of ITO and aluminum and with applying a voltage of 2.6 V. When a voltage of 2.6 V was applied and the ITO electrode side was irradiated with light with an LED adjusted to be an irradiation light wavelength of 500 nm and 1.6 μW from a height of 10 cm, a current (bright current) was 2.9×10⁻⁷ A/cm². That is, a contrast ratio was 8.8×10² with applying a voltage of 2.6 V. Table 3 shows the results.

### Examples 2 to 9

Photoelectric conversion devices were produced in the same manner as in Example 1 except that compounds shown in Table 3 were used as the electron blocking layer.

### Comparative Examples 1 to 3

Photoelectric conversion devices were produced in the same manner as in Example 1 except that compounds shown in Table 3 were used as the electron blocking layer. Table 3 shows the results of Examples 1 to 9 and Comparative Examples 1 to 4.

The compounds used in Examples and Comparative Examples are shown below.

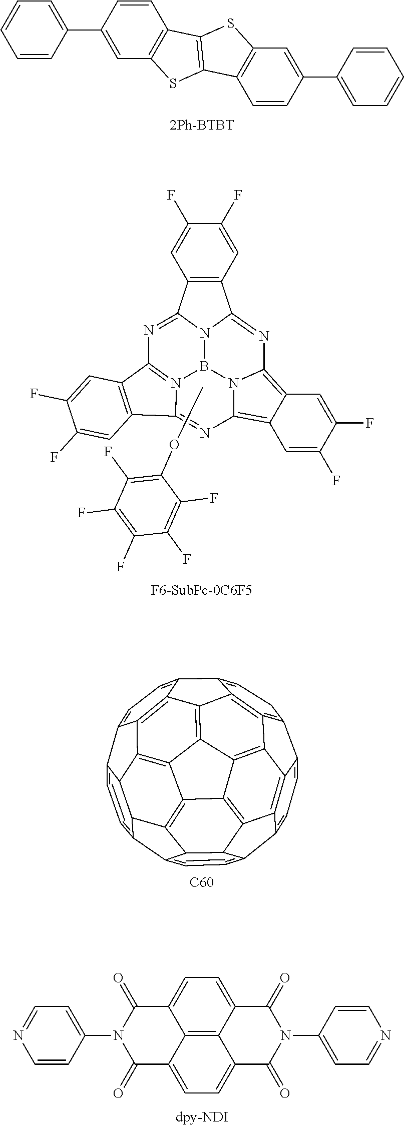

TABLE 3

| | | Current value | Current value | |
|---|---|---|---|---|
| | | in dark | during light | |
| | | place | irradiation | Contrast |
| | Compound | [A/cm²] | [A/cm²] | ratio |
| Example 1 | A06 | 3.3 × 10⁻¹⁰ | 2.9 × 10⁻⁷ | 8.8 × 10² |
| Example 2 | A28 | 4.0 × 10⁻¹⁰ | 3.0 × 10⁻⁷ | 7.5 × 10² |
| Example 3 | A133 | 3.1 × 10⁻¹⁰ | 2.9 × 10⁻⁷ | 9.4 × 10³ |
| Example 4 | B01 | 2.5 × 10⁻¹⁰ | 3.1 × 10⁻⁷ | 1.2 × 10³ |
| Example 6 | B95 | 2.9 × 10⁻¹⁰ | 2.8 × 10⁻⁷ | 9.7 × 10² |
| Example 7 | C07 | 3.8 × 10⁻¹⁰ | 2.9 × 10⁻⁷ | 7.6 × 10² |
| Example 8 | C144 | 4.5 × 10⁻¹⁰ | 3.3 × 10⁻⁷ | 7.3 × 10² |
| Example 9 | E101 | 4.1 × 10⁻¹⁰ | 3.2 × 10⁻⁷ | 7.8 × 10² |
| Comparative | H1 | 7.5 × 10⁻¹⁰ | 2.5 × 10⁻⁷ | 3.3 × 10² |
| Example 1 | | | | |
| Comparative | H2 | 6.3 × 10⁻¹⁰ | 3.0 × 10⁻⁷ | 4.8 × 10² |
| Example 2 | | | | |
| Comparative | H3 | 5.5 × 10⁻¹⁰ | 3.2 × 10⁻⁷ | 5.8 × 10² |
| Example 3 | | | | |
| Comparative | H4 | 7.2 × 10⁻¹⁰ | 2.5 × 10⁻⁷ | 3.5 × 10² |
| Example 4 | | | | |

### Industrial Applicability

Appropriate move of the hole and the electron in the photoelectric conversion device for imaging can be achieved by using the material for a photoelectric conversion device for imaging of the present invention represented by the general formula (1), and consequently enables to reduce a leakage current generated by applying a bias voltage during the conversion of light into electric energy. As a result, it is considered that the photoelectric conversion device of the present invention that achieves a low dark current value and a high contrast ratio has been obtained. Therefore, the material of the present invention represented by the general formula (1) is useful as the material for a photoelectric conversion device for a photoelectric conversion film-laminated imaging device.

### REFERENCE SIGNS LIST

1 Electrode
2 Hole blocking layer
3 Photoelectric conversion layer
4 Electron blocking layer
5 Electrode
6 Substrate

1. A photoelectric conversion device, comprising a material for a photoelectric conversion device comprising a compound represented by the following general formula (1): 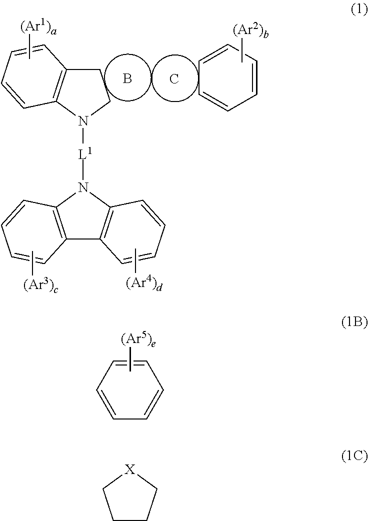
wherein L¹ represents an substituted or unsubstituted aromatic hydrocarbon group having 6 to 18 carbon atoms or a substituted or unsubstituted linked aromatic group in which 2 to 6 of these aromatic groups are linked, the ring B is fused with an adjacent ring at any position, and represents a six-membered ring represented by the formula (1B), the ring C is fused with an adjacent ring at any position, and represents a five-membered ring represented by the formula (1C), X is represented by O, S, or N—Ar^{E}, Ar¹ to Ar⁶ each independently represent deuterium, a halogen, an alkyl group having 1 to 20 carbon atoms, a substituted or unsubstituted aromatic amino group having 12 to 36 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 10 of these aromatic groups are linked, provided that, when X is represented by N—Ar^{E}, Ar⁰ includes one or more structures represented by the following general formula (2), “a” to “e” represent the number of substitutions, “a” to “d” each independently represent an integer of 0 to 4, and “e” represents an integer of 0 to 2, 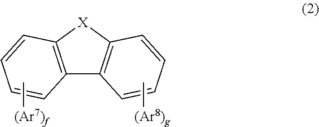
wherein Y is each independently represented by any of N—Ar⁹, O, S, and C—Ar¹⁰Ar¹¹, Ar⁷ to Ar¹¹ each independently represent deuterium, a halogen, an alkyl group having 1 to 20 carbon atoms, a substituted or unsubstituted aromatic amino group having 12 to 36 carbon atoms, a substituted or unsubstituted aromatic hydrocarbon group having 6 to 18 carbon atoms, a substituted or unsubstituted aromatic heterocyclic group having 3 to 18 carbon atoms, or a substituted or unsubstituted linked aromatic group in which 2 to 5 of these aromatic groups are linked, “f” and “g” represent the number of substitutions, and each independently represent an integer of 0 to 4.

2. The photoelectric conversion device according to claim 1, wherein X in the general formula (1) is represented by N—Ar⁶.

3. The photoelectric conversion device according to claim 1, wherein Y in the general formula (2) is each independently represented by any of N—Ar⁹, O, and S.

4. The photoelectric conversion device according to claim 1, wherein L¹ in the general formula (1) is represented by any of a substituted or unsubstituted phenyl group, a substituted or unsubstituted biphenyl group, or a substituted or unsubstituted terphenyl group.

5. The photoelectric conversion device according to claim 1, wherein the general formula (1) is represented by the following formulae (3) to (8).

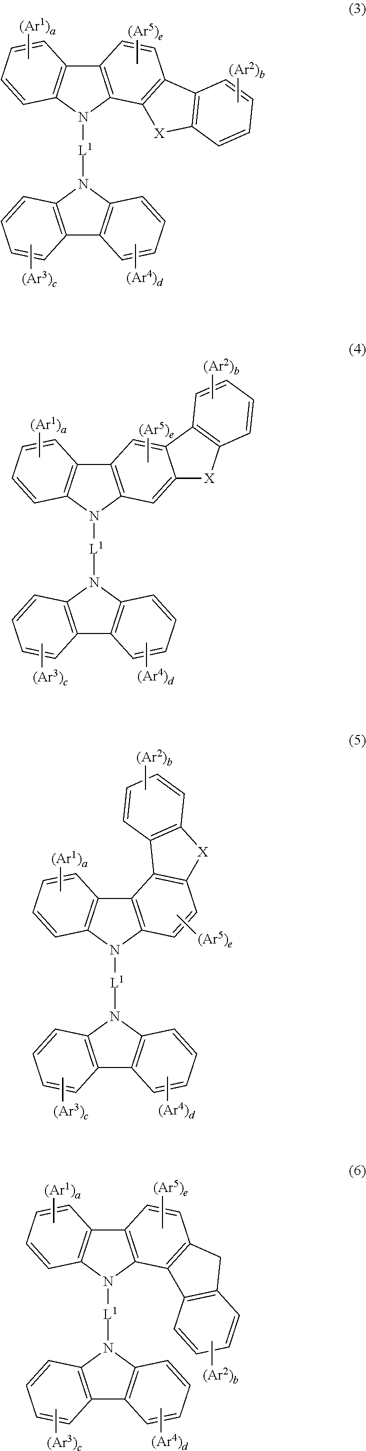

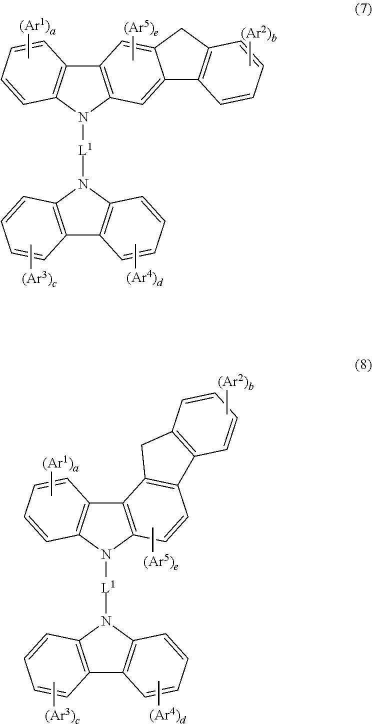

6. A photoelectric conversion device for imaging, comprising a material for a photoelectric conversion device for imaging, comprising the compound represented by the general formula (1) according to claim 1.

7. The photoelectric conversion device for imaging according to claim 6, wherein the material for a photoelectric conversion device for imaging, comprising the compound represented by the general formula (1) has an energy level of highest occupied molecular orbital (HOMO) obtained by structural optimization calculation with a density functional calculation B3LYP/6-31G(d) of −4.3 eV or lower.

8. The photoelectric conversion device for imaging according to claim 6, wherein the material for a photoelectric conversion device for imaging, comprising the compound represented by the general formula (1) has an energy level of lowest unoccupied molecular orbital (LUMO) obtained by the structural optimization calculation of −2.5 eV or higher.

9. The photoelectric conversion device for imaging according to claim 6, wherein the material for a photoelectric conversion device for imaging, comprising the compound represented by the general formula (1) has a hole mobility of 1×10⁻⁶ cm²/Vs or more.

10. The photoelectric conversion device for imaging according to claim 6, wherein the compound represented by the general formula (1) is amorphous.

11. The photoelectric conversion device for imaging according to claim 6, wherein the compound represented by the general formula (1) is used as a hole transport material of a photoelectric conversion device for imaging.

12. The photoelectric conversion device for imaging according to claim 6, wherein the photoelectric conversion device for imaging comprises a photoelectric conversion layer and an electron blocking layer between two electrodes, wherein at least one layer of the photoelectric conversion layer and the electron blocking layer contains the material for a photoelectric conversion device for imaging, comprising the compound represented by the general formula (1).

13. The photoelectric conversion device for imaging according to claim 12, wherein the electron blocking layer contains the material for a photoelectric conversion device for imaging, comprising the compound represented by the general formula (1).

14. The photoelectric conversion device for imaging according to claim 13, wherein the photoelectric conversion layer contains an electron transport material.

15. The photoelectric conversion device for imaging according to claim 14, wherein the photoelectric conversion device for imaging comprises a fullerene derivative as the electron transport material.
